(19) United States
(12) Patent Application Publication
(10) Pub. No.: US 2006/0163605 A1
(43) Pub. Date: Jul. 27, 2006

(54) Substrate for thin film formation, thin film substrate, and light-emitting device

(76) Inventor: Kenichiro Miyahara, Fujisawa-shi (JP)

Correspondence Address: BROWDY AND NEIMARK, P.L.L.C.;624 NINTH STREET, NW, SUITE 300, WASHINGTON, DC, 20001-5303, US

(21) Appl. No.: 11/320,873

(22) Filed: Dec. 30, 2005

Related U.S. Application Data
(63) Continuation-in-part of application No. PCT/JP04/00051, filed on Jan. 7, 2004.

(30) Foreign Application Priority Data
Jun. 30, 2003 (JP) 2003-186175
Aug. 18, 2003 (JP) 2003-294259
Nov. 26, 2003 (JP) 2003-396236

(51) Int. Cl. H01L 33/00

(52) U.S. Cl. 257/103; 257/E33.003

(57) ABSTRACT

A substrate for forming a thin film composed mainly of gallium nitride, indium nitride or aluminum nitride, the substrate consisting of a sintered compact composed mainly of a ceramic material; and a thin-film substrate furnished with the thin film. The use of the sintered compact composed mainly of a ceramic material, especially translucent sintered compact, as the substrate enables formation thereon of a highly crystalline single-crystal thin film composed mainly of at least one member selected from among gallium nitride, indium nitride and aluminum nitride. Thus, there is provided a thin-film substrate furnished with a highly crystalline single-crystal thin film. Further, the use of the sintered compact composed mainly of a ceramic material enables providing of a light emitting element excelling in luminous efficiency.

### TECHNICAL FIELD

This invention relates to a substrate for forming a thin film comprising gallium nitride, indium nitride, and aluminum nitride as a main component, a thin film substrate in which the thin film is formed, and a light-emitting device produced using the substrate.

### BACKGROUND ART

In recent years, various light-emitting semiconductor devices, such as a light-emitting diode (LED) or a laser diode (LD), came to be used for the light source of a display, a luminaire, an optical communication, and a storage apparatus, etc.

In such light-emitting semiconductor devices, a device which emits light of a green and blue color—a blue color—a purple and blue color—ultraviolet rays has been developed growing epitaxially mainly the III-V group nitride thin film comprising as a main component at least one selected from gallium nitride, indium nitride and aluminum nitride and which is constituted with at least three or more layers of the III-V group nitride single-crystal thin film layers which were semiconductorized into P and N-type by doping and the luminescence layer, such as quantum well structure, onto the substrate, such as sapphire.

As for the above light-emitting device constituted with a laminate comprising a thin film comprising at least one selected from gallium nitride, indium nitride and aluminum nitride as a main component and contains N-type semiconductor layer, a luminescence layer, and P-type semiconductor layer at least (hereafter, unless it refuses especially it is only called a “light-emitting device”.), it is used for the light sources of a signal, a backlight for liquid crystals, and a general lighting replaced with the incandescent lamp or fluorescent lamp, and the laser light source of high capacity optical disc devices, etc.

In some cases, using the light from a light-emitting device as it is, or it changes into white light by an interaction using a phosphor, and is used.

Usually, the light-emitting device has two-terminal device (diode) construction constituted with the P-type semiconductor, N-type semiconductor, and luminescence layer of each above nitride or each nitride mixed crystal, and is driven applying direct current power.

The output of a light-emitting device increases using such a light-emitting device as a light source of high-output laser, or using as a light source of general lighting, etc.

When it is going to use a light-emitting device for such an intended use, as for the substrate for forming a thin film comprising an epitaxial film as the main substance and comprising as a main component at least one selected from gallium nitride, indium nitride and aluminum nitride and constitutes a light-emitting device, problems are arising.

That is, even if the conventional sapphire substrate is a single crystal, the crystal structure and the thermal expansion coefficient, etc. differ from gallium nitride, indium nitride, and aluminum nitride which constitute a light-emitting device, therefore, the thin film comprising as a main component at least one selected from gallium nitride, indium nitride and aluminum nitride and formed on the sapphire substrate cannot become into good crystallinity easily, it has been able to form as a single-crystal thin film with high crystallinity by research in recent years at last.

However, since it is easy to generate a crystal dislocation and a strain in the thin film by the crystal lattice mismatching or difference of thermal expansion coefficient between the sapphire substrate and the thin film, even if it is a single-crystal thin film with high crystallinity, manufacture yield of the light-emitting device manufactured using such a thin film tends to be lowered, and achievement of the improvement in luminous efficiency of a light-emitting device or improvement in characteristics, such as high-output-izing and long-life of a laser oscillation, is also difficult.

Since a sapphire substrate is a single crystal, manufacture cost is also highly, and there is a problem in which it can be hard to use for an extensive use the single-crystal thin film comprising as a main component at least one selected from gallium nitride, indium nitride and aluminum nitride and formed on it.

Various optical waveguides for conducting light from a light-emitting device of this invention, or from a conventional laser or light-emitting diode at desired intensity, distance and a position have been proposed hitherto.

Usually, it is obtained forming a high refractive index portion in crystal substrates, such as LiNbO₃ and silicon, or in glass substrates, such as silica glass.

In conventional optical waveguides, there are problems that they have low permeability to short-wavelength light such as blue or ultraviolet rays, that it is hard to form electrical circuits simultaneously on the substrate in which an optical waveguide is formed because the electric insulation of a substrate is small, and that it is hard to mount simultaneously a high-output light-emitting device on the substrate in which an optical waveguide is formed because the thermal conductivity of a substrate is low, etc.

As mentioned above, when using a conventional sapphire substrate, the thin film comprising as a main component at least one selected from gallium nitride, indium nitride and aluminum nitride and formed on it has become to be able to be formed as a single-crystal thin film with comparatively high crystallinity in recent years.

However, when using a sapphire substrate, the luminous efficiency of the light-emitting device constituted mainly with such a thin film is low and is usually about 2-8%, so 92-98% of the electric power applied to the device is consumed other than the radiant power output to the outside of a device, and the light emitting characteristics in which the III-V group nitride semiconductor originally has have not been shown sufficiently.

As the cause, it is easy to produce a crystal dislocation and a distortion in the thin film by the crystal lattice mismatching, or the difference of thermal expansion coefficient between the sapphire substrate and the thin film, even if the thin film constituting a light-emitting device can be formed on a sapphire substrate as a single-crystal thin film with high crystallinity, furthermore, it seems that many of light emitted from the light-emitting device are reflected in the interface of the sapphire substrate and the above thin film, or in the surface of a sapphire substrate, and are easily shut up by being returned into the inside of a light-emitting device because the refractive index of a sapphire substrate is still smaller than a thin film of gallium nitride, indium nitride, and aluminum nitride, a sapphire substrate is a transparent and homogeneous bulk single crystal.

Therefore, about the substrate material for manufacturing a light-emitting device by forming the thin film comprising as a main component at least one selected from gallium nitride, indium nitride and aluminum nitride and includes an epitaxial film, there have been proposals of the single crystal substrate materials comprising silicon carbide, silicon, etc. as a main component instead of the conventional sapphire.

It is considered as the example using the silicon carbide single crystal as a substrate, for example, methods, such as JP,10-27947A or JP,11-40884A, are proposed.

Methods, such as JP,10-214959A, are proposed as the silicon substrate.

However, even if these substrates are used, a good single-crystal thin film is hard to be formed on these substrates for the reasons of the difference of a crystal structure and a lattice constant between the substrates and the single-crystal thin film comprising as a main component at least one selected from gallium nitride, indium nitride and aluminum nitride.

In JP,9-172199A, the method which uses the glass substrates, such as a quartz glass, and the substrates produced by the sintering process, such as a polycrystalline silicon, is proposed instead of the single crystal substrates to solve the problems in which conventional single crystal substrates have.

However, although this method must form the film material comprising an oxide of II group elements, such as zinc oxide and mercury oxide, before forming gallium nitride system compound semiconductor layer on a substrate, that effect is not necessarily clarified.

When the substrate having the oxide of such II group elements is used, the crystallinity of the thin film constituting the gallium nitride system compound semiconductor formed there is not necessarily clear, and there is no clearness about the characteristics, such as luminous efficiency of the produced semiconductor device, and having not resulted in problem solving after all.

As mentioned above, although the substrate which can form a excellent single-crystal thin film that comprises as a main component at least one selected from gallium nitride, indium nitride and aluminum nitride is being requested for instead of the conventional single crystal substrates, such as a sapphire and silicon carbide, such substrate has not realized yet.

The thin film substrate having the above excellent single-crystal thin film comprising as a main component at least one selected from gallium nitride, indium nitride and aluminum nitride, however, has not be provided yet.

Thus, the luminous efficiency of the light-emitting device which is made using a conventional sapphire substrate is low, so it is hard to say that the original luminescence characteristics of III-V group nitride semiconductor can be shown sufficiently, though that having at least equivalent luminous efficiency to the light emitting device produced using a sapphire substrate is requested, the luminous efficiency of the light-emitting device produced using substrates proposed to improve the fault of a sapphire substrate instead of a sapphire substrate has not improved, and there was a problem in which the original luminescence characteristics of III-V group nitride semiconductor have not realized yet sufficiently.

On the other hand, and, the method indicated in the Japanese Patent 3119965 as an optical waveguide for leading a light with short wavelength, such as blue light and ultraviolet rays from a light-emitting device, in desired intensity, distance, and a location, is proposed.

In this proposal, although the method of forming the optical waveguide by an aluminum nitride thin film in the single crystal substrate comprising silicon, sapphire, etc. is indicated, the buffer layer comprising aluminum oxynitride, sialon, etc. needs to be provided to obtain the transmission nature of a light with short wavelength, such as blue light and ultraviolet rays.

As the reason of such a device, because there is a mismatching of crystal lattice, or a difference of thermal expansion coefficient between the silicon and sapphire of the substrate material and the aluminum nitride, it is probably surmised that it will be because formation of an aluminum nitride thin film with high crystallinity is difficult, and transmission loss of a waveguide becomes large as a result.

Other than the mismatching of crystal lattice, and the difference of thermal expansion coefficient, when the silicon substrate is used, it seems a big cause that it does not function as a waveguide too, since a total reflection of light does not occur in the aluminum nitride thin film because the refractive index of an aluminum nitride thin film formed directly is small if it is compared with the silicon.

Since the electric insulation nature is small and the dielectric constant is high when silicon is used for a substrate, it can be hard to form an electrical circuit on a substrate directly, and there is a problem in which it can be hard to mount a light-emitting device on the substrate unitedly.

When using the sapphire for a substrate, in case a high-output light-emitting device is mounted, a problem of the nature of radiating heat arises since the thermal conductivity is small.

Therefore, there were problems, such that the satisfactory optical waveguide which transmits a light with short wavelength, such as blue light and ultraviolet rays, from a light-emitting device provided with an electric circuit for driving a device and can mount a high power light-emitting device has not been realized.

### DISCLOSURE OF THE INVENTION

This invention is made to solve the problems described above.

This inventor has examined various ceramic-based sintered compacts as a substrate for forming a single-crystal thin film comprising as a main component at least one selected from gallium nitride, indium nitride and aluminum nitride, focusing on an aluminum nitride-based sintered compact, and found that the single-crystal thin film excellent in crystallinity comprising as a main component at least one selected from gallium nitride, indium nitride and aluminum nitride can be formed directly in the state which adhered firmly with neither a crack nor exfoliation if the substrate comprising the ceramic-based sintered compact is used, and having proposed in the JP application for patent 2002-362783, the application for patent 2003-186175, and the JP application for patent 2003-294259, etc.

It was found that it can be formed directly in a state where there is neither a crack nor exfoliation and it adhered firmly into the ceramic-based sintered compact and can form directly the single-crystal thin film comprising gallium nitride, indium nitride, and aluminum nitride as a main component, such as aluminum nitride, even if it is the thin film comprising as a main component at least one selected from gallium nitride, indium nitride and aluminum nitride and which is not necessarily the epitaxially grown single-crystal thin film, such as an amorphous thin film, a polycrystalline thin film, and an orientated polycrystalline thin film, etc.

Using as a substrate the ceramic-based sintered compact and formed beforehand the thin film of such a various crystallization state, if growing the single-crystal thin film comprising as a main component at least one selected from gallium nitride, indium nitride and aluminum nitride into the substrate, it can be formed in a state where there is neither a crack nor exfoliation and it adhered firmly, and it was found that the single-crystal thin film obtained excelled in crystallinity compared with the single-crystal thin film directly formed on the ceramic-based sintered compact, such as aluminum nitride, etc.

It was found that a single-crystal thin film more excellent in crystallinity comprising as a main component at least one selected from gallium nitride, indium nitride and aluminum nitride can be formed on the ceramic-based sintered compact with optical permeability.

A thin film comprising as a main component at least one selected from gallium nitride, indium nitride and aluminum nitride and which is not necessarily the epitaxially grown single-crystal thin film, such as an amorphous thin film, a polycrystalline thin film, and an orientated polycrystalline thin film, etc. can be formed on the ceramic-based sintered compact with optical permeability.

If the ceramic-based sintered compact with optical permeability having beforehand the thin film of such a various crystallization state is used, it was found that a single-crystal thin film still more excellent in crystallinity comprising as a main component at least one selected from gallium nitride, indium nitride and aluminum nitride can be formed.

Thus, it was found that a single-crystal thin film excellent in crystallinity comprising as a main component at least one selected from gallium nitride, indium nitride and aluminum nitride can be formed on the ceramic-based sintered compact with or without optical permeability.

If the ceramic-based sintered compact, and the ceramic-based sintered compact with optical permeability are used, it was found that it can obtain a thin film substrate having the above single-crystal thin film excellent in crystallinity comprising as a main component at least one selected from gallium nitride, indium nitride and aluminum nitride.

Using the ceramic-based sintered compact, and ceramic-based sintered compact with optical permeability which do not form the above thin film, or using the thin film substrate in which the single-crystal thin film comprising as a main component at least one selected from gallium nitride, indium nitride and aluminum nitride was formed on the above ceramic-based sintered compact, and ceramic-based sintered compact with optical permeability, a light-emitting device having equivalent luminous efficiency at least or is a maximum of not less than 4-5 times can be produced compared with the light-emitting device produced using a sapphire substrate.

Using the above thin film substrate, it became clear that an optical waveguide in which the transmission loss is small and which can transmit ultraviolet light in low loss can be manufactured.

It was found that a thin film comprising as a main component at least one selected from gallium nitride, indium nitride and aluminum nitride and having various crystallization states, such as a single-crystal thin film, an amorphous thin film, a polycrystal thin film, and an orientated polycrystal thin film, etc. can be formed on the ceramic-based sintered compact having large surface roughness.

Using the ceramic-based sintered compact having such large surface roughness, a light-emitting device having higher luminous efficiency than light-emitting devices produced using conventional sapphire substrates can be produced.

It was found that the thin film substrate having the synergistic effect which a single crystal and a ceramic-based sintered compact cannot make separately, respectively, can be realized, if a single-crystal thin film comprising as a main component at least one selected from gallium nitride, indium nitride and aluminum nitride, and a ceramic-based sintered compact are unified firmly.

Thus, it was found that those having a high crystallinity which is equivalent to the lump-like or bulk-like single crystal, such as conventional sapphire and silicon carbide, or is near to it can be produced, even if it is a single-crystal thin film integrally adhered to a ceramic-based sintered compact.

It was found that a substrate having a characteristic in which realization is difficult in the material which exists and is used as a single crystal separately in itself, such as the shape of a lump and the shape of bulk, etc., such as conventional sapphire and silicon carbide, can realize when producing electronic devices, such as a light-emitting device, or electronic components, such as a circuit substrate, by unifying firmly a single-crystal thin film which is excellent in crystallinity and comprising at least one which are selected from gallium nitride, indium nitride and aluminum nitride as a main component and a ceramic-based sintered compact, and by drawing the synergistic effect which a single crystal and a ceramic-based sintered compact cannot make separately respectively.

In addition, this inventor found that the thin film comprising as a main component at least one selected from gallium nitride, indium nitride and aluminum nitride can be formed on the ceramic-based sintered compact having a hexagonal or trigonal crystal structure, such as silicon carbide, silicon nitride, gallium nitride, beryllium oxide, zinc oxide, and aluminum oxide, etc., and that the single-crystal thin film which is excellent in crystallinity and comprising as a main component at least one selected from gallium nitride, indium nitride and aluminum nitride can be formed using the sintered compact of a specific surface state or surface roughness, even if it does not have the intermediate oxide film material of II group elements, such as mercury oxide, etc.

It has been found that a single-crystal thin film with excellent crystallinity can be formed on a ceramic-based sintered compact having a hexagonal or trigonal crystal structure provided with a thin film comprising as a main component at least one selected from gallium nitride, indium nitride and aluminum nitride beforehand.

Among the above sintered compacts comprising as a main component a ceramic material having a hexagonal or trigonal crystal structure, it found that those comprising beryllium oxide, zinc oxide, aluminum oxide, and gallium nitride as a main component and having specific composition is excellent for forming a single-crystal thin film. since those excellent in optical permeability can be obtained, it found that it is desirable as a substrate for producing a light-emitting device.

It has been found that a light-emitting device excellent in luminous efficiency can be produced by using a zinc oxide-based sintered compact containing aluminum or a gallium nitride-based sintered compact, since they have electrical conductivity and optical permeability.

This invention includes the substrate for a thin film comprising the above ceramic-based sintered compact having a hexagonal or trigonal crystal structure, such as silicon carbide, silicon nitride, gallium nitride, beryllium oxide, zinc oxide, and aluminum oxide, etc.

And this invention also includes the thin film substrate in which a thin film comprising as a main component at least one selected from gallium nitride, indium nitride and aluminum nitride is formed on the a ceramic-based sintered compact substrate having a hexagonal or trigonal crystal structure.

This invention includes the light-emitting device produced using the ceramic-based sintered compact having a hexagonal or trigonal crystal structure, such as silicon carbide, silicon nitride, gallium nitride, beryllium oxide, zinc oxide, and aluminum oxide, etc., or the light-emitting device produced using a sintered compact provided with beforehand the thin film comprising at least one selected from gallium nitride, indium nitride and aluminum nitride as a main component and comprising as a main component a ceramic material having a hexagonal or trigonal crystal structure, such as silicon carbide, silicon nitride, gallium nitride, beryllium oxide, zinc oxide, etc., and aluminum oxide, etc.

The light-emitting device in which the luminous efficiency is equivalent or more at least or is a maximum of not less than 3-4 times can be manufactured compared with the light-emitting device produced using a sapphire substrate.

In addition, this inventor found that a single-crystal thin film more excellent in crystallinity can be formed on the various sintered compact provided with beforehand the thin film comprising at least one selected from gallium nitride, indium nitride and aluminum nitride as a main component and comprising as a main component a ceramic material, such as zirconium oxide, magnesium oxide, magnesium aluminate, titanium oxide, barium titanate, lead titanate zirconate, rare-earth oxides, such as yttrium oxide, thorium oxide, various ferrites, mullite, forsterite, steatite and glass, for example.

A single-crystal thin film excellent in crystallinity can be formed on the above various sintered compact provided with beforehand the thin film comprising at least one selected from gallium nitride, indium nitride and aluminum nitride as a main component and comprising as a main component a ceramic material, such as zirconium oxide, magnesium oxide, magnesium aluminate, titanium oxide, barium titanate, lead titanate zirconate, and rare-earth element oxides such as yttrium oxide, thorium oxide, various ferrites, mullite, forsterite, steatite and glass

In these various ceramic-based sintered compacts, it was found that that has optical permeability is also producible comparatively easily.

The inventor has found that the luminous efficiency of the light-emitting device produced using not only an aluminum nitride-based sintered compact and a ceramic-based sintered compact having a hexagonal or trigonal crystal structure, such as silicon carbide, silicon nitride, gallium nitride, beryllium oxide, zinc oxide, and aluminum oxide, etc., but also a ceramic-based sintered compact, such as zirconium oxide, magnesium oxide, magnesium aluminate, titanium oxide, barium titanate, lead titanate zirconate, rare-earth oxides, such as yttrium oxide, thorium oxide, various ferrites, mullite, forsterite, steatite and glass is equal to or more than that of light-emitting devices produced on sapphire substrates, not less than 3-4 times at maximum.

In addition, this inventor found that the luminous efficiency tends to be improved compared with the light-emitting device produced using those with small surface roughness in the light-emitting device produced using a ceramic-based sintered compact having a surface state with comparatively much unevenness, if saying in other words, a ceramic-based sintered compact having large surface roughness, even if it is the material comprising the same ceramics as a main component.

As mentioned above, this invention includes a substrate for a thin film for forming a single-crystal thin film comprising as a main component at least one selected from gallium nitride, indium nitride and aluminum nitride, characterized by comprising a ceramic-based sintered compact.

This invention includes a thin film substrate characterized in that a single-crystal thin film comprising as a main component at least one selected from gallium nitride, indium nitride and aluminum nitride is formed on the ceramic-based sintered compact.

As mentioned above, this invention includes a substrate for a thin film for forming a single-crystal thin film comprising as a main component at least one selected from gallium nitride, indium nitride and aluminum nitride, characterized by comprising a ceramic-based sintered compact with optical permeability.

This invention includes a thin film substrate characterized in that a single-crystal thin film comprising as a main component at least one selected from gallium nitride, indium nitride and aluminum nitride is formed on the ceramic-based sintered compact with optical permeability.

As mentioned above, this invention includes a light-emitting device produced using not only a ceramic-based sintered compact having a hexagonal or trigonal crystal structure, such as aluminum nitride, silicon carbide, silicon nitride, gallium nitride, beryllium oxide, zinc oxide, and aluminum oxide, etc., but also a ceramic-based sintered compact, such as zirconium oxide, magnesium oxide, magnesium aluminate, titanium oxide, barium titanate, lead titanate zirconate, rare-earth oxides, such as yttrium oxide, thorium oxide, various ferrites, mullite, forsterite, steatite and glass, for example.

Thus, this invention also includes a light-emitting device produced using not only a ceramic-based sintered compact having a hexagonal or trigonal crystal structure, such as aluminum nitride, silicon carbide, silicon nitride, gallium nitride, beryllium oxide, zinc oxide, and aluminum oxide, etc., but also a ceramic-based sintered compact, such as zirconium oxide, magnesium oxide, magnesium aluminate, titanium oxide, barium titanate, lead titanate zirconate, rare-earth oxides, such as yttrium oxide, thorium oxide, various ferrites, mullite, forsterite, steatite and glass, for example.

As mentioned above, this invention also includes a light-emitting device produced using not only a ceramic-based sintered compact having a hexagonal or trigonal crystal structure, such as aluminum nitride, silicon carbide, silicon nitride, gallium nitride, beryllium oxide, zinc oxide, and aluminum oxide, etc., but also a sintered compact having optical permeability and comprising as a main component a ceramic material, such as zirconium oxide, magnesium oxide, magnesium aluminate, titanium oxide, barium titanate, lead titanate zirconate, rare-earth oxides, such as yttrium oxide, thorium oxide, various ferrites, mullite, forsterite, steatite and glass, for example.

As mentioned above, this invention also includes a light-emitting device produced using not only a ceramic-based sintered compact having a hexagonal or trigonal crystal structure, such as aluminum nitride, silicon carbide, silicon nitride, gallium nitride, beryllium oxide, zinc oxide, and aluminum oxide, etc., but also a sintered compact having a thin film comprising at least one selected from gallium nitride, indium nitride and aluminum nitride as a main component and comprising as a main component a ceramic material, such as zirconium oxide, magnesium oxide, magnesium aluminate, titanium oxide, barium titanate, lead titanate zirconate, rare-earth oxides, such as yttrium oxide, thorium oxide, various ferrites, mullite, forsterite, steatite and glass, for example.

As mentioned above, this invention also includes a light-emitting device produced using not only a ceramic-based sintered compact having a hexagonal or trigonal crystal structure, such as aluminum nitride, silicon carbide, silicon nitride, gallium nitride, beryllium oxide, zinc oxide, and aluminum oxide, etc., but also a sintered compact having a single-crystal thin film comprising at least one selected from gallium nitride, indium nitride and aluminum nitride as a main component and comprising as a main component a ceramic material, such as zirconium oxide, magnesium oxide, magnesium aluminate, titanium oxide, barium titanate, lead titanate zirconate, rare-earth oxides, such as yttrium oxide, thorium oxide, various ferrites, mullite, forsterite, steatite and glass, for example.

As mentioned above, this invention also includes a light-emitting device produced using not only a ceramic-based sintered compact having a hexagonal or trigonal crystal structure, such as aluminum nitride, silicon carbide, silicon nitride, gallium nitride, beryllium oxide, zinc oxide, and aluminum oxide, etc., but also a sintered compact having large surface roughness and comprising as a main component a ceramic material, such as zirconium oxide, magnesium oxide, magnesium aluminate, titanium oxide, barium titanate, lead titanate zirconate, rare-earth oxides, such as yttrium oxide, thorium oxide, various ferrites, mullite, forsterite, steatite and glass, for example.

As mentioned above, this invention has been made by finding out that a single-crystal thin film comprising at least one selected from gallium nitride, indium nitride and aluminum nitride as a main component can be formed even if it is a ceramic-based sintered compact and is heterogeneous compared with a single crystal or an orientated polycrystal having a specific crystal direction, and a thin film substrate in which the single-crystal thin film was formed can manufacture comparatively easily as a result.

In addition, a single-crystal thin film comprising as a main component at least one selected from gallium nitride, indium nitride and aluminum nitride can be formed even if a ceramic-based sintered compact and formed beforehand a thin film comprising as a main component at least one selected from gallium nitride, indium nitride and aluminum nitride is used, and a thin film substrate in which the single-crystal thin film was formed can manufacture comparatively easily as a result.

It was found that those in which the luminous efficiency is equivalent or more at least or is a maximum of not less than 4-5 times compared with the light-emitting device produced using bulk-like single crystal substrates, such as conventional sapphire, can manufacture even if it is a light-emitting device produced using a ceramic-based sintered compact and is heterogeneous compared with a single crystal or an orientated polycrystal having a specific crystal direction.

This inventor found that those in which the luminous efficiency is equivalent or more at least or is a maximum of not less than 4-5 times compared with the light-emitting device produced using a sapphire substrate, can manufacture even if it is a light-emitting device produced using a ceramic-based sintered compact and formed beforehand a thin film comprising as a main component at least one selected from gallium nitride, indium nitride and aluminum nitride.

Thus, this invention was made by finding out the phenomenon in which a thin film comprising as a main component at least one selected from gallium nitride, indium nitride and aluminum nitride and contains a single crystal or a single crystal layer at least and a ceramic-based sintered compact are unified.

A boron component can be contained in the above thin film comprising as a main component at least one selected from gallium nitride, indium nitride and aluminum nitride and contains a single crystal or a single crystal layer at least, it was found that it is unified more firmly with the ceramic-based sintered compact. It was also found that the light-emitting device which emits the light of short wavelength 200 or less nm by using the thin film containing such a boron component can produce.

The above substrate for a thin film, thin film substrate, and electronic devices, such as an optical waveguide and a semiconductor device, such as a light-emitting device, can be obtained by using such a phenomenon.

This invention provides:
(1) A semiconductor device comprising a thin film comprising at least one selected from gallium nitride, indium nitride and aluminum nitride and is integrally adhered to a ceramic-based sintered compact, and the above thin film is at least partially a single crystal or has at least a single crystal layer.
(2) The semiconductor device, wherein the ceramic-based sintered compact having optical permeability.
(3) The semiconductor device, wherein the sintered compact comprises as a main component alumnum nitride.
(4) The semiconductor device, wherein the ceramic-based sintered compact having a hexagonal and/or trigonal crystal structure.
(5) The semiconductor device, wherein the ceramic material contains at least one selected from zinc oxide, beryllium oxide, aluminum oxide, silicon carbide, silicon nitride, and gallium nitride.
(6) The semiconductor device, wherein the sintered compact comprises as a main component at least one ceramic material selected from zirconium oxide, magnesium oxide, magnesium aluminate, titanium oxide, barium titanate, lead titanate zirconate, a rare earth oxide, thorium oxide, various ferrites, mullite, forsterite, steatite and glass.
(7) The semiconductor device, wherein at least one selected from gallium nitride, indium nitride and aluminum nitride is at least 50 mol % in the thin film.
(8) The semiconductor device, wherein the thin film comprises as a main component at least one selected from gallium nitride, indium nitride and aluminum nitride further contains at least one selected from magnesium, beryllium, calcium, zinc, cadmium, carbon, silicon, germanium, oxygen, selenium and tellurium.

This invention is the semiconductor device, wherein the content of at least one selected from magnesium, beryllium, calcium, zinc, cadmium, carbon, silicon, germanium, oxygen, selenium and tellurium is 0.00001-10 mol %.
(1) A boron component is contained in the thin film.

The boron component is at least one selected from boron, boron nitride, boron carbide, and metal borides.
(8) A metal constituting the metal boride is at least one selected from aluminum, gallium, indium, rare earth metals and alkaline-earth metals.
(8) The boron component is not more than 50 mol % in the thin film.
(8) A semiconductor device comprising a thin film comprising as a main component at least one selected from gallium nitride, indium nitride and aluminum nitride, and the above thin film contains a portion of a single crystal and contains further at least one of crystallization states selected from an amorphous state, a polycrystal, and an orientated polycrystal is formed on a ceramic-based sintered compact.
(8) The ceramic-based sintered compact having optical permeability.
(8) The ceramic-based sintered compact is a sintered compact comprising as a main component aluminum nitride.
(8) The ceramic-based sintered compact is a ceramic-based sintered compact having at least one of the crystal structures selected from a hexagonal system or a trigonal system.
(8) The sintered compact comprising as a main component a material having at least one of crystal structures selected from a hexagonal system or a trigonal system is a sintered compact comprising as a main component at least one selected from zinc oxide, beryllium oxide, aluminum oxide, silicon carbide, silicon nitride, and gallium nitride.
(8) The ceramic-based sintered compact is a sintered compact comprising as a main component at least one selected from zirconium oxide, magnesium oxide, magnesium aluminate, titanium oxide, barium titanate, lead titanate zirconate, a rare earth oxide, thorium oxide, various ferrites, mullite, forsterite, steatite and glass.
(8) A boron component is contained in the thin film comprising as a main component at least one selected from gallium nitride, indium nitride and aluminum nitride.
(8) A substrate for a thin film for forming a single-crystal thin film comprising as a main component at least one selected from gallium nitride, indium nitride and aluminum nitride, and the substrate comprises a ceramic-based sintered compact.
(8) A substrate for a thin film for forming a thin film comprising as a main component at least one selected from gallium nitride, indium nitride and aluminum nitride, and the substrate comprises a ceramic-based sintered compact with optical permeability.
(8) The substrate for a thin film, wherein the ceramic-based sintered compact and is used for the above substrate for a thin film is an aluminum nitride-based sintered compact.
(8) The substrate for a thin film, wherein the ceramic-based sintered compact and is used for the above substrate for a thin film is a ceramic-based sintered compact having at least one of the crystal structures selected from a hexagonal system or a trigonal system.
(8) The substrate for a thin film, wherein the ceramic-based sintered compact and is used for the above substrate for a thin film is a sintered compact comprising as a main component at least one selected from zinc oxide, beryllium oxide, aluminum oxide, silicon carbide, silicon nitride, and gallium nitride.
(8) The substrate for a thin film, wherein the ceramic-based sintered compact and is used for the above substrate for a thin film is a sintered compact comprising as a main component at least one selected from zirconium oxide, magnesium oxide, magnesium aluminate, titanium oxide, barium titanate, lead titanate zirconate, a rare earth oxide, thorium oxide, various ferrites, mullite, forsterite, steatite and glass.
(8) A manufacture method of the substrate for forming a thin film comprising as a main component at least one selected from gallium nitride, indium nitride and aluminum nitride, and the aluminum nitride-based sintered compact substrate and is manufactured using as a raw material at least respectively one of either which is selected from the reduction of aluminum oxide and the direct nitriding of metal aluminum, or that of the mixture made by reduction of aluminum oxide and by direct nitriding of metal aluminum.
(8) A method for producing the substrate for forming a thin film comprising as a main component at least one selected from gallium nitride, indium nitride and aluminum nitride, and the aluminum nitride-based sintered compact substrate obtained by firing the powder compact or aluminum nitride-based sintered compact for not less than 10 minutes at the temperature not less than 1500° C. in non-oxidizing atmosphere.

This invention is an aluminum nitride-based sintered compact with optical permeability, wherein at least one selected from a rare earth element and an alkaline-earth metal is a total of not more than 0.5 weight % on an element basis, oxygen is not more than 0.9 weight % on an element basis, AlN is not less than 95% as a crystal phase, the average size of aluminum nitride particles is not less than 5 μm.

This invention is a zinc oxide-based sintered compact and containing an aluminum component at least and having optical permeability.

This invention is a gallium nitride-based sintered compact having optical permeability.

This invention is a gallium nitride-based sintered compact having electrical conductivity.

This invention is a gallium nitride-based sintered compact having optical permeability and electrical conductivity.

This invention is a gallium nitride-based sintered compact and contains at least one selected from an alkaline-earth metal and a rare earth element.

This invention is a gallium nitride-based sintered compact and contains at least one selected from zinc, cadmium, beryllium, magnesium, carbon, silicon, germanium, selenium and tellurium.

This invention is a gallium nitride-based sintered compact and contains at least one selected from aluminum, indium, and oxygen.

This invention is a gallium nitride-based sintered compact and contains at least one selected from a transition metal.

This invention is a powder comprising gallium nitride as a main component and is the oxygen content not more than 10 weight %.

This invention is a powder comprising gallium nitride as a main component and is the average particle diameter not more than 10 μm.

This invention is a manufacture method of the powder comprising gallium nitride as a main component and is made by carrying out the nitriding reaction of metal gallium and a nitrogen-containing compound.

This invention is a manufacture method of the powder comprising gallium nitride as a main component and is made by carrying out the nitriding reaction of gallium oxide using a reducing agent and a nitrogen-containing compound.

This invention is a manufacture method of the powder comprising gallium nitride as a main component and is made by carrying out the nitriding reaction of a gas-like gallium compound and a nitrogen-containing compound.

This invention is a thin film substrate in which a single-crystal thin film comprising as a main component at least one selected from gallium nitride, indium nitride and aluminum nitride is formed on the ceramic-based sintered compact.

This invention is a thin film substrate in which a thin film comprising as a main component at least one selected from gallium nitride, indium nitride and aluminum nitride is formed on the ceramic-based sintered compact with optical permeability.

This invention is the thin film substrate, wherein the ceramic-based sintered compact and is used for the above thin film substrate is an aluminum nitride-based sintered compact.

This invention is the thin film substrate, wherein the ceramic-based sintered compact and is used for the above thin film substrate is a ceramic-based sintered compact having at least one of the crystal structures selected from a hexagonal system or a trigonal system.

This invention is the thin film substrate, wherein the ceramic-based sintered compact and is used for the above thin film substrate is a sintered compact comprising as a main component at least one selected from zinc oxide, beryllium oxide, aluminum oxide, silicon carbide, silicon nitride, and gallium nitride.

This invention is the thin film substrate, wherein the ceramic-based sintered compact and is used for the above thin film substrate is a sintered compact comprising as a main component at least one selected from zirconium oxide, magnesium oxide, magnesium aluminate, titanium oxide, barium titanate, lead titanate zirconate, a rare earth oxide, thorium oxide, various ferrites, mullite, forsterite, steatite and glass.

This invention is a thin film substrate in which an optical waveguide is formed on the aluminum nitride-based sintered compact by the thin film comprising as a main component at least one selected from gallium nitride, indium nitride and aluminum nitride.

This invention is a manufacture method of the thin film substrate in which a single-crystal thin film comprising as a main component at least one selected from gallium nitride, indium nitride and aluminum nitride is formed on the ceramic-based sintered compact, and the thin film is formed using an organic compound containing at least one selected from gallium, indium, and aluminum as the main raw material and using at least one selected from ammonia, nitrogen, and hydrogen as the reactive gas.

This invention is a manufacture method of the thin film substrate in which a single-crystal thin film comprising as a main component at least one selected from gallium nitride, indium nitride and aluminum nitride is formed on the ceramic-based sintered compact, and the thin film is formed using a halogenated compound containing at least one selected from gallium, indium, and aluminum as the main raw material and using at least one selected from ammonia, nitrogen, and hydrogen as the reactive gas.

This invention is a manufacture method of the thin film substrate in which a thin film comprising as a main component at least one selected from gallium nitride, indium nitride and aluminum nitride is formed on the ceramic-based sintered compact with optical permeability, and the thin film is formed using an organic compound containing at least one selected from gallium, indium, and aluminum as the main raw material and using at least one selected from ammonia, nitrogen, and hydrogen as the reactive gas.

This invention is a manufacture method of the thin film substrate in which a thin film comprising as a main component at least one selected from gallium nitride, indium nitride and aluminum nitride is formed on the ceramic-based sintered compact with optical permeability, and the thin film is formed using a halogenated compound containing at least one selected from gallium, indium, and aluminum as the main raw material and using at least one selected from ammonia, nitrogen, and hydrogen as the reactive gas.

This invention is an optical waveguide comprising as a main component at least one selected from gallium nitride, indium nitride and aluminum nitride and contains at least one selected from niobium and tantalum.

This invention is a light-emitting device constituted with the laminate comprising a thin film comprising at least one selected from gallium nitride, indium nitride and aluminum nitride as a main component and contains at least N-type semiconductor layer, luminescence layer, and P-type semiconductor layer, and the laminate of N-type semiconductor layer, luminescence layer, and P-type semiconductor layer is formed on the ceramic-based sintered compact.

This invention is a light-emitting device constituted with the laminate comprising a thin film comprising at least one selected from gallium nitride, indium nitride and aluminum nitride as a main component and contains at least N-type semiconductor layer, luminescence layer, and P-type semiconductor layer, and the laminate of N-type semiconductor layer, luminescence layer, and P-type semiconductor layer is formed on the ceramic-based sintered compact with optical permeability.

This invention is a light-emitting device constituted with the laminate comprising a thin film comprising at least one selected from gallium nitride, indium nitride and aluminum nitride as a main component and contains at least N-type semiconductor layer, luminescence layer, and P-type semiconductor layer, and the laminate of N-type semiconductor layer, luminescence layer, and P-type semiconductor layer is formed on the ceramic-based sintered compact having large surface roughness.

This invention is a light-emitting device constituted with the laminate comprising a thin film comprising at least one selected from gallium nitride, indium nitride and aluminum nitride as a main component and contains at least N-type semiconductor layer, luminescence layer, and P-type semiconductor layer, and the laminate of N-type semiconductor layer, luminescence layer, and P-type semiconductor layer is formed on the ceramic-based sintered compact and formed the thin film comprising at least one selected from gallium nitride, indium nitride and aluminum nitride as a main component.

This invention is a light-emitting device constituted with the laminate comprising a thin film comprising at least one selected from gallium nitride, indium nitride and aluminum nitride as a main component and contains at least N-type semiconductor layer, luminescence layer, and P-type semiconductor layer, and the laminate of N-type semiconductor layer, luminescence layer, and P-type semiconductor layer is formed on the ceramic-based sintered compact and formed the single-crystal thin film comprising at least one selected from gallium nitride, indium nitride and aluminum nitride as a main component.

This invention is the light-emitting device, wherein the ceramic-based sintered compact and is used for the above light-emitting device is an aluminum nitride-based sintered compact.

This invention is the light-emitting device, wherein the ceramic-based sintered compact and is used for the above light-emitting device is a sintered compact comprising as a main component a material having at least one of the crystal structure selected from a hexagonal system or a trigonal system.

This invention is the light-emitting device, wherein the sintered compact which is used for the above light-emitting device and comprising as a main component a material having at least one of the crystal structure selected from a hexagonal system or a trigonal system is a sintered compact comprising at least one selected from zinc oxide, beryllium oxide, aluminum oxide, silicon carbide, silicon nitride, and gallium nitride as a main component.

This invention is the light-emitting device, wherein the ceramic-based sintered compact and is used for the above light-emitting device is a sintered compact comprising at least one selected from zirconium oxide, magnesium oxide, magnesium aluminate, titanium oxide, barium titanate, lead titanate zirconate, a rare earth oxide, thorium oxide, various ferrites, mullite, forsterite, steatite and glass as a main component.

### BRIEF DESCRIPTION OF THE DRAWINGS

FIG. 1 is a drawing showing the substrate for a thin film of this invention and the crystal orientation of the single-crystal thin film formed on that substrate.

FIG. 2 is a drawing showing the X-ray diffraction by the single-crystal thin film formed on the substrate for a thin film according to this invention.

FIG. 3 is a perspective view showing one example of the substrate for a thin film with conduction vias according to this invention.

FIG. 4 is the drawing showing the substrate for a thin film of this invention and the crystal orientation of the single-crystal thin film formed on the substrate.

FIG. 5 is a perspective view showing one example of the substrate for a thin film and the thin film substrate according to this invention.

FIG. 6 is a perspective view showing one example of the thin film substrate according to this invention.

FIG. 7 is a perspective view showing one example of the substrate for a thin film and the thin film substrate having conduction vias according to this invention.

FIG. 8 is a perspective view showing one example of the thin film substrate with conduction vias according to this invention.

FIG. 9 is a diagram showing the optical transmissivity of the aluminum nitride-based sintered compact according to this invention.

FIG. 10 is a perspective view showing one example of the substrate for a thin film according to this invention, wherein the thin conductive film was formed.

FIG. 11 is a perspective view showing one example of the substrate for a thin film according to this invention, wherein the thin conductive film was formed.

FIG. 12 is a perspective view showing one example of the substrate for a thin film with conduction vias according to this invention, wherein the thin conductive film was formed.

FIG. 13 is a perspective view showing one example of the substrate for a thin film according to this invention, wherein the thin conductive film of pattern form was formed.

FIG. 14 is a perspective view showing one example of the thin film substrate according to this invention, wherein the thin film comprising as a main component at least one selected from gallium nitride, indium nitride and aluminum nitride is formed on the thin conductive film.

FIG. 15 is a perspective view showing one example of the thin film substrate according to this invention, wherein the thin conductive film and the thin film comprising as a main component at least one selected from gallium nitride, indium nitride and aluminum nitride were formed respectively in the different surface.

FIG. 16 is a perspective view showing one example of the thin film substrate according to this invention, wherein the thin film comprising as a main component at least one selected from gallium nitride, indium nitride and aluminum nitride was formed on the thin conductive film and the thin conductive film was formed furthermore on the different surface.

FIG. 17 is a perspective view showing one example of the thin film substrate according to this invention, wherein the thin conductive film was formed on the thin film comprising as a main component at least one selected from gallium nitride, indium nitride and aluminum nitride.

FIG. 18 is a perspective view showing one example of the thin film substrate according to this invention, wherein the thin film comprising as a main component at least one selected from gallium nitride, indium nitride and aluminum nitride was formed on the aluminum nitride-based sintered compact and provided with beforehand a thin conductive film, and the thin conductive film was formed furthermore on it.

FIG. 19 is a perspective view showing one example of the thin film substrate according to this invention, wherein the thin film comprising as a main component at least one selected from gallium nitride, indium nitride and aluminum nitride was formed on the aluminum nitride-based sintered compact having conduction vias and provided with beforehand a thin conductive film, and the thin conductive film was formed furthermore on the surface of a thin film.

FIG. 20 is a perspective view showing one example of the thin film substrate according to this invention, wherein the thin film comprising as a main component at least one selected from gallium nitride, indium nitride and aluminum nitride was formed furthermore on the aluminum nitride-based sintered compact and provided with beforehand the thin conductive film, and the thin conductive film was formed furthermore on the surface of a thin film.

FIG. 21 is a perspective view showing one example of the thin film substrate according to this invention, wherein the two-dimension optical waveguide is being formed on the aluminum nitride-based sintered compact by the thin film comprising as a main component at least one selected from gallium nitride, indium nitride and aluminum nitride.

FIG. 22 is a perspective view showing one example of the thin film substrate according to this invention, wherein the cladding layer was formed on the two-dimension optical waveguide.

FIG. 23 is a perspective view showing one example of the thin film substrate according to this invention, wherein the-two-dimension optical waveguide was formed.

FIG. 24 is a perspective view showing one example of the thin film substrate according to this invention, wherein the three dimension optical waveguide was formed.

FIG. 25 is a perspective view showing one example of the thin film substrate according to this invention, wherein the three dimension optical waveguide was formed.

FIG. 26 is a perspective view showing one example of the thin film substrate according to this invention, wherein a ridge type of three dimension optical waveguide was formed.

FIG. 27 is a perspective view showing one example of the thin film substrate according to this invention, wherein the three dimension optical waveguide was formed inside a two-dimension optical waveguide by the formation of a dielectric material in the two-dimension optical waveguide.

FIG. 28 is a perspective view showing one example of the thin film substrate according to this invention, wherein the three dimension optical waveguide was formed in the inside of a two-dimension optical waveguide by carrying out the direct formation of a metal material into the two-dimension optical waveguide.

FIG. 29 is a perspective view showing one example of the thin film substrate according to this invention, wherein the three dimension optical waveguide was formed by forming an electrode in the two-dimension optical waveguide via a buffer layer and applying potential between these electrodes.

FIG. 30 is a perspective view showing one example of the thin film substrate according to this invention, wherein an embedded type of three dimension optical waveguide is formed in the thin film comprising as a main component at least one selected from gallium nitride, indium nitride and aluminum nitride.

FIG. 31 is a perspective view showing one example of the thin film substrate according to this invention, wherein an embedded type of three dimension optical waveguide is formed and the electrodes are formed furthermore.

FIG. 32 is a perspective view showing one example of the thin film substrate according to this invention, wherein an embedded type of three dimension optical waveguide is formed and the electrodes are formed furthermore.

FIG. 33 is a perspective view showing one example of the thin film substrate according to this invention, wherein an embedded type of three dimension optical waveguide is formed and the electrodes are formed furthermore.

FIG. 34 is a perspective view showing one example of the thin film substrate according to this invention, wherein the three dimension optical waveguide is formed and the electrical circuit is formed furthermore.

FIG. 35 is a perspective view showing one example of the thin film substrate according to this invention, wherein an embedded type of three dimension optical waveguide is formed and the electrical circuit is formed furthermore.

FIG. 36 is a perspective view showing one example of the substrate for a thin film according to this invention.

FIG. 37 is a perspective view showing one example of the thin film substrate according to this invention, wherein the thin film comprising as a main component at least one selected from gallium nitride, indium nitride and aluminum nitride was formed on the thin conductive film.

FIG. 38 is a perspective view showing one example of the thin film substrate with conduction vias according to this invention, wherein the thin film comprising as a main component at least one selected from gallium nitride, indium nitride and aluminum nitride was formed on the thin conductive film.

FIG. 39 is a sectional drawing showing one example of the constitution of a light-emitting device.

FIG. 40 is a sectional drawing showing one example of a light-emitting device which used a conventional substrate.

FIG. 41 is a sectional drawing showing one example of a light-emitting device which used a conventional substrate.

FIG. 42 is a sectional view showing one example of the light-emitting device of this invention.

FIG. 43 is a sectional view showing one example of the light-emitting device of this invention.

FIG. 44 is a sectional view showing one example of the light-emitting device of this invention.

FIG. 45 is a perspective view showing one example of the light-emitting device of this invention.

FIG. 46 is a perspective view showing one example of the light-emitting device of this invention.

FIG. 47 is a sectional view showing one example of the light-emitting device of this invention.

FIG. 48 is a sectional view showing one example of the light-emitting device of this invention.

FIG. 49 is a sectional view showing one example of the light-emitting device of this invention.

FIG. 50 is a sectional view showing one example of the light-emitting device of this invention.

FIG. 51 is a sectional view showing one example of the light-emitting device of this invention.

FIG. 52 is a sectional view showing one example of the light-emitting device of this invention.

FIG. 53 is a sectional view showing one example of the light-emitting device of this invention.

FIG. 54 is a sectional view showing one example of the light-emitting device of this invention.

FIG. 55 is a sectional view showing one example of the light-emitting device of this invention.

FIG. 56 is a sectional view showing one example of the light-emitting device of this invention.

FIG. 57 is a sectional view showing one example of the light-emitting device of this invention.

FIG. 58 is a sectional view showing one example of the light-emitting device of this invention.

FIG. 59 is a sectional drawing showing one example of luminescence of the light-emitting device of this invention.

FIG. 60 is a perspective view showing one example of luminescence of the light-emitting device of this invention.

FIG. 61 is a perspective view showing one example of the light-emitting device of this invention.

FIG. 62 is a figure showing one example of an X-ray diffraction pattern of an amorphous AlN thin film.

FIG. 63 is a figure showing one example of an X-ray diffraction pattern of a polycrystalline AlN thin film.

FIG. 64 is a figure showing one example of an X-ray diffraction pattern of an orientated-polycrystalline AlN thin film formed in such a direction that its C axis is perpendicular to the substrate surface.

FIG. 65 is a figure showing one example of an X-ray diffraction pattern of a single-crystalline AlN thin film a formed in such a direction that its C axis is perpendicular to the substrate surface.

FIG. 66 is a pattern showing one example of the rocking curve of X-ray diffraction line from a lattice plane (002), measured by the ω scanning of the single-crystal AlN thin film formed in such a direction that its C axis is perpendicular to the substrate surface.

FIG. 67 is a figure showing one example of an X-ray diffraction pattern of a single-crystal GaN thin film formed in such a direction that its C axis is perpendicular to the substrate surface.

FIG. 68 is a figure showing one example of an X-ray diffraction pattern of a single-crystal InN thin film formed in such a direction that its C axis is perpendicular to the substrate surface.

FIG. 69 is an elevational view showing one example of the thin conductive film of this invention.

FIG. 70 is an elevational view showing one example of the thin conductive film of this invention.

FIG. 71 is a mimetic diagram showing one example of the surface state of the ceramic-based sintered compact with comparatively large roughness.

FIG. 72 is a perspective view showing one example of the surface state of the ceramic-based sintered compact with usual roughness.

FIG. 73 is a perspective view showing one example of the surface state of the ceramic-based sintered compact with usual roughness.

### BEST MODE FOR CARRYING OUT THE INVENTION

The meaning and the purpose of this invention are to offer the substrate having outstanding function, the electronic devices, such as a light-emitting device which used this substrate, or the electronic components, such as a circuit substrate, which are hard to realize by the material which exists as a single crystal and is used independently in itself, such as the shape of a lump and the shape of bulk, such as conventional sapphire and silicon carbide, by unifying firmly a single-crystal thin film which is excellent in crystallinity and comprising at least one selected from gallium nitride, indium nitride and aluminum nitride as a main component and a ceramic-based sintered compact, and by drawing the synergistic effect which a single crystal and a ceramic-based sintered compact cannot make independently respectively. It is the offering of a ceramic-based sintered compact and brings about such an effect.

This invention relates to the thin film substrate using the ceramic-based sintered compact, and the electronic devices using the substrate, if it sees widely. More specifically,
(1) A substrate for forming the single-crystal thin film comprising gallium nitride, indium nitride, and aluminum nitride as a main component,
(2) A material of the above substrate for single-crystal thin film formation,
(3) A thin film substrate in which the single-crystal thin film comprising gallium nitride, indium nitride, and aluminum nitride as a main component was formed,
(4) An optical waveguide constituted by the single-crystal thin film comprising gallium nitride, indium nitride, and aluminum nitride as a main component,
(5) A light-emitting device constituted by the single-crystal thin film comprising gallium nitride, indium nitride, and aluminum nitride as a main component, the feature is in the point using various ceramic-based sintered compacts as a substrate, such as an aluminum nitride-based sintered compact.
(6) A substrate for forming the thin film comprising gallium nitride, indium nitride, and aluminum nitride as a main component,
(7) A material of the above substrate for a thin film,
(8) A thin film substrate in which the thin film comprising gallium nitride, indium nitride, and aluminum nitride as a main component was formed,
(9) An optical waveguide constituted by the thin film comprising gallium nitride, indium nitride, and aluminum nitride as a main component,
(10) A light-emitting device constituted by the thin film comprising gallium nitride, indium nitride, and aluminum nitride as a main component, the feature is in the point using a ceramic-based sintered compact with optical permeability as a substrate, such as an aluminum nitride-based sintered compact.

That is, these inventions are based on the findings that the thin film excellent in crystallinity comprising gallium nitride, indium nitride, and aluminum nitride as a main component can be formed on the various ceramic-based sintered compacts, such as an aluminum nitride-based sintered compact, and it has been based on the phenomenon newly found in process of examination which forms the single-crystal thin film excellent in crystallinity comprising gallium nitride, indium nitride, and aluminum nitride as a main component into the various ceramic-based sintered compacts, such as an aluminum nitride-based sintered compact.

The electronic devices are constituted by those in which a thin film comprising as a main component at least one selected from gallium nitride, indium nitride and aluminum nitride and contains a single crystal or a single crystal layer at least and a ceramic-based sintered compact are unified, They contain semiconductor devices, such as the above light-emitting device which functions by the constitution of carrying out PN junction in which the above thin films containing a single crystal or a single crystal layer are made into the N-type and P-type semiconductor, and in which such N-type and P-type semiconductor is combined, and contain those used as it is without carrying out PN junction of the above thin films, such as an optical waveguide.

Though the semiconductor device is those in which a thin film comprising as a main component at least one selected from gallium nitride, indium nitride and aluminum nitride and contains a single crystal or a single crystal layer at least and a ceramic-based sintered compact are unified, the above thin films are used by making them into N-type and P-type semiconductor in many cases. These N-type and P-type semiconductor thin films are combined, and the semiconductor device can be constituted by PN junction of the above-described N-type and P-type semiconductor thin films. As a semiconductor device, two-terminal device comprising an N-type or a P-type semiconductor layer is included. As a two-terminal device, the light-emitting device in which the luminescence layer was formed between N-type thin film layer and P-type thin film layer is included. as a semiconductor device, not only two-terminal device but also three-terminal device, such as a transistor which combined N-type and the P-type semiconductor thin film as PNP or NPN, are contained. In addition to these, as a semiconductor device, there is four-terminal device, such as a thyristor, and there are IC (integrated circuit), LSI (large scale integration circuit), etc., functions, such as luminescence, amplification of a signal, rectification, switching, operation, and memory, etc., are shown. It also has a function as the so-called solar cell which produces electromotive force by irradiating light. It also has a function as various sensors.

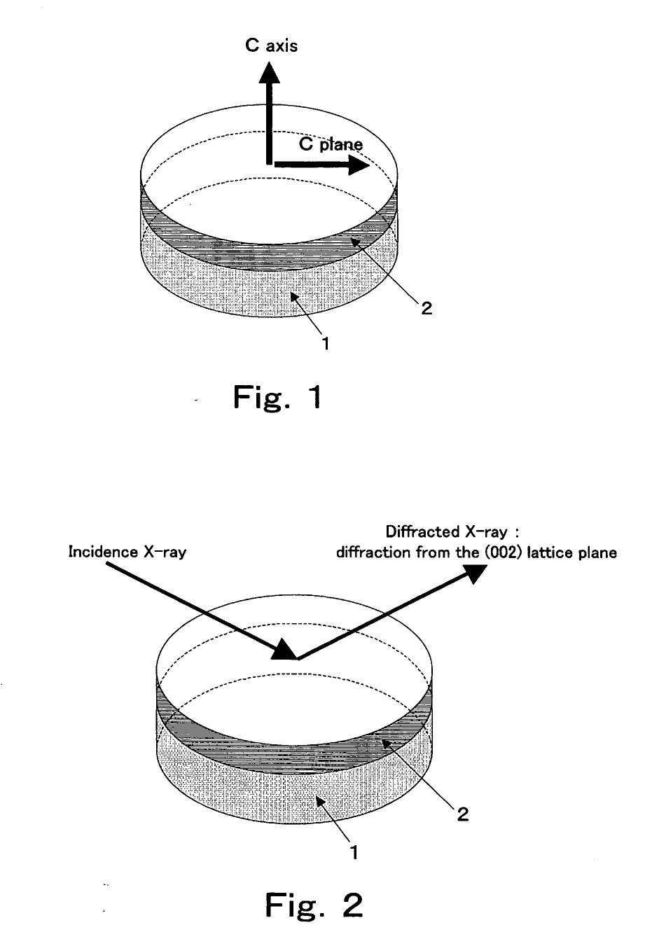

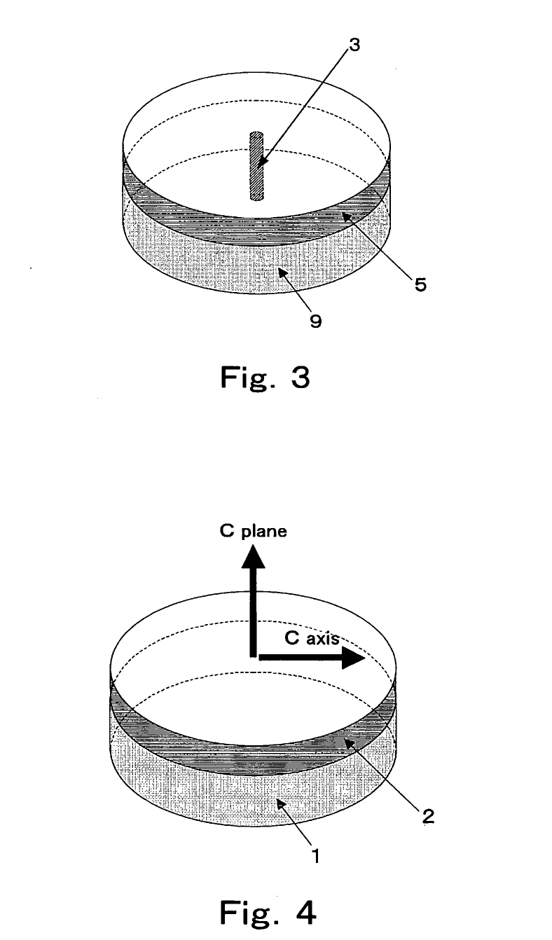

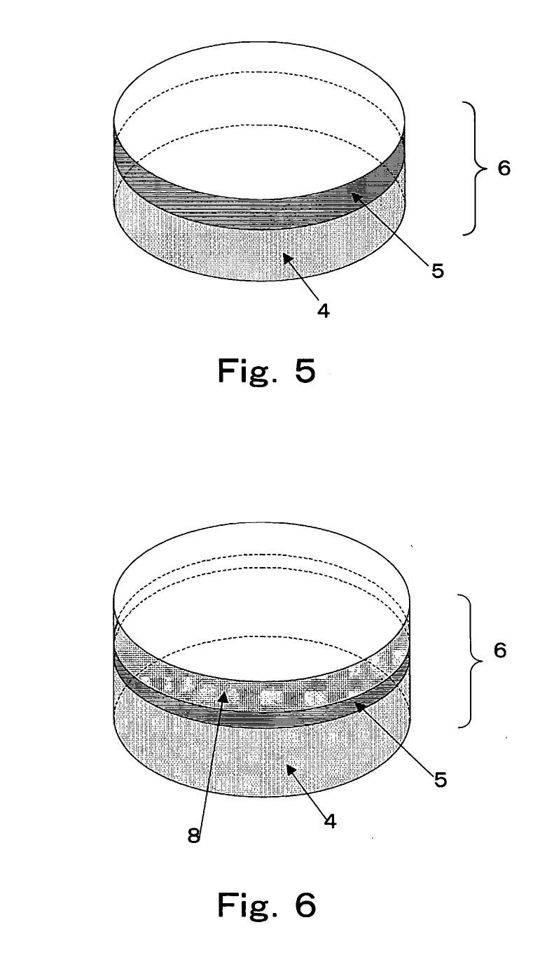

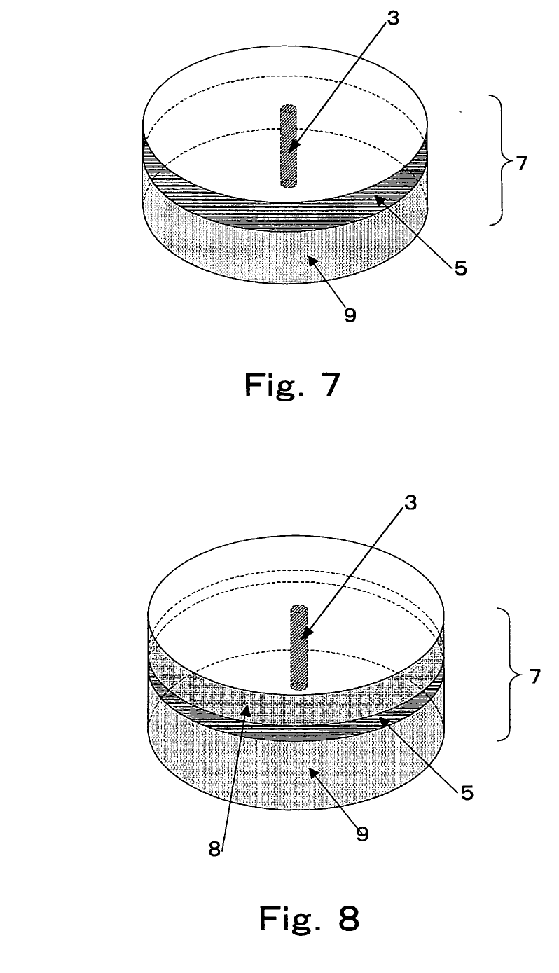

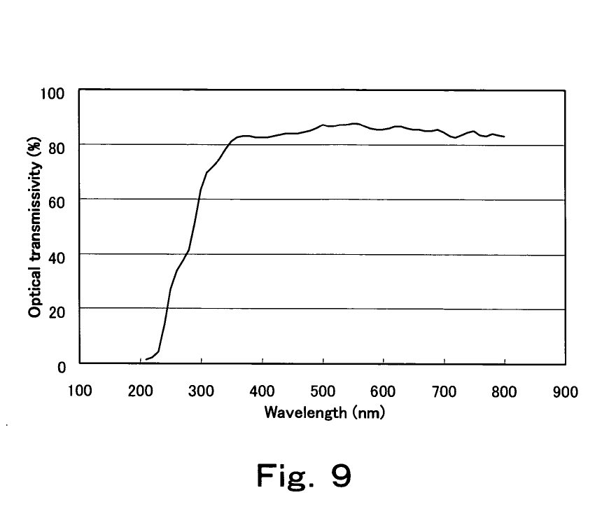

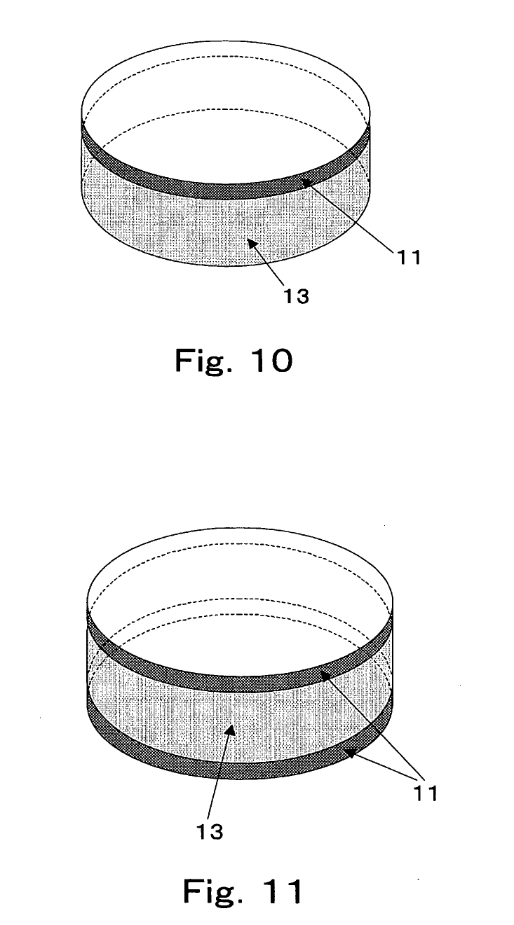

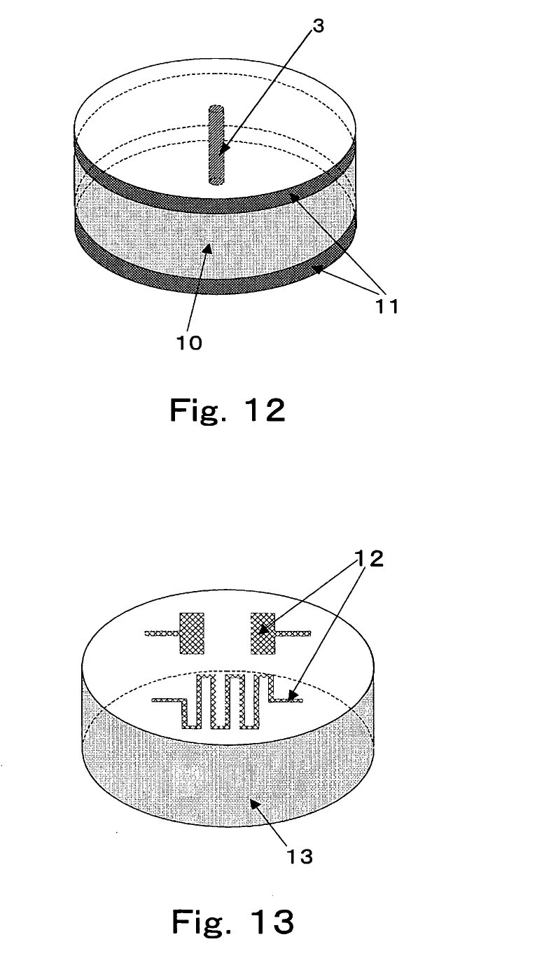

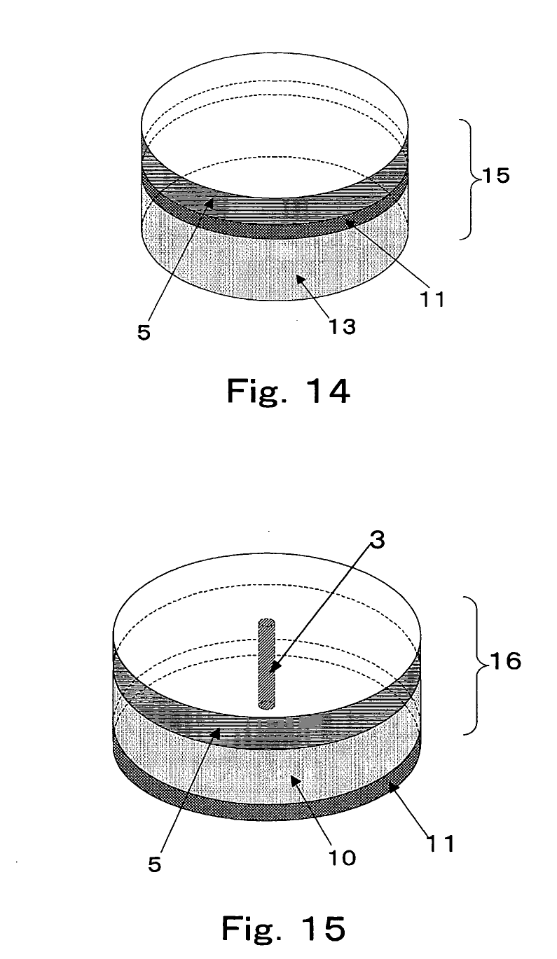

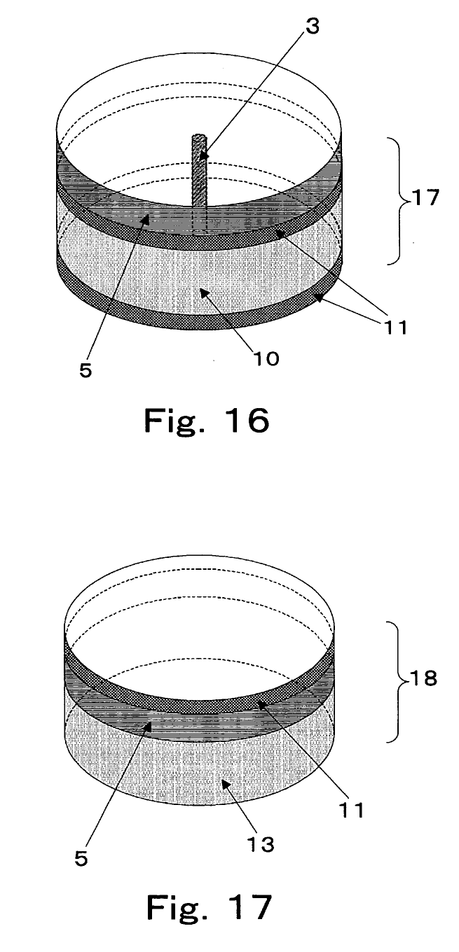

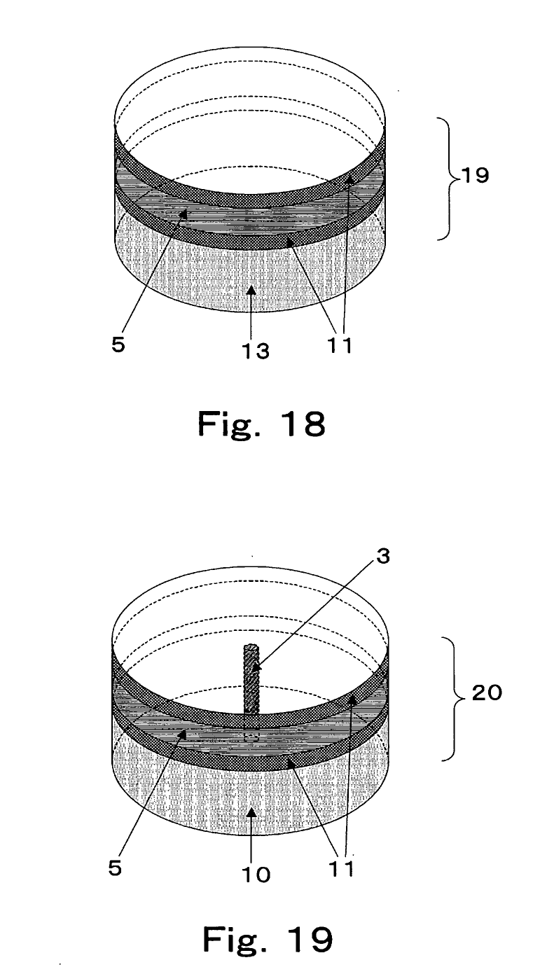

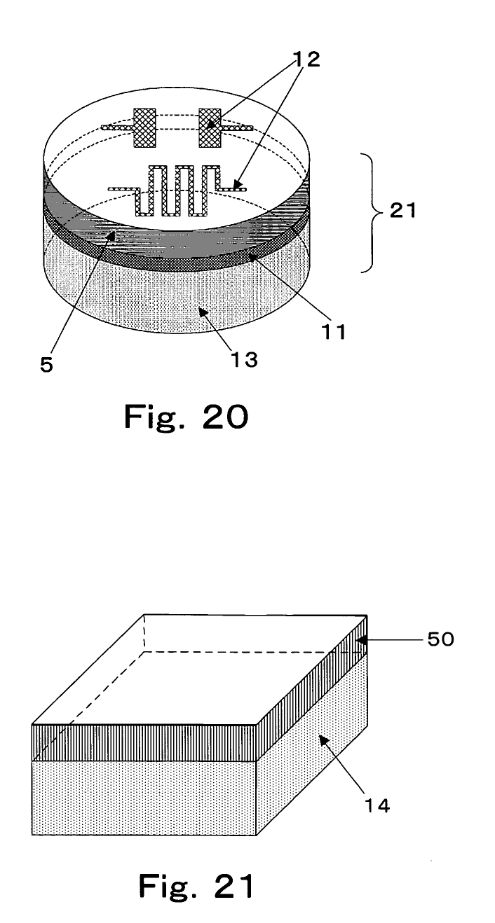

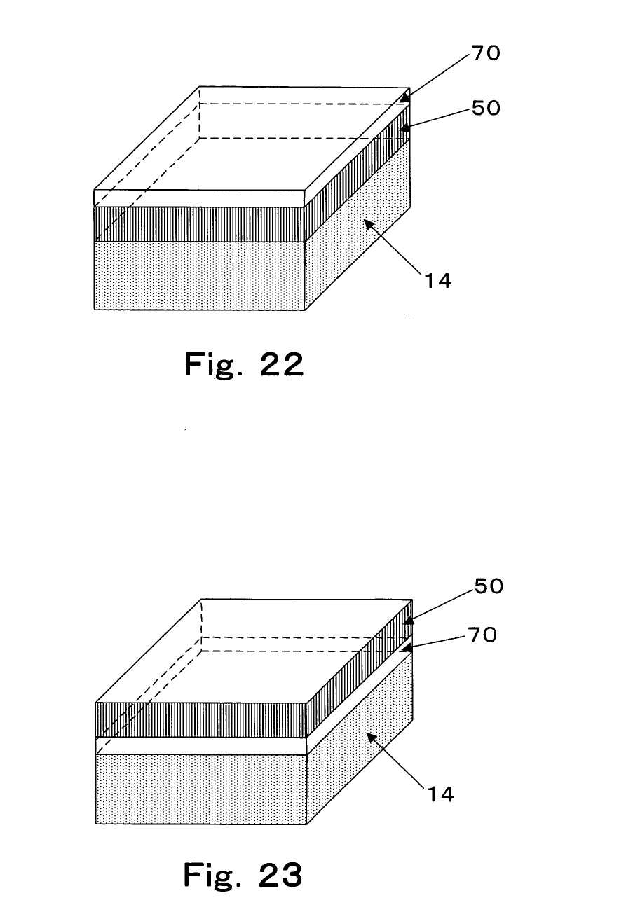

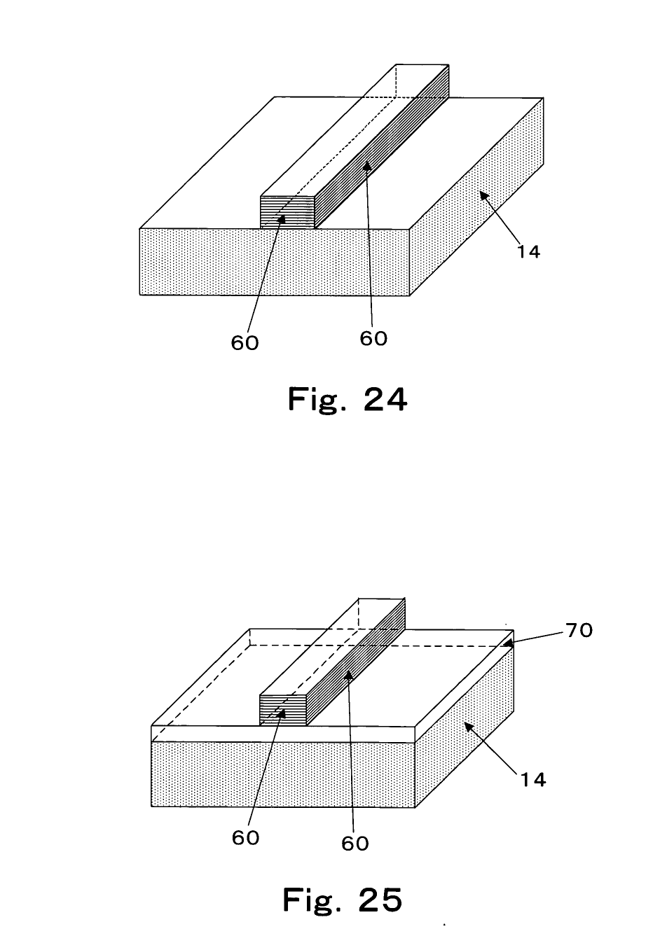

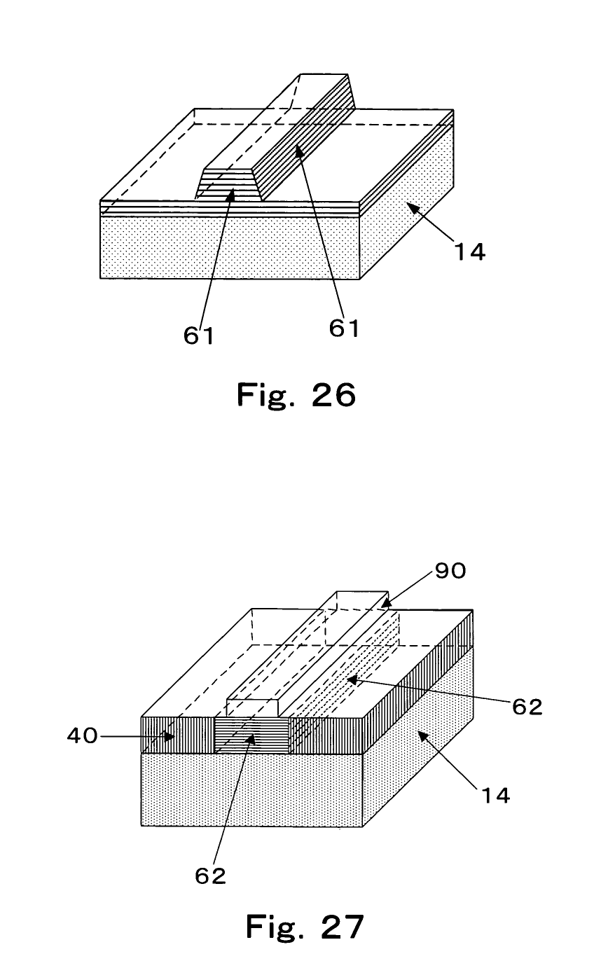

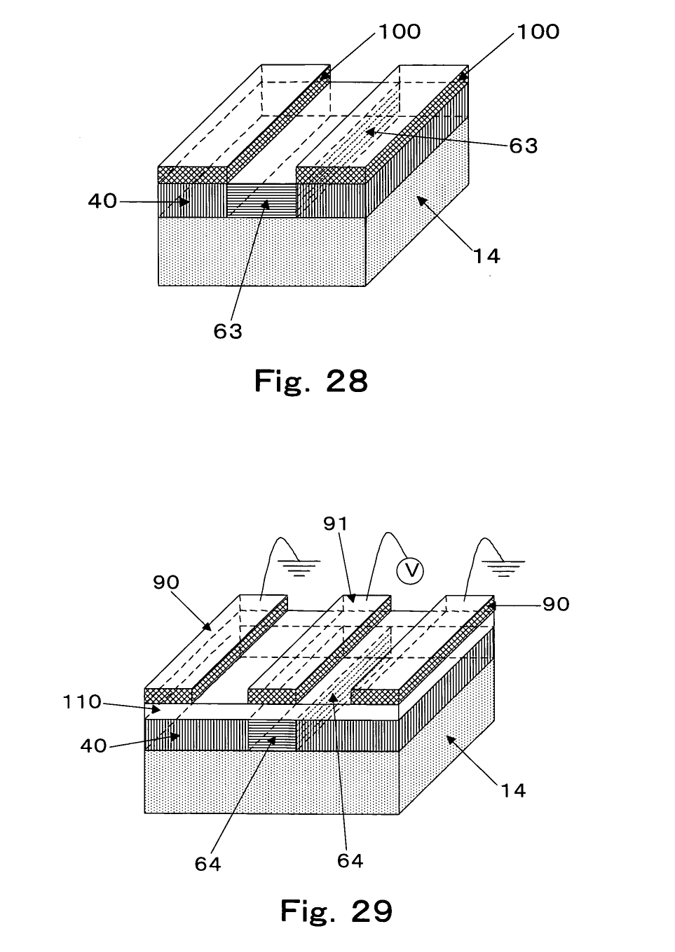

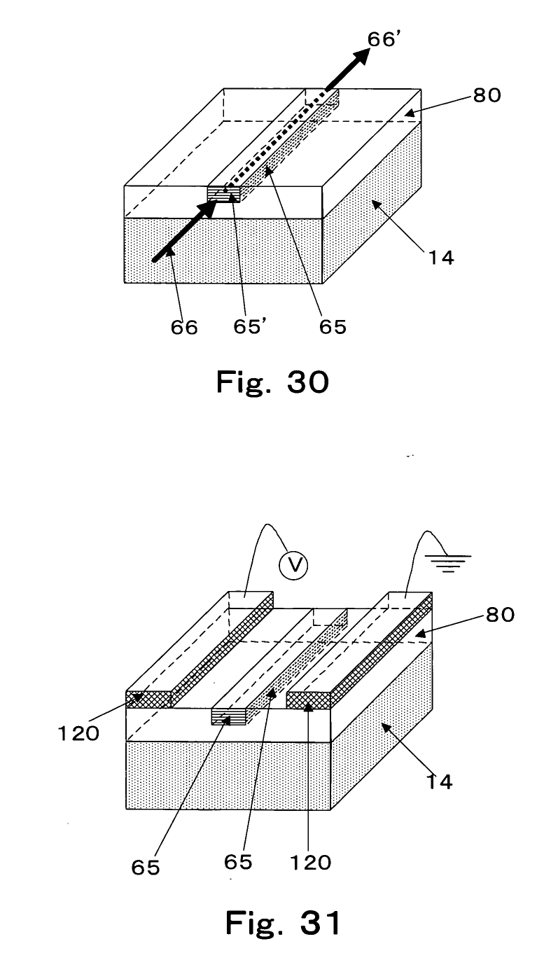

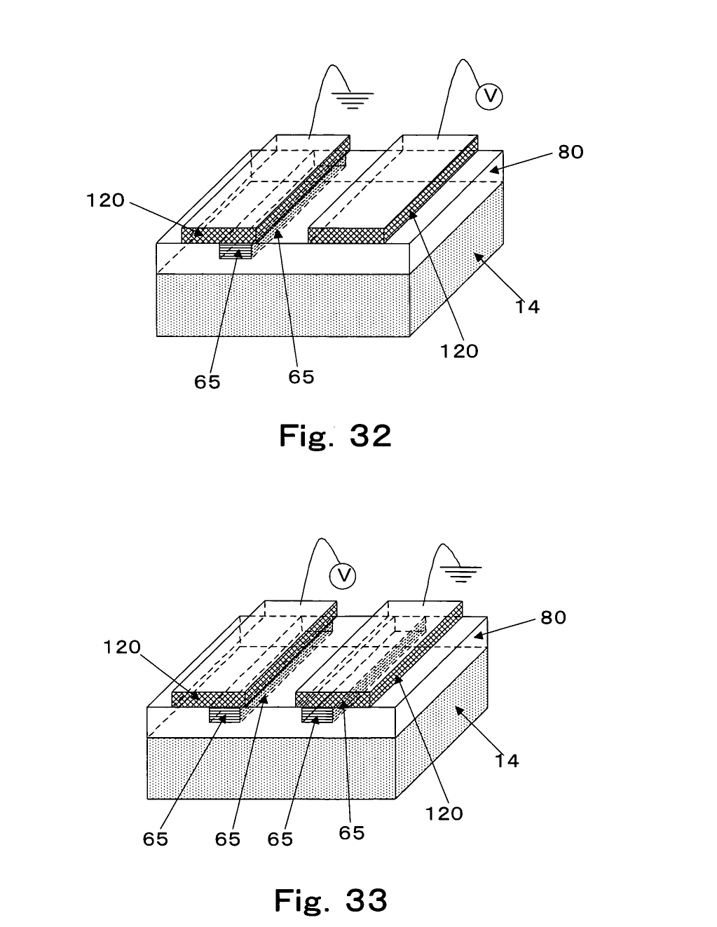

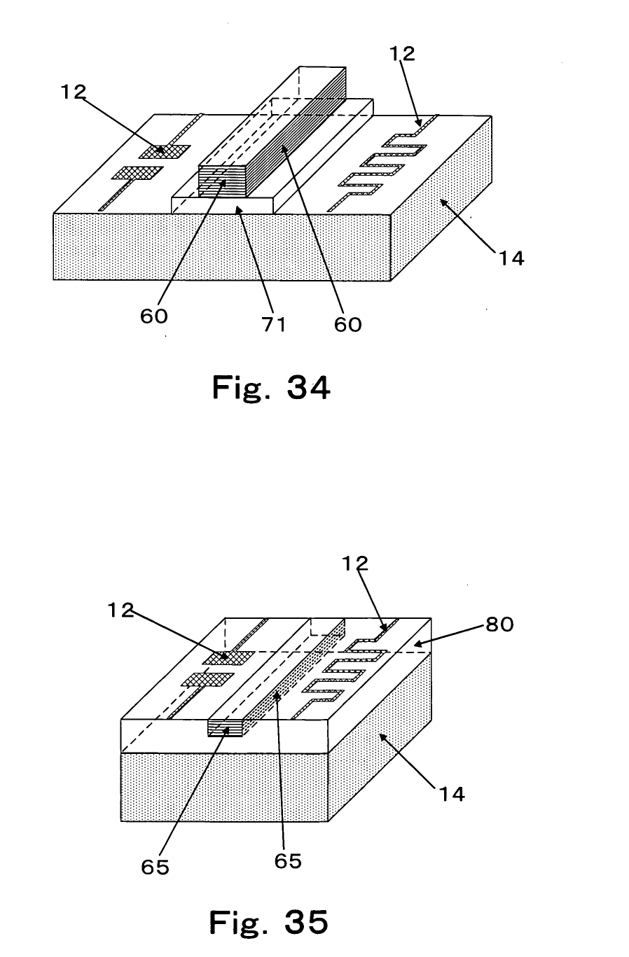

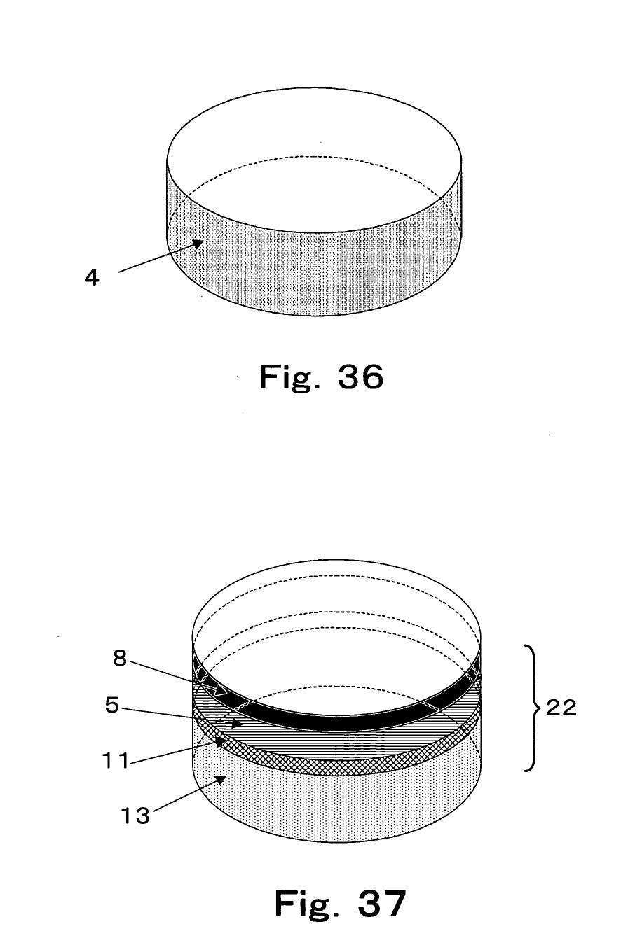

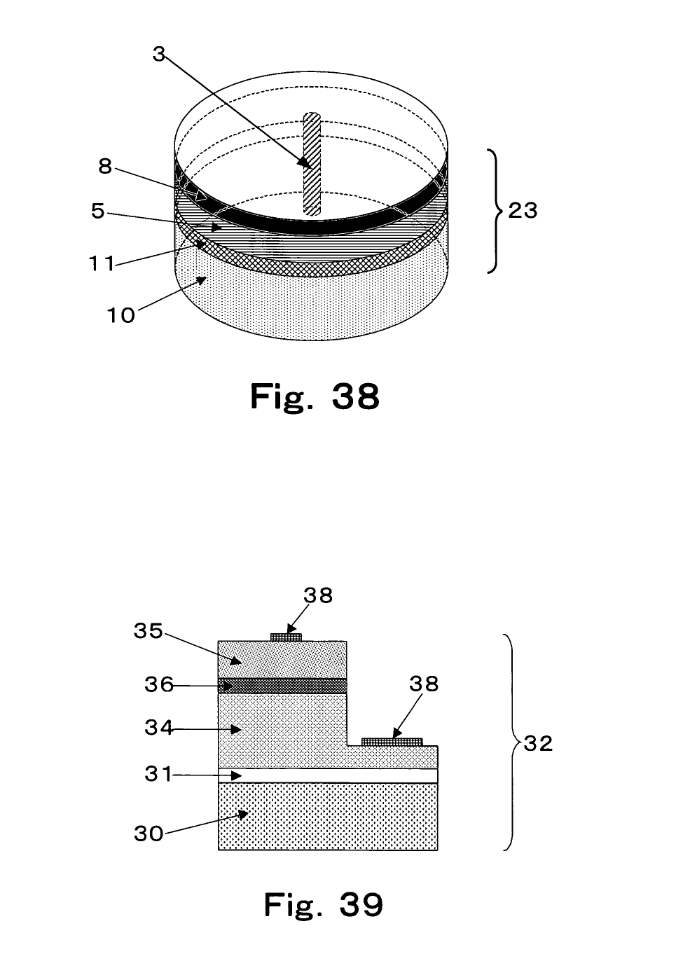

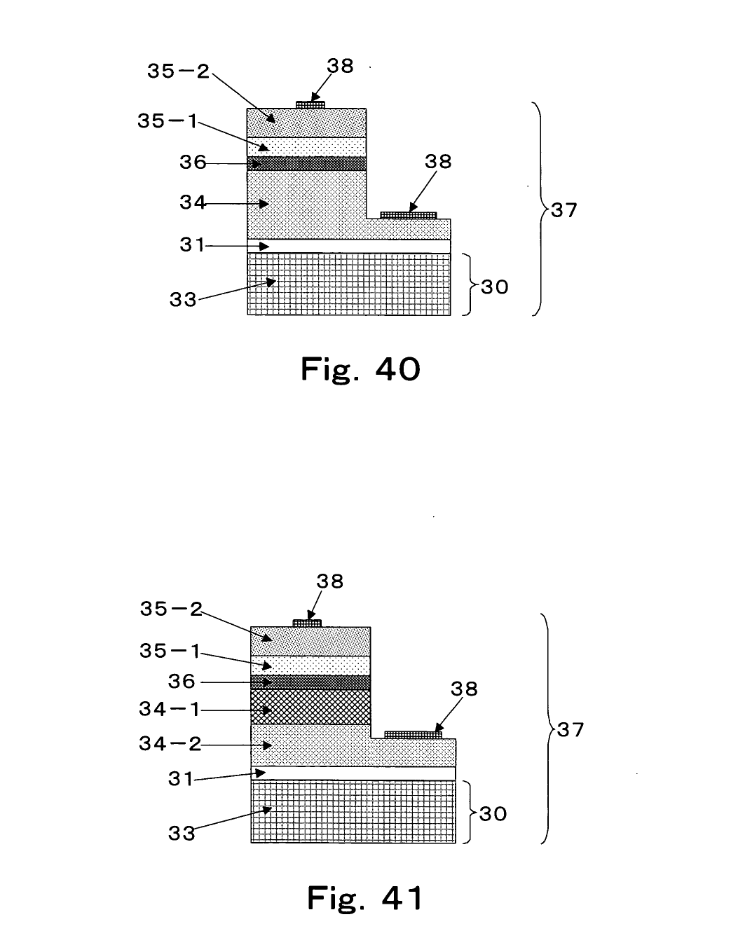

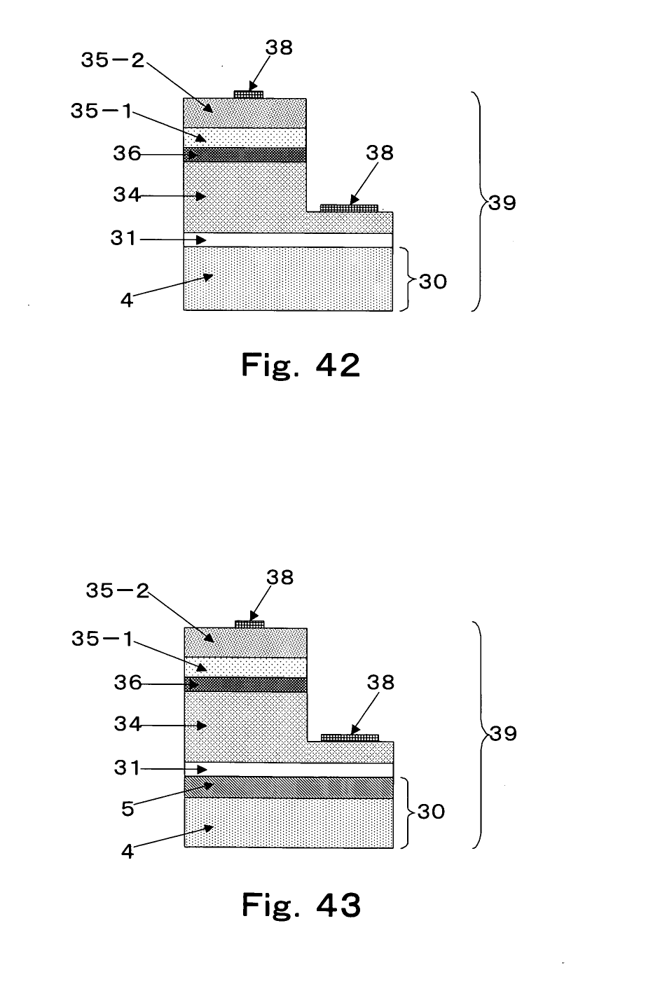

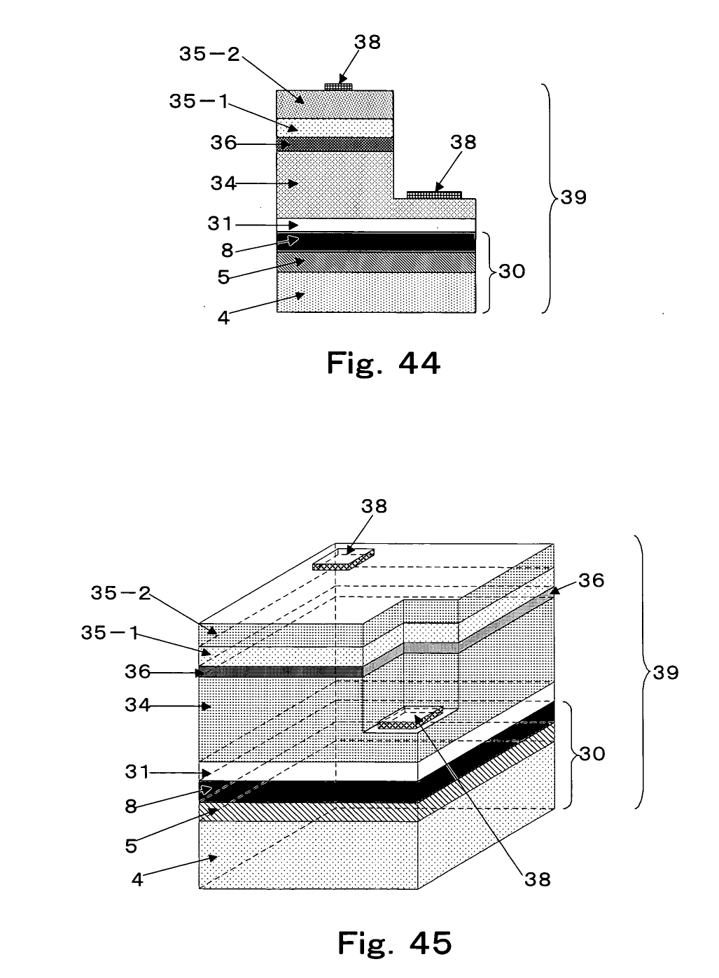

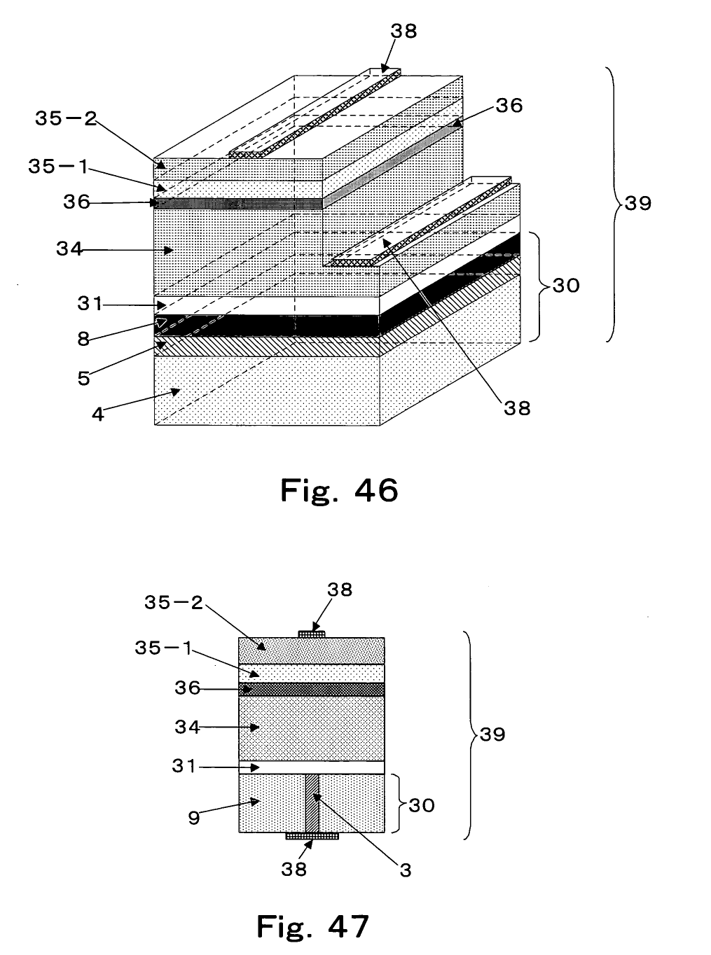

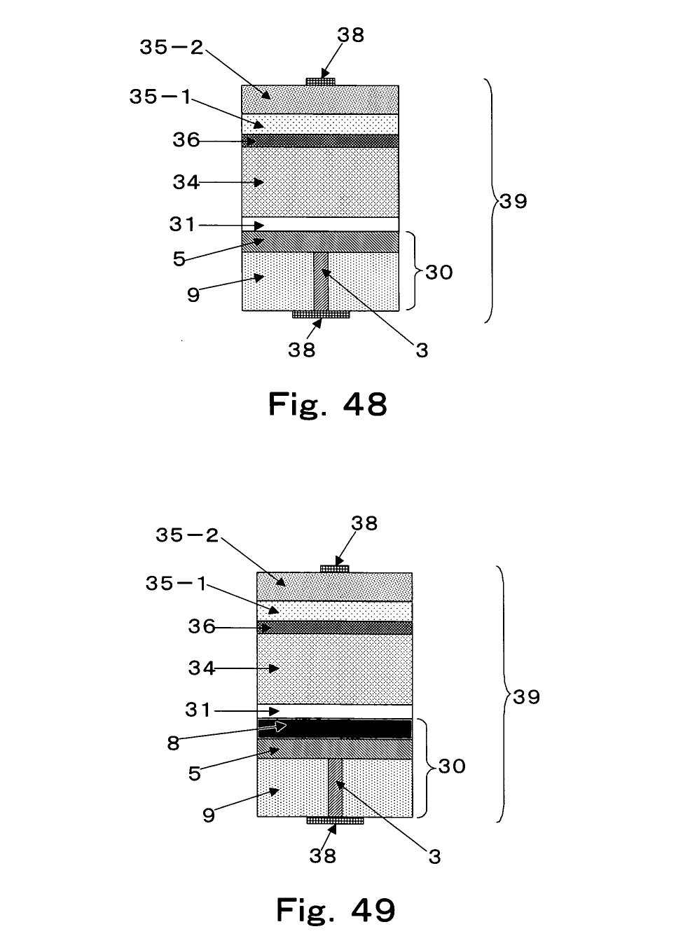

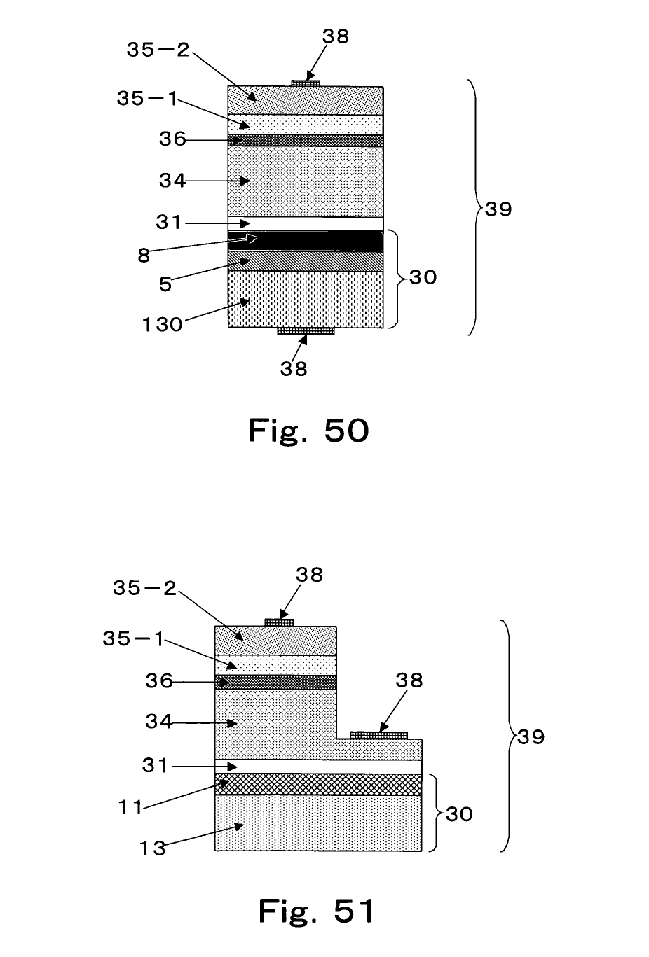

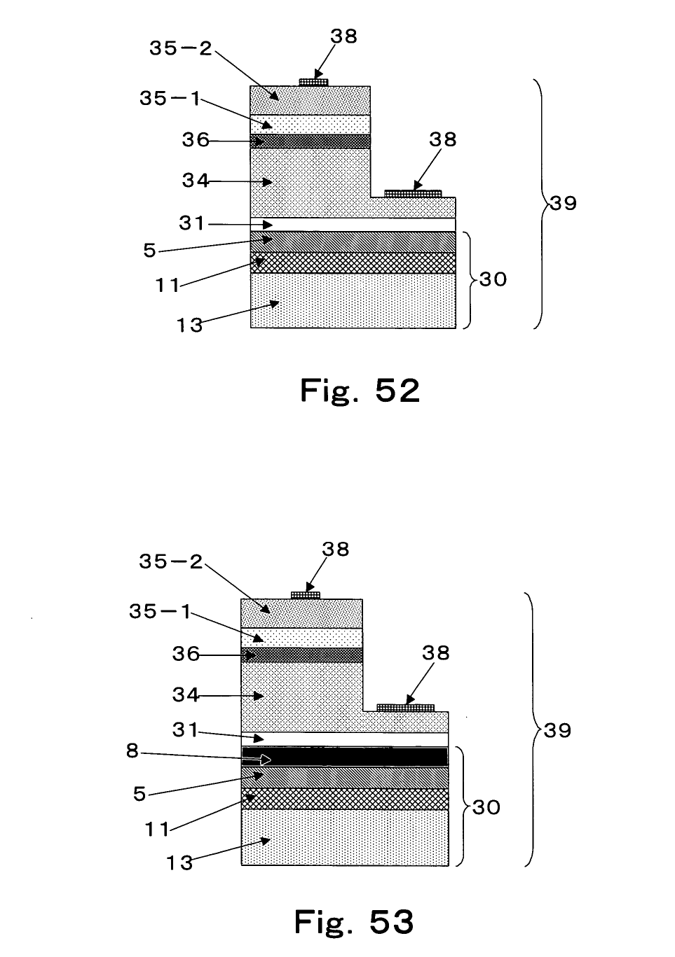

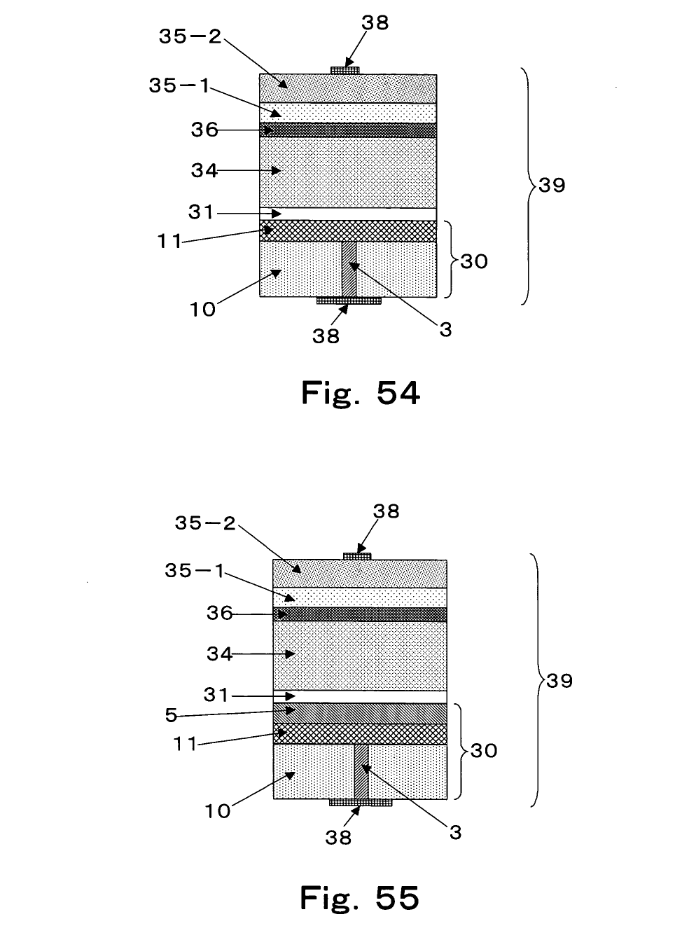

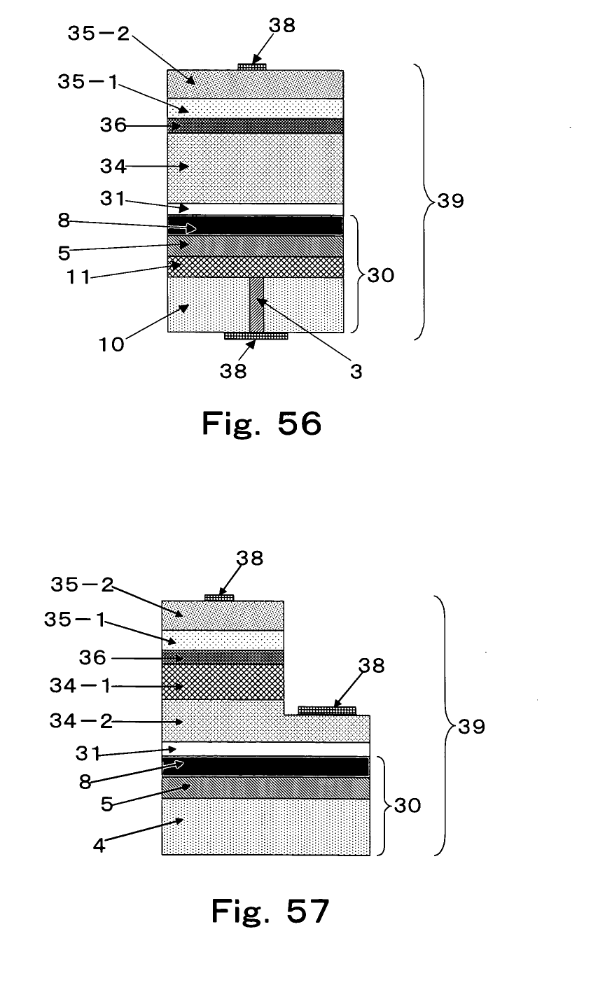

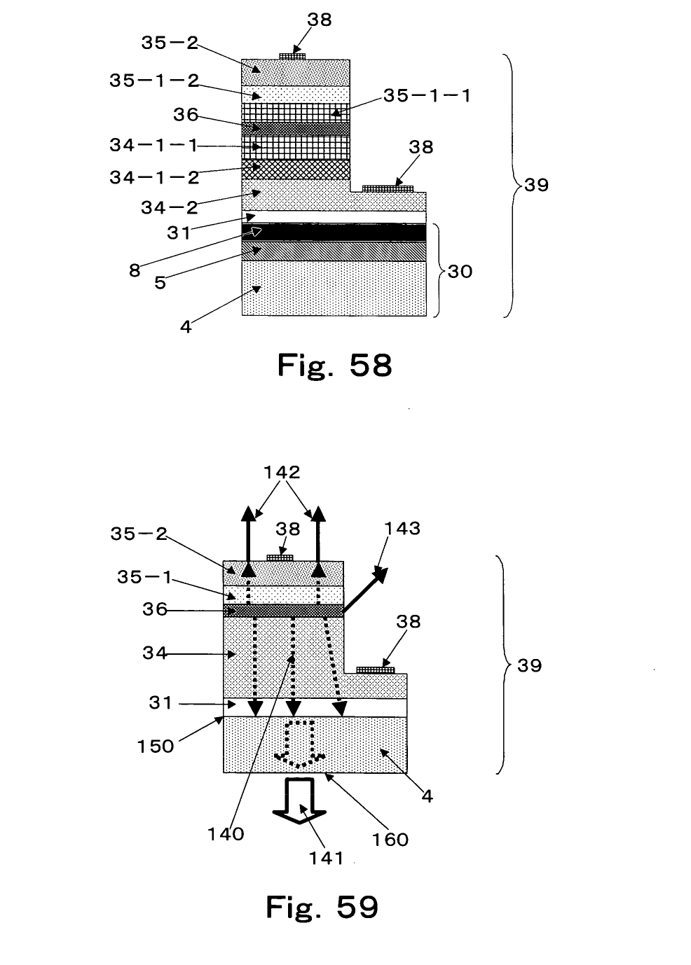

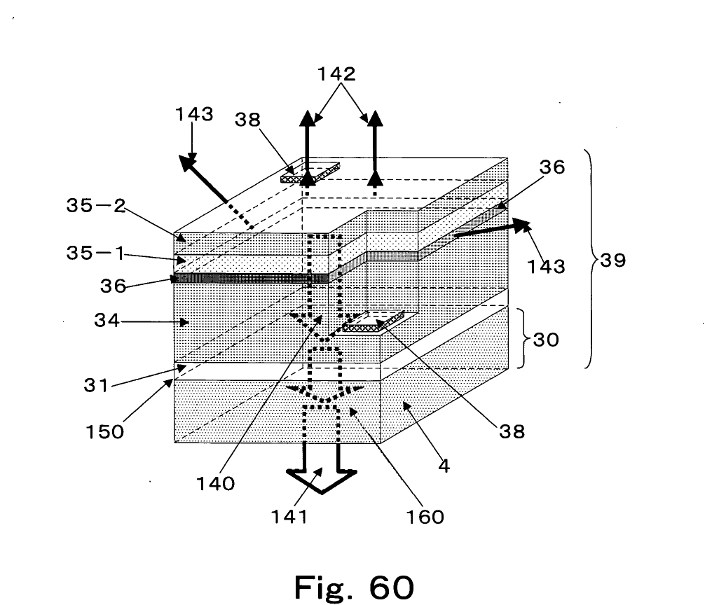

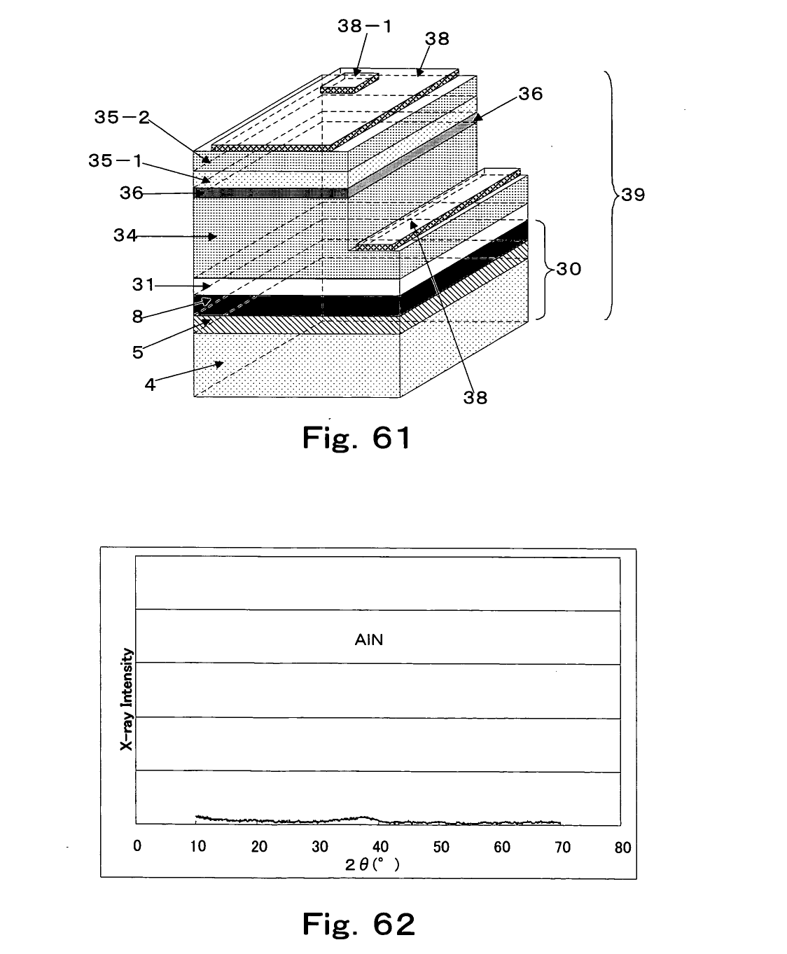

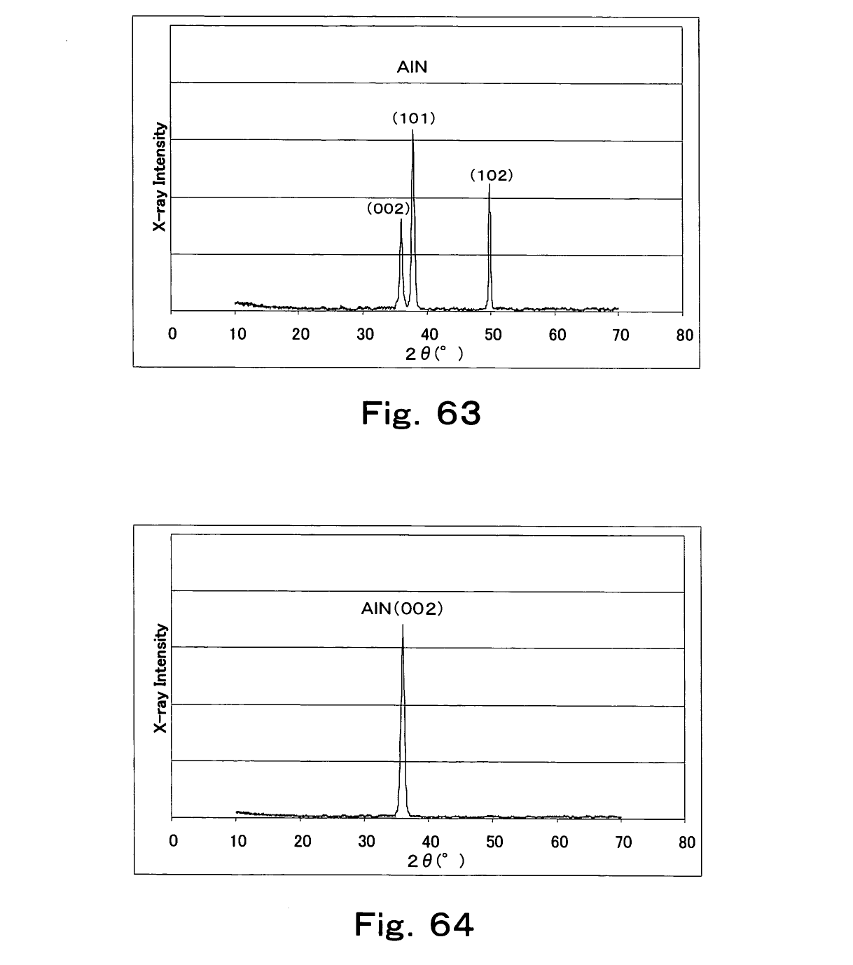

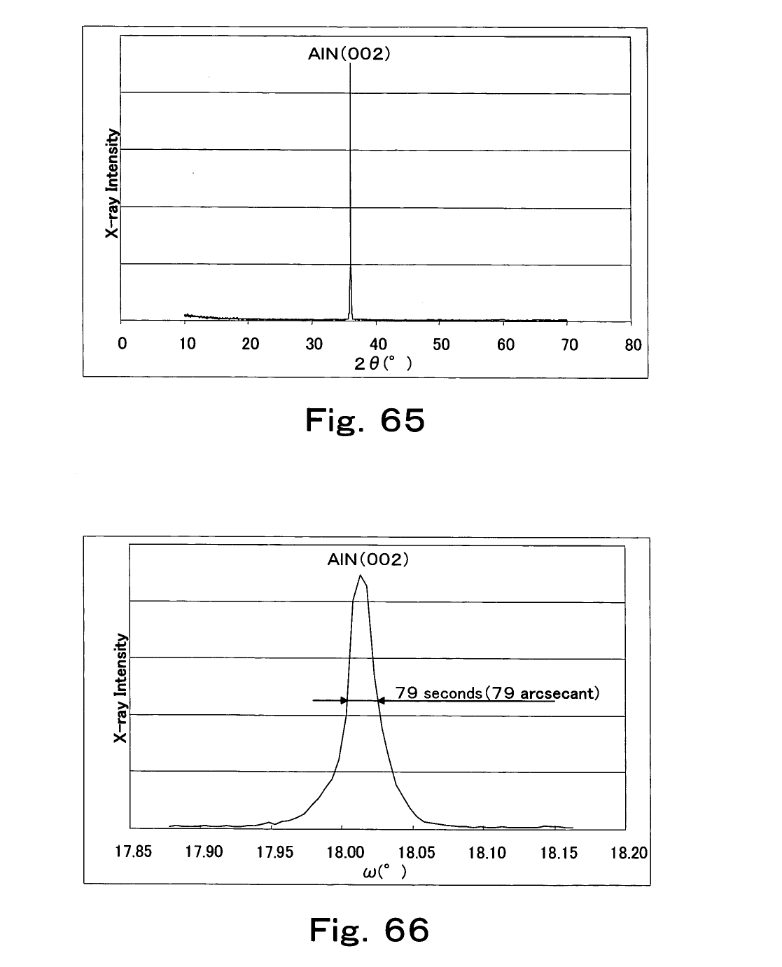

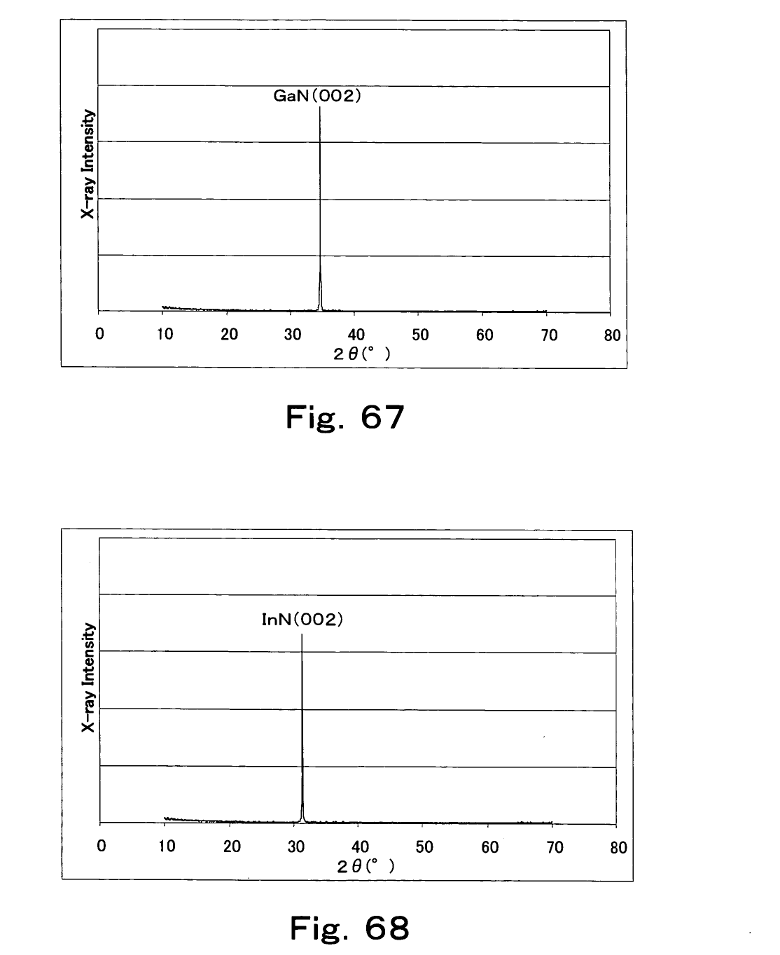

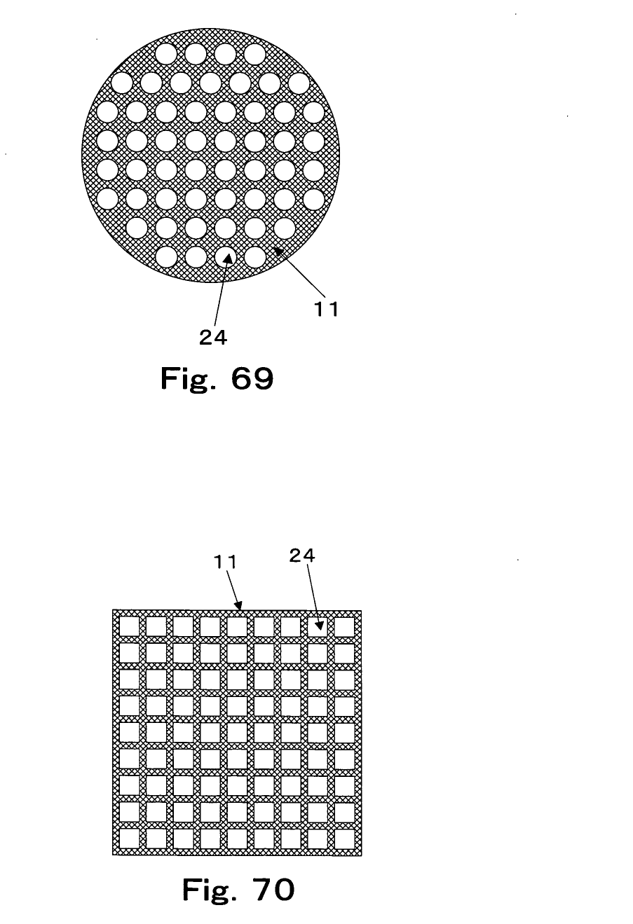

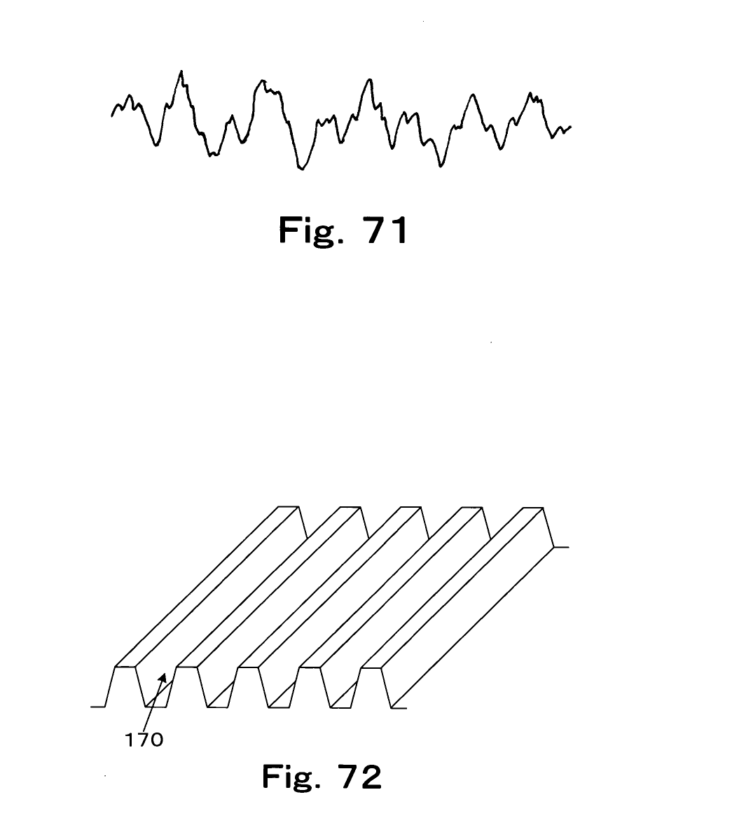

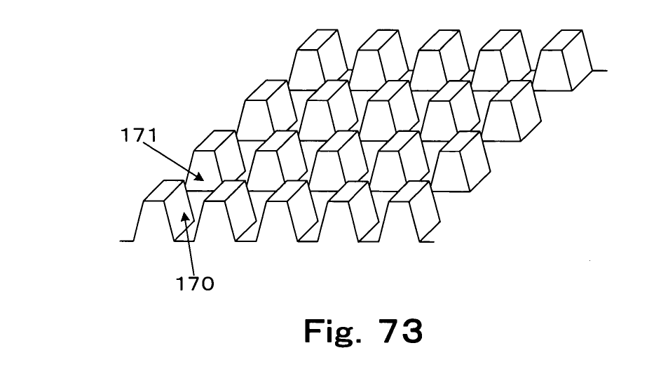

The reference numerals in FIGS. 1-73 are as follows:
1 Substrate comprising the aluminum nitride-based sintered compact,
2 Single crystal thin film comprising as a main component at least one selected from gallium nitride, indium nitride and aluminum nitride,
3 Conduction via,
4 Sintered compact substrate comprising aluminum nitride as a main component, sintered compact substrate comprising as a main component a ceramic material having the crystal structure which can be classified as a hexagonal system, such as silicon carbide, silicon nitride, gallium nitride, zinc oxide, and beryllium oxide, etc., and can be classified as a trigonal system or a hexagonal system, such as aluminum oxide, etc., or other ceramic-based sintered compact substrates,
5 Thin film comprising as a main component at least one selected from gallium nitride, indium nitride and aluminum nitride,
6 Thin film substrate,
7 Thin film substrate having conduction vias,
8 Thin film comprising as a main component at least one selected from gallium nitride, indium nitride and aluminum nitride,
9 Substrate with conduction vias comprising an aluminum nitride-based sintered compact, various ceramic-based sintered compact having the crystal structure which can be classified as a hexagonal system, such as silicon carbide, silicon nitride, gallium nitride, zinc oxide, and beryllium oxide, etc., and can be classified as a trigonal system or a hexagonal system, such as aluminum oxide, etc., and other various sintered compact comprising a ceramic material as a main component in addition to these
10: Substrate comprising an aluminum nitride-based sintered compact having conduction vias
11: Thin conductive film
12: Thin conductive film in a circuit pattern form
13: Substrate comprising aluminum nitride-based sintered compact,
14: Substrate comprising aluminum nitride-based sintered compact,
15: Thin film substrate with a thin conductive film,
16: Thin with conduction vias and a thin conductive film,
17: Thin film substrate with conduction vias and a thin conductive film,
18: Thin film substrate with a thin conductive film
19: Thin film substrate with a thin conductive film
20: Thin with conduction vias and a thin conductive film
21: Thin film substrate with a thin conductive film
24: Space formed in a thin conductive film
30: Substrate for light-emitting device,
31: Buffer layer,
32: Light-emitting device,
32-1: Thin film,
32-2: Thin film comprising as a main component at least one selected from gallium nitride, indium nitride and aluminum nitride,
33: Conventional substrate for light-emitting device
34: Thin film layer comprising as a main component at least one selected from gallium nitride, indium nitride and aluminum nitride and having N- or P-type semiconductor characteristics
34-1: Thin film layer comprising as a main component at least one selected from gallium nitride, indium nitride and aluminum nitride and having N- or P-type semiconductor characteristics
34-1-1: Thin film layer comprising as a main component at least one selected from gallium nitride, indium nitride and aluminum nitride and having N- or P-type semiconductor characteristics
34-1-2: Thin film layer comprising as a main component at least one selected from gallium nitride, indium nitride and aluminum nitride and having N- or P-type semiconductor characteristics
34-2: Thin film layer comprising as a main component at least one selected from gallium nitride, indium nitride and aluminum nitride and having N- or P-type semiconductor characteristics
34-2-1: Thin film layer comprising as a main component at least one selected from gallium nitride, indium nitride and aluminum nitride and having N- or P-type semiconductor characteristics
34-2-2: Thin film layer comprising as a main component at least one selected from gallium nitride, indium nitride and aluminum nitride and having N- or P-type semiconductor characteristics
35: Thin film layer comprising as a main component at least one selected from gallium nitride, indium nitride and aluminum nitride and having N- or P-type semiconductor characteristics
35-1: Thin film layer comprising as a main component at least one selected from gallium nitride, indium nitride and aluminum nitride and having N- or P-type semiconductor characteristics
35-1-1: Thin film layer comprising as a main component at least one selected from gallium nitride, indium nitride and aluminum nitride and having N- or P-type semiconductor characteristics
35-1-2: Thin film layer comprising as a main component at least one selected from gallium nitride, indium nitride and aluminum nitride and having N- or P-type semiconductor characteristics
35-2: Thin film layer comprising as a main component at least one selected from gallium nitride, indium nitride and aluminum nitride and having N- or P-type semiconductor characteristics
35-2-1: Thin film layer comprising as a main component at least one selected from gallium nitride, indium nitride and aluminum nitride and having N- or P-type semiconductor characteristics
35-2-2: Thin film layer comprising as a main component at least one selected from gallium nitride, indium nitride and aluminum nitride and having N- or P-type semiconductor characteristics
36: Luminescence layer
37: Light-emitting device using a conventional substrate
38: Electrode
38-1: Terminal for electric power supplies
39: Light-emitting device according to this invention
40: Dielectric material
50: Two dimensional optical waveguide
60: Three dimension optical waveguide
61: Ridge type of three dimension optical waveguide
62: Three dimension optical waveguide
63: Three dimension optical waveguide
64: Three dimension optical waveguide
65: Embedded type of three dimension optical waveguide
65′: Optical introductory part of the optical waveguide
66: Introductory light to an optical waveguide
66′: Emission light from the optical waveguide
70: Cladding layer
71: Cladding layer
80: Thin film comprising as a main component at least one selected from gallium nitride, indium nitride and aluminum nitride
90: Electrode
91: Electrode
100: Metal material
110: Buffer layer
120: Electrode
130: Substrate comprising a ceramic-based sintered compact having electrical conductivity
140: Light emitted from the luminescence layer
141: Light penetrating the substrate and emitted outside from a light-emitting device
142: Light emitted to the outside of a light-emitting device from the thin film layer
143: Light emitted to the outside of a light-emitting device from the luminescence layer
150: Interface of the substrate and the thin film layer
160: Interface of the substrate and the outside space
170: Slot
171: Slot

The substrate for a thin film may be formed by a ceramic-based sintered compact with or without optical permeability.
(1) A ceramic-based sintered compact with or without optical permeability is provided with a thin film comprising as a main component at least one selected from gallium nitride, indium nitride and aluminum nitride.

Specifically,
(2) The ceramic-based sintered compact is an aluminum nitride-based sintered compact substrate.
(3) The ceramic-based sintered compact has a hexagonal or trigonal crystal structure.
(4) The aluminum nitride-based sintered compact substrate is provided with a thin film comprising as a main component at least one selected from gallium nitride, indium nitride and aluminum nitride.
(5) The ceramic-based sintered compact substrate having a hexagonal or trigonal crystal structure is provided with a thin film comprising as a main component at least one selected from gallium nitride, indium nitride and aluminum nitride.
(6) The sintered compact substrate comprises as a main component at least one of various ceramics, such as zirconium oxide, magnesium oxide, magnesium aluminate, titanium oxide, barium titanate, lead titanate zirconate, and rare-earth element oxides such as yttrium oxide, thorium oxide, various ferrites, mullite, forsterite, steatite and glass.
(7) The sintered compact comprises as a main component at least one of various ceramics, such as zirconium oxide, magnesium oxide, magnesium aluminate, titanium oxide, barium titanate, lead titanate zirconate, and rare-earth element oxides such as yttrium oxide, thorium oxide, ferrite, mullite, forsterite, steatite and glass, on which a thin film comprising as a main component at least one selected from gallium nitride, indium nitride and aluminum nitride is formed.
(8) The ceramic-based sintered compact substrate with or without optical permeability is provided with a single-crystal thin film comprising as a main component at least one selected from gallium nitride, indium nitride and aluminum nitride.
(9) The ceramic-based sintered compact substrate is provided with a thin film comprising as a main component at least one selected from gallium nitride, indium nitride and aluminum nitride, which may be in a single-crystalline, amorphous, polycrystalline or orientated polycrystalline.
(10) The single-crystal thin film comprising as a main component at least one selected from gallium nitride, indium nitride and aluminum nitride is formed on the ceramic-based sintered compact with or without optical permeability.

Specifically,
(11) The aluminum nitride-based sintered compact is provided with a single-crystal thin film comprising as a main component at least one selected from gallium nitride, indium nitride and aluminum nitride.
(12) The ceramic-based sintered compact having a hexagonal or trigonal crystal structure is provided with a single-crystal thin film comprising as a main component at least one selected from gallium nitride, indium nitride and aluminum nitride.
(13) The sintered compact comprising as a main component at least one of various ceramics, such as zirconium oxide, magnesium oxide, magnesium aluminate, titanium oxide, barium titanate, lead titanate zirconate, and rare-earth element oxides such as yttrium oxide, thorium oxide, various ferrites, mullite, forsterite, steatite and glassa is provided with a single-crystal thin film comprising as a main component at least one selected from gallium nitride, indium nitride and aluminum nitride.
(14) The aluminum nitride-based sintered compact with optical permeability is provided with a thin film comprising as a main component at least one selected from gallium nitride, indium nitride and aluminum nitride.
(15) The sintered compact having optical permeability and comprising as a main component a ceramic material having a hexagonal or trigonal crystal structure is provided with a thin film comprising as a main component at least one selected from gallium nitride, indium nitride and aluminum nitride.
(16) The thin film substrate having a thin film comprising as a main component at least one selected from gallium nitride, indium nitride and aluminum nitride, which is formed on a sintered compact having optical permeability and comprising as a main component zirconium oxide, magnesium oxide, magnesium aluminate, titanium oxide, barium titanate, lead titanate zirconate, and rare-earth element oxides such as yttrium oxide, thorium oxide, various ferrites, mullite, forsterite, steatite and glass.
(17) The thin film comprising as a main component at least one selected from gallium nitride, indium nitride and aluminum nitride, which is single-crystalline, amorphous, polycrystalline or orientated-polycrystalline, is formed on either one of the aluminum nitride-based sintered compact, the ceramic-based sintered compact having a hexagonal or trigonal crystal structure, and the ceramic-based sintered compact such as zirconium oxide, magnesium oxide, magnesium aluminate, titanium oxide, barium titanate, lead titanate zirconate, and rare-earth element oxides such as yttrium oxide, thorium oxide, various ferrites, mullite, forsterite, steatite and glass.

The above thin film can use not only the single layer but also the thin film comprising two or more layers, such that at least one of crystallization states selected from a single crystal, an amorphous state, a polycrystal, and an orientated polycrystal is formed beforehand on the ceramic-based sintered compact and that a single-crystal thin film is formed furthermore on it.

Usually, the crystallinity of the single-crystal thin film is preferably formed on it after at least one of crystallization states selected from a single crystal, an amorphous state, a polycrystal, and an orientated polycrystal is formed beforehand, since it tends to improve than what was directly formed on the ceramic-based sintered compact.

The above thin film substrate can be used as a substrate for a thin film for forming the thin film comprising as a main component at least one selected from gallium nitride, indium nitride and aluminum nitride.

In addition, about the glass used as the above ceramic-based sintered compact, it has the structure in which crystal substances, such as cordierite, anorthite (anorthite), corundum (Al₂O₃), mullite (3Al₂O₃.2SiO₂), wollastonite (CaO—SiO₂), and magnesium silicate (MgO—SiO₂), exist in the glass matrix, for example, such as borosilicate glass (usually, it comprises SiO₂ and B₂O₃ as a main component, and contains components, such as Al₂O₃, CaO, BaO, and PbO, etc., in addition to this).

Glass ceramics is usually produced by the method which fires and sinters the powder compact which is made by the uniaxial press method or the sheet forming method, adding suitably alumina powder, silica powder, magnesia powder, calcium carbonate powder, barium carbonate powder, boron oxide powder, lead oxide, etc. into glass powder, adding furthermore components, such as TiO₂, ZrO₂, SnO₂, ZnO, and Li₂O, if it requires, and mixing them.

If what added suitably components, such as above TiO₂, ZrO₂, SnO₂, ZnO, and Li₂O, at the time of manufacture is fired, crystallization will be promoted in many cases.

In addition, glass can be produced with the method which deposits a crystal in the molded glass, etc., heat-treating the molded glass which was fused and formed.

“Ceramic material” means that the material constituting a sintered compact is what comprises an inorganic material as a main component, in the ceramic-based sintered compact or the ceramic-based sintered compact with optical permeability which are used as the substrate for a thin film and the thin film substrate according to this invention.

Usually, the inorganic material comprises the composite or compound of at least one selected from metal elements and semimetal elements and at least one selected from nonmetallic elements, or the composite or compound of at least one selected from metal elements and at least one selected from semimetal elements, or the composite or compound of at least two selected from semimetal elements.

As the above nonmetallic element, usually, nitrogen, phosphorus, oxygen, sulfur, halogen element (fluorine, chlorine, bromine, iodine, astatine), etc. are used suitably.

As semimetal elements, usually, boron, carbon, silicon, germanium, arsenic, antimony, bismuth, selenium, tellurium, polonium, etc. are used suitably.

The above ceramic materials usually comprise as a main component an inorganic compound, and such ceramic materials may be a crystallization state, or an amorphous state, such as glass, etc., or a state in which a crystalline material and an amorphous material are intermingled.

The above ceramic material usually comprises as a main component a compound or a composite, such as nitrides, carbides, oxides, borides and silicides.

If these compounds or composites are shown Specifically, for example, there are aluminum nitride, a compound having at least one of crystal structures selected from a hexagonal system or a trigonal system (for example, silicon carbide, silicon nitride, gallium nitride, zinc oxide, beryllium oxide, aluminum oxide, etc.), zirconium oxide, magnesium oxide, magnesium aluminate, titanium oxide, barium titanate, lead titanate zirconate, rare-earth oxides, such as yttrium oxide, thorium oxide, various ferrites, mullite, forsterite, steatite and glass

As the above ceramic materials, the things containing non-metal, such as a halogen element or a chalcogen element, etc., for example, in addition to a metal, an alloy, an intermetallic compound, an organic substance, an organic compound, and an organic resin are included other than the inorganic material which is the main components.

The above ceramic-based sintered compact preferably has optical permeability, since a single-crystal thin film formed thereon and comprising as a main component at least one selected from gallium nitride, indium nitride and aluminum nitride easily has improved crystallinity.

According to this invention, the above substrate for a thin film and thin film substrate can be used as a substrate for producing a light-emitting device by forming the epitaxially grown thin film comprising as a main component at least one selected from gallium nitride, indium nitride and aluminum nitride onto them.

The epitaxially grown thin film can be used as a substrate for field emission material.

The thin film substrate can be used for an optical waveguide, the piezo-electric film of surface acoustic wave devices, etc., and the insulation film or dielectric film of electrical wiring boards, etc., by processing suitably the thin film formed on it from the first, without forming furthermore a thin film or a single-crystal thin film.

The sintered compact substrate for forming a single-crystal thin film comprising as a main component at least one selected from gallium nitride, indium nitride and aluminum nitride is neither a bulk-like single crystal nor an orientated polycrystalline substance.

A bulk-like single crystal cannot exist as a single crystal only in a state where it is formed in other material, such as a substrate, it means those which can exist as a single crystal in the self state.

Therefore, it is not related to the size, if it can exist as a single crystal in the self state, it is a bulk-like single crystal even if it is a thin film shape and is a small grain shape, and even if coexisting with other materials, such as being temporarily formed on a substrate.

An orientated polycrystal is a polycrystal in which the crystal of constitution material has turned to the specific crystal-axis direction and turned to the random direction to the other crystal-axis direction, and differs from a bulk-like single crystal.

For example, it differs from the usual polycrystal in which the crystal of constitution material, such as a sintered compact, has turned to the random direction.

On the sintered compact substrate comprising as a main component at least one selected from gallium nitride, indium nitride and aluminum nitride, aluminum nitride crystal grains are oriented randomly in the thin film.

On the ceramic-based sintered compact substrate having a hexagonal or trigonal crystal structure, or on the sintered compact comprising as a main component at least one of various ceramics, such as zirconium oxide, magnesium oxide, magnesium aluminate, titanium oxide, barium titanate, lead titanate zirconate, and rare-earth element oxides such as yttrium oxide, thorium oxide, various ferrites, mullite, forsterite, steatite and glass in addition to aluminum nitride, fine crystal grains are oriented randomly in the thin film.

When single-wavelength characteristic X-rays are irradiated to the substrate of this invention, only diffraction lines from a specific crystal plane appear in the case of a bulk-like single crystal and an orientated polycrystal, but all diffraction lines except for those which cannot appear as a basis appear by an extinction rule in the case of the substrate of this invention. In this sense, the substrate of the present invention is clearly distinguishable from those of bulk-like single crystals.

The aluminum nitride-based sintered compact, the ceramic-based sintered compact having a hexagonal or trigonal crystal structure, or the sintered compact comprising as a main component at least one of various ceramics, such as zirconium oxide, magnesium oxide, magnesium aluminate, titanium oxide, barium titanate, lead titanate zirconate, and rare-earth element oxides such as yttrium oxide, thorium oxide, various ferrites, mullite, forsterite, steatite and glass are polycrystalline. Such sintered compact is produced by high-temperature firing of a green body comprising ceramic powders, a sintering aid, an organic binder, a solvent, etc.

The single-crystal thin film is formed integrally on the ceramic-based sintered compact substrate. It extends two-dimensionally and integrally with the substrate, unlike the three-dimensional bulk-like single crystal.

Conventionally, when the single crystals having comparative large size and can be expressed with the three-dimensional size, such as the shape of a lump and the shape of bulk, are grown up on a substrate by the sublimating method, etc. for example, those which is comparatively excellent in crystallinity can be produced easily in many cases, without seldom being influenced with the composition and material quality of a substrate or the internal structure and surface state of a substrate, etc.

The lump-like or bulk-like single crystal formed can be separated from a substrate. On the other hand, the two-dimensional, single-crystal thin film of this invention is adhered to the ceramic-based sintered compact substrate. However, when such single-crystal thin film adhered to the ceramic-based sintered compact is as thin as 300 sum or less, usually about 100-200 μm, it is easily influenced by the composition and material, heterogeneous internal structure and surface state of the polycrystalline, ceramic-based sintered compact, resulting in as low crystallinity as amorphous, polycrystalline or an orientated-polycrystalline. It is thus difficult to form a single-crystal thin film.

For the reasons of the difference of the internal structure of a film-like single crystal and the internal structures of the ceramic-based sintered compact, a crack and a defect arise in the single-crystal thin film formed, and it was easy to produce exfoliation, etc. in the interface of the single-crystal thin film and ceramic-based sintered compact.

Though it seems that methods, such as the above sublimating method for example, are suitable as a method of obtaining an independently large-sized single crystal, such as the shape of a lump and the shape of bulk, it is easy to produce distortion since the crystal growth is performed at high temperature, and the single-crystal thin film and substrate have the fault of being easy to produce faults, such as crack and exfoliation when growing a single-crystal thin film into a substrate.

It was thus difficult to produce the single-crystal thin film integral with the substrate.

In such a situation, according to this invention, to the ceramic-based sintered compact, directly, the single-crystal thin film comprising as a main component at least one selected from gallium nitride, indium nitride and aluminum nitride adheres and is unified firmly, it became possible to be able to form in a state where there is nothing, such as the above crack, defect, or exfoliation.

According to this invention, even a single-crystal thin film is adhered integrally to the ceramic-based sintered compact.

Using the ceramic-based sintered compact and formed beforehand the thin film comprising as a main component at least one selected from gallium nitride, indium nitride and aluminum nitride and having various crystal states, such as the single crystal, the amorphous, the polycrystal, and the orientated polycrystal, etc. for example, the single-crystal thin film comprising as a main component at least one selected from gallium nitride, indium nitride and aluminum nitride and is more excellent in crystallinity is unified firmly on it, and it became clear that it can be formed in a state where there is nothing, such as the above crack, defect, or exfoliation.

Even if such single-crystal thin film formed has comparatively thick thickness and is thicker, for example than 100-200 μm, those excellent in crystallinity can be formed.

As the reason the crystalline improvement in such a single-crystal thin film is seen, it becomes hard to be influenced with the composition, quality of the material, internal structure, or surface state, etc. of the ceramic-based sintered compact and is a polycrystalline substance by forming beforehand the thin film of the various above crystal states, therefore it probably seems that the single-crystal thin film which is more excellent in crystallinity becomes easy to grow.

This invention provides the substrate for a thin film which used such a ceramic-based sintered compact.

This invention also provides the thin film substrate in which a ceramic-based sintered compact, and a single-crystal thin film with higher crystallinity comprising as a main component at least one selected from gallium nitride, indium nitride and aluminum nitride are unified firmly.

The single-crystal thin film comprising as a main component at least one selected from gallium nitride, indium nitride and aluminum nitride and is more excellent in crystallinity can be formed on the various sintered compacts having optical permeability and comprise as a main component a ceramic material, such as aluminum nitride, etc., in many cases, and even if a thin film has comparatively thick thickness and is thicker, for example than 100-200 μm, comparatively high crystallinity can be obtained in many cases.

The sintered compact based on ceramics such as aluminum nitride with optical permeability has higher purity and more homogeneous internal structure than those without optical permeability.

The single-crystal thin film comprising as a main component at least one selected from gallium nitride, indium nitride and aluminum nitride, which is adhered integrally to the polycrystalline sintered compact, is easily influenced by the composition, material, internal structure and surface state of the sintered compact, unlike the lump-like or bulk-like single crystal.

A high-crystallinity, field-like, single-crystal thin film comprising as a main component at least one selected from gallium nitride, indium nitride and aluminum nitride can be formed integrally with the ceramic-based sintered compact with optical permeability.

The high-crystallinity, single-crystal thin film comprising as a main component at least one selected from gallium nitride, indium nitride and aluminum nitride, which is single-crystalline, amorphous, polycrystalline or orientated-polycrystalline, is suitably formed on a ceramic-based sintered compact with optical permeability.

The thin film substrate of the present invention comprises a ceramic-based sintered compact with optical permeability, and a high-crystallinity, single-crystal thin film comprising as a main component at least one selected from gallium nitride, indium nitride and aluminum nitride, which is formed integrally on the ceramic-based sintered compact.

The three-dimensional single crystals having comparative large size, such as a lump or a bulk, after sublimating the material itself by heating the raw material containing the single-crystal material itself (for example, in the case of the bulk-like single crystal comprising silicon carbide as a main component, it is silicon carbide powder, and when producing the bulk-like single crystal comprising aluminum nitride as a main component, it is aluminum nitride powder.) in the comparatively high temperature or near the melting point and decomposition temperature of a material (for example, in the case of the bulk-like single crystal comprising silicon carbide as a main component, it is about 2000-2600° C., In the case of the bulk-like single crystal comprising aluminum nitride as a main component, it is about 1700-2200° C.) which are probably near the equilibrium state, controlling the pressure of atmosphere, gas composition, etc. like the sublimating method, for example, it is usually produced by the method of making it deposit as a single crystal in many cases. The large single crystal excellent in crystallinity independently can be produced comparatively easily in many cases without seldom being influenced by the material quality of a substrate or the internal structure or surface state of a substrate, etc.

This is probably considered that a single crystal with high crystallinity grows without seldom being influenced by a substrate, since it is carried out in the state near equilibrium and the sublimation substance itself tends to become a seed crystal when growing the above lump-like or bulk-like single crystal onto a substrate by the sublimating method.

Since the alumina of a raw material is fused and a single crystal is grown when producing sapphire, for example by the Czochralski method, etc., the single crystal is produced in the state near equilibrium.

According to this invention, if the single-crystal thin film having the shape of two-dimensional spread is formed in the state which adhered to the a ceramic-based sintered compact substrate and is integrally adhered to it, it is usually produced by the MOCVD (Metal Organic Chemical Vapor Deposition) method, the MOVPE (Metal Organic Vapor Phase Epitaxy) method or the Halide VPE (Halogen Transport Vapor Phase Epitaxy) method, etc. to make the crystallinity of a single-crystal thin film easier to raise.

In such a method, the substrate temperature is usually about 1500° C. at maximum, there is a substrate temperature range which is easily single-crystallized by the forming method or the single crystal composition. As raw materials for a single-crystal thin film, metal-containing compounds, for example, gallium-containing compounds such as trimethyl gallium for gallium nitride, indium-containing compounds such as trimethyl indium for indium nitride, or aluminum-containing compounds such as trimethyl aluminum for aluminum nitride, are mostly used for a target, there is a low crystallinity case where it becomes an amorphous, a polycrystal thin film, or an orientated polycrystal thin film, for example, according to conditions, because such a compound passes through process in which a single-crystal thin film is obtained by being once decomposed and being made into the target composition by a nitriding reaction after that, and formation of a single-crystal thin film is easily performed in a non-equilibrium state.

Though the sputtering method, the ion plating method, or the vapor-depositing method, etc. can be used as a method of performing thin film formation using the thin film composition itself which does not pass through process, such as decomposition and a reaction, as a raw material for thin film formation, usually, the thin film cannot become a single crystal easily since thin film formation is performed under a non-equilibrium state, such that it is performed under the low substrate temperature of about not more than 600-700° C., it is easy to become an amorphous thin film, a polycrystal thin film, or an orientated polycrystal thin film which are low in crystallinity.

The single-crystal thin film formed on a substrate tends to have lower crystallinity than the lump-like or bulk-like single crystal having three-dimensional size, resulting in such defects as cracking and exfoliation.

This invention presents the method which can provide those having comparatively high crystallinity equally close to the lump-like or bulk-like single crystal and having few defects, such as a crack and exfoliation between substrates even if it is the single-crystal thin film in which the crystallinity tends to become small and having the tendency which produces a defect, etc.

According to this invention, even if it is not only those as thick as less than 300 μm, usually about 200 μm, but also those as thick as about 0.1 nm, it can form now suitably as the single-crystal thin film comprising as a main component at least one selected from gallium nitride, indium nitride and aluminum nitride, for example.

As mentioned above, the single-crystal thin film comprising as a main component at least one selected from gallium nitride, indium nitride and aluminum nitride can be formed directly on the ceramic-based sintered compact.

When it is going to form a single-crystal thin film having higher crystallinity in the ceramic-based sintered compact, it is preferred to use methods, for example, such as the method using the ceramic-based sintered compact and formed the thin film comprising as a main component at least one selected from gallium nitride, indium nitride and aluminum nitride, or the method using the ceramic-based sintered compact with optical permeability, or the method using the ceramic-based sintered compact with optical permeability and formed the thin film comprising as a main component at least one selected from gallium nitride, indium nitride and aluminum nitride.

Specifically, In the method using the ceramic-based sintered compact and formed the thin film comprising as a main component at least one selected from gallium nitride, indium nitride and aluminum nitride, those which is in an amorphous, polycrystalline, orientated polycrystalline or single-crystalline state can be used suitably as the thin film comprising as a main component at least one selected from gallium nitride, indium nitride and aluminum nitride.

Among the thin films having these crystallization states, an at least partially single-crystalline thin film is preferred.

In the thin film with two or more layers, each layer may be amorphous, polycrystalline, orientated polycrystalline or single-crystalline.

In the thin film with two or more layers, a thin film layer directly formed on the ceramic-based sintered compact may be amorphous, polycrystalline, orientated polycrystalline or single-crystalline.

In the thin film with two or more layers, a thin film layer directly formed on the ceramic-based sintered compact is suitably amorphous, polycrystalline or orientated polycrystalline.

In the thin film with two or more layers, a thin film layer directly formed on the ceramic-based sintered compact is suitably orientated-polycrystalline.

In the two-layer thin film, at least one layer may be single-crystalline, and the top layer is preferably single-crystalline.

When the top thin film layer is single crystalline, a high-crystallinity thin film comprising as a main component at least one selected from gallium nitride, indium nitride and aluminum nitride can be formed thereon.

The thin film comprising as a main component at least one selected from gallium nitride, indium nitride and aluminum nitride, which has at least a single-crystal thin film layer as thick as 300 μm or less, usually 200 μm or less, particularly 100 μm or less, is preferably formed on the ceramic-based sintered compact.

As thick a thin film as 0.1 nm or more is preferably formed on the ceramic-based sintered compact, to prevent defects due to pinholes and crystal disorders, etc. in the thin film.

When a thin film comprises a thin film layer of two or more layers, if the total thickness of the thin film layers is not less than 0.1 nm even if the thickness of each thin film layer is respectively thinner than 0.1 nm, it is hard to avoid the above defects. More desirable thickness is not less than 0.5 nm, and the thickness of not less than 0.3 μm is more preferred. The ceramic-based sintered compact provided with a thin film as thick as not less than 3.5 μm, or not less than 10 μm, or not less than 50 μm can also be used suitably as a substrate for a thin film.

A thin film containing at least gallium nitride can be formed on the ceramic-based sintered compact. Specifically, a thin gallium nitride film or a gallium nitride-based thin film can be formed on the ceramic-based sintered compact. The high-crystallinity, single-crystal thin film comprising as a main component at least one selected from gallium nitride, indium nitride and aluminum nitride is easily formed on the ceramic-based sintered compact, providing high luminous efficiency for light-emitting devices.

The gallium nitride thin film or the gallium nitride-based thin film may contain indium nitride and/or aluminum nitride, a doping component such as Si and Mg, etc. Specifically, the thin film containing at least gallium nitride, which is formed on the ceramic-based sintered compact, comprises as a main component at least one selected from gallium nitride, indium nitride and aluminum nitride. Its composition is expressed by AlₓGa_{y}In_{1-x-y}N, wherein 0≦x<1, and 0≦1-x-y<1. The gallium nitride-based thin film usually contains 50 mol % or more of gallium nitride.

Usually, the thin film comprising as a main component at least one selected from gallium nitride, indium nitride and aluminum nitride contains totally a component selected from gallium nitride, indium nitride and aluminum nitride at least 50 mol %. the III-V group nitride thin film is the thin film comprising as a main component at least one selected from gallium nitride, indium nitride and aluminum nitride, and a boron component can be contained suitably as an III group element, in addition to those. By including a boron component, it has the feature in which light may be emitted in light with a short wavelength of 200 nm or less, when a light-emitting device is produced with the above III group nitride semiconductor and light is made to emit.

If the boron component is contained in the thin film comprising as a main component at least one selected from gallium nitride, indium nitride and aluminum nitride and contains a single crystal or a single crystal layer at least, there is the feature in which the thin film and a ceramic-based sintered compact can be unified more firmly. That is, the thin film and the ceramic-based sintered compact are adhered in a state where there is neither crack nor exfoliation, and adhesion strength is usually at least 3-5 kg/mm². The content of the boron component in the thin film comprising as a main component at least one selected from gallium nitride, indium nitride and aluminum nitride and containing a single crystal or a single crystal layer at least is usually not more than 50 mol % on a boron basis. If the content of a boron component increases to more than 50 mol %, it is not desirable, since it becomes easy to produce fault, such that the unification with the thin film and the ceramic-based sintered compact is no longer carried out enough, or it is hard to show N- or P-type semiconductor characteristic.

As a method of forming the thin film containing boron, the above methods, such as the MOCVD method, the various CVD methods, the MBE method, and the sputtering method, etc., can use similarly satisfactorily. When forming the thin film, organic boron compounds, such as trimethyl boron and triethyl boron, etc., halogenated compounds, such as boron trifluoride, boron trichloride, and boron tribromide, etc., and hydride, such as diborane, etc., etc., can be used, as the raw material containing a boron component. In addition to these, at least one of the material selected from boron, boron nitride, boron carbide, and metal boride, etc. can be used. At least one of the material selected from aluminum, gallium, indium, rare earth metals and alkaline-earth metals, etc. can be used, as the metal constituting the above metal boride. It seems that it usually exists as a nitride although existence form of the boron component in thin film is not necessarily clear.

The III-V group nitride thin film usually contains a component selected from gallium nitride, indium nitride and aluminum nitride as a main component, and contains furthermore a boron component if needed as mentioned above, and it can contain a component used usually as a doping agent, such as silicon (Si), germanium (Ge), selenium (Se), tellurium (Te), oxygen (O), magnesium (Mg), beryllium (Be), calcium (Ca), zinc (Zn), cadmium (Cd), and carbon (C), etc., and other metal component(s), semimetal component(s), and nonmetallic component(s), for example, in addition to those. As the metal component(s), the III-V group nitride thin film can contain alkaline metals, such as Li, Na, K, Rb, Cs, and Fr, alkaline-earth metals, such as Sr, Ba, and Ra, rare earth metals, such as Sc, Y, La, Ce, Pr, Nd, Pm, Sm, Eu, Gd, Tb, Dy, Ho, Er, Tm, Yb, and Lu, and other metals, such as titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), cobalt (Co), nickel (nickel), ruthenium (Ru), rhodium (Rd), palladium (Pd), osmium (Os), iridium (Ir), platinum (Pt), copper (Cu), silver (Ag), gold (Au), mercury (Hg), thallium (Tl), tin (Sn), and lead (Pb), etc. As the semimetal component(s), such as antimony (Sb), bismuth (Bi), polonium (Po), and arsenic (As), may usually be contained. As nonmetallic component(s), such as hydrogen (H), phosphorus (P), sulfur (S), and halogen elements, such as fluoride (F), chlorine (Cl), bromine (Br), iodine (I), and astatine (At), may usually be contained other than nitrogen. it is preferred that the content of the component other than gallium nitride, indium nitride, and aluminum nitride which are contained in the thin film is usually less than 50 mol %. If the content of the component other than gallium nitride, indium nitride, and aluminum nitride is not less than 50 mol %, it is not desirable, because fault, such that the thin film becomes hard to be semiconductorized, and a good crystalline single-crystal thin film becomes hard to be formed, arises.

When those containing a single crystal at least is used as a thin film formed on the ceramic-based sintered compact, it is preferred that the single-crystal thin film is the crystallinity in which the half width of the X ray diffraction rocking curve of a lattice plane (002) is not more than 3600 seconds, and it is more preferred that it is not more than 300 seconds. Those of not more than 240 seconds, not more than 200 seconds, not more than 150 seconds, or not more than 130 seconds is more preferred, and those not more than 100 seconds is most preferred.

In the method of using the ceramic-based sintered compact with optical permeability, a ceramic-based sintered compact and is the optical transmissivity not less than 1% can usually be used.

What is the optical transmissivity not less than 10%, not less than 20%, not less than 30%, not less than 40%, not less than 50%, not less than 60%, furthermore what is the optical transmissivity not less than 80% and not less than 85%, can also be used.

In the method of using the ceramic-based sintered compact with optical permeability and provided with the thin film comprising at least one selected from gallium nitride, indium nitride and aluminum nitride as a main component, those which is in an amorphous, polycrystalline, orientated polycrystalline or single-crystalline state can be used suitably as the thin film comprising as a main component at least one selected from gallium nitride, indium nitride and aluminum nitride.

Among the thin films having these crystallization states, those in which a part is a single crystal at least is preferred.

As for the thin film formed on the ceramic-based sintered compact with optical permeability, what has the thin film which includes gallium nitride at least or comprises gallium nitride as a main component can be used.

Those comprising only one layer as these thin films can be used.

Those comprising at least two layers as these thin films can be used.

In the thin film comprising two or more layers, each layer can use suitably those having in an amorphous, polycrystalline, orientated polycrystalline or single-crystalline state, respectively.

In the thin film comprising two or more layers, the thin film layer directly formed on the ceramic-based sintered compact with optical permeability can use those having in an amorphous, polycrystalline, orientated polycrystalline or single-crystalline state.

In the thin film comprising two or more layers, the thin film layer directly formed on the ceramic-based sintered compact with optical permeability can use those which is in an amorphous, polycrystalline or orientated polycrystalline.

In the thin film comprising two or more layers, the thin film layer directly formed on the ceramic-based sintered compact with optical permeability can use those which is an orientated polycrystal.

The two-layer thin film, in which at least one layer is a single crystal, can be used.

In the thin film comprising two or more layers, it is preferred that a top thin film layer is a single crystal. If the top thin film layer is a single crystal, a thin film comprising as a main component at least one selected from gallium nitride, indium nitride and aluminum nitride with excellent crystallinity can be formed on it.

It is preferred to use those in which the thin film comprising as a main component at least one selected from gallium nitride, indium nitride and aluminum nitride and formed on the ceramic-based sintered compact with optical permeability has a single-crystal thin film layer at least and whose thickness of the single-crystal thin film layer is less than 300 μm, usually not more than 200 μm.

The more desirable thickness of the single-crystal thin film layer formed on the ceramic-based sintered compact with optical permeability is not more than 100 μm.

It is preferred to use what has the thickness of at least not less than 0.1 nm as a thin film formed on the ceramic-based sintered compact with optical permeability. This is preferred to prevent the defect due to a pinhole and a disorder of crystal, etc. in a thin film.

When a thin film comprises a thin film layer of two or more layers, if the total thickness of the thin film layers is not less than 0.1 nm even if the thickness of each thin film layer is a case respectively thinner than 0.1 nm, it will be hard to produce the above defect. More desirable thickness is not less than 0.5 nm, and the thickness of not less than 0.3 μm is more preferred. The ceramic-based sintered compact with optical permeability having a thin film having thickness not less than 3.5 μm, or not less than 10 μm, or not less than 50 μm was formed as a substrate for a thin film suitably.

What contains at least gallium nitride as a thin film formed on the ceramic-based sintered compact with optical permeability can be used.

Specifically, the thin film formed on the ceramic-based sintered compact with optical permeability can use what has the thin film which includes gallium nitride at least or comprises gallium nitride as a main component.

what comprises gallium nitride as a main component can be used as a thin film formed on the ceramic-based sintered compact with optical permeability.

For example, when the ceramic-based sintered compact and formed the above thin film containing at least gallium nitride is used, on it, it becomes easy to form the single-crystal thin film comprising as a main component at least one selected from gallium nitride, indium nitride and aluminum nitride and is excellent in crystallinity, if a light-emitting device is produced using the ceramic-based sintered compact and formed the above thin film containing at least gallium nitride, what has higher luminous efficiency can produce.

As for the gallium nitride-based thin film, it may be the thin film in which doping components, such as at least one selected from indium nitride and aluminum nitride besides the gallium nitride component, and Si, and Mg, etc., for example, are contained.

Specifically, the thin film containing at least gallium nitride and formed on the ceramic-based sintered compact with optical permeability comprises as a main component at least one selected from gallium nitride, indium nitride and aluminum nitride. Its composition may be expressed by the chemical formula of AlₓGa_{y}In_{1-x-y}N, in which 0≦x<1, and 0≦1-x-y<1. Usually, the gallium nitride-based thin film contains 50 mol % or more of gallium.

When a thin film having at least a single crystal is formed on the ceramic-based sintered compact with optical permeability, the single-crystal thin film has crystallinity with a half width of an X ray diffraction rocking curve of a lattice plane (002), preferably 3600 seconds or less, more preferably 300 seconds or less. Those of not more than 240 seconds, 200 seconds or less, not more than 150 seconds, or not more than 130 seconds is more preferred, and those not more than 100 seconds is most preferred.

Even if it is the ceramic-based sintered compact with low optical permeability, for example, a ceramic-based sintered compact with optical transmissivity less than 1% or a ceramic-based sintered compact with 0% optical transmissivity, a single-crystal thin film comprising as a main component at least one selected from gallium nitride, indium nitride and aluminum nitride can be formed.

For example, when a thin film comprising as a main component at least one selected from gallium nitride, indium nitride and aluminum nitride is formed on such a ceramic-based sintered compact having small optical permeability, a single-crystal thin film with higher crystallinity can be formed.

As mentioned above, a substrate for a thin film of this invention comprises a ceramic-based sintered compact and a ceramic-based sintered compact with optical permeability, furthermore, it contains a ceramic-based sintered compact having the thin film comprising as a main component at least one selected from gallium nitride, indium nitride and aluminum nitride, and a ceramic-based sintered compact with optical permeability having the thin film comprising as a main component at least one selected from gallium nitride, indium nitride and aluminum nitride.

A thin film substrate is those in which the thin film comprising as a main component at least one selected from gallium nitride, indium nitride and aluminum nitride was formed on the ceramic-based sintered compact, and those in which the thin film comprising as a main component at least one selected from gallium nitride, indium nitride and aluminum nitride was formed on the ceramic-based sintered compact with optical permeability.

As for the above ceramic-based sintered compact, and ceramic-based sintered compact with optical permeability, they include at least the aluminum nitride-based sintered compact, or the ceramic-based sintered compact having at least one of the crystal structures selected from a hexagonal system or a trigonal system, or the sintered compact comprising at least one of materials selected from zirconium oxide, magnesium oxide, magnesium aluminate, titanium oxide, barium titanate, lead titanate zirconate, a rare earth element oxide, thorium oxide, various ferrites, mullite, forsterite, steatite and glass

The above ceramic-based sintered compact having at least one of the crystal structures selected from a hexagonal system or a trigonal system includes the various ceramic-based sintered compacts, such as the zinc oxide-based sintered compact, the sintered compact comprising beryllium oxide as a main component, the sintered compact comprising aluminum oxide as a main component, the sintered compact comprising silicon carbide as a main component, the sintered compact comprising silicon nitride as a main component, and the gallium nitride-based sintered compact, etc.

In the above-explained ceramic-based sintered compact substrate for a thin film and a ceramic-based sintered compact with optical permeability, about those having a thin film comprising at least one which are selected from gallium nitride, indium nitride and aluminum nitride as a main component, those having at least one of crystallization states selected from a single crystal, an amorphous state, a polycrystal, and an orientated polycrystal can be used as the formed thin film, these thin films may be not only those in which at least one of crystallization states selected from a single crystal, an amorphous state, a polycrystal, and an orientated polycrystal exists independently, respectively, but also those in which at least two of each crystallization state exist simultaneously.

That is, for example, it may be the condition in which the thin film of each crystallization state does not form a clear layer, but is intermingled in two or more crystallization states.

Specifically, it may be the condition which does not form a clear layer, such as an amorphous state and an orientated polycrystal, or an orientated polycrystal and a single crystal, or an amorphous state and a single crystal, or an amorphous state and a polycrystal, but exists as a single layer.

For example, when the thin film formed on the ceramic-based sintered compact comprises a single layer or at least two layers, at least one layer of the thin films may be at least two crystallization states selected from a single crystal, an amorphous state, a polycrystal, and an orientated polycrystal is intermingled simultaneously.

In the above thin film substrate, the thin film comprising as a main component at least one selected from gallium nitride, indium nitride and aluminum nitride is formed on at least one of sintered compacts selected from the ceramic-based sintered compact with or without optical permeability, it can use those having at least one of crystallization states selected from a single crystal, an amorphous state, a polycrystal, and an orientated polycrystal, these thin films may be not only those in which at least one of crystallization states selected from a single crystal, an amorphous state, a polycrystal, and an orientated polycrystal exists independently, respectively, but also those in which at least two of each crystallization state exist simultaneously. That is, for example, it may be those in which the thin film of each crystallization state does not form a clear layer, but is intermingled in two or more crystallization states. Specifically, it may be those which does not form a clear layer, such as an amorphous state and an orientated polycrystal, or an orientated polycrystal and a single crystal, or an amorphous state and a single crystal, or an amorphous state and a polycrystal, but exists as a single layer.

Although it can form directly in the a ceramic-based sintered compact substrate even if thicker than 200 μm as thickness of a single-crystal thin film comprising as a main component at least one selected from gallium nitride, indium nitride and aluminum nitride, for example, when forming directly in the ceramic-based sintered compact substrate, it is preferred to form in the thin state, for example less than 300 μm usually not more than 200 μm as thickness to obtain a single-crystal thin film excellent in crystallinity because the crystallinity of the single-crystal thin film tends to become small if the thickness of a thin film is formed thickly.

When it is going to form the above single-crystal thin films with thickness thicker than 200 μm for example, in the ceramic-based sintered compact, for example, it is preferred to use the ceramic-based sintered compact having the thin film comprising as a main component at least one selected from gallium nitride, indium nitride and aluminum nitride, or the ceramic-based sintered compact with optical permeability, or the ceramic-based sintered compact with optical permeability having the thin film comprising as a main component at least one selected from gallium nitride, indium nitride and aluminum nitride, etc.

Using the ceramic-based sintered compact with or without optical permeability, if a light-emitting device is produced forming on it the laminate comprising the thin film comprising at least one selected from gallium nitride, indium nitride and aluminum nitride as a main component and contains at least N-type semiconductor layer, luminescence layer, and P-type semiconductor layer, a light-emitting device which is at least equivalent or has superior luminous efficiency can be provided compared with the light-emitting device produced using the bulk-like single crystals, such as a conventional sapphire.

If what formed the thin film comprising at least one selected from gallium nitride, indium nitride and aluminum nitride is used as the ceramic-based sintered compact, and the ceramic-based sintered compact with optical permeability, a light-emitting device which is more excellent in luminous efficiency can be produced.

In the ceramic-based sintered compact with or without optical permeability, a light-emitting device which is still more excellent in luminous efficiency can be produced using what formed those which includes gallium nitride at least or those comprising gallium nitride as a main component, among the above thin films.

In the method of producing a light-emitting device on a ceramic-based sintered compact with or without optical permeability, a thin film comprising at least one selected from gallium nitride, indium nitride and aluminum nitride as a main component is preferably a single crystal, so that the light-emitting device has better luminous.

Usually, a single-crystal thin film excellent in crystallinity can be formed using the ceramic-based sintered compact having an average surface roughness Ra of not more than 2000 nm.

Usually, such a surface of the ceramic-based sintered compact can be obtained as-fired, or by mirror-polishing, blast-polishing, chemical corrosion, plasma gas corrosion, mechanical processing, etc.

Using the ceramic-based sintered compact having the above surface state, and the ceramic-based sintered compact with optical permeability, if a light-emitting device is produced forming on it the laminate constituting a light-emitting device and comprising the thin film comprising at least one selected from gallium nitride, indium nitride and aluminum nitride as a main component and contains at least N-type semiconductor layer, luminescence layer, and P-type semiconductor layer, a light-emitting device which is equivalent at least or has superior luminous efficiency can be provided compared with the light-emitting device produced using the bulk-like single crystals, such as a conventional sapphire.

Even if the surface roughness is large as a ceramic-based sintered compact and a ceramic-based sintered compact with optical permeability, the single-crystal thin film with excellent crystallinity can be formed.

For example, a single-crystal thin film with excellent crystallinity can be formed on the ceramic-based sintered compact with or without optical permeability having large surface roughness, even if the average surface roughness Ra is not less than 70 nm.

A single-crystal thin film with excellent crystallinity can be formed, even if the ceramic-based sintered compact with or without optical permeability have an average surface roughness Ra of more than 2000 nm.

Usually, such a surface state can be obtained in the as-fired surface, the surface by which lap polish was carried out, the surface by which blast polish was carried out, the surface by which chemistry corrosion was carried out, the surface corroded by plasma gas, or the surface where mechanical processings, such as the slot end, were given, etc., in the ceramic-based sintered compact with or without optical permeability.

Using the ceramic-based sintered compact, and the ceramic-based sintered compact with optical permeability, if a light-emitting device is produced forming on it the laminate constituting a light-emitting device and comprising the thin film comprising at least one selected from gallium nitride, indium nitride and aluminum nitride as a main component and contains at least N-type semiconductor layer, luminescence layer, and P-type semiconductor layer, the luminous efficiency of the light-emitting device can be raised more by using those with large surface roughness illustrated above, as the ceramic-based sintered compact or the ceramic-based sintered compact with optical permeability.

The ceramic-based sintered compact with or without optical permeability having large surface roughness preferably has an average surface roughness Ra of not less than 70 nm. Those having an average surface roughness Ra of larger than 100 nm, and those having an average surface roughness Ra of larger than 1000 nm are usable to produce a light-emitting device with high luminous efficiency.

Although a single-crystal thin film comprising as a main component at least one selected from gallium nitride, indium nitride and aluminum nitride and is comparatively excellent in crystallinity can be formed directly on the ceramic-based sintered compact with or without optical permeability which are the average surface roughness Ra not more than 2000 nm or have large surface roughness, if a single-crystal thin film comprising as a main component at least one selected from gallium nitride, indium nitride and aluminum nitride is formed on it using what formed the thin film comprising as a main component at least one selected from gallium nitride, indium nitride and aluminum nitride, what is more excellent in crystallinity can be produced.

Although it is also possible to produce a light-emitting device by forming directly the laminate constituting a light-emitting device and comprising the thin film comprising at least one selected from gallium nitride, indium nitride and aluminum nitride as a main component and contains at least N-type semiconductor layer, luminescence layer, and P-type semiconductor layer, onto it, using the ceramic-based sintered compact with or without optical permeability with an average surface roughness Ra of not more than 2000 nm or have large surface roughness, usually, a light-emitting device with higher luminous efficiency can be produced by forming the above laminate on it using what formed the thin film comprising as a main component at least one selected from gallium nitride, indium nitride and aluminum nitride into the ceramic-based sintered compact with or without optical permeability with an average surface roughness Ra of not more than 2000 nm or have large surface roughness.

This invention provides the light-emitting device which used the ceramic-based sintered compact as mentioned above.

This invention provides the light-emitting device using the ceramic-based sintered compact with optical permeability.

This invention provides the light-emitting device using the ceramic-based sintered compact having large surface roughness.

This invention provides the light-emitting device using the ceramic-based sintered compact and in which the thin film comprising at least one selected from gallium nitride, indium nitride and aluminum nitride was formed.

This invention provides the light-emitting device using the ceramic-based sintered compact and in which the single-crystal thin film comprising at least one selected from gallium nitride, indium nitride and aluminum nitride was formed.

In addition, luminous efficiency in this invention means a percentage ratio of the electric power (electric energy) impressed to the device to make a light-emitting device drive and the optical output (optical energy) which was changed into light by the light-emitting device and actually emitted to the outside of a light-emitting device.

For example, that the luminous efficiency is 10% is that 180 mW is obtained as an optical output when a light-emitting device is made to drive by impressing the voltage of 3.6 V and the current of 500 mA.

An optical output can be measured using a spectrophotometer, etc. by collecting all the light emitted after a light-emitting device is put into an integrating sphere and is made to emit light, for example.

In addition, although the luminous efficiency generally used in the lighting field is the quantity of the light (lumen: lm) to the optical energy per unit time (W); (that is, it is expressed with lm/W), the luminous efficiency in this invention differs from the luminous efficiency generally being used in the lighting field.

The characteristics as a material, such as crystallinity, a lump-like or bulk-like single crystal has been superior to the single-crystal thin film which was integrally adhered to the ceramic-based sintered compact substrate, in many cases.

However, as mentioned above, according to this invention, a single-crystal thin film comprising at least one selected from gallium nitride, indium nitride and aluminum nitride and which is equally close in crystallinity of the lump-like or bulk-like single crystal has become to be able to form in the ceramic-based sintered compact.

Consequently, in those which is the state where the single-crystal thin film and the ceramic-based sintered compact are unified, it was found that the characteristic which could not be realized by the conventional lump-like or bulk-like single crystal can be produced.

For example, a light-emitting device which is equivalent at least or has superior luminous efficiency has been provided compared with the light-emitting device produced using the bulk-like single crystals, such as a conventional sapphire, even if it is the light-emitting device produced using a ceramic-based sintered compact.

Even if the crystallinity of the single-crystal thin film formed on the above ceramic-based sintered compact is inferior to the single crystals with the shape of a lump and the shape of bulk, etc., when electronic devices and electronic components, such as a light-emitting device, an optical waveguide, or a wiring board, are produced, if the thin film substrate in which a ceramic-based sintered compact and a single-crystal thin film are adhered and unified, and the ceramic-based sintered compact substrate for a thin film and can form a single-crystal thin film are used, that having the characteristic superior to that which used as a substrate a single crystal independently, such as the lump-like or bulk-like single crystal, is easily obtained.

That is, the characteristic of the produced electronic devices or electronic components is not necessarily excellent even if it uses it for the substrate for producing electronic devices or electronic components just because the characteristic of a material is good.

As shown by this invention, if those in which a ceramic-based sintered compact, and a single-crystal thin film were unified is used, electronic devices or electronic components with the excellent characteristic which could not be realized by using only the conventional lump-like or bulk-like single crystal are producible.

That is, when a light-emitting device is produced for example, what was produced using the thin film substrate having the single-crystal thin film which is integrally adhered to the sintered compact of this invention comprising a ceramic material as a main component, and the ceramic-based sintered compact substrate for a thin film and which can form such a thin film, is more excellent in the aspect of luminous efficiency, compared with what was produced using only single crystals, such as the shape of a lump and the shape of bulk, as a substrate. That is, large luminescence energy is obtained in low power consumption.

When only single crystals, such as the shape of a lump and the shape of bulk, are used as a substrate, although a thing with good crystallinity can be formed about the laminate constituting a light-emitting device and comprising the thin film comprising at least one selected from gallium nitride, indium nitride and aluminum nitride as a main component and contains at least N-type semiconductor layer, luminescence layer, and P-type semiconductor layer, it is thought that it is because the light from a luminescence layer becomes easily shut up in the inside of the laminate constituting a light-emitting device, since it becomes easy to produce reflection of light in the interface of the laminate and the substrate which constitute the light-emitting device by influence of homogeneity, etc. which the lump-like or bulk-like single crystal has.

On the other hand, and, when the above thin film substrate or substrate for a thin film of this invention are used, it is thought that it has the synergistic effect of two functions which cannot be realized in those which used only single crystals, such as the shape of a lump and the shape of bulk, as a substrate, such that the above laminate constituting a light-emitting device can form those with comparatively high crystallinity, and that it becomes hard to generate reflection of light in the interface of a laminate and a substrate since the ceramic-based sintered compact is a polycrystalline substance comprising a particulate, and the light from a luminescence layer is not shut up in the inside of the laminate constituting a light-emitting device, but becomes easily emitted to the outside of a device.

In addition, for example, if the above thin film substrate or substrate for a thin film of this invention are used also when producing electronic devices and electronic components, such as an optical waveguide and a wiring board, since an electric circuit can form in the inside of a ceramic-based sintered compact, it can miniaturize and there is little leading about of wiring, and what has the outstanding function which cannot be realized in those which used only single crystals, such as the shape of a lump and the shape of bulk, as a substrate, is realizable.

The meaning and the purpose of this invention are to provide the substrate having outstanding function, the electronic devices, such as a light-emitting device which used this substrate, or the electronic components, such as a circuit substrate, which are hard to be realized by the material which exists as a single crystal and is used independently in itself, such as the shape of a lump and the shape of bulk, such as conventional sapphire and silicon carbide, by making into the shape of a thin film a single crystal which is excellent in crystallinity and comprising as a main component at least one which are selected from gallium nitride, indium nitride and aluminum nitride, and unifying firmly it and a ceramic-based sintered compact, and drawing the synergistic effect which a single crystal and a ceramic-based sintered compact cannot make independently respectively. It is the offering of a ceramic-based sintered compact and brings about such an effect.

Hereafter, it explains in more detail about this invention.

A thin film comprising as a main component at least one selected from gallium nitride, indium nitride and aluminum nitride can be formed directly on the surface of the aluminum nitride-based sintered compact substrate of this invention, and it can carry out the direct formation of a single crystal which grew epitaxially at least as a thin film.

When an aluminum nitride-based sintered compact is used as a substrate, a thin film of not only the above single crystal state but also the various crystallization states, such as an amorphous state, a polycrystalline state, or an orientated polycrystalline state, etc., can be formed directly there as a thin film comprising as a main component at least one selected from gallium nitride, indium nitride and aluminum nitride.

When a single-crystal thin film comprising as a main component at least one selected from gallium nitride, indium nitride and aluminum nitride is grown up in this substrate using the aluminum nitride-based sintered compact and formed a thin film of various crystallization states, such as the above single crystal state, amorphous state, polycrystalline state, and orientated polycrystalline state, etc., the single-crystal thin film obtained is easily formed as a single-crystal thin film whose crystallinity was improved than the single-crystal thin film formed directly on the aluminum nitride-based sintered compact substrate.

The meaning “formed directly” is literally that the thin film comprising as a main component at least one selected from gallium nitride, indium nitride and aluminum nitride is formed directly on the aluminum nitride-based sintered compact substrate without intervening of other material, intermediate, etc.

To form the above thin film, a special material, an intermediate, or an intervention material are not needed to the surface of the aluminum nitride-based sintered compact substrate.

Thus, a single-crystal thin film which is excellent in crystallinity and comprising as a main component at least one selected from gallium nitride, indium nitride and aluminum nitride can be formed using the aluminum nitride-based sintered compact substrate of this invention.

The thin film formed directly on the aluminum nitride-based sintered compact substrate of this invention may be a single crystal or in other states such as an amorphous, polycrystalline or orientated-polycrystalline state.

When it is going to form a single-crystal thin film comprising as a main component at least one selected from gallium nitride, indium nitride and aluminum nitride, a single-crystal thin film with higher crystallinity is obtained by forming a single-crystal thin film on it using the thin film substrate in which a thin film comprising as a main component at least one selected from gallium nitride, indium nitride and aluminum nitride and having the above various crystallization states was formed beforehand on the aluminum nitride-based sintered compact substrate of this invention.

As for the effect of the thin film substrate obtained by forming beforehand the thin film comprising as a main component at least one selected from gallium nitride, indium nitride and aluminum nitride and having various crystallization states including a single crystal or an amorphous state, etc. into the substrate comprising this aluminum nitride-based sintered compact, and forming a single-crystal thin film furthermore, it will become still larger when this thin film substrate in which the single-crystal thin film was formed is used as a substrate for light-emitting device.

A light-emitting device comprises as a main component at least one selected from gallium nitride, indium nitride and aluminum nitride and is manufactured by growing epitaxially plural thin film layers, such as P-type semiconductor layer, an N-type semiconductor layer, and luminescence layer, etc., and laminating these layers, the more the crystallinity of the thin film grown epitaxially (namely, the single-crystal thin film) is high, the more the characteristic of such a light-emitting device is excellent.

Thus, for example, in the case of manufacturing a light-emitting device, when it is required that the thin film comprising as a main component at least one selected from gallium nitride, indium nitride and aluminum nitride should be formed as a single-crystal thin film having higher crystallinity, it becomes more effective to use the thin film substrate of this invention in which a single-crystal thin film was formed as mentioned above.

In addition, the thin film substrate of this invention in which the single-crystal thin film was formed includes not only the thin film substrate obtained by forming beforehand the thin film comprising as a main component at least one selected from gallium nitride, indium nitride and aluminum nitride and having various crystallization states, such as a single crystal, an amorphous state, a polycrystal, and an orientated polycrystal, etc., into the substrate comprising the above aluminum nitride-based sintered compact, and forming a single-crystal thin film furthermore, but also the thin film substrate obtained by forming the single-crystal thin film comprising as a main component at least one selected from gallium nitride, indium nitride and aluminum nitride directly onto the aluminum nitride-based sintered compact substrate.

Thus, according to this invention, the thin film can exist in a state where it is integrally adhered to the substrate comprising various ceramic-based sintered compacts, unlike an independent bulk material.

As mentioned above, a thin film comprising as a main component at least one selected from gallium nitride, indium nitride and aluminum nitride and having various crystallization states, such as a single crystal state, an amorphous state, a polycrystalline state, or an orientated polycrystalline state, etc., can be formed directly on the aluminum nitride-based sintered compact substrate of this invention.

It is important to form a single-crystal thin film comprising as a main component at least one selected from gallium nitride, indium nitride and aluminum nitride, it will not be preferred to use the substrate on which those of a single crystal state cannot form even if it is able to form a thin film of various crystallization states.

That is, the big purposes of this invention is to provide the substrate which can form a single-crystal thin film comprising as a main component at least one selected from gallium nitride, indium nitride and aluminum nitride, and to provide the single-crystal thin film substrate on which the single-crystal thin film comprising as a main component at least one selected from gallium nitride, indium nitride and aluminum nitride was formed.

As mentioned above, a thin film comprising as a main component at least one selected from gallium nitride, indium nitride and aluminum nitride and which is a single crystal state at least can be formed directly on the aluminum nitride-based sintered compact substrate of this invention.

Thus obtained is an excellent substrate for a thin film on which a single-crystal thin film comprising as a main component at least one selected from gallium nitride, indium nitride and aluminum nitride can be formed directly.

However, in the actual use form in which the substrate for a thin film of this invention is used, it is not necessarily limited to only the above substrate for forming a single-crystal thin film comprising as a main component at least one selected from gallium nitride, indium nitride and aluminum nitride.

A thin film comprising as a main component at least one selected from gallium nitride, indium nitride and aluminum nitride and which is various crystallization states, such as an amorphous state, a polycrystalline state, and an orientated polycrystalline state, other than a single crystal, can also be formed directly on the substrate for single-crystal thin film formation of this invention comprising an aluminum nitride-based sintered compact.

As for the substrate for a thin film of this invention comprising an aluminum nitride-based sintered compact, it can be actually used as a substrate not only for forming a thin film of single crystal state comprising as a main component at least one selected from gallium nitride, indium nitride and aluminum nitride but also for forming a thin film comprising as a main component at least one selected from gallium nitride, indium nitride and aluminum nitride and which is various crystallization states, such as an amorphous state, a polycrystal, and an orientated polycrystal.

As mentioned above, the sintered compact of this invention can be provided with not only a aluminum nitride-based, single-crystal thin film but also a thin film comprising as a main component at least one selected from gallium nitride, indium nitride and aluminum nitride and which is various crystallization states, such as an amorphous state, a polycrystal, and an orientated polycrystal.

Specifically, this invention can also provide the thin film substrates in which a thin film of various crystallization state, such as amorphous thin film, a polycrystalline thin film, or an orientated polycrystalline thin film, was formed, other than the aluminum nitride-based sintered compact substrate and in which a single-crystal thin film was formed, for example,
(1) The thing, in which a single-crystal thin film comprising as a main component at least one selected from gallium nitride, indium nitride and aluminum nitride was formed on the aluminum nitride-based sintered compact substrate,
(2) The thing, in which an amorphous thin film comprising as a main component at least one selected from gallium nitride, indium nitride and aluminum nitride was formed on the aluminum nitride-based sintered compact substrate,
(3) The thing, in which a polycrystalline thin film comprising as a main component at least one selected from gallium nitride, indium nitride and aluminum nitride was formed on the aluminum nitride-based sintered compact substrate,
(4) The thing, in which an orientated polycrystalline thin film comprising as a main component at least one selected from gallium nitride, indium nitride and aluminum nitride was formed on the aluminum nitride-based sintered compact substrate, etc.

That is, this invention is a substrate for forming a thin film comprising as a main component at least one selected from gallium nitride, indium nitride and aluminum nitride, and the substrate contains a substrate for a thin film comprising an aluminum nitride-based sintered compact.

This invention also includes the thin film substrate in which a thin film comprising as a main component at least one selected from gallium nitride, indium nitride and aluminum nitride is being formed on the aluminum nitride-based sintered compact substrate.

The aluminum nitride-based sintered compact of this invention can use equally to both uses, for the substrate for a thin film, and for the thin film substrate.

When forming a thin film comprising as a main component at least one selected from gallium nitride, indium nitride and aluminum nitride and is various crystallization states, such as a single crystal, an amorphous state, a polycrystal, and an orientated polycrystal, etc., special film formation technique is not needed, anything is arbitrarily applicable if it is the method of growing the thin film of the target composition, that is, decomposing or not decomposing chemically, physically a compound and a simple substance containing at least a part of target chemical component, making it into gas, ion, or a molecular beam in the state as it is, it is made to react or not to react with the compound except the above suitably, after making the component containing the target chemical component into the gaseous phase, such as the usual MOCVD (Metal Organic Chemical Vapor Deposition) method, the MOVPE (Metal Organic Vapor Phase Epitaxy) method, the Hydride VPE (Hydride Vapor Phase Epitaxy) method, the Halide VPE (Halogen Transport Vapor Phase Epitaxy) method containing the Chloride VPE (Chloride Vapor Phase Epitaxy) method, etc., the Plasma CVD method, the other CVD (Chemical Vapor Deposition) methods, and the MBE (Molecular Beam Epitaxy) method, or the laser ablation method using the Excimer laser, etc. and using as a raw material the solid material containing the purpose component which was formed beforehThe PLD method (Pulse Laser Deposition: Pulse Laser Deposition), the Sputtering method, the Ion-plating method, or the Vapor-depositing method, etc.

As the raw material for thin film production of various crystallization states, such as a single crystal state, an amorphous state, a polycrystalline state, and an orientated polycrystalline state, various compounds, such as organic metallic compounds, such as trimethyl gallium, triethyl gallium, tri-iso-butyl gallium, trimethyl indium, triethyl indium, tri-iso-butyl indium, trimethyl aluminum, triethyl aluminum, and tri-iso-butyl aluminum, the halogenated compounds of gallium, indium, and aluminum, such as chlorides such as a gallium chloride, an indium chloride, and an aluminium chloride, and bromides such as a gallium bromide, an indium bromide, and an aluminum bromide, the organic compounds of gallium, indium, and aluminum containing halogens such as diethyl gallium chloride, diethyl indium chloride, diethyl aluminum chloride, nitrides, such as gallium nitride, indium nitride, and aluminum nitride, pure metals, such as gallium, indium, and aluminum, can be used, in addition, Si, or silane compounds, such as SiH₄, SiHCl₃, and Si(C₂H₅)₄, the halogenated compound of silicon, such as SiCl₄ and SiBr₄, silicon compounds, such as Si₃N₄ and SiC, metals, such as magnesium, beryllium, calcium, zinc, cadmium, and germanium, and compounds, such as halogenated compounds and the organic metallic compounds containing these metals, such as dialkyl beryllium (for example, dimethyl beryllium, etc.), dialkylmagnesiums (for example, dimethyl magnesium, etc.) and bis-cyclopentadienyl magnesium (MgCp₂), bis-cyclopentadienyl calcium (CaCp₂), diethyl zinc, dimethyl cadmium, tetramethyl germanium, BeCl₂, BeBr₂, MgCl₂, MgBr₂, CaCl₂, CaBr₂, ZnCl₂, ZnBr₂, CdCl₂, CdBr₂, GeCl₄, GeBr₄, or the compound containing a nonmetal and these nonmetals, such as carbon, silicon, selenium, tellurium, and oxygen, etc., can be used, and they can be used as a main component and the doping elements.

In the MOCVD method and the MOPVE method, organic compounds, such as trimethyl gallium, trimethyl indium, and trimethyl aluminum, are used as a main raw material.

In the Chloride VPE and the Halide VPE method, halogenated compounds, such as gallium chloride, indium chloride, and aluminium chloride, are used as a main raw material.

In the methods of forming a thin film by making a raw material into a gaseous state, such as the above MOCVD method, MOPVE method, Hydride VPE method, Chloride VPE method, Halide VPE method, Plasma CVD method, other CVD methods, and MBE method, ammonia or nitrogen are usually used in the state which was independent or mixed, as gas for reacting with a raw material.

As career gas, hydrogen, argon or nitrogen is used alone or in combination.

To form the single-crystal thin film excellent in crystallinity, it is more preferred to use what contains hydrogen at least as the above career gas.

As an atmosphere in the thin film formation chamber, ammonia, hydrogen, argon, nitrogen, etc. are usually used under normal pressure or decompression.

When forming a thin film by the sputtering method, what formed the various above raw materials is used as a target material.

According to such a method, a thin film comprising as a main component at least one selected from gallium nitride, indium nitride and aluminum nitride can be arbitrarily obtained in the various crystallization states, such as a single crystal, an amorphous state, a polycrystal, and an orientated polycrystal.

In addition, when a single-crystal thin film comprising as a main component at least one selected from gallium nitride, indium nitride and aluminum nitride is formed, for example, using the compound containing the metal component of the target composition (in the case of gallium nitride, it is a compound in which a gallium component is included, for example, trimethyl gallium, gallium trichloride, etc., or in the case of indium nitride, it is a compound containing an indium component, for example, trimethyl indium, indium trichloride, etc., or in the case of aluminum nitride, it is a compound containing an aluminum component, for example, trimethyl aluminum, aluminium chloride, etc.) as a raw material, it is preferred to use the method of forming a single-crystal thin film through process in which those of the target composition is formed after the compound is once decomposed and a nitriding reaction is carried out with reactive gas, such as ammonia, after that, like the MOCVD method or the halide VPE method.

When a single-crystal thin film is formed on the ceramic-based sintered compact, as mentioned above, a single crystal with higher crystallinity can be produced by the method of once decomposing the compound using the compound containing the metal component of the target composition, carrying out a nitriding reaction after that, and acquiring the target composition, than the method of making the raw material only sublimate at high temperature, and producing a single crystal in the state near equilibrium using a raw material of the target composition as it is like the case of producing the bulk-like and lump-like single crystal by the sublimating method, etc.

As the reason, since a ceramic-based sintered compact is constituted with a fine crystal grain which turned to all the direction, when it is going to form a single-crystal thin film having two-dimensional spread, the range of selection of the material used as a raw material or a compound is widely, control of the substrate temperature or the supply direction and supply amount of a raw material and reactive gas to the a ceramic-based sintered compact substrate is easy, and it is considered because it is possible to control so that a single crystal grows in the target direction instead of spontaneous crystal growth according to the crystal orientation of the fine crystal grain which turned to all the direction and exists in the ceramic-based sintered compact (that is, it is controllable to grow up only in such a direction that its C axis is perpendicular to a substrate surface, for example).

On the other hand, and, in the method of producing a single crystal by making it sublimate at high temperature using the raw material of the target composition as it is like the sublimating method, a lot of raw materials can be sublimated, therefore, it seems that it is suitable when it is going to obtain the bulk-like and lump-like single crystal large-sized in a short time.

However, since the selection range of a raw material is narrowly when it is going to obtain a single-crystal thin film into the substrate comprising the ceramic-based sintered compact, and control of the supply direction and supply amount, etc. of a raw material tends to become difficult, it is not necessarily the suitable method as the method which produces the single-crystal thin film according to this invention.

As substrate temperature in the case of forming the above thin film comprising as a main component at least one selected from gallium nitride, indium nitride and aluminum nitride, it can be selected suitably in difference of the composition of a thin film or the forming method of a thin film, etc.

When forming a single crystal as a thin film, usually it is more preferred to raise a substrate temperature than what has crystallization states, such as an amorphous state, a polycrystal, and an orientated polycrystal, it may become hard to form a single-crystal thin film if the substrate temperature is low.

For example, as substrate temperature, usually it is desirable to carry out at 400-1200° C. when forming the gallium nitride-based thin film, 400-1000° C. when forming the indium nitride-based thin film, and 500-1500° when forming the aluminum nitride-based thin film.

In each above thin film, in the case of forming a gallium nitride-based thin film having a crystallization state other than single crystal, such as an amorphous state, a polycrystal, and an orientated polycrystal, 400-900° C. are desirable as substrate temperature, and in the case of forming a single-crystal thin film, it is desirable to carry out by raising the substrate temperature into 700-1200° C.

In case of forming a indium nitride-based thin film having a crystallization state other than single crystal, such as an amorphous state, a polycrystal, and an orientated polycrystal, 400-700° C. are desirable as substrate temperature, and in the case of forming a single-crystal thin film, it is desirable to carry out by raising the substrate temperature into 500-900° C.

In case of forming a aluminum nitride-based thin film having a crystallization state other than single crystal, such as an amorphous state, a polycrystal, and an orientated polycrystal, 500-1200° C. are desirable as substrate temperature, and in the case of forming a single-crystal thin film, it is desirable to carry out by raising the substrate temperature into 600-1500° C.

If saying Specifically, as substrate temperature in the case of forming a single-crystal thin film by the MOCVD method and the MOVPE method, etc., for example, 900-1100° C. are preferable when forming a gallium nitride-based thin film, 600-900° C. are preferable when forming a indium nitride-based thin film, and 900-1200° C. are preferable when forming a aluminum nitride-based thin film.

As the substrate temperature in the case of forming a single-crystal thin film by the Chloride VPE method or the Halide VPE method, etc., 900-1250° C. are preferable when forming a thin film comprising gallium nitride(GaN) as a main component, 700-1000° C. are preferable when forming a thin film comprising indium nitride(InN) as a main component, and 1000-1500° C. are preferable when forming a thin film comprising aluminum nitride(AlN) the main components, that it is not less than 1100° C. is more desirable since a single-crystal thin film with high crystallinity can be formed.

If the substrate temperature is lower than the temperature illustrated above, it usually tends to become hard to form a single-crystal thin film.

Thus, it is preferred to raise the substrate temperature in the case of forming a single-crystal thin film comprising as a main component at least one selected from gallium nitride, indium nitride and aluminum nitride, and it is preferred to make the substrate temperature low in many cases in the case of forming a thin film of crystallization states, such as an amorphous state, a polycrystal, and an orientated polycrystal.

As for heating of a substrate, any methods, such as resistance heating which used various heaters, high frequency heating using an RF generator, and heating by an infrared lamp, etc., can be used.

Even if it uses what kind of thin film forming method, as substrate temperature, it is not limited only to the above range. It can form at low temperature comparatively, such that room temperature −400° C. are preferable when forming a gallium nitride-based thin film, room temperature −400° C. are preferable as substrate temperature when forming a indium nitride-based thin film, and that room temperature −500° C. are preferable when forming a aluminum nitride-based thin film.

Using methods, such as Sputtering method, Ion-plating method, and Vapor-depositing method, as an example of such method, a thin film can be formed comparatively at low temperature as mentioned above.

For example, also in the method of forming a thin film by the raw material of a gaseous state and the reactive gas, for example, if the reactive gas, such as ammonia or nitrogen, has plasma state by high frequency (for example, microwave with a frequency of 2.45 GHz or a radio wave with a frequency of 13.56 MHz, etc.), magnetism, etc., even if substrate temperature is low temperature as mentioned above, a good thin film can be obtained.

When a thin film comprising as a main component at least one selected from gallium nitride, indium nitride and aluminum nitride and contains a single crystal or a single crystal layer at least is formed onto the ceramic-based sintered compact substrate, if applying potential to the substrate, there is a feature wherein it adheres firmly with a substrate without generating exfoliation and crack, etc. in the thin film formed and the single-crystal thin film excellent in crystallinity tends to become easily formed. As for the reason, this inventor is surmising that it will be because the component containing at least one selected from gallium nitride, indium nitride and aluminum nitride goes to the substrate in the state with higher energy and the crystal orientation becomes easily gathered in the fixed direction in the time that the component deposits on the substrate, by impressing potential to a substrate. As for the potential impressed, although both of alternating current and direct current can be used, it is usually preferred to use direct-current potential. When direct-current potential is impressed to the substrate, polarity of the substrate changes also by the quality of the material of the substrate, composition of the thin film, or thin film forming methods, and the thin film is formed in a state where the substrate is suitably made into minus(−) or plus(+). Usually, it is preferred to form the thin film by applying minus(−) potential to the substrate. As voltage to impress, those of the range of 1 volt to several 100,000 volts can use suitably, for example. As the method of forming the thin film by applying potential to the substrate, the ion plating method is usually used, and methods, such as the MOCVD method, the MOVPE method, the hydride VPE method, the halide VPE method including the chloride VPE method, etc., the plasma CVD method, other CVD methods (Chemical Vapor Phase Deposition), the MBE method (Molecular Beam Epitaxy), the laser ablation method, the PLD method (Pulse Laser Deposition), the sputtering method, and the vapor-depositing method, etc., for example, can use in addition to the above ion plating method.

As for the single-crystal thin film comprising as a main component at least one selected from gallium nitride, indium nitride and aluminum nitride and grows on the aluminum nitride-based sintered compact substrate, the crystal system is expressed with a hexagonal system.

When the above CVD method, etc. are used, a single-crystal thin film formed has the tendency which is usually easy to grow epitaxially in the C axis direction of the hexagonal system to a substrate surface.

If saying in other words, the above single-crystal thin film has the tendency which is easy to grow epitaxially in the direction where the C plane is parallel to a substrate surface.

Since the strong diffraction line from a lattice plane (002) of the hexagonal system will be observed if carrying out X-ray diffraction of the above single-crystal thin film formed on the substrate, it can be explained from the observation in which the above single-crystal thin film is growing epitaxially in the direction of C axis to a substrate surface.

If saying in other words, it can be explained from the observation in which the above single-crystal thin film is growing epitaxially in a state where the C plane is parallel to a substrate surface.

In FIG. 1, the single-crystal thin film 2 comprising as a main component at least one selected from gallium nitride, indium nitride and aluminum nitride is formed on the substrate 1 comprising an aluminum nitride-based sintered compact.

In the substrate in which the single-crystal thin film 2 was formed in such a direction that its C axis is perpendicular to the substrate surface as shown in FIG. 1, only the diffraction line from a lattice plane (002) of aluminum nitride crystal having a hexagonal wurtzite type crystal structure will be obtained if X-ray is irradiated to the surface of the single-crystal thin film 2.

This situation is shown in FIG. 2.

If the thin film formed on the substrate 1 is not a single crystal but the polycrystallized condition, since plural diffraction lines, such as diffraction from the lattice plane (100), for example, other than a lattice plane (002) of hexagonal system as shown in FIG. 2, will be observed, it is clearly distinguishable.

In addition, an orientated polycrystal is a polycrystalline substance of the special state in which the crystal grain gathered in the direction of a specific crystallographic axis.

Even if it is such orientated polycrystal, it can be distinguished from a single crystal comparatively easily.

If saying Specifically, a thin film comprising as a main component at least one selected from gallium nitride, indium nitride and aluminum nitride has a wurtzite type crystal structure, if the usual 2θ/θ scan of X-ray diffraction will be performed, for example, in the single-crystal thin film formed in such a direction that its C axis is perpendicular to the substrate surface, only the diffraction line from a lattice plane (002) will appear.

On the other hand, and, in the orientated polycrystal formed in such a direction that its C axis of a thin film is perpendicular to a substrate surface, only the diffraction line from a lattice plane (002) appears by the 2θ/θ scan of X-ray diffraction.

However, in the case of a single-crystal thin film, only the diffraction line from the lattice plane of the Miller Index (100) will appear if the 2θ/φ (p scanning is performed fixing the lattice plane of the Miller Index (100) parallel to C axis. In the case of an orientated polycrystalline thin film, since the diffraction line(s) from other lattice plane parallel to C axis, for example the lattice plane of the Miller Index (110), also appears, the difference in which the thin film formed is either a single crystal or an orientated polycrystal can be judged easily. That is, while a rotation in the C plane is not seen in the case of a single crystal, a rotation of a crystal in the C plane is seen in the case of an orientated polycrystalline thin film.

It is considered that; in the case of a single crystal, it is homogeneous, and is unifying, and there is no boundary as a crystal grain. However, an orientated polycrystal is the aggregate of a crystal grain, the crystallographic axis (for example, C axis) is assembled in the specific direction in each crystal grain, but other crystallographic axes (for example, A-axis) has a different azimuth in each crystal grain.

Thus, an orientated polycrystal can also be called a polycrystalline substance of the special state where the crystal grain gathered in the direction of a specific crystal axis.

As mentioned above, in the case of an usual polycrystalline thin film, if the 2θ/θ scan of X-ray diffraction is performed, the diffraction line appears not only from a lattice plane (002) but also from the lattice plane of (100) for example, so it can distinguish the usual polycrystalline thin film from the usual orientated polycrystalline thin film easily.

If the thin film formed on the substrate 1 is not the single crystal or polycrystal but the amorphous state, a diffraction line with the clear peak is not obtained so the diffraction line becomes into a broad pattern, therefore it can be distinguished clearly from the single crystal, the polycrystal, or the orientated polycrystal.

In FIG. 1, the single-crystal thin film 2 tends to grow in the direction of C axis, the growth direction is a perpendicular direction to the substrate surface, that is, a parallel direction to the substrate surface is the direction of the C plane of the single-crystal thin film 2.

C axis of the single-crystal thin film comprising as a main component at least one selected from gallium nitride, indium nitride and aluminum nitride and formed on the aluminum nitride-based sintered compact substrate tends to grow in the perpendicular direction spontaneously to a substrate surface.

However, if the growth method of a thin film is devised suitably even when the substrate comprising the above aluminum nitride-based sintered compact is used, C axis of the single-crystal thin film comprising as a main component at least one selected from gallium nitride, indium nitride and aluminum nitride can be formed in the parallel direction to the substrate surface.

For example, if the device, such that the source gas for thin film formation is supplied from a parallel direction to the substrate, setting up the above substrate temperature lowness at first, and raising temperature gradually, is carried out, C axis of the single-crystal thin film comprising as a main component at least one selected from gallium nitride, indium nitride and aluminum nitride can be formed in the parallel direction to a substrate surface.

This situation is shown in FIG. 4.

FIG. 4 shows those in which C axis of the single-crystal thin film 2 comprising as a main component at least one selected from gallium nitride, indium nitride and aluminum nitride and formed on the substrate 1 comprising an aluminum nitride-based sintered compact is formed in the parallel direction to the substrate surface (namely, the C plane is formed in the perpendicular direction to the substrate surface).

Thus, although C axis of a single-crystal thin film can be formed in the perpendicular or parallel direction to a substrate surface, it means that C axis of a single-crystal thin film can be formed so that it may become the arbitrary angles between 0-90° to a substrate surface.

As for evaluation of the crystallinity of the single-crystal thin film comprising as a main component at least one selected from gallium nitride, indium nitride and aluminum nitride according to an X ray rocking curve, it was carried out by using those which grew in such a direction that its C axis is perpendicular to the substrate surface as shown in FIG. 1, unless it refuses especially.

If surface X-ray diffraction is performed only by the substrate 1 comprising an aluminum nitride-based sintered compact, the diffraction line which is equivalent to AlN powder described in JCPDS (Joint Committee on Powder Diffraction Standards) file number 25-1134 is obtained, and the aluminum nitride particle in a sintered compact shows that it is the polycrystalline state which turned to not a specific direction but all the direction.

In addition, although the form of the substrate illustrated in FIG. 1, FIG. 2, and FIG. 4 is circular, the form of the substrate which can be used in this invention can use those of arbitrary form, such as not only a round shape but a square, a rectangle, or other polygons.

As for the thin film substrate produced using the substrate for a thin film of this invention comprising an aluminum nitride-based sintered compact and is illustrated in FIG. 1, FIG. 2, and FIG. 4, and the aluminum nitride-based sintered compact, what has arbitrary size can be produced using the method which is usually used in the sintered compact production and the thin film production. In the case of a sintered compact, for example, the contour of about 0.01-1000 mm and the thickness of about 1 μm-20 mm are easily obtained.

The thin film which was formed on the aluminum nitride-based sintered compact and comprising as a main component at least one selected from gallium nitride, indium nitride and aluminum nitride and having various crystallization states, such as a single crystal, an amorphous state, a polycrystal, and an orientated polycrystal, etc. and the sintered compact comprising as a main component aluminum nitride are unified firmly, the crack in the formed thin film and the exfoliation at the junction interface, etc. are not seen between this thin film and the aluminum nitride-based sintered compact.

About the junction nature, even if the test, such that pressure sensitive adhesive tape is pasted up to the above formed thin film and torn off, for example, is carried out, exfoliation or breakdown in the junction interface of the thin film and the aluminum nitride-based sintered compact is not seen.

As for the junction nature between the thin film comprising as a main component at least one selected from gallium nitride, indium nitride and aluminum nitride and having various crystallization states, such as a single crystal, an amorphous state, a polycrystal, and an orientated polycrystal, etc., and the aluminum nitride-based sintered compact, it is usually not less than 2 kg/mm² by perpendicular tension strength, and what is not less than 4 kg/mm² by perpendicular tension strength is also obtained further.

In the single-crystal thin film comprising gallium nitride and indium nitride as a main component among the single-crystal thin film comprising as a main component at least one selected from gallium nitride, indium nitride and aluminum nitride, when the crystallinity of the contained thin film of the single crystal state is judged by an X-ray diffraction as mentioned above, the diffraction line from a lattice plane (002) of the single-crystal thin film having a hexagonal wurtzite type crystal structure, and the diffraction line from a lattice plane (002) of hexagonal system of the base aluminum nitride-based sintered compact substrate can be distinguished clearly, so the X-ray diffraction method can be used for the crystallinity judgment of those with almost all the thickness of the single-crystal thin film formed.

It is because the locations of the diffraction line from a lattice plane (002) of hexagonal system by X-ray diffraction differ in the degree which can be distinguished easily, since lattice constants differ little by little even if gallium nitride, indium nitride, and aluminum nitride have a wurtzite type crystal structure which belongs to the same hexagonal system.

When the CuKa rays (wavelength 1.542 A) are used as characteristic X-rays, the diffraction line from a lattice plane (002) of the base substrate made from an aluminum nitride-based sintered compact appears in the range θ=17.65-18.45° as diffraction angle, the diffraction line from a lattice plane (002) of gallium nitride single-crystal thin film appears in a range of θ of 17.20-17.53° as diffraction angle, the diffraction line from a lattice plane (002) of indium nitride single-crystal thin film appears near θ of 15.55-15.88° as diffraction angle, so an overlap which makes judgment of these diffraction lines impossible does not arise substantially.

On the other hand, the diffraction line from a lattice plane (002) of the single-crystal aluminum nitride-based thin film is θ=17.88-18.20° as diffraction angle.

Therefore, when the crystallinity of the single-crystal aluminum nitride-based thin film among the above single-crystal thin films is judged by an X-ray diffraction, if the thickness of the single-crystal thin film which is being formed becomes thin, the X-ray penetrates the single-crystal thin film, so the diffraction line from the base aluminum nitride-based sintered compact will be overlapped, the influence comes to be seen.

As the characteristic X-rays, the CrKα rays (wavelength 2.291 A), or CuKα which are comparatively long wavelength are used to control penetration energy small, and it handled by applying acceleration voltage as small as possible to an X-ray tube.

When the crystallinity of the single-crystal aluminum nitride-based thin film is judged by an X-ray diffraction, the limit thickness of the single-crystal thin film which can eliminate the effect of the diffraction from the base aluminum nitride-based sintered compact is about 500 nm by the above devices.

For the judgment of the single crystal nature of the aluminum nitride-based thin film having thickness up to not more than 500 nm from about 5 nm, electron diffraction, such as RHEED (Reflection High Energy Electron Diffraction), was used together, and it was considered that there was no influence from the aluminum nitride-based sintered compact and is a substrate.

Therefore, crystallinity evaluation by the half width of the rocking curve of the X-ray diffraction line from a lattice plane (002) of the single-crystal aluminum nitride-based thin film and forms on the aluminum nitride-based sintered compact substrate was usually performed by the single-crystal thin film with the thickness not less than 500 nm, or preferably not less than 1000 nm.

As for the thin film comprising as a main component at least one selected from gallium nitride, indium nitride and aluminum nitride and which was formed according to this invention, what is the thickness of about 0.5 nm can be formed. Even if the thickness is about such at least 0.5 nm, it is thought that it is being formed as a single crystal.

The above thin film can form not only the single crystal but those of various crystallization states, such as an amorphous state, a polycrystal, and an orientated polycrystal.

These thin films can be as thick as about 0.1-0.2 nm.

When the above thin film is directly formed on the substrate, using the aluminum nitride-based sintered compact as a substrate for a thin film, it is preferred that it is not less than 0.5 nm as the thickness of the thin film.

The thin film comprising as a main component at least one selected from gallium nitride, indium nitride and aluminum nitride and which is various crystallization states, such as a single crystal, an amorphous state, a polycrystal, and an orientated polycrystal, etc., can be formed using the substrate for a thin film comprising various sintered compacts comprising as a main component a ceramic material, such as aluminum nitride.

There can obtain a thin film substrate having a single-crystal thin film comprising as a main component at least one selected from gallium nitride, indium nitride and aluminum nitride directly into the above substrate for a thin film, and a thin film substrate having furthermore a single-crystal thin film comprising as a main component at least one selected from gallium nitride, indium nitride and aluminum nitride into the thin film substrate having a thin film comprising as a main component at least one selected from gallium nitride, indium nitride and aluminum nitride and is various crystallization states, such as a single crystal, an amorphous state, a polycrystal, and an orientated polycrystal, etc.

The thin film comprising as a main component at least one selected from gallium nitride, indium nitride and aluminum nitride and is various crystallization states, such as a single crystal used, an amorphous state, a polycrystal, and an orientated polycrystal, etc., can be formed on the above thin film substrate.

A thin film of various crystallization states, such as an amorphous state, a polycrystal, and an orientated polycrystal, can also usually be formed comparatively easily in the substrate in which a single crystal among the above thin films can be formed.

It was judged by evaluating the crystallinity of the single crystal which was formed on the substrate whether the above substrate for a thin film and the thin film substrate would be excellent.

As mentioned above, the crystallization state of the thin film comprising as a main component at least one selected from gallium nitride, indium nitride and aluminum nitride can be easily judged by analysis according to X-ray diffraction.

If the above thin film is a single crystal, when C axis of the single-crystal thin film is formed in the perpendicular azimuth to the substrate surface, only the diffraction line from a lattice plane (002) of a hexagonal wurtzite type crystal is detected.

When C axis of the single-crystal thin film is formed in the parallel azimuth to the substrate surface, only the diffraction line from the lattice plane of the Miller Index (100) of a hexagonal wurtzite type crystal is detected.

If the above thin film is polycrystal, it can distinguish easily since plural diffraction lines from a lattice plane (002), (100), etc., are detected.

If the above thin film is amorphous, it can distinguish easily since a clear diffraction peak is not detected but becomes a broad diffraction pattern.

When the aluminum nitride-based sintered compact of this invention is used as a substrate for a thin film, C axis of the single-crystal thin film comprising as a main component at least one selected from gallium nitride, indium nitride and aluminum nitride is easily formed in the perpendicular azimuth to the substrate surface, so only the diffraction line from a lattice plane (002) of a hexagonal wurtzite type crystal is usually detected.

Unless it refuses especially, crystallinity evaluation of the single-crystal thin film was usually carried out by measuring the half width of the rocking curve of the X-ray diffraction line from a lattice plane (002) of the single-crystal thin film.

The used characteristics X-rays are CuKa rays (wavelength 1.542 A).

Unless reference is made especially, the half width of the rocking curve of the X-ray diffraction line from a lattice plane (002) is measured by the usual o) scan, and an unit is shown with second (arcsecant).

When performing such crystallinity evaluation, the surface of the substrate comprising various sintered compacts which are used as a substrate for the single-crystal thin film formation and comprise as a main component a ceramic material, such as aluminum nitride, a thing which was mirror-polished to an average surface roughness Ra of about 30 nm can be used, unless reference is made especially.

The substrate for a thin film of this invention should just be the aluminum nitride-based sintered compact, and the thin film comprising as a main component at least one selected from gallium nitride, indium nitride and aluminum nitride and is the various crystallization states containing the single crystal can be formed directly on the substrate.

If using what has optical permeability in the above aluminum nitride-based sintered compact, it tends to raise the crystallinity of the single-crystal thin film comprising as a main component at least one selected from gallium nitride, indium nitride and aluminum nitride and formed on the substrate.

In such sintered compact, the crystallinity of the formed single-crystal thin film comprising as a main component at least one selected from gallium nitride, indium nitride and aluminum nitride will increase if the optical permeability at least in a visible light area is higher, so it is desirable.

As for the optical permeability in a visible light area of the range of 380-800 nm wavelength, it is preferred that the optical transmissivity is not less than 1% in the sintered compact having a disc-like shape with the diameter of 25.4 mm and the thickness of 0.5 mm and having been mirror-polished to an average surface roughness Ra of about 30 nm.

If the aluminum nitride-based sintered compact substrate with optical transmissivity of not less than 1% is used, the crystallinity of the single-crystal thin film comprising as a main component at least one selected from gallium nitride, indium nitride and aluminum nitride is easily formed directly on it, such that the half width of the rocking curve of the X-ray diffraction line from a lattice plane (002) is not more than 300 seconds.

Using the aluminum nitride-based sintered compact substrate and whose optical transmissivity is not less than 5%, a better thing, such that the half width of the above rocking curve of the X-ray diffraction is not more than 240 seconds, is easily obtained.

Using the aluminum nitride-based sintered compact substrate and whose optical transmissivity is not less than 10%, a still better thing, such that the half width of the above rocking curve of the X-ray diffraction is not more than 200 seconds, is easily obtained, it is more desirable.

The optical transmissivity in the visible light area is the optical transmissivity in the light of the range of the above 380-800 nm wavelength, and unless reference is made especially the value of the optical transmissivity measured by the light of 605 nm wavelength was used.

According to this invention, the aluminum nitride-based sintered compact having the optical transmissivity in the above visible light has also the same optical transmissivity in the light of the ultraviolet region of 200-380 nm wavelength, what is not less than 1%, as the optical transmissivity, is obtained.

In such aluminum nitride-based sintered compact, if the optical permeability to the light of the range of at least 200-800 nm wavelength is higher, the crystallinity of the formed single-crystal thin film comprising as a main component at least one selected from gallium nitride, indium nitride and aluminum nitride will desirably increase.

In the aluminum nitride-based sintered compact of this invention having the visible optical permeability, what has the optical transmissivity not less than 5% in the ultraviolet light of the range of 250-380 nm wavelength is obtained, what has the optical transmissivity not less than 10% in the ultraviolet light of the range of 300-380 nm wavelength is obtained.

In the aluminum nitride-based sintered compact according to this invention, what has the optical transmissivity not less than 40% is obtained in the ultraviolet light of the above range of 200-380 nm wavelength, and what has a maximum of 60-80%, or what has the optical transmissivity not less than 80% are also obtained furthermore.

As mentioned above, the aluminum nitride-based sintered compact substrate of this invention also has optical permeability to the ultraviolet light, if the device for emitting ultraviolet-rays is formed on the substrate of this invention using the single-crystal thin film comprising as a main component at least one selected from gallium nitride, indium nitride and aluminum nitride, for example, it is rare to absorb the ultraviolet rays emitted from the device into the substrate portion, so the effect that the luminous efficiency of a light-emitting device increases is acquired, and it is desirable.

Thus, the aluminum nitride-based sintered compact substrate has the optical transmissivity at least not less than 1% in the light of the range of 200-800 nm, it was shown clearly that the single-crystal thin film comprising as a main component at least one selected from gallium nitride, indium nitride and aluminum nitride and having more excellent crystallinity could be formed using the substrate having such optical transmissivity.

Using the aluminum nitride-based sintered compact substrate having the optical transmissivity not less than 1%, the thin film comprising as a main component at least one selected from gallium nitride, indium nitride and aluminum nitride and is the various crystallization states, such as an amorphous state, a polycrystal, and an orientated polycrystal, other than the single crystal, can also be formed.

Unless reference is made especially, hereafter, optical transmissivity is measured by the light with a wavelength of 605 nm.

According to this invention, the aluminum nitride-based sintered compact having optical permeability shows usually the almost same transmissivity as the transmissivity measured by the light with a wavelength of 605 nm to the light of any wavelength at least in the visible light area of the range of a wavelength of 380-800 nm.

Though the aluminum nitride-based sintered compact of this invention does not necessarily have the same optical transmissivity as the 605 nm wavelength in the light of all the wavelength ranges of 200-800 nm wavelength except the wavelength of 605 nm, only using the optical transmissivity measured by the light with a wavelength of 605 nm, it can distinguish on behalf of the performances of the aluminum nitride-based sintered compact according to this invention, for example, the crystallinity when forming a single-crystal thin film comprising as a main component at least one selected from gallium nitride, indium nitride and aluminum nitride.

That is, the characteristic as a substrate of the aluminum nitride-based sintered compact having optical permeability is represented with the optical transmissivity measured by the light of the above wavelength of 605 nm and can be judged.

The aluminum nitride-based sintered compact having optical permeability usually shows optical permeability to the light with a wavelength not less than 200 nm in many cases.

That is, optical permeability begins to be shown to the light of the range of 200-250 nm wavelength, the optical permeability goes up rapidly to the light of the range of 250-350 nm wavelength, and there is a tendency of having almost fixed optical transmissivity to the light with a wavelength not less than 350-400 nm which is in the boundary area which goes into a visible light area from ultraviolet light.

In the cases of a sintered compact, for example, the one which has the contour of 0.01 mm-1000 mm and the thickness of about 1 μm-20 mm is easily producible. Usually, it is preferred to use a ceramic substrate with the thickness not less than 0.01 mm from the point of a handling strength, for a substrate for a thin film, a thin film substrate, or a substrate for light-emitting device, etc.

Since the optical transmissivity will tend to lower if the thickness becomes thick, usually it is preferred to use a thing with the thickness not more than 8.0 mm, as a substrate for a thin film, a thin film substrate, or a substrate for light-emitting device.

In the above aluminum nitride-based sintered compact and other ceramic-based sintered compact, it is effective if the substrate for a thin film, the thin film substrate, or the substrate for light-emitting device, etc. have optical permeability in a state where it is actually used, in the range in which the thickness is at least 0.01-8.0 mm.

That is, even if the thickness of the above aluminum nitride-based sintered compact and other ceramic-based sintered compact is the range of at least 0.01-8.0 mm, or except it, the optical transmissivity may just be at least not less than 1% in a state where it is actually used, for example, even if the thickness, such as 0.1 mm or 2.0 mm, etc., is not actually 0.5 mm necessarily as a substrate for light-emitting device, the luminous efficiency of the light-emitting device produced will tend to improve if it has optical permeability and optical transmissivity is at least not less than 1%.

That having optical permeability by making it thin even if it does not have optical permeability in the thick state is included in this invention.

That is, for example, even if it does not have optical permeability when the thickness of the aluminum nitride-based sintered compact and other ceramic-based sintered compact is 0.5 mm, it is contained in this invention if it shows optical permeability by making thickness thin.

Even if it does not have optical permeability when the thickness of the aluminum nitride-based sintered compact and other ceramic-based sintered compact is thicker than 0.5 mm, for example, it is contained in this invention if it shows optical permeability by setting thickness to 0.5 mm.

If another word expresses optical permeability, as optical transmissivity of this invention, it is unrelated to the thickness of the aluminum nitride-based sintered compact and other ceramic-based sintered compact, and it is contained in this invention if the optical transmissivity of the sintered compact is not less than 1%.

That is, even if the optical transmissivity is smaller than 1% when the thickness of the aluminum nitride-based sintered compact and other ceramic-based sintered compact is 0.5 mm, for example, it is contained in this invention if the optical transmissivity is not less than 1% by making thickness thin.

For example, even if the optical transmissivity is smaller than 1% when the thickness of the aluminum nitride-based sintered compact and other ceramic-based sintered compact is thicker than 0.5 mm, it is contained in this invention if the optical transmissivity is not less than 1% by making thickness 0.5 mm.

As mentioned above, the optical permeability in a state where the sintered compact is actually used is important, as optical permeability of the aluminum nitride-based sintered compact and other ceramic-based sintered compact according to this invention.

Therefore, it is contained in this invention if it has optical permeability in a state where the sintered compact is actually used, as the aluminum nitride-based sintered compact and other ceramic-based sintered compact.

In the ceramic-based sintered compact, a sintered compact comprising as a main component aluminum nitride is preferred for a substrate because the thermal conductivity is high and the thermal expansion coefficient is close to the III-V group nitride thin film.

That is, the thermal expansion coefficient of the gallium nitride is 5.59×10⁻⁶ (° C.⁻¹), that of the indium nitride is 5.70×10⁻⁶ (° C.⁻¹), and that of the aluminum nitride is 5.64×10⁻⁶ (° C.⁻¹), in 0-800° C.

Therefore, it has a feature in which warp of a substrate is small when a thin film is formed.

The difference of the thermal expansion coefficient between the sapphire and the thin film is near to 3.0×10⁻⁶ (° C.⁻¹). Therefore, it is desirable to use the substrate in which the difference of the thermal expansion coefficient between the substrate and the III-V group nitride thin film is not less than 3.0×10⁻⁶ (° C.⁻¹) in 0-800° C. in order to form a thin film with high crystallinity.

The thermal conductivity of an aluminum nitride-based sintered compact is at least not less than 50 W/mK at room temperature by controlling the amount of sintering aids, oxygen, or other impurities, usually it can obtain those of not less than 100 W/mK.

Therefore, in the light-emitting device produced using as a base material the aluminum nitride-based sintered compact, it has the advantage in which the luminescence output of a light-emitting device increases since the electric power applied there can enlarge compared with the case where the base material is sapphire.

In the case of the aluminum nitride-based sintered compact and contains the above sintering aids, oxygen, or other impurities, what has the thermal conductivity not less than 150 W/mK at room temperature is obtained easily, so the input electric power to the light-emitting device which is manufactured using the aluminum nitride-based sintered compact as a base material can be heightened more, it is desirable.

In the case of the aluminum nitride-based sintered compact and contains the above sintering aids, oxygen or other impurities, what has the thermal conductivity not less than 170 W/mK at room temperature is also obtained easily, so the input electric power to the light-emitting device which is manufactured using the aluminum nitride-based sintered compact as a base material can be heightened furthermore, it is more desirable.

In the aluminum nitride-based sintered compact, when AlN purity is high, and/or aluminum nitride particles have grown, the optical transmissivity in the visible light or in the ultraviolet light will increase. it brings the secondary effect in which the thermal conductivity can also be improved into not less than 200 W/mK at room temperature or not less than 220 W/mK.

Usually, the size of aluminum nitride particles in the sintered compact is 1-5 μm, but the size can grow to not less than 5 μm, not less than 8 μm, not less than 15 μm, and not less than 25 μm by the high-temperature and long-time firing. On the case, the size of aluminum nitride particles can grow to about 100 μm. AlN purity in the sintered compact may become high by the above high-temperature and long-time firing, the sintered compact in which tha AlN content is not less than 95% may be obtained, and the sintered compact having AlN single phase may be obtained depending on the case.

When the as-fired surface of the above a ceramic-based sintered compact substrate is used, it is preferred to use what has the condition of having removed affixes, dust particles, and projections, etc. in the surface of a substrate by brushing or honing using the alumina powder, etc.

Lap grinding can be satisfactorily carried out by the method which used alumina abrasive grain, silicon carbide abrasive grain, a diamond abrasive grain, etc. with the lap grinding machine usually used.

Blast polish can be satisfactorily carried out with the usual sandblasting machine, etc. by using alumina abrasive grain, silicon carbide abrasive grain, etc.

Specular surface polish can be satisfactorily carried out by the method which used suitably the abradant comprising as a main component a fine grain, such as alumina, cerium oxide, a diamond, silicon oxide, or chromium oxide, etc., with the grinder having usual tools (polisher), such as a pad made by cloth and a polyurethane pad, etc. In a ceramic-based sintered compact, those having an average surface roughness of not more than 10 nm, not more than 5 nm, and not more than 1-3 nm, may be obtained by these methods.

As for the average surface roughness Ra of the substrate wherein the thin film was first formed on the ceramic-based sintered compact substrate, that which is not more than 2 nm at least, and is not more than 1 nm is easily obtained, and a single-crystal thin film, an amorphous thin film, a polycrystalline thin film, and an orientated polycrystalline thin film may be formed further on it.

Though such surface smoothness by the thin film formed on the a ceramic-based sintered compact substrate may be produced spontaneously, it is attained also by carrying out the mechanochemical grinding (grinding by mechanical chemical operation) or mirror-polishing using the grinding or polishing machines and the abradants which were illustrated above.

A usual method in which the processing is carried out using chemicals and abrasive soap, etc. may be used as the above mechanochemical grinding or polishing.

By carrying out the mechanochemical grinding or mirror-polishing, the average surface roughness Ra of a thin film substrate can be at least not more than 10 nm. A thin film substrate having an average surface roughness Ra of not more than 3 nm, preferably not more than 2 nm, more preferably not more than 1 nm, can be produced.

As for the reason wherein the excellent smoothness which is at least equivalent to the ceramic-based sintered compact is obtained by carrying out the mechanochemical grinding or polishing, it is surmised that it will be because there are few defects of nm level because the thin film formed on the ceramic-based sintered compact comprises finer particles compared with the ceramic-based sintered compact, or comprises the homogeneous, continuous, and unified construction (monolithic construction) which is not constituted with a particulate, etc.

If furthermore processing is carried out onto the substrate on which the above thin films were formed, such as immersing in acid, such as hydrofluoric acid (HF), hydrofluoric-nitric acid (mixed acid of HF+HNO₃), nitric acid (HNO₃), hydrochloric acid (HCl), and sulfuric acid (H₂SO₄), or heating and annealing in non-oxidizing atmosphere containing H₂, N₂, Ar, etc. or under reduced pressure, or carrying out by combining these two or more, for example, it is possible to aim at the improvement of crystallinity of the single-crystal thin film formed on the substrate surface, and it can become effective. In addition, an alkaline medicine can also be used for processing the substrate surface on which the thin films were formed.

Using the thin film substrate having such surface smoothness, if electronic devices or electronic components, such as a light-emitting device, an optical waveguide, a wiring board, and a surface acoustic wave device, are produced, what has more excellent characteristic will be easily obtained.

Especially a light-emitting device excellent in luminous efficiency can be produced.

The above mechanochemical grinding or polishing may be used for grinding or polishing of a sintered ceramic-based substrate on which a thin film is not formed. In a ceramic-based sintered compact substrate, high surface smoothness, such as not more than 10 nm, not more than 5 nm, and 1-3 nm, may be obtained by the mechanochemical grinding or polishing.

While the zinc oxide-based sintered compact not containing aluminum usually has low conductivity, the zinc oxide-based sintered compact containing aluminum in not more than 45.0 mol % on the basis of Al₂O₃ has higher conductivity.

Specifically, the zinc oxide-based sintered compact containing aluminum in a range of 0.001-45.0 mol % on the basis of Al₂O₃ has electric resistivity of at least not more than 1×10² Ω·cm at room temperature.

Since the zinc oxide-based sintered compact having such conductivity does not need especially to provide conduction vias for connecting the up-and-down surface of a substrate electrically, it is preferred.

A gallium nitride-based sintered compact comprises gallium nitride particles, therefore the grain boundaries exist, in spite of not being comparatively near to a homogeneous state like a single crystal or a thin film, that usually having conductivity is obtained in many cases.

In the gallium nitride-based sintered compact, even if it is what does not contain substantially component(s), such as Be, Mg, Zn, Cd, C, Si, Ge, Se, Te, and oxygen, etc., what has the conductivity in which the electric resistivity is not more than 1×10⁸ Ω·cm at room temperature is obtained in many cases.

In the gallium nitride-based sintered compact and contains at least one selected from Be, Mg, Zn, Cd, C, Si, Ge, Se, Te, and oxygen, etc., the conductivity tends to be improved, so it is preferred.

In the gallium nitride-based sintered compact and does not contain substantially component(s), such as Be, Mg, Zn, Cd, C, Si, Ge, Se, Te, and oxygen, etc., it does not necessarily have the conductivity in which the electric resistivity is not more than 1×10⁴ Ω·cm in room temperature, but in the gallium nitride-based sintered compact and contains at least one selected from Be, Mg, Zn, Cd, C, Si, Ge, Se, Te, and oxygen, the conductivity tends to be improved to the electric resistivity of not more than 1×10⁴ Ω·cm in room temperature, so it is preferred.

Specifically, in the gallium nitride-based sintered compact and contains at least one selected from Be, Mg, Zn, Cd, C, Si, Ge, Se, Te, and oxygen not more than 10.0 mol % on an element basis, the conductivity improves, what is the electric resistivity not more than 1×10⁴ Ω·cm at least at room temperature is easily obtained, for example.

In the gallium nitride-based sintered compact and contains at least one selected from Be, Mg, Zn, Cd, C, Si, Ge, Se, Te, and oxygen in the range of 0.00001-10.0 mol % on an element basis, the conductivity improves, what is the electric resistivity not more than 1×10³ Ω·cm at least at room temperature is easily obtained, for example.

In the above gallium nitride-based sintered compact, even if it contains at least one selected from an alkaline earth metal component, such as CaO, SrO, and BaO, etc., a rare earth element component, such as Sc₂O₃, Y₂O₃, La₂O₃, CeO₂, Pr₆O₁₁, Nd₂O₃, Pm₂O₃, Sm₂O₃, Eu₂O₃, Gd₂O₃, Tb₄O₇, Dy₂O₃, Ho₂O₃, Er₂O₃, Tm₂O₃, Yb₂O₃, and Lu₂O₃, etc., etc., a transition-metals component, such as MnO, CoO, NiO, Fe₂O₃, Cr₂O₃, TiO₂, MoO₃, WO₃, Nb₂O₅, Ta₂O₅, and V₂O₅, etc., an aluminum component, and an indium component, etc., other than at least one selected from Be, Mg, Zn, Cd, C, Si, Ge, Se, Te, and oxygen, there are few degrees in which the conductivity is spoiled.

In the above gallium nitride-based sintered compact, what has comparatively high optical permeability can be produced by firing in reduced atmosphere containing CO or H₂, etc., or in normal pressure of the non-oxidizing atmosphere containing Ar, He, or N₂, etc., or in decompression, or in high pressure condition by the hot press and HIP, etc.

That is, even if the gallium nitride-based sintered compact is what kind of composition, what has optical permeability to visible light with a wavelength not less than 360 nm and light with a wavelength longer than visible light can be produced.

For example, even if the gallium nitride-based sintered compact is what kind of composition, the optical transmissivity can be not less than 1%.

Usually, in the gallium nitride-based sintered compact and contains a gallium component not less than 55.0 mol % on a GaN basis, the optical transmissivity can be not less than 1%.

Among them, the alkaline-earth-metal component, such as BeO, MgO, CaO, SrO, and BaO, etc., and the rare earth element component, such as Sc₂O₃, Y₂O₃, La₂O₃, CeO₂, Pr₆O₁₁, Nd₂O₃, Pm₂O₃, Sm₂O₃, Eu₂O₃, Gd₂O₃, Tb₄O₇, Dy₂O₃, Ho₂O₃, Er₂O₃, Tm₂O₃, Yb₂O₃, and Lu₂O₃, etc., are effective for the optical permeability of a gallium nitride-based sintered compact.

The alkaline-earth-metal component and rare earth element component may be contained in the gallium nitride-based sintered compact separately or in combination.

In the gallium nitride-based sintered compact and contains at least one selected from a alkaline-earth-metal component and a rare earth element component not more than 30.0 mol % on an oxide basis, what is the optical transmissivity not less than 10% can be produced.

In the gallium nitride-based sintered compact and contains at least one selected from an alkaline-earth-metal component and a rare earth element component in the range of 0.0001-3.0 mol % on an oxide basis, what is the optical transmissivity not less than 60% is easily obtained.

The optical transmissivity of not less than 80%, 86% at maximum, is also obtained.

In the gallium nitride-based sintered compact and contains at least one selected from a transition-metal-elements component, such as MnO, CoO, NiO, Fe₂O₃, Cr₂O₃, TiO₂, MoO₃, WO₃, Nb₂O₅, Ta₂O₅, and V₂O₅, etc., not more than 10.0 mol % on an element basis, what is the optical transmissivity not less than 10% can be produced.

In the gallium nitride-based sintered compact and contains at least one selected from Zn, Cd, C, Si, Ge, Se, and Te not more than 10.0 mol % on an element basis, what is the optical transmissivity not less than 10% can be produced.

In the gallium nitride-based sintered compact and contains at least one selected from aluminum, indium, and oxygen not more than 40.0 mol % on an element basis, what is the optical transmissivity not less than 10% can be produced.

In the gallium nitride-based sintered compact and contains at least one selected from aluminum, indium, and oxygen not more than 30.0 mol % on an element basis, what is the optical transmissivity not less than 20% can be produced, so it is desirable.

Even if it is the gallium nitride-based sintered compact and contains simultaneously at least two above components, such as at least one selected from an alkaline-earth-metal component and a rare earth element component, at least one selected from a transition-metal-elements component, such as MnO, CoO, NiO, Fe₂O₃, Cr₂O₃, TiO₂, MoO₃, WO₃, Nb₂O₅, Ta₂O₅, and V₂O₅, etc., at least one selected from Zn, Cd, C, Si, Ge, Se, and Te, or at least one selected from aluminum, indium, and oxygen, what has optical permeability can be produced.

The gallium nitride-based sintered compact containing at least one selected from Be, Mg, Zn, Cd, C, Si, Ge, Se, Te, and oxygen in an amount of not more than 10.0 mol % on an element basis, which has not only conductivity but also improved optical permeability of not less than 10% can be produced.

In the gallium nitride-based sintered compact and contains at least one selected from Be, Mg, Zn, Cd, C, Si, Ge, Se, Te, and oxygen in the range of 0.00001-10.0 mol % on an element basis, not only what has conductivity but also what is the optical permeability not less than 20% can be produced, furthermore what is the optical permeability not less than 30%, not less than 40%, not less than 50%, not less than 60%, and not less than 80% is also producible.

In the gallium nitride-based sintered compact having conductivity and optical permeability, even if it is not only what contains at least one selected from Be, Mg, Zn, Cd, C, Si, Ge, Se, Te, and oxygen but also what contains simultaneously at least one selected from an alkaline-earth-metal component, such as CaO, SrO, and BaO, etc., and a rare earth element component, such as Sc₂O₃, Y₂O₃, La₂O₃, CeO₂, Pr₆O₁₁, Nd₂O₃, Pm₂O₃, Sm₂O₃, Eu₂O₃, Gd₂O₃, Tb₄O₇, Dy₂O₃, Ho₂O₃, Er₂O₃, Tm₂O₃, Yb₂O₃, and Lu₂O₃, etc., or what contains simultanesouly at least one selected from Be, Mg, Zn, Cd, C, Si, Ge, Se, Te, and oxygen and at least one selected from a transition-metal-elements component, such as MnO, CoO, NiO, Fe₂O₃, Cr₂O₃, TiO₂, MoO₃, WO₃, Nb₂O₅, Ta₂O₅, and V₂O₅, etc., or what contains simultaneously at least one selected from Be, Mg, Zn, Cd, C, Si, Ge, Se, Te, and oxygen and at least one selected from aluminum and indium, it is rare that the above conductivity or optical permeability decrease.

A gallium nitride-based sintered compact is produced easily by firing a gallium nitride-based powder compact at about 1000-1700° C. in a non-oxidizing atmosphere.

It is preferably fired at 1200° C. or higher to have high optical permeability.

Any raw material powder of gallium nitride can be used to produce the above gallium nitride-based sintered compact, and it is desirable to use those excellent in sinterability to produce the gallium nitride-based sintered compact having optical permeability.

Fine powder with an average particle diameter of not more than 10 μm can be used suitably to produce a gallium nitride-based sintered compact having optical permeability. Powder having an average particle diameter not more than 5.0 μm is more preferred, and powder having an average particle diameter not more than 2.0 μm is more preferred. Powder having an average particle diameter not more than 1.0 μm can be used.

Even if the average particle diameter is larger than 10 μm, it can be used suitably by grinding it to finer powder of not more than 10 μm by a ball mill, or a jet mill, etc.

Such gallium nitride-based raw material powder may be as follows:
(1) A product of a direct nitriding reaction of metal gallium with a nitrogen-containing compound such as nitrogen and ammonia.
(2) A product of a reduction-nitriding of gallium oxide with a reducing agent such as carbon, and a nitrogen-containing compound such as nitrogen and ammonia.
(3) A product of a chemical transport method in which a gaseous gallium compound such as trimethyl gallium and gallium chloride state is reacted with a nitrogen-containing compound.

Gallium nitride powder may be produced by reacting metal gallium with a gas containing a nitrogen compound such as nitrogen and ammonia at about 300-1700° C., after the metal gallium is vaporized by heating at about 300-1700° C. in an inert atmosphere such as argon and helium, or in a reducing atmosphere such as hydrogen.

Gallium nitride powder may also be produced by a reduction and nitriding reaction of gallium oxide by heating a mixture of gallium oxide powder and carbon powder with a gas containing a nitrogen compound at about 400-1600° C. Remaining carbon may be removed by heating in an oxidizing atmosphere such as air.

Gallium nitride powder may also be produced by vaporizing a gallium compound such as gallium chloride, gallium bromide or trimethyl gallium by heating at about 50-1800° C. in a non-oxidizing atmosphere such as argon, helium or nitrogen, or in a reducing atmosphere such as hydrogen, and reacting a gaseous gallium compound with a gas containing a nitrogen compound at about 300-1800° C., in the presence of a reducing gas, if needed.

Oxygen may be contained as impurities in such powder comprising gallium nitride as a main component and can be used as a raw material for sintered compact production, but a dense sintered compact having optical permeability, and a sintered compact having conductivity are producible, even if it is the gallium nitride-based sintered compact and is produced using such raw material powder containing impurities oxygen.

Usually, if the oxygen content of gallium nitride powder is not more than 10 weight %, in the gallium nitride-based sintered compact and is produced using this powder, optical permeability or conductivity may be shown.

When the gallium nitride-based sintered compact and is produced using the gallium nitride powder in which the oxygen content is not more than 10 weight % is used, a single-crystal thin film comprising as a main component at least one selected from gallium nitride, indium nitride and aluminum nitride and is excellent in crystallinity, such that the half width of the rocking curve of the X-ray diffraction line from a lattice plane (002) is not more than 300 seconds, can be formed directly on it.

If a thin film comprising as a main component at least one selected from gallium nitride, indium nitride and aluminum nitride and having various crystallization states, such as an amorphous state, a polycrystal, an orientated polycrystal, and a single crystal, etc., is formed beforehand on the gallium nitride-based sintered compact and a single-crystal thin film comprising as a main component at least one selected from gallium nitride, indium nitride and aluminum nitride is formed furthermore on it, a thing excellent in crystallinity, such that the half width of the rocking curve of the X-ray diffraction line from a lattice plane (002) of the single-crystal thin film is not more than 130 seconds, can be formed comparatively easily.

If the oxygen content of gallium nitride powder is not more than 5.0 weight %, a gallium nitride-based sintered compact and which is the optical transmissivity not less than 5% or is the electric resistivity not more than 1×10⁴ Ω·cm at room temperature is obtained, so it is preferred.

In addition, the above powder comprising gallium nitride as a main component of this invention means usually a powder containing a gallium component not less than 55.0 mol % on a GaN basis.

The content of an alkaline-earth metal in the gallium nitride-based sintered compact is expressed on the basis of BeO, MgO, CaO, SrO and BaO, respectively. The content of a rare earth metal in the sintered compact is expressed on the basis of Sc₂O₃, Y₂O₃, La₂O₃, CeO₂, Pr₆O₁₁, Nd₂O₃, Pm₂O₃, Sm₂O₃, Eu₂O₃, Gd₂O₃, Tb₄O₇, Dy₂O₃, Ho₂O₃, Tm₂O₃, Yb₂O₃ and Lu₂O₃, respectively.

If a light-emitting device is produced using a conductive ceramic-based sintered compact, such as the above zinc oxide and gallium nitride, it has the feature in which the light-emitting device having the form wherein the electric connection between electrodes and the device is possible by arranging electrodes up and down without forming conduction vias in a substrate can be produced.

When the ceramic-based sintered compact having conductivity is used, a light-emitting device of the form wherein the electrodes were arranged up and down can be produced, if the electric resistivity of the sintered compact is not more than 1×10⁴ Ω·cm in room temperature.

Usually, electric power can be supplied sufficiently in a little loss, if the electric resistivity is not more than 1×10² Ω·cm at room temperature in the sintered compact having conductivity

As the electric resistivity at room temperature of the sintered compact having conductivity, what is not more than 1×10¹ Ω·cm is preferred, what is not more than 1×10⁰ Ω·cm is more preferred, and what is 1×10⁻¹ Ω·cm is more preferred.

As the substrate for forming a thin film, a sintered compact which comprises a ceramic material as a main component and contains a component other than the main component may be used suitably.

For example, the component may be rare-earth oxides, such as Sc₂O₃, Y₂O₃, La₂O₃, CeO₂, Pr₆O₁₁, Nd₂O₃, Pm₂O₃, Sm₂O₃, Eu₂O₃, Gd₂O₃, Tb₄O₇, Dy₂O₃, Ho₂O₃, Er₂O₃, Tm₂O₃, Yb₂O₃, Lu₂O₃, or rare-earth components, such as Sc, Y, La, Ce, Pr, Nd, Pm, Sm, Eu, Gd, Tb, Dy, Ho, Er, Tm, Yb, and Lu, etc. If the they are actually used, inorganic rare earth compounds, such as carbonate, nitrate, sulfate, and chloride, containing Sc, Y, La, Ce, Pr, Nd, Pm, Sm, Eu, Gd, Tb, Dy, Ho, Er, Tm, Yb, Lu, etc., and other various rare-earth compounds, such as organic rare earth compounds, such as acetate, oxalate, and citrate.

The component may be alkaline earth metal oxides, such as BeO, MgO, CaO, SrO, and BaO, or alkaline earth metal components, such as Be, Mg, Ca, Sr, and Ba, or inorganic alkaline-earth-metal compounds, such as carbonate, nitrate, sulfate, and chloride, etc. containing Be, Mg, Ca, Sr, Ba, etc., or other various alkaline-earth-metal compounds, such as organoalkaline-earth-metal compounds, such as acetate, oxalate, and citrate.

Alkali metals and alkali metal compounds, such as Li₂O, Li₂CO₃, LiF, LiOH, Na₂O, Na₂CO₃, NaF, NaOH, K₂O, K₂CO₃, KF, and KOH, may be used as the component.

III group elements and their compounds, such as B, Al, Ga, In, B₂O₃, BN, Al₂O₃, AlN, Ga₂O₃, GaN, In₂O₃, InN, etc., may be used as the component.

Silicon and silicon compounds, such as SiO₂, Si₃N₄, and SiC, may be used as the component.

Transition metals, alloy, and metal compound containing Mo, W, V, Nb, Ta, Ti, Fe, Ni, Co, Cr, Mn, Zr, Hf, Cu, and Zn, etc., may be used as the component.

Carbon may also be used as the component.

The above component other than the main component may be used for a sintering aid, an agent for decreasing the firing temperature, and an agent for blackening the sintered compact which comprises a ceramic material as a main component, etc.

The above component other than the main component may control the characteristic of the sintered compact which comprises a ceramic material as a main component, such as the diameter of a particle, optical permeability, and thermal conductivity, etc., by the existence and content of these components.

Furthermore, the above component other than the main component may be used for an agent for controlling the electrical conductivity of a sintered compact which comprises a ceramic material as a main component.

The content of the main component is 50 or more volume % in the sintered compact which comprises a ceramic material as a main component, the content of the above component other than the main component may be 50 or less volume %.

As the sintered compact which comprises a ceramic material as a main component, that which contains comparatively a lot of the component other than the main component may be used for forming a thin film. For example, even if it is the sintered compact in which the content of the component other than the main component is 1-50 volume %, it may be used suitably for the substrate for forming a thin film.

A high purity sintered compact in which the content of the component other than the main component is 1 or less volume %, for example, almost 100 or less ppm, may also be used for the substrate for forming a thin film.

Even if it is a ceramic-based sintered compact which has such composition, a thin film which comprises as a main component at least one selected from gallium nitride, indium nitride, and aluminum nitride may be formed on it, the thin film which is at least partially a single crystal or has at least a single crystal layer may be unified with it.

In this invention, the “thin film” usually means the “thin film comprising III-V group nitride, such as gallium nitride, indium nitride, and aluminum nitride,” unless it is indicated specially. It differs from the “thin film conductivity material comprising various metal and alloy, etc.”, and is distinguished clearly. It also differs from the “thin film which comprises as a main component zinc oxide” and is distinguished clearly. The explanation about the “thin film conductivity material” is also shown below. The explanation about the “thin film which comprises as a main component zinc oxide” is shown below independently.

This inventor has investigated about the formation of a thin film which comprises as a main component at least one selected from gallium nitride, indium nitride, and aluminum nitride, using a sintered compact which comprises a ceramic material as a main component and on which a thin film comprising a material having electric conductivity is formed.

The above “thin film comprising a material having electric conductivity” is usually various metals, alloys, multilayered metals, metal nitrides, metal carbides, and metal silicides, etc., it is different from the thin film which comprises III-V group nitride, such as gallium nitride, indium nitride, and aluminum nitride.

If saying more concretely, the above “thin film comprising a material having electric conductivity” is a material comprising as a main component at least one selected from gold, silver, copper, aluminum, iron, cobalt, nickel, manganese, ruthenium, rhenium, rhodium, palladium, osmium, iridium, platinum, molybdenum, tungsten, chromium, titanium, zirconium, vanadium, niobium, tantalum, rare earth metals, such as Sc, Y, La, Ce, Pr, Nd, Sm, Eu, Gd, Dy, Ho, Er, Yb, and Lu, etc., tungsten/copper alloy, nickel/chromium alloy, three-layer metal of titanium/platinum/gold(Ti/Pt/Au), titanium nitride, zirconium nitride, tantalum nitride, titanium carbide, tungsten carbide, and molybdenum silicide, etc.

In this invention, the above “thin film comprising a material having electric conductivity” is only called “thin film conductivity material,” the thin film conductivity material is different from a thin film which comprises as a main component at least one selected from gallium nitride, indium nitride, and aluminum nitride, and is distinguished clearly.

The thin film conductivity material may be formed sufficiently by the conventional methods for forming a thin film, such as the CVD method including the MOCVD method, the sputtering method, the ion-plating method, the vapor-depositing method, etc.

In this invention, even if it is a sintered compact which comprises a ceramic material as a main component and on which a thin film conductivity material is formed, a thin film which comprises as a main component at least one selected from gallium nitride, indium nitride, and aluminum nitride may be formed on it, and the thin film which comprises as a main component at least one selected from gallium nitride, indium nitride, and aluminum nitride may be unified firmly with the sintered compact which comprises a ceramic material as a main component. If the thin film which comprises as a main component at least one selected from gallium nitride, indium nitride, and aluminum nitride is at least partially a single crystal or has at least a single crystal layer, the thin film may be unified firmly with the sintered compact which comprises a ceramic material as a main component.

Cracks are not seen in the formed thin film which comprises as a main component at least one selected from gallium nitride, indium nitride, and aluminum nitride, and in the thin film conductivity material. Faults, such as exfoliation, are hard to be seen in the interface between the thin film conductivity material and the thin film which comprises as a main component at least one selected from gallium nitride, indium nitride, and aluminum nitride. Junction strength between the thin film which comprises as a main component at least one selected from gallium nitride, indium nitride, and aluminum nitride and the sintered compact which comprises a ceramic material as a main component and on which a thin film conductivity material is formed is usually 2 or more Kg/mm², and is 4 or more Kg/mm² depending on the case.

Therefore, it seems that the thin film conductivity material is joined firmly with the sintered compact which comprises a ceramic material as a main component, and that the junction strength between the sintered compact which comprises a ceramic material as a main component and the thin film conductivity material is usually 2 or more Kg/mm².

The thin film conductivity material may usually be formed in the state where the thickness is 0.1 nm-10 or more μm. Even if the thin film conductivity material has such thickness, a thin film which comprises as a main component at least one selected from gallium nitride, indium nitride, and aluminum nitride may be formed firmly on the ceramic-based sintered compact on which the thin film conductivity material is formed.

The crystallinity of the III-V group nitride thin film formed on the thin film conductivity material may be improved depending on the case. If the thickness of the formed thin film conductivity material is 100 or less nm (usually, 0.05-100 nm), the crystallinity of the thin film formed on the thin film conductivity material may usually be improved. It is more preferred that the thickness of the thin film conductivity material is 30 or less nm (usually, 0.05-30 nm) in order to improve the crystallinity more. It is still more preferred that the thickness of the thin film conductivity material is 10 or less n (usually, 0.05-10-nm). It is most preferred that the thickness of the thin film conductivity material is 5 or less m-n (usually, 0.05-5 nm). The reason in which such improvement is attained is not clear necessarily, but it seems that the monoatomic layer of the thin film conductivity material is first formed in the state where the crystal direction is aligned almost in one direction if the thickness becomes thin.

Thus, a single-crystal thin film which comprises as a main component at least one selected from gallium nitride, indium nitride, and aluminum nitride and has high crystallinity may be formed on a sintered compact which comprises a ceramic material as a main component and on which a thin film conductivity material is formed.

The above thin film conductivity material may also be used for an electrode of a semiconductor device.

The thin film conductivity material may be formed firmly on the surface of the thin film which comprises as a main component at least one selected from gallium nitride, indium nitride, and aluminum nitride. The thin film conductivity material may also be formed firmly in the inside of the thin film. The junction strength between the thin film conductivity material and the thin film is usually 2 or more Kg/mm² in the above state.

Such a thin film conductivity material formed on the thin film may be used for an electrode of a semiconductor device, or for a terminal for evaluating the junction nature between the thin film and the sintered compact comprising a ceramic material as a main component, using the method wherein a lead is attached to the terminal by soldering, etc. and the perpendicular tensile strength is carried out.

A thin film comprising as a main component at least one selected from gallium nitride, indium nitride and aluminum nitride and contains a single crystal or a single crystal layer at least is integrally adhered to the above zinc oxide-based sintered compact, and furthermore a thin film comprising as a main component zinc oxide and contains a single crystal or a single crystal layer at least can also be integrally adhered to the sintered compact, in addition to this. Besides the thin film containing a single crystal or a single crystal layer at least, thin films, such as an amorphous state, a polycrystal, and an orientated polycrystal, can also be formed, and it may be unified. The thin film comprising as a main component zinc oxide and contains a single crystal or a single crystal layer at least means usually the thin film which indicates the crystallinity in which the half width of the rocking curve of the X ray diffraction from a lattice plane (002) is 3600 or less seconds. Usually, that with high crystallinity in which the half width of the rocking curve is 300 or less seconds, for example 100 or less seconds, may be formed easily.

The thin film comprising as a main component zinc oxide and containing a single crystal or a single crystal layer at least or contains an amorphous state, a polycrystal or an orientated polycrystal at least is unified firmly with the zinc oxide-based sintered compact. The thin film comprising as a main component zinc oxide is preferred because it has a function as a semiconductor device emitting light with a comparatively short wavelength of about 300-500 nm.

By containing metals such as lithium, magnesium, calcium, aluminum, gallium, indium and silicon, and nonmetals such as carbon, nitrogen, phosphorus, arsenic and sulfur, the characteristic as N- or P-type semiconductor can be improved.

The zinc oxide-based thin film is more easily integrated with the zinc oxide-based sintered compact, than the thin film comprising gallium nitride, indium nitride or aluminum nitride as a main component. The adhesion strength of the zinc oxide-based thin film to the zinc oxide-based sintered compact is at least 2 kg/mm², particularly 5 kg/MM² or more, higher than that of the non-oxide thin film, thereby avoiding cracking and exfoliation. This is presumably due to high affinity to the zinc oxide-based sintered compact.

If it is not less than 0.1-0.5 nm as thickness of the zinc oxide-based thin film, it may be unified satisfactorily with the zinc oxide-based sintered compact. Even if the thickness is comparatively thick, such as about 200-300 μm, it may be unified satisfactorily. Usually, desirable thickness is not more than 100 μm. It is more preferable that the thickness is not more than 10-50 μm, firm unification can be attained. The thin film having such a feature and comprising as a main component a metal oxide, such as zinc oxide, can be easily formed by the same method as the case where the thin film of non-oxides, such as gallium nitride, indium nitride, and aluminum nitride, is formed. It can use the MOCVD method, other CVD methods, the MBE method, the sputtering method, the ion-plating method, and the vapor-depositing method, etc.

The thin film comprising as a main component zinc oxide means usually those containing a zinc oxide component at least 50 or more mol %. The other components in the thin film are preferably 50 mol % or less. It is desirable that a thin film contains a zinc oxide component 50 or more mol %, because it can unify more firmly with the zinc oxide-based sintered compact.

Thus, this invention includes a semiconductor device, wherein a thin film comprising as a main component zinc oxide and a zinc oxide-based sintered compact are unified.

The thin film comprising as a main component zinc oxide contains a single crystal or a single crystal layer at least. The thin film comprising as a main component zinc oxide contains at least one of crystallization states selected from an amorphous state, a polycrystal, and an orientated polycrystal.

The above thin films comprising as a main component zinc oxide may also be unified firmly with a ceramic-based sintered compact other than zinc oxide.

There is neither crack nor exfoliation, and adhesion strength is at least 2 kg/mm², usually as high as 3 or more kg/mm².

Though the reason is not necessarily clear, this inventor is surmising that it has higher affinity to the sintered compact comprising as the main components a ceramic material, because oxygen is contained in the constitution component, as well as the case of the zinc oxide-based sintered compact.

It is more desirable to use a ceramic material having a hexagonal and/or trigonal crystal structure, such as beryllium oxide, aluminum oxide, silicon carbide, silicon nitride, aluminum nitride, and gallium nitride, as the above ceramic material.

In addition, it is also desirable to use an oxide ceramic material as the ceramic material, because it is unified firmly with the zinc oxide-based thin film. For example, as such a sintered compact, there is a sintered compact comprising at least one selected from zirconium oxide, magnesium oxide, magnesium aluminate, titanium oxide, barium titanate, lead titanate zirconate, a rare earth element oxide, thorium oxide, various ferrites, mullite, forsterite, steatite and glass

As the above zinc oxide-based thin film formed on a ceramic-based sintered compact, not only the crystallization state containing a single crystal or a single crystal layer at least but the crystallization state of an amorphous state, a polycrystal, and an orientated polycrystal, etc., may be unified firmly with the sintered compact comprising as the main components a ceramic material.

About the crystallinity of the zinc oxide-based thin film formed on the sintered compact which comprises as a main component a ceramic material, a single-crystal thin film in which the half width of the rocking curve of the X ray diffraction from the lattice plane of the Miller Index (002) is 3600 or less seconds may be formed. Usually, that with high crystallinity in which the half width of the rocking curve is 300 or less seconds, for example 100 or less seconds, may be formed easily.

Using mainly a thin film comprising as a main component zinc oxide and formed on a ceramic-based sintered compact, such as zinc oxide, semiconductor devices, such as a light-emitting device and a transistor, and another electronic devices, etc., are producible. The present invention will be explained in further detail referring to Examples below, without intension of restricting the present invention thereto.

### EXAMPLE 1

High-purity, submicron ceramic raw material powders used were aluminum nitride powder of grade “F” available from Tokuyama, Inc., silicon carbide powder of grade “OY-15” available from Yakushima Denko Co., Ltd., silicon nitride powder of grade “SN-E05” available from Ube Industries, Ltd., aluminum oxide powder of grade “AKP-30” available from Sumitomo Chemical Co., Ltd., partially stabilized zirconia powder of grade “TZ-3Y” containing 3 mol % of Y₂O₃ as a stabilization agent available from TOSOH CORP., zinc oxide of “first grade” available from Sakai Chemical Industry Co., Ltd., guaranteed magnesium oxide powder available from Kanto Kagaku, and beryllium oide powder and magnesium aluminate (MgAl₂O₄: spinel) powder both available from Kojundo Chemical Laboratory Co., Ltd. The purity was not less than 99 weight % except for partially stabilized zirconia. The oxygen content was 1.0 weight % in the aluminum nitride powder. 1.0% by weight of B₄C powder and 1.0% by weight of carbon powder were added to silicon carbide. 2.0% by weight of Y₂O₃ powder and 2.0% by weight of Al₂O₃ powder were added to silicon nitride powder. 1.8% by weight of CaCO₃ powder was added to beryllium oxide powder. Each resultant mixture was wet-blended in ethanol in ball mill for 24 hours, and dried.

5% by weight of paraffin wax was added to each powder to produce powder for molding, and disk-like powder compacts of 25.4 mm in diameter and 1.5 mm in thickness and those of 32 mm in diameter and 1.5 mm in thickness were obtained by uniaxial pressing.

These powder compacts were fired under the conditions shown in Table 1 after degreasing under reduced pressure at 300° C. to obtain sintered compacts.

The relative density of each sintered compact was not less than 99%. The surfaces of these sintered compacts were mirror-polished using a chromic oxide and alumina abradant, ultrasonic washing was carried out with acetone, and the substrates for thin film formation were produced. The surface roughness of each substrate obtained is shown in Table 1.

The constitution phase of these substrates was investigated by X ray diffraction. As the result, the X ray diffraction pattern shown by the sintered compact obtained using aluminum nitride powder as raw material was the crystal phase indicated by the file number 25-1133 of JCPDS, comprising as a main phase AlN (hexagonal).

The X ray diffraction pattern shown by the sintered compact obtained using silicon carbide powder as raw material had as a main phase α-SiC (hexagonal) indicated by the above file number 29-1131.

The X ray diffraction pattern shown by the sintered compact obtained using silicon nitride powder as raw material had as a main phase β-Si₃N₄ (Hexagonal) indicated by the above file number 33-1160, and contains unknown phase 6.6% in addition to this.

The X ray diffraction pattern shown by the sintered compact obtained using aluminum oxide powder as raw material had as a main phase α-Al₂O₃ (Trigonal) indicated by the above file number 10-173.

The X ray diffraction pattern shown by the sintered compact obtained using zirconium oxide powder as raw material had as a main phase ZrO₂ (Tetragonal) indicated by the above file number 17-923.

The X ray diffraction pattern shown by the sintered compact obtained using zinc oxide powder as raw material had as a main phase ZnO (Hexagonal) indicated by the above file number 36-1451.

The X ray diffraction pattern shown by the sintered compact obtained using magnesium oxide powder as raw material had as a main phase MgO (Cubic) indicated by the above file number 4-829.

The X ray diffraction pattern shown by the sintered compact obtained using beryllium oxide powder as raw material had as a main phase BeO (Hexagonal) indicated by the above file number 35-818.

The X ray diffraction pattern shown by the sintered compact obtained using magnesium aluminate powder as raw material had as a main phase MgAl₂O₄ (Cubic) indicated by the above file number 21-1152.

These sintered compacts were clearly polycrystalline substances in which the direction of the crystal grain of the main component inside a sintered compact has turned to all directions.

The result of the phase constitution by X ray diffraction of the substrate for a thin film was shown in Table 1.

Using each substrate obtained, the thin films of gallium nitride, indium nitride, and aluminum nitride were directly formed on the substrate surface by the MOCVD (Metal Organic Chemical Vapor Deposition growth) equipment by high frequency induction heating.

The produced substrates were heated at 1000° C. in a hydrogen gas in a reaction container of the above equipment.

Trimethyl gallium (TMG), trimethyl indium (TMI), and trimethyl aluminum (TMA) were used as thin film-forming materials, hydrogen or nitrogen+hydrogen was introduced into the above each three kinds of fluid raw materials as career gas, and was bubbled, and each raw material was introduced to the reaction part in which high frequency induction heating will be carried out with ammonia gas. The gallium nitride thin film was formed at the substrate temperature of 1000° C., the indium nitride thin film was formed at the substrate temperature of 700° C., the aluminum nitride thin film was formed at the substrate temperature of 1100° C., and the mixed crystal thin film of 50 mol % GaN+50 mol % AlN was formed at the substrate temperature of 1050° C. The formation rate of the thin film is about 0.2-0.4 μm/hour, 0.2-0.5 μm/hour, 1-3 μm/hour, 0.5-1.5 μm/hour, respectively. In addition, the thickness of each formed thin film is 0.25 μm.

Only in the case of the aluminum nitride thin film formed on the aluminum nitride-based sintered compact substrate, what has the thickness of 3 μm and 6 μm was produced.

Observation of each thin film obtained was performed using the optical microscope and the electron microscope, but a crack was not seen inside the thin films, and exfoliation was not seen in the interface between the thin film, the aluminum nitride-based sintered compact, and the other various ceramic-based sintered compacts.

Tested by pasting up and tearing off after adhesive tape is pasted up to each thin film obtained, but exfoliation was not seen in the interface between the thin films, the sintered compacts comprising aluminum nitride as a main component, and the other various ceramic-based sintered compacts, so the thin films have been unified firmly with the sintered compacts comprising aluminum nitride as a main component, and the other various ceramic-based sintered compacts.

The thin conductive film of Ti/Pt/Au was formed in each above thin film formed, the metal leads were soldered, and the perpendicular tensile strength was investigated, but it all is not less than 2 kg/mm², so the aluminum nitride-based sintered compact, and the other various ceramic-based sintered compacts, are integrally adhered to each thin film.

The crystallization state of the thin film was investigated by measuring the X ray diffraction pattern of each thin film using the CuKα line after thin film formation, furthermore, the rocking curve of the X ray diffraction from a lattice plane (002) of each thin film was taken, and the half width was measured.

Only in the case of the aluminum nitride thin film as thick as 0.25 μm formed on the aluminum nitride-based sintered compact substrate, electron beam diffraction was performed, and the crystallization state of the thin film was investigated.

The result is shown in Table 1.

Table 1 indicates that a thin film directly formed on the substrate comprising a sintered compact comprising as a main component zirconium oxide, magnesium oxide, or a spinel is not a single crystal.

Since the diffraction line has appeared not only from the Miller Index (002) lattice plane but also from the (100) lattice plane, it is obvious that it is a polycrystalline state.

In the thin film formed on the other sintered compact substrate, only the diffraction line from the Miller Index (002) lattice plane does appear, it has been in single crystal state.

In every substrate, the half width of the rocking curve of the Miller Index (002) lattice plane of the single-crystal-ized thin film was not more than 3600 seconds.

As for the formation direction of these single-crystal thin films to the substrate, C axis of these single-crystal thin films was a perpendicular direction to the substrate surface, in all the sintered compact in which the thin film has become a single crystal state.

From this experimental result, I can guess that the cause in which a thin film did not become a single crystal state is that the crystal system of zirconium oxide is a tetragonal system and it is a cubic system in the case of magnesium oxide and a spinel.

The main component of other substrates is a hexagonal system altogether except aluminum oxide.

Though the crystal system of the above aluminum oxide is a trigonal system, the classification as a hexagonal system is also possible for it. As for those in which the thin film formed directly on it can become a single crystal state, it seems that it is essentially only the case of the substrate comprising a sintered compact comprising as a main component the material of a hexagonal system and the material which can be classified as a hexagonal system.

As is clear from the experimental result, a single-crystal thin film was formed directly on the aluminum nitride-based sintered compact substrate.

In almost all the formed thin film, the half width of the rocking curve of the X ray diffraction from a lattice plane (002) is as sharp as not more than 300 seconds, and it excels in crystallinity.

As mentioned above, even if the various sintered compacts comprising as a main component a ceramic material are used as a substrate, it was confirmed that the single-crystal thin film comprising as a main component at least one selected from gallium nitride, indium nitride and aluminum nitride can be formed directly on the substrates made from a sintered compact.

The crystallinity of the single-crystal thin film produced using the aluminum nitride-based sintered compact was most excellent in it.

TABLE 1

| | Characteristics of the substrates consisting | | | | Characteristics of the thin films formed | | | |
|---|---|---|---|---|---|---|---|---|
| | of a various sintered compact | | | | on the sintered compact | | | |
| | | | Main | Average | | | | Half width |
| | | Firing | constitution | surface | | | | of the (002) |
| | Main | conditions | phase | roughness | | Thickness | | X ray |
| | component | at the time | of | of the | | of the | | diffraction |
| Experi- | of | of | the obtained | substrate | Composition | thin | | rocking |
| ment | the sintered | sintered compact | sintered | Ra | of | film | X ray | curve |
| No. | compact | production | compact | (nm) | the thin film | (μm) | diffraction pattern | (second) |
| 1 | Aluminum | 1950° C. × 2 | AlN | 67 | 100% GaN | 0.25 | only (002) diffraction line | 239 |
| 2 | nitride | hours | | | 100% InN | 0.25 | only (002) diffraction line | 290 |
| 3 | | in N₂ | | | 100% AlN | 0.25 | only (002) diffraction line *) | — |
| 4 | | Normal pressure | | | 100% AlN | 6.0 | only (002) diffraction line | 189 |
| 5 | | sintering | | | 50 mol % GaN + | 3.0 | only (002) diffraction line | 196 |
| | | | | | 50 mol % AlN | | | |
| 6 | | 1850° C. × 2 | AlN | 64 | 100% GaN | 0.25 | only (002) diffraction line | 275 |
| 7 | | hours | | | 100% InN | 0.25 | only (002) diffraction line | 247 |
| 8 | | in N₂ | | | 100% AlN | 0.25 | only (002) diffraction line *) | — |
| 9 | | Hot press | | | 100% AlN | 6.0 | only (002) diffraction line | 195 |
| 10 | | (300 atm) | | | 100% AlN | 3.0 | only (002) diffraction line | 229 |
| 11 | Silicon | 2050° C. × 3 hours | α-SiC | 59 | 100% GaN | 0.25 | only (002) diffraction line | 920 |
| 12 | carbide | in Ar | | | 100% InN | 0.25 | only (002) diffraction line | 970 |
| 13 | | Normal pressure | | | 100% AlN | 0.25 | only (002) diffraction line | 287 |
| | | sintering | | | | | | |
| 14 | Silicon | 1770° C. × 3 hours | β.Si₃N₄ + 6.6% | 55 | 100% GaN | 0.25 | only (002) diffraction line | 890 |
| 15 | nitride | in N₂ | of unknown | | 100% InN | 0.25 | only (002) diffraction line | 760 |
| 16 | | Gas pressure | phase | | 100% AlN | 0.25 | only (002) diffraction line | 447 |
| | | sintering | | | | | | |
| | | (9.4 atm) | | | | | | |
| 17 | Aluminum | 1600° C. × 3 hours | α.Al₂O₃ | 42 | 100% GaN | 0.25 | only (002) diffraction line | 521 |
| 18 | oxide | in air | | | 100% InN | 0.25 | only (002) diffraction line | 545 |
| 19 | | Normal pressure | | | 100% AlN | 0.25 | only (002) diffraction line | 366 |
| | | sintering | | | | | | |
| 20 | Zirconium | 1500° C. × 3 hours | ZrO₂ | 36 | 100% GaN | 0.25 | (002) diffraction line + (100) | — |
| | oxide | in air | (Tetragonal) | | | | diffraction line | |
| 21 | | Normal pressure | | | 100% AlN | 0.25 | (002) diffraction line + (100) | — |
| | | sintering | | | | | diffraction line | |
| 22 | Zinc oxide | 1350° C. × 3 hours | ZnO | 119 | 100% GaN | 0.25 | only (002) diffraction line | 1780 |
| 23 | | in air | | | 100% InN | 0.25 | only (002) diffraction line | 3270 |
| 24 | | Normal pressure | | | 100% AlN | 0.25 | only (002) diffraction line | 960 |
| | | sintering | | | | | | |
| 25 | Magnesium | 1550° C. × 3 hours | MgO | 60 | 100% GaN | 0.25 | (002) diffraction line + (100) | — |
| | oxide | in air | | | | | diffraction line | |
| 26 | | Normal pressure | | | 100% InN | 0.25 | (002) diffraction line + (100) | — |
| | | sintering | | | | | diffraction line | |
| 27 | Beryllium | 1500° C. × 3 hours | BeO | 108 | 100% GaN | 0.25 | only (002) diffraction line | 2240 |
| 28 | oxide | in air | | | 100% InN | 0.25 | only (002) diffraction line | 2970 |
| 29 | | Normal pressure | | | 100% AlN | 0.25 | only (002) diffraction line | 910 |
| | | sintering | | | | | | |
| 30 | Magnesium | 1600° C. × 3 hours | MgAl₂O₄ | 63 | 100% GaN | 0.25 | (002) diffraction line + (100) | — |
| | aluminate | in air | | | | | diffraction line | |
| 31 | | Normal pressure | | | l00% AlN | 0.25 | (002) diffraction line + (100) | — |
| | | sintering | | | | | diffraction line | |

*) by electron beam diffraction

### EXAMPLE 2

As for the crystallinity of the single-crystal thin film comprising as a main component at least one selected from gallium nitride, indium nitride and aluminum nitride and is formed directly on the aluminum nitride-based sintered compact substrate, the influence by the characteristics, such as the composition of the aluminum nitride-based sintered compact, the microstructure of the sintered compact, and the optical transmissivity, etc., was investigated.

As the raw material powder for sintered compact production used for the experiment the same high purity aluminum nitride powder [the grade “F” by Tokuyama Soda Co., Ltd. (present: Tokuyama, Inc.)] as those having been used in Example 1 was prepared.

The raw material powder is manufactured by the method of oxide reduction.

After additives, such as sintering aids, and blackening agents, etc., are suitably added to the raw material powder, it mixes by the ball mill with ethanol for 24 hours, and it was dried and the ethanol was vaporized, then paraffine wax was added to the mixed powder 5% by weight, powders for molding were produced, and the disk-like powder compacts with the diameter of 25.4 mm×thickness of 1.5 mm and the diameter of 32 mm×thickness of 1.5 mm were acquired by the uniaxial pressing.

After that, paraffine wax was degreased under reduced pressure at 300° C., the setter made from tungsten is used as an firing implement, normal-pressure sintering and atmospheric pressure sintering (gas pressure sintering) were performed surrounding the circumference of the powder compact which is a fired thing with the frame made from tungsten in pure nitrogen atmosphere so that it may not become reduced atmosphere, then the various sintered compacts comprising aluminum nitride as a main component were produced.

The various sintered compacts comprising aluminum nitride as a main component were also produced by the hot pressing and HIP (hot isostatic press: hydrostatic pressure sintering).

The detail of firing conditions is indicated in Table 2.

The aluminum nitride-based sintered compact substrate was produced by grinding and polishing the sintered compact into the size with the diameter of 25.4 mm×thickness of 0.5 mm.

In the inside of obtained various aluminum nitride-based sintered compacts, components, such as unescapable mixing components, such as oxygen in raw material powder, sintering aids, such as a rare earth element compound and an alkaline-earth-metal compound, alkaline metal, silicon component, molybdenum, tungsten, niobium, titanium, carbon, iron, nickel, etc., are not vaporized and removed almost, almost the same quantity as the inside of a powder compact is existing.

Using such obtained various substrates, a thin film comprising as a main component gallium nitride, indium nitride, and aluminum nitride was formed on the substrate surface by the method which used the MOCVD (Metal Organic Chemical Vapor Deposition) equipment with the same high frequency induction heating as Example 1.

The mixed crystal thin film of 50 mol % GaN+50 mol % InN was formed under the substrate temperature of 780° C.

It is admitted that all the obtained thin film is a single crystal by measurement of the X ray diffraction pattern using CuKa characteristic X-rays and the electron beam diffraction.

Observation of the obtained single-crystal thin films was performed using the optical microscope and the electron microscope, but a crack was not seen in the inside of the single-crystal thin films, and exfoliation in the junction interface between the single-crystal thin films and the aluminum nitride-based sintered compact is not seen.

Tested by pasting up and tearing off after adhesive tape is pasted up to each single-crystal thin film obtained, but the exfoliation and destruction in the junction interface between the single-crystal thin films and the sintered compacts comprising aluminum nitride as a main component were not seen.

The thin conductive film of Ti/Pt/Au was formed in each above single-crystal thin film formed, the metal leads were soldered and the perpendicular tensile strength was investigated, but it all is not less than 2 kg/mm², so the aluminum nitride-based sintered compact and each above single-crystal thin film have unified firmly.

The half width of the rocking curve of the X ray diffraction from a lattice plane (002) was measured, and the crystallinity of the above single-crystal thin film was investigated.

As for the formation direction of these single-crystal thin films to the substrate, C axis of these single-crystal thin films was perpendicular direction to the substrate surface altogether.

These results are shown in Table 2 and Table 3.

In Table 2, the production conditions and the characteristics of the examined substrates comprising an aluminum nitride-based sintered compact are shown.

In Table 3, composition, film thickness, and crystallinity of the single-crystal thin film comprising as a main component at least one selected from gallium nitride, indium nitride and aluminum nitride and formed on the substrates are shown, using the above various substrates comprising an aluminum nitride-based sintered compact.

TABLE 2

| | Characteristics of the substrates which consist of a sintered compact | | | | | | | | | |
|---|---|---|---|---|---|---|---|---|---|---|
| | which comprises an aluminum nitride as the main component | | | | | | | | | |
| | | | | Characteristics of the sintered compacts comprising an | | | | | | |
| | Characteristics of the powder compacts | | | aluminum nitride as the main component | | | | | | |
| | Additives | | | | | Average | Total | | Degree of | |
| | Additive name | | | | | size of | amount | Amount | the surface | |
| | in the | Amount of | | Relative | Average | AlN | of | of | smoothness | Optical |
| Experiment | powder | addition | Firing | density | pore size | particles | oxygen | ALON | Ra | transmissivity |
| No. | compact | (volume %) *1) | conditions *3) | (%) | (μm) | (μm) | (weight %) | (%) | (nm) | (%) |
| 32 | none | — | (1) | 99.4 | <0.5 | 11.2 | 0.8 | 1.6 | 32 | 28 |
| 33 | none | — | (2) | 99.6 | <0.5 | 16.7 | 0.7 | 1.5 | 34 | 46 |
| 34 | none | — | (3) | 99.6 | <0.5 | 4.5 | 1.0 | 2.1 | 35 | 52 |
| 35 | none | — | (4) | 99.7 | <0.5 | 8.9 | 0.9 | 1.8 | 32 | 49 |
| 36 | none | — | (5) | 99.2 | 0.5 | 8.4 | 0.8 | 1.7 | 32 | 19 |
| 37 | Al₂O₃ | 2.0 | (1) | 99.3 | 0.5 | 11.6 | 2.1 | 5.7 | 36 | 8.4 |
| 38 | Al₂O₃ | 7.0 | (1) | 98.6 | 0.5 | 10.9 | 4.9 | 13.4 | 37 | 5.4 |
| 39 | Al₂O₃ | 12.0 | (1) | 98.3 | 0.7 | 9.7 | 7.4 | 19.0 | 37 | 4.0 |
| 40 | Al₂O₃ | 20.0 | (1) | 98.4 | 0.6 | 12.3 | 11.9 | 25.5 | 41 | 0.6 |
| 41 | CaCO₃ | 0.01 | (6) | 99.4 | <0.5 | 4.2 | 0.9 | 1.2 | 31 | 16 |
| 42 | Y₂O₃ | 0.02 | (6) | 99.1 | 0.5 | 3.9 | 0.9 | 1.3 | 35 | 7.4 |
| 43 | Y₂O₃ | 0.1 | (6) | 99.3 | <0.5 | 4.0 | 0.9 | 1.3 | 29 | 10.6 |
| 44 | Y₂O₃ | 0.1 | (3) | 99.7 | <0.5 | 2.5 | 1.0 | 1.2 | 27 | 22 |
| 45 | CaCO₃ | 0.5 | (6) | 99.1 | 0.6 | 4.7 | 1.1 | 0.0 | 33 | 12 |
| 46 | CaCO₃ | 0.5 | (3) | 99.6 | <0.5 | 2.7 | 1.1 | 0.0 | 29 | 55 |
| 47 | Y₂O₃ | 1.0 | (6) | 99.4 | <0.5 | 4.5 | 1.3 | 0.0 | 30 | 25 |
| 48 | CaCO₃ | 3.0 | (6) | 99.2 | 0.6 | 5.0 | 2.4 | 0.0 | 32 | 23 |
| 49 | Y₂O₃ | 3.3 | (6) | 99.5 | <0.5 | 2.9 | 1.9 | 0.0 | 26 | 34 |
| 50 | Y₂O₃ | 5.0 | (6) | 99.4 | <0.5 | 3.3 | 2.4 | 0.0 | 29 | 30 |
| 51 | Y₂O₃ | 12.0 | (6) | 99.0 | 0.5 | 3.5 | 4.2 | 0.0 | 25 | 37 |
| 52 | Y₂O₃ | 15.0 | (3) | 98.9 | 0.6 | 3.9 | 5.0 | 0.0 | 21 | 28 |
| 53 | Y₂O₃ | 25.0 | (6) | 99.1 | <0.5 | 3.8 | 8.2 | 0.0 | 22 | 19 |
| 54 | Gd₂O₃ | 9.0 | (6) | 99.0 | <0.5 | 4.2 | 3.5 | 0.0 | 27 | 29 |
| 55 | Dy₂O₃ | 3.5 | (6) | 99.2 | <0.5 | 3.4 | 2.0 | 0.0 | 28 | 31 |
| 56 | Ho₂O₃ | 3.5 | (6) | 99.2 | <0.5 | 3.4 | 1.9 | 0.0 | 31 | 26 |
| 57 | Er₂O₃ | 1.0 | (6) | 99.3 | <0.5 | 3.0 | 1.2 | 0.0 | 33 | 33 |
| 58 | Er₂O₃ | 3.6 | (6) | 99.1 | <0.5 | 2.9 | 2.1 | 0.0 | 28 | 35 |
| 59 | Er₂O₃ | 10.5 | (6) | 98.8 | 0.5 | 3.7 | 4.1 | 0.0 | 23 | 21 |
| 60 | Yb₂O₃ | 0.5 | (6) | 99.2 | <0.5 | 3.8 | 1.0 | 0.0 | 34 | 17 |
| 61 | Li₂CO₃ | 0.5 | (3) | 99.4 | <0.5 | 2.5 | 0.9 | 1.4 | 45 | 8.4 |
| 62 | Si | 0.02 | (3) | 99.5 | <0.5 | 2.7 | 0.8 | 1.7 | 37 | 26 |
| 63 | Si₃N₄ | 2.5 | (3) | 99.6 | <0.5 | 2.4 | 0.8 | 0.0 | 20 | 13 |
| 64 | MoO₃ | 0.10 *2) | (1) | 99.4 | <0.5 | 9.6 | 0.8 | 1.5 | 30 | 12 |
| 65 | WO₃ | 4.5 *2) | (1) | 99.6 | <0.5 | 9.4 | 0.9 | 1.9 | 28 | 0.0 |
| 66 | Nb₂O₅ | 0.2 *2) | (1) | 99.5 | <0.5 | 11.2 | 0.9 | 1.9 | 28 | 0.2 |
| 67 | TiO₂ | 0.07 *2) | (1) | 99.1 | <0.5 | 12.3 | 0.8 | 1.6 | 30 | 4.5 |
| 68 | C | 0.7 *2) | (1) | 99.0 | <0.5 | 9.1 | 0.4 | 0.9 | 29 | 0.0 |
| 69 | Fe | 0.04 *2) | (1) | 99.3 | <0.5 | 10.7 | 0.8 | 1.5 | 32 | 12 |
| 70 | Ni | 0.6 *2) | (1) | 99.2 | <0.5 | 11.5 | 1.0 | 2.0 | 32 | 0.0 |

*1) The quantity of the additives is based on oxide conversion.
*2) The amount of addition of the additives of experiment No. 64-70 is based on element conversion.
*3) Firing conditions:
(1) Normal pressure sintering 1950° C. × 4 hours, in N₂
(2) Gas pressure sintering 1950° C. × 12 hours, in N₂ (9 Kg/cm²)
(3) Hot press 1800° C. × 2 hours, in N₂ (300 Kg/cm²)
(4) HIP firing 1900° C. × 3 hours, (2000 Kg/cm²)
(5) Normal pressure sintering 1900° C. × 4 hours, in N₂
(6) Normal pressure sintering 1800° C. × 1 hour, in N₂

TABLE 3

| | Characteristics of the single crystal thin films | | |
|---|---|---|---|
| | formed on the sintered compact comprising an | | |
| | aluminum nitride as the main component | | |
| | | | Half width of the |
| | | Thickness | (002) X ray |
| | Composition | of the | diffraction |
| Experiment | of | thin film | rocking curve |
| No. | the thin film | (μm) | (second) |
| 32 | 100% GaN | 0.25 | 180 |
| 33 | 100% GaN | 0.25 | 142 |
| 34 | 100% GaN | 0.25 | 189 |
| 35 | 100% GaN | 0.25 | 156 |
| 36 | 100% GaN | 0.25 | 175 |
| 37 | 100% GaN | 0.25 | 169 |
| 38 | 100% GaN | 0.25 | 181 |
| 39 | 100% GaN | 0.25 | 187 |
| 40 | 100% GaN | 0.25 | 774 |
| 41 | 100% GaN | 0.25 | 185 |
| 42 | 50 mol % GaN + | 0.25 | 233 |
| | 50 mol % InN | | |
| 43 | 100% InN | 0.25 | 189 |
| 44 | 50 mol % GaN + | 6.0 | 194 |
| | 50 mol % AlN | | |
| 45 | 100% GaN | 0.25 | 188 |
| 46 | 100% GaN | 0.25 | 137 |
| 47 | 100% GaN | 0.25 | 184 |
| 48 | 100% GaN | 0.25 | 179 |
| 49 | 100% GaN | 0.25 | 195 |
| 50 | 20 mol % GaN + | 6.0 | 170 |
| | 80 mol % AlN | | |
| 51 | 100% GaN | 0.25 | 167 |
| 52 | 50 mol % GaN + | 0.25 | 161 |
| | 50 mol % InN | | |
| 53 | 100% GaN | 0.25 | 652 |
| 54 | 100% GaN | 0.25 | 183 |
| 55 | 100% GaN | 0.25 | 194 |
| 56 | 100% GaN | 0.25 | 216 |
| 57 | 100% GaN | 0.25 | 226 |
| 58 | 100% GaN | 0.25 | 167 |
| 59 | 100% GaN | 0.25 | 190 |
| 60 | 100% GaN | 0.25 | 155 |
| 61 | 100% GaN | 0.25 | 224 |
| 62 | 100% GaN | 0.25 | 216 |
| 63 | 100% GaN | 0.25 | 189 |
| 64 | 100% GaN | 0.25 | 169 |
| 65 | 100% GaN | 0.25 | 186 |
| 66 | 100% GaN | 0.25 | 178 |
| 67 | 100% GaN | 0.25 | 199 |
| 68 | 100% GaN | 0.25 | 197 |
| 69 | 100% GaN | 0.25 | 191 |
| 70 | 100% GaN | 0.25 | 179 |

### EXAMPLE 3

High purity aluminum nitride powder (the grade “H” available from Tokuyama, Inc.) was prepared as the raw material powder for producing an aluminum nitride-based sintered compact. This raw material powder was manufactured by the method of oxide reductionin. This raw material powder contains oxygen 1.3 weight % as impurities.

Added to this raw material powder were 3.3 volume % of Y₂O₃ powder, 4.02 volume % of Er₂O₃ powder, and 0.6 volume % by of CaCO₃ powder on a CaO basis, and mixed with toluene and isopropyl alcohol by the ball mill for 24 hours, then an acrylic binder was added 12 weight parts to 100 weight parts of the powder raw materials, furthermore they were mixed for 12 hours and made into a paste, and the green sheets having three kinds of composition as thick as 0.75 mm by the doctor blade method were produced.

The green sheets were formed into square sheets of 35 mm×35 mm, to which circular through-holes having a diameter of 25 μm, 50 μm, 250 μm and 500 μm, respectively, were bored by YAG laser.

Each paste for conduction via produced using three kinds of powder, pure tungsten, mixed powder of 50 volume % tungsten+50 volume % copper, and a pure copper powder as a conductive component, and adding α-terpineol as a solvent, and an acrylic resin as a binder was charged into the above through-holes and dried, and normal-pressure sintering was carried out at 1820° C. in N₂ for 2 hours after a binder was removed suitably in the atmosphere comprising as a main component nitrogen or a nitrogen/hydrogen mixture, to obtain an aluminum nitride-based sintered compact having conduction vias.

Conduction vias were exposed by grinding and polishing the sintered compacts obtained into specular surface with the surface roughness Ra 26 nm.

The single-crystal thin films of gallium nitride were formed directly in the thickness of 0.25 μm by the same MOCVD method used in Example 1 and 2 on one surface side of the above substrates, and the half width of the rocking curve of the X ray diffraction from the lattice plane of the Miller Index (002) of the single-crystal thin films was measured.

Those results were shown in Table 4.

The conduction vias and the electrical conductive single-crystal thin films comprising gallium nitride as a main component were unified firmly, also the electrical connection was confirmed.

TABLE 4

| | | | Size | Electric | |
|---|---|---|---|---|---|
| | | | of | resistivity of the | Half width of |
| | | | the | conduction via | the (002) X ray |
| | Conduction | | through | (10⁻⁶ Ω · cm) | diffraction |
| Experiment | via | Sintering | hole | (Room | rocking curve |
| No. | materials | aids | (μm) | temperature) | (second) |
| 71 | 100% | Y₂O₃ | 25 | 7.4 | 189 |
| 72 | tungsten | | 50 | 6.9 | 196 |
| 73 | | Er₂O₃ | 25 | 7.7 | 207 |
| 74 | | | 250 | 6.6 | 226 |
| 75 | 50 volume % | Y₂O₃ | 25 | 4.9 | 177 |
| 76 | tungsten + 50 | | 50 | 4.4 | 192 |
| 77 | volume % | Er₂O₃ | 25 | 5.0 | 200 |
| 78 | copper | | 50 | 4.8 | 233 |
| 79 | | CaO | 25 | 5.6 | 167 |
| 80 | 100% | Y₂O₃ | 25 | 3.4 | 201 |
| 81 | copper | | 250 | 2.9 | 223 |
| 82 | | Er₂O₃ | 25 | 3.9 | 225 |
| 83 | | | 50 | 3.1 | 239 |
| 84 | | CaO | 25 | 2.7 | 155 |
| 85 | | | 500 | 2.0 | 174 |

### EXAMPLE 4

The square sheets of 35 mm×35 mm were produced from the green sheets produced in Example 3, and the sintered compacts comprising as a main component aluminum nitride were obtained by carrying out the normal-pressure sintering at 1800° C. in nitrogen for 1 hour, after the binder was degreased at 500° C. in air.

The substrates in which the degree of surface roughness Ra is 25 nm and comprising a sintered compact comprising as a main component aluminum nitride were produced by grinding and polishing the sintered compacts obtained into the square with one-side of 25.4 mm×thickness of 0.5 mm.

The thin films with various thickness of 0.7-4200 nm comprising as a main component at least one selected from gallium nitride, indium nitride and aluminum nitride were formed directly on the substrate using the same MOCVD equipment as what was used in Example 1 and 2.

In addition, the mixed thin film of 50 mol % InN+50 mol % AlN was formed at a substrate temperature of 820° C.

The resultant thin films have the diffraction line from a lattice plane (002) and were a single crystal, when X ray diffraction patterns were taken by CuKα except for the 100% aluminum nitride of the experiment No.90.

In addition, the 100% aluminum nitride thin film was investigated by electron beam diffraction, but only the diffraction line from a lattice plane (002) appeared, diffraction from the lattice plane of the Miller Index (100) was not recognized, so this was also in the state of a single crystal.

The half width of the rocking curve of the X ray diffraction from a lattice plane (002) of the obtained single-crystal thin film was measured.

The result was shown in Table 5.

In all the thickness of the single-crystal thin films, the half width of the rocking curve of the X ray diffraction from a lattice plane (002) is not more than 300 seconds.

TABLE 5

| | | | | | Half width of |
|---|---|---|---|---|---|
| | | | | | the (002) X ray |
| | | | Thin film | | diffraction |
| Experiment | Sintering | Thin film | thickness | | rocking curve |
| No. | aids | composition | (nm) | X ray diffraction pattern | (second) |
| 86 | Y₂O₃ | 100% GaN | 0.7 | only (002) diffraction line | — |
| 87 | | 100% GaN | 1000 | only (002) diffraction line | 184 |
| 88 | | 100% InN | 2.5 | only (002) diffraction line | 290 |
| 89 | | 100% InN | 1500 | only (002) diffraction line | 159 |
| 90 | | 100% AlN | 25 | only (002) diffraction line *) | — |
| 91 | | 50 mol % GaN + 50 mol % | 7.5 | only (002) diffraction line | 290 |
| | | InN | | | |
| 92 | | 50 mol % GaN + | 70 | only (002) diffraction line | 240 |
| | | 50 mol % AlN | | | |
| 93 | Er₂O₃ | 100% GaN | 2.5 | only (002) diffraction line | 260 |
| 94 | | 100% GaN | 80 | only (002) diffraction line | 250 |
| 95 | | 100% InN | 7.0 | only (002) diffraction line | 270 |
| 96 | | 100% InN | 700 | only (002) diffraction line | 166 |
| 97 | | 100% AlN | 4200 | only (002) diffraction line | 179 |
| 98 | | 50 mol % InN + 50 mol % | 5.0 | only (002) diffraction line | 290 |
| | | AlN | | | |
| 99 | | 50 mol % GaN + 50 mol % | 16 | only (002) diffraction line | 290 |
| | | AlN | | | |
| 100 | CaO | 100% GaN | 120 | only (002) diffraction line | 221 |
| 101 | | 100% InN | 6.0 | only (002) diffraction line | 290 |
| 102 | | 50 mol % GaN + 50 mol % | 10 | only (002) diffraction line | 290 |
| | | AlN | | | |

*) by electron beam diffraction

### EXAMPLE 5

The substrates comprising a sintered compact comprising as a main component aluminum nitride were newly produced using the same raw material as Example 2, the characteristics of the substrates were investigated like Example 2, furthermore, the single-crystal thin films comprising as a main component at least one selected from gallium nitride, indium nitride and aluminum nitride were formed like Example 1 and Example 2 on these substrates, and the crystallinity was investigated.

When the sintered compacts comprising as a main component aluminum nitride were produced, forming of powder compacts and degreasing of the powder compacts were performed by the same method as Example 2.

As the powder compacts, what has no additives, such as sintering aids was used, and MgO, CaCO₃, Al₂O₃, Y₂O₃, Er₂O₃, V₂O₅, and Cr₂O₃ were used as the additives, such as sintering aids.

The details are indicated in Table 6.

After degreasing the above powder compacts containing the various additives, the powder compacts were fired as a fired thing.

The firing of the powder compacts was carried out using the setter made from tungsten, that is, another prepared powder compacts comprising only aluminum nitride powder were put on the setter with the fired things, and they were fired by surrounding the circumferences by the frame of tungsten, or by surrounding the circumference of the fired things by the frame made from aluminum nitride using the setter made from aluminum nitride.

Normal pressure sintering was carried out at 1820° C. for 2 hours in N₂ of 1 atmospheric pressure.

In carrying out the hot press, firing under pressure was performed using what was once made into the sintered compacts after the normal-pressure sintering of the powder compacts was once carried out at 1820° C. for 1 hour in nitrogen using the tungsten setter.

The result is shown in Table 6.

As a result, the optical transmissivity of all the sintered compacts comprising aluminum nitride as a main component was not less than 30%.

Improving was confirmed compared with the optical transmissivity of that which does not contain an additive and was produced in Example 2.

TABLE 6

| | Characteristics of the substrates which consist of a sintered compact | | | | | | | | |
|---|---|---|---|---|---|---|---|---|---|
| | comprising an aluminum nitride as the main component | | | | | | | | |
| | Characteristics of | | Characteristics of the produced sintered compacts comprising an | | | | | | |
| | the powder compacts | | aluminum nitride as the main component | | | | | | |
| | Additives, and | | | | Average | Total | | Degree | |
| | amount of | | | Average | size of | amount | Amount | of | |
| | addition in the | | Relative | pore | AlN | of | of | the surface | Optical |
| Experiment | powder compact | Firing | density | size | particles | oxygen | ALON | smoothness | transmissivity |
| No. | (volume %) *1) | conditions *3) | (%) | (μm) | (μm) | (weight %) | (%) | Ra (nm) | (%) |
| 103 | no additive | (2) | 99.6 | <0.5 | 3.0 | 0.8 | 1.6 | 27 | 62 |
| 104 | MgO (0.4) | (1) | 99.6 | <0.5 | 2.4 | 0.9 | 1.5 | 29 | 33 |
| 105 | CaCO₃ (0.2) | (2) | 99.6 | <0.5 | 2.5 | 0.9 | 0.5 | 28 | 69 |
| 106 | CaCO₃ (0.2) | (3) | 99.4 | <0.5 | 2.4 | 0.8 | 0.4 | 27 | 54 |
| 107 | Al₂O₃ (0.4) | (1) | 99.7 | <0.5 | 2.9 | 1.0 | 2.2 | 29 | 62 |
| 108 | Y₂O₃ (0.2) | (2) | 99.7 | <0.5 | 1.9 | 0.8 | 0.6 | 26 | 74 |
| 109 | Y₂O₃ (0.2) | (3) | 99.6 | <0.5 | 2.3 | 0.8 | 0.5 | 28 | 56 |
| 110 | Er₂O₃ (3.0) | (2) | 99.8 | <0.5 | 2.0 | 1.9 | 0.0 | 26 | 67 |
| 111 | Er₂O₃ (3.0) | (3) | 99.6 | <0.5 | 2.3 | 1.9 | 0.0 | 27 | 58 |
| 112 | V₂O₅ (0.5) *2) | (1) | 99.6 | <0.5 | 2.9 | 0.9 | 1.4 | 31 | 39 |
| 113 | Cr₂O₃ (1.0) *2) | (1) | 99.4 | <0.5 | 2.2 | 0.8 | 2.0 | 33 | 31 |

| | Characteristic of the single crystal thin film formed on | | |
|---|---|---|---|
| | the sintered compact which comprises an aluminum | | |
| | nitride as the main component(s) | | |
| | | Thickness | Half width of the |
| | Composition | of the | (002) X ray diffraction |
| Experiment | of | thin film | rocking curve |
| No. | the thin film | (μm) | (second) |
| 103 | 100% GaN | 0.25 | 127 |
| 104 | 50 mol % GaN + | 0.25 | 152 |
| | 50 mol % AlN | | |
| 105 | 100% GaN | 0.25 | 122 |
| 106 | 100% GaN | 0.25 | 134 |
| 107 | 100% GaN | 0.25 | 140 |
| 108 | 100% GaN | 0.25 | 122 |
| 109 | 100% GaN | 0.25 | 141 |
| 110 | 50 mol % GaN + | 0.25 | 127 |
| | 50 mol % InN | | |
| 111 | 100% GaN | 0.25 | 131 |
| 112 | 100% InN | 0.25 | 157 |
| 113 | 100% GaN | 0.25 | 186 |

*1) The quantity of an additive is based on oxide conversion.
*2) However, in experiment No. 112 and 113, it is shown by element conversion. The amount of addition was shown in the inside of( ).
*3) Firing conditions:
(1) 1820° C. × 2 hours, in 1 atm N₂ Hot press (pressure: 300 Kg/cm²)
(2) 1900° C. × 2 hours, in 1 atm N₂ Hot press (pressure: 300 Kg/cm²)
(3) 1820° C. × 2 hours, in N₂ Normal pressure sintering

### EXAMPLE 6

Here prepared the sintered compacts which were produced in Example 1-5 and comprise as a main component aluminum nitride, and the various sintered compacts which were produced in Example 1 and comprise as a main component the ceramic material of silicon carbide, silicon nitride, aluminum oxide, zinc oxide, and beryllium oxide.

The relation between the surface smoothness of these substrates and the crystallinity of the single-crystal thin films which were formed directly on there and comprise as a main component at least one selected from gallium nitride, indium nitride and aluminum nitride was investigated.

As the surface smoothness of the substrates, what is the following three kinds of states was used.

That is, 1) those in which the substrate surface is in the as-fired state (however, surface adhesion objects were removed with a brush using alumina powder), 2) those of the state where the substrate surfaces were ground by lap polish using the grain of SiC or alumina, 3) those of the state where the substrate surfaces were mirror-polished using the abradant comprising as a main component alumina, cerium oxide, a diamond, silicon oxide, or a chromic oxide.

As for the abradant used for lap polish and its particle size, in the case of the aluminum nitride-based sintered compact, #240 of SiC was used in what was produced and used in the experiment No. 1-5 of Example 1 and what was produced in the experiment No.62 and 64 of Example 2, #280 of SiC was used in what was produced in the experiment No.107 of Example 5, #400 of SiC was used in what was produced in the experiment No.34 and 46 of Example 2, what was produced and used in the experiment No.86-92 of Example 4, what was produced and used in the experiment No. 100-102 of Example 5, and what was produced in the experiment No.105 of Example 5, and #600 of SiC was used in the case of the other sintered compacts.

In the case of the sintered compact comprising silicon carbide as a main component, the abradant with the grain size #240 of SiC was used.

In the case of the sintered compact comprising silicon nitride as a main component, the abradant with the grain size #800 of SiC was used.

In the case of the zinc oxide-based sintered compact, the abradant with the grain size #400 of alumina was used.

As for the sintered compacts comprising aluminum nitride as a main component, and the sintered compact comprising silicon nitride as a main component, heat-treatment was performed at 1200° C. in N₂ for 1 hour, after the grinding processing of lap polish.

As for the sintered compact comprising silicon carbide as a main component and carried out lap polish, heat-treatment was performed at 1 200° C. in argon for 1 hour after the grinding processing.

As for the zinc oxide-based sintered compact and carried out lap polish, heat-treatment was performed at 1000° C. in air for 1 hour after the grinding processing.

The mirror-surface polishing was carried out using the pad made from cloth of commercial item as a polisher, and using the followings as an abradant respectively.

That is, the abradant comprising as a main component a chromic oxide with the particle diameter of 0.1 μm and 0.2 μm was used for the mirror-polishing of the substrates comprising an aluminum nitride-based sintered compact.

The abradant comprising as a main component a diamond with the particle diameter of 0.1 μm (mirror-polished surface 1), and the abradant comprising as a main component a colloidal alumina with the particle diameter of 0.05 μm (mirror-polished surface 2) were used for mirror-polish of the substrates comprising a sintered compact comprising silicon carbide as a main component,

The abradant comprising as a main component a diamond with the particle diameter of 0.25 μm (mirror-polished surface 3), and the abradant comprising as a main component a colloidal alumina with the particle diameter of 0.05 μm (mirror-polished surface 4) were used for mirror-polished surface polish of the substrates comprising a sintered compact comprising silicon nitride as a main component,

The abradant comprising as a main component a diamond with the particle diameter of 0.1 μm (mirror-polished surface 5), and the abradant comprising as a main component a colloidal silicon oxide with the particle diameter of 0.02 μm (mirror-polished surface 6) were used for mirror-polished surface polish of the substrates comprising a sintered compact comprising aluminum oxide as a main component.

The abradant comprising as a main component cerium oxide with the particle diameter of 0.5 μm (mirror-polished surface 7) was used for mirror-polished surface polish of the substrate comprising a zinc oxide-based sintered compact,

The abradant comprising as a main component a diamond with the particle diameter of 0.25 μm (mirror-polished surface 8), and the abradant comprising as a main component a colloidal alumina with the particle diameter of 0.05 μm (mirror-polished surface 9) were used for mirror-surface polish of the substrates comprising a sintered compact comprising beryllium oxide as a main component.

Though not indicated in Table 7, in the case of the substrates which used what is the particle diameter 0.1 μm among the abradant comprising as a main component the chromic oxide and used for mirror-surface polish of the aluminum nitride-based sintered compact substrate, altogether what has the surface smoothness in which the surface roughness Ra is not more than 100 nm were obtained (the substrates used in the experiment No. 198-200 and the experiment No.210-211).

All other substrates carried out mirror-surface polish by the abradant comprising as a main component a chromic oxide with the particle diameter of 0.2 μm.

The surface smoothness (shown as the surface roughness Ra) of each above substrate and the surface state of the substrates which were thus produced are shown in Table 7.

After each substrate having the above surface states was washed by ultrasonic using acetone and IPA, the thin films comprising as a main component at least one selected from gallium nitride, indium nitride and aluminum nitride were formed in the thickness shown in Table 7, like the Example 1 and the Example 2, and the crystallinity was investigated.

The above experimental result is shown in Table 7.

As a result, in the substrates which used the aluminum nitride-based sintered compact, the thin films comprising as a main component at least one selected from gallium nitride, indium nitride and aluminum nitride can be formed in the state of single crystal without becoming the polycrystalline state directly in the surface even if it is in the as-fired state.

TABLE 7

| | | | | | | Characteristics of the thin films formed on a | | |
|---|---|---|---|---|---|---|---|---|
| | Characteristics of the sintered compact substrates | | | | | various sintered compact | | |
| | | Used substrates | | | | | | Half width of |
| | | Example which carried | | Surface | | | Thickness | the (002) X ray |
| | | out substrate production | | smoothness | Processing state | Composition | of | diffraction |
| Experiment | Main | Example | Experiment | Ra | in the | of | the thin film | rocking curve |
| No. | component | No. | No. | (nm) | substrate surface | the thin film | (μm) | (second) |
| 140 | Aluminum | Example 1 | 1˜5 | 670 | as-fired | 50 mol % GaN + | 0.25 | 236 |
| | nitride | | | | | 50 mol % InN | | |
| 141 | | | | 1070 | lap | 50 mol % GaN + | 0.25 | 860 |
| | | | | | | 5.0 mol % InN | | |
| 142 | | | | 34 | specular surface | 50 mol % GaN + | 0.25 | 206 |
| | | | | | | 50 mol % InN | | |
| 143 | | Example 2 | 34 | 530 | lap | 100% AlN | 6.0 | 390 |
| 144 | | | | 25 | specular surface | 100% AlN | 6.0 | 164 |
| 145 | | Example 2 | 46 | 460 | lap | 100% AlN | 6.0 | 292 |
| 146 | | | | 28 | specular surface | 100% AlN | 6.0 | 157 |
| 147 | | Example 2 | 62 | 1260 | lap | 100% AlN | 6.0 | 970 |
| 148 | | | | 22 | specular surface | 100% AlN | 6.0 | 159 |
| 149 | | Example 2 | 64 | 570 | as-fired | 100% AlN | 3.0 | 288 |
| 150 | | | | 1220 | lap | 100% AlN | 3.0 | 1330 |
| 151 | | | | 17 | specular surface | 100% AlN | 3.0 | 134 |
| 152 | | Example 4 | 86˜92 | 96 | as-fired | 100% AlN | 6.0 | 190 |
| 153 | | | | 530 | lap | 100% AlN | 6.0 | 330 |
| 154 | | | | 24 | specular surface | 100% AlN | 6.0 | 150 |
| 155 | | Example 4 | 93˜99 | 270 | as-fired | 100% InN | 0.25 | 212 |
| 156 | | | | 240 | lap | 100% InN | 0.25 | 420 |
| 157 | | | | 29 | specular surface | 100% InN | 0.25 | 171 |
| 158 | | Example 4 | 100˜102 | 210 | as-fired | 50 mol % GaN + | 1.0 | 199 |
| | | | | | | 50 mol % AlN | | |
| 159 | | | | 530 | lap | 50 mol % GaN + | 1.0 | 390 |
| | | | | | | mol % AlN | | |
| 160 | | | | 26 | specular surface | 50 mol % GaN + | 1.0 | 166 |
| | | | | | | mol % AlN | | |
| 161 | | Example 6 | 103 | 330 | lap | 100% AlN | 3.0 | 285 |
| 162 | | | | 16 | specular surface | 100% AlN | 3.0 | 126 |
| 163 | | Example 6 | 105 | 460 | lap | 100% AlN | 6.0 | 370 |
| 164 | | | | 27 | specular surface | 100% AlN | 6.0 | 160 |
| 165 | | Example 6 | 107 | 890 | lap | 100% AlN | 6.0 | 570 |
| 166 | | | | 23 | specular surface | 100% AlN | 6.0 | 161 |
| 167 | | Example 6 | 108 | 320 | lap | 100% AlN | 6.0 | 274 |
| 168 | | | | 22 | specular surface | 100% AlN | 6.0 | 159 |
| 169 | | Example 6 | 109 | 310 | as-fired | 100% GaN | 0.25 | 207 |
| 170 | | | | 300 | lap | 100% GaN | 0.25 | 274 |
| 171 | | | | 27 | specular surface | 100% GaN | 0.25 | 169 |
| 172 | | Example 6 | 110 | 310 | lap | 100% AlN | 3.0 | 282 |
| 173 | | | | 22 | specular surface | 100% AlN | 3.0 | 154 |
| 174 | Silicon | Example 1 | 11˜13 | 820 | lap | 100% AlN | 3.0 | 2670 |
| 175 | carbide | | | 6.8 | specular surface 1 | 100% AlN | 3.0 | 287 |
| 176 | | | | 2.9 | specular surface 2 | 100% AlN | 3.0 | 210 |
| 177 | Silicon | Example 1 | 14˜16 | 140 | lap | 100% InN | 3.0 | 3280 |
| 178 | nitride | | | 15 | specular surface 3 | 100% InN | 3.0 | 777 |
| 179 | | | | 4.4 | specular surface 4 | 100% InN | 3.0 | 239 |
| 180 | Aluminum | Example 1 | 17˜19 | 920 | as-fired | 100% AlN | 3.0 | 2210 |
| 181 | oxide | | | 11 | specular surface 5 | 100% AlN | 3.0 | 405 |
| 182 | | | | 1.9 | specular surface 6 | 100% AlN | 3.0 | 206 |
| 183 | Zinc oxide | Example 1 | 22˜24 | 740 | as-fired | 100% GaN | 3.0 | 2380 |
| 184 | | | | 630 | lap | 100% GaN | 3.0 | 2020 |
| 185 | | | | 29 | specular surface 7 | 100% GaN | 3.0 | 834 |
| 186 | Beryllium | Example 1 | 27˜29 | 340 | as-fired | 100% AlN | 3.0 | 2284 |
| 187 | oxide | | | 20 | specular surface 5 | 100% AlN | 3.0 | 770 |
| 188 | | | | 9.4 | specular surface 9 | 100% AlN | 3.0 | 282 |

### EXAMPLE 7

Here prepared the sintered compacts which were produced in Example 1-5 and comprise aluminum nitride as a main component, and the sintered compacts which were produced in Example 1 and comprise as a main component various ceramicss of silicon carbide, silicon nitride, aluminum oxide, zinc oxide, and beryllium oxide

The single-crystal thin films comprising as a main component at least one selected from gallium nitride, indium nitride and aluminum nitride were formed directly on these substrates by the same method as Example 1 and Example 2, and the relation between the thickness after forming the single-crystal thin films and the crystallinity of the single-crystal thin films formed was investigated.

Specular surface polish of the used substrates made from the sintered compacts comprising as a main component aluminum nitride and various ceramicss has been carried out beforehand by the same method as Example 6, and the surface roughness is shown in Table 8.

The substrate comprising a zinc oxide-based sintered compact used in this Example was ground using abradant comprising as a main component cerium oxide with the particle diameter of 0.2 μm.

In this Example, using the MOCVD method in which the conditions were changed and which was shown in Example 1, the thin film formation was performed in the condition where the substrate temperature is 1050° C. in the case of gallium nitride thin film, 650° C. in the case of indium nitride thin film, 1200° C. in the case of aluminum nitride thin film, and 1100° C. in the case of the mixed crystal thin film of 50 mol % GaN+50 mol % AlN.

The formation rate of each thin film is about 0.5-1.5 μm/hour, about 0.5-1.5μm/hour, about 2-6 μm/hour, and about 1-3 μm/hour, respectively.

Production of the single-crystal thin films comprising as a main component gallium nitride, indium nitride, and aluminum nitride was also carried out newly by the Chloride VPE (Chloride Vapor Phase Epitaxy) method which used a gallium chloride, an indium chloride, and an aluminium chloride as a raw material.

Nitrogen was used as a career gas of the vaporized raw materials, and ammonia was used for a reactive gas.

Rapid thin film formation was possible, such as 5-200 μm per hour, as the thin film formation rate.

The single-crystal thin film by the Chloride VPE method was formed on the substrates used in the experiment No.193, 195, 197, 200, 202, 203, 209, 210, 211, 213, 215, 217, and 222.

As for the substrate temperature at the time of the formation of single-crystal thin films by the Chloride VPE method, it was carried out at 1150° C. in the case of a gallium nitride thin film, at 800° C. in the case of an indium nitride thin film, and at 1280° C. in the case of an aluminum nitride thin film.

Using a silica tube as the reaction chamber, a carbon setter is heated by the high frequency induction from the outside, and the indirect heating of the substrates which were placed on it and comprise the sintered compacts comprising as a main component aluminum nitride and various ceramicss was carried out.

The result is shown in Table 8.

Table 8 shows that as for the crystallinity of the single-crystal thin films comprising as a main component at least one selected from gallium nitride, indium nitride and aluminum nitride and formed directly on the substrates of this invention comprising an aluminum nitride-based sintered compact, the half width of the rocking curve of the X ray diffraction from a lattice plane (002) of the single-crystal thin films comprising as a main component at least one selected from gallium nitride, indium nitride and aluminum nitride was not more than 240 seconds, when the thickness of the single-crystal thin films was not less than 0.3 μm.

In the above formation method of single-crystal thin films, it was confirmed that the thick thin films up to about 500-1000 μm can be formed using the Chloride VPE method.

Tested by pasting up and tearing off after adhesive tape is pasted up to each thin film obtained, as a result, there are no exfoliations in the interface between the thin films, the sintered compacts comprising aluminum nitride as a main component, and the other various ceramic-based sintered compacts, and the sintered compacts comprising aluminum nitride as a main component, and the other various ceramic-based sintered compacts, are integrally adhered to the thin films.

The thin conductive film of Ti/Pt/Au was formed in each above thin film formed, the metal leads were soldered and perpendicular tensile strength was investigated, as a result, it all is not less than 2 kg/mm², so the aluminum nitride-based sintered compact, and the other various ceramic-based sintered compacts, are integrally adhered to the thin film.

TABLE 8

| | | | | | Characteristics of the thin films formed on a | | |
|---|---|---|---|---|---|---|---|
| | Characteristics of the sintered compact substrates | | | | various sintered compact | | |
| | | Used substrates | | | | | Half width of |
| | | | | Degree of | | Thickness | the (002) X ray |
| | | Example which produced | | the surface | Composition | of | diffraction |
| Experiment | Main | Example | Experiment | smoothness | of | the thin film | rocking curve |
| No. | component | No. | No. | Ra (nm) | the thin film | (μm) | (second) |
| 189 | Aluminum | Example 1 | 1˜5 | 34 | 50 mol % GaN + 50 mol % | 1.0 | 214 |
| | nitride | | | | InN | | |
| 190 | | | | | 50 mol % GaN + 50 mol % | 4.0 | 175 |
| | | | | | InN | | |
| 191 | | | | | 50 mol % GaN + 50 mol % | 15.0 | 146 |
| | | | | | InN | | |
| 192 | | Example 2 | 34 | 25 | 100% AlN | 15.0 | 141 |
| 193 | | | | | 100% AlN | 200 | 126 |
| 194 | | Example 2 | 46 | 28 | 100% AlN | 15.0 | 140 |
| 195 | | | | | 100% AlN | 100 | 122 |
| 196 | | Example 2 | 62 | 22 | 100% AlN | 15.0 | 132 |
| 197 | | | | | 100% AlN | 100 | 127 |
| 198 | | Example 2 | 64 | 17 | 100% AlN | 7.0 | 136 |
| 199 | | | | | 100% AlN | 15.0 | 143 |
| 200 | | | | | 100% AlN | 100 | 125 |
| 201 | | Example 4 | 86˜92 | 24 | 100% AlN | 15.0 | 137 |
| 202 | | | | | 100% AlN | 60.0 | 124 |
| 203 | | | | | 100% AlN | 200 | 122 |
| 204 | | Example 4 | 93˜99 | 29 | 100% InN | 1.0 | 186 |
| 205 | | | | | 100% InN | 5.0 | 165 |
| 206 | | | | | 100% InN | 15.0 | 139 |
| 207 | | Example 4 | 100˜102 | 26 | 50 mol % GaN + 50 mol % | 6.0 | 187 |
| | | | | | AlN | | |
| 208 | | | | | 50 mol % GaN + 50 mol % | 15.0 | 135 |
| | | | | | AlN | | |
| 209 | | | | | 50 mol % GaN + 50 mol % | 100 | 120 |
| | | | | | AlN | | |
| 210 | | Example 6 | 103 | 16 | 100% AlN | 100 | 124 |
| 211 | | | | | 100% AlN | 500 | 114 |
| 212 | | Example 6 | 105 | 27 | 100% AlN | 15.0 | 122 |
| 213 | | | | | 100% AlN | 100 | 113 |
| 214 | | Example 6 | 107 | 23 | 100% AlN | 15.0 | 140 |
| 215 | | | | | 100% AlN | 100 | 121 |
| 216 | | Example 6 | 108 | 22 | 100% AlN | 15.0 | 131 |
| 217 | | | | | 100% AlN | 1000 | 109 |
| 218 | | Example 6 | 109 | 27 | 100% GaN | 1.0 | 184 |
| 219 | | | | | 100% GaN | 6.0 | 156 |
| 220 | | | | | 100% GaN | 15.0 | 135 |
| 221 | | Example 6 | 110 | 22 | 100% AlN | 15.0 | 126 |
| 222 | | | | | 100% AlN | 60.0 | 119 |
| 223 | Silicon | Example 1 | 11˜13 | 6.8 | 100% AlN | 0.5 | 260 |
| 224 | carbide | | | | 100% AlN | 15.0 | 202 |
| 225 | Silicon | Example 1 | 14˜16 | 15 | 100% InN | 0.5 | 669 |
| 226 | nitride | | | | 100% InN | 15.0 | 216 |
| 227 | Aluminum | Example 1 | 17˜19 | 11 | 100% AlN | 1.0 | 391 |
| 228 | oxide | | | | 100% AlN | 6.0 | 217 |
| 229 | | | | | 100% AlN | 15.0 | 216 |
| 230 | Zinc oxide | Example 1 | 22˜24 | 8.8 | 100% GaN | 0.5 | 289 |
| 231 | | | | | 100% GaN | 15.0 | 220 |
| 232 | Beryllium | Example 1 | 27˜29 | 9.4 | 100% AlN | 1.0 | 276 |
| 233 | oxide | | | | 100% AlN | 6.0 | 219 |
| 234 | | | | | 100% AlN | 15.0 | 214 |

### EXAMPLE 8

The high purity aluminum nitride powder [the grade “H” by Tokuyama Soda Co., Ltd. (present: Tokuyama, Inc.)] manufactured by the method of reduction of an oxide (aluminum oxide), and the “TOYALNITE” by Toyo Aluminium K.K. produced by the method of direct nitriding of metal aluminum were prepared as a raw material powder for producing the sintered compacts comprising aluminum nitride as a main component, and various powders of a rare earth element compound and an alkaline-earth-metal compound were prepared as sintering aids.

As a result of analysis, oxygen is contained 1.2 weight % in the “H” grade, and oxygen is contained 1.4 weight % in the “TOYALNITE”, as impurities.

Mean particle size of the powders is 0.9 μm and 1.1 μm, respectively.

In addition to those, aluminum oxide, carbon, and silicon, etc. were prepared as additives.

The powder compacts of various composition were produced by the same method as Example 2 using these raw materials.

They were fired at 1800° C. for 1 hour by the same method as Example 2 so that sintering aids, etc. are not vaporized as much as possible using some of the powder compacts obtained in this way, and the beforehand fired sintered compacts were also produced.

As the beforehand fired sintered compacts, the samples of the experiment No.283-286 of Table 9 and Table 10 in which the contents of this Example are shown are them.

After putting the powder compacts and beforehand fired sintered compacts which were obtained onto the setter made from carbon, they were put into the saggar made from carbon, they were fired in nitrogen atmosphere containing carbon monoxide 1000 ppm at high temperature and for long time using a carbon furnace, and the sintered compacts comprising aluminum nitride as a main component were obtained.

As for the sintered compacts obtained, the chemical composition analysis, the fixed quantity of the AlN crystal phase by X ray diffraction, and the measurement of the size of aluminum nitride particles were carried out.

The fixed quantity of the AlN crystal phase by X ray diffraction is the value calculated by deducting the quantity of the crystal phases other than AlN from the quantity of the whole crystal phases, after the diffraction peaks of the crystal phases other than AlN were measured and the percentage ratio between those and the strongest diffraction peak of AlN was asked for.

Specular polish of the surface of the sintered compacts obtained was carried out into 30 nm, and the optical transmissivity to the light with a wavelength of 605 nm was measured by the same method as Example 2.

The optical transmissivity measured is the total transmissivity.

Using the substrates in which the mirror-surface polish was carried out, the single-crystal thin films comprising as a main component at least one selected from gallium nitride, indium nitride and aluminum nitride were formed by the same method as Example 1 and Example 2, and the crystallinity of the single-crystal thin films was investigated.

These results are shown in Table 9 and Table 10.

In Table 9, the compositions of powder compacts for producing a sintered compact comprising as a main component aluminum nitride, the firing conditions, and the compositions and characteristics of the sintered compacts obtained are shown.

In Table 10, the compositions of the single-crystal thin films formed on the substrates, and their crystallinity are shown, when the sintered compacts comprising as a main component aluminum nitride are used for a substrate.

That is, the sintered compacts comprising aluminum nitride as a main component and which raised the AlN purity by the above method were obtained.

As for the sintered compacts which were obtained except in the experiment No.252-255 and 272, 273, 275, and 276 and comprise aluminum nitride as a main component, they had high characteristics in which the thermal conductivity is not less than 200 W/mK in room temperature.

In the aluminum nitride-based sintered compact, when AlN is contained not less than 99% as a crystal phase, and it comprises AlN single phase, that having still higher characteristics in which the thermal conductivity is not less than 220 W/mK at room temperature and is a maximum of 237 W/mK was obtained.

### COMPARATIVE EXAMPLE 1

To compare, the same powder compact as the experiment No.265 is put on the setter made from tungsten, it put into the saggar made from tungsten with the aluminum nitride powder prepared separately, then it was fired at the temperature of 2200° C. for 8 hours in pure nitrogen atmosphere by the tungsten furnace comprising tungsten furnace material and a heating element, as a result, most yttrium oxide which is a sintering aid is not vaporized and removed but it remained in the state of the powder compact as it is, high purity is not attained.

The thermal conductivity is also lower than 200 W/mK, the optical permeability is also 62%, they were smaller than what was produced in the experiment No.265 of Table 9.

TABLE 9
Characteristics of the sintered compact substrates comprising an aluminum nitride as the main component

| | | | | | Characteristics of the sintered compact comprising an | | | | | |
|---|---|---|---|---|---|---|---|---|---|---|
| | | | | | aluminum nitride as the main component | | | | | |
| | The powder compacts or the sintered compacts fired | | | | Content of | | | | | |
| | Kind of the raw | Additive | | | additives, such as | | | Quantity | Average | |
| | material powder, | agents, | Content of | | sintering aids | | | of | size of | |
| | Kind of the | such as | the additive | Firing | Additive | Content | Oxygen | the AlN | AlN | Optical |
| Experiment | sintered | sintering | agent | conditions | agent | (ppm) | content | crystal | particles | transmissivity |
| No. | compact fired | aids | (weight %) *1) | *2) | element | *3) | (weight %) | phase (%) | (μm) | (%) |
| 252 | The method | None | — | (1) | — | — | 1.2 | 96.2 | 3.6 | 56 |
| 253 | of | None | — | (8) | — | — | 1.3 | 97.1 | 38 | 64 |
| 254 | oxide reduction | Al₂O₃ | 2.0 | (1) | — | — | 1.5 | 96.7 | 3.7 | 18 |
| 255 | | Al₂O₃ | 2.0 | (11) | — | — | 1.4 | 97.4 | 44 | 52 |
| 256 | | CaCO₃ | 0.5 | (3) | Ca | 800 | 0.4 | 98.5 | 7.5 | 46 |
| 257 | | CaCO₃ | 0.5 | (6) | Ca | 320 | 0.17 | 99.1 | 28 | 66 |
| 258 | | CaCO₃ | 0.5 | (7) | Ca | 75 | 0.09 | single phase | 32 | 77 |
| 259 | | CaCO₃ | 0.5 | (10) | Ca | 45 | 0.06 | single phase | 49 | 81 |
| 260 | | Y₂O₃ | 1.0 | (3) | Y | 1900 | 0.4 | 96.9 | 8.8 | 53 |
| 261 | | Y₂O₃ | 1.0 | (7) | Y | 20 | 0.07 | single phase | 31 | 74 |
| 262 | | Y₂O₃ | 1.0 | (10) | Y | <0.5 | 0.03 | single phase | 46 | 82 |
| 263 | | Y₂O₃ | 5.0 | (3) | Y | 4600 | 0.7 | 96.4 | 7.7 | 37 |
| 264 | | Y₂O₃ | 5.0 | (7) | Y | 85 | 0.04 | 99.2 | 35 | 76 |
| 265 | | Y₂O₃ | 5.0 | (10) | Y | 10 | 0.02 | single phase | 47 | 86 |
| 266 | | Y₂O₃ | 5.0 | (2) | Y | 4200 | 0.8 | 97.2 | 6.4 | 47 |
| | | CaCO₃ | 0.5 | | Ca | 200 | | | | |
| 267 | | Y₂O₃ | 5.0 | (5) | Y | 850 | 0.09 | 98.6 | 17 | 75 |
| | | CaCO₃ | 0.5 | | Ca | 65 | | | | |
| 268 | | Y₂O₃ | 5.0 | (6) | Y | 10 | 0.04 | single phase | 29 | 81 |
| | | CaCO₃ | 0.5 | | Ca | 6 | | | | |
| 269 | | Y₂O₃ | 5.0 | (9) | Y | <0.5 | 0.02 | single phase | 37 | 86 |
| | | CaCO₃ | 0.5 | | Ca | <0.5 | | | | |
| 270 | | Yb₂O₃ | 5.0 | (6) | Yb | 25 | 0.03 | single phase | 27 | 82 |
| | | CaCO₃ | 0.5 | | Ca | 5 | | | | |
| 271 | | Er₂O₃ | 10.0 | (7) | Er | 170 | 0.06 | 99.2 | 30 | 68 |
| 272 | | Si | 0.5 | (4) | Si | 1500 | 0.7 | 95.5 | 11 | 42 |
| 273 | | MoO₃ | 1.0 | (4) | Mo | 2100 | 0.8 | 95.4 | 12 | 34 |
| 274 | | carbon | 1.0 | (4) | C | 160 | 0.07 | 98.1 | 10 | 27 |
| 275 | | Fe | 0.5 | (4) | Fe | 510 | 0.3 | 96.1 | 13 | 44 |
| 276 | | Ni | 0.5 | (4) | Ni | 740 | 0.4 | 95.9 | 9.5 | 40 |
| 277 | The | Y₂O₃ | 1.0 | (3) | Y | 1700 | 0.6 | 96.4 | 9.4 | 53 |
| 278 | direct nitriding | Y₂O₃ | 1.0 | (7) | Y | 10 | 0.04 | single phase | 36 | 81 |
| 279 | method | Y₂O₃ | 1.0 | (10) | Y | <0.5 | 0.03 | single phase | 48 | 85 |
| 280 | of | Y₂O₃ | 5.0 | (2) | Y | 4200 | 0.7 | 96.7 | 7.2 | 51 |
| | metal | CaCO₃ | 0.5 | | Ca | 500 | | | | |
| 281 | aluminum | Y₂O₃ | 5.0 | (6) | Y | 6 | 0.03 | single phase | 28 | 83 |
| | | CaCO₃ | 0.5 | | Ca | 6 | | | | |
| 282 | | Y₂O₃ | 5.0 | (9) | Y | <0.5 | 0.02 | single phase | 40 | 87 |
| | | CaCO₃ | 0.5 | | Ca | <0.5 | | | | |
| 283 | The fired | Y₂O₃ | 1.0 | (5) | Y | 920 | 0.08 | 99.1 | 20 | 77 |
| 284 | sintered | Y₂O₃ | 1.0 | (10) | Y | <0.5 | 0.02 | single phase | 46 | 88 |
| 285 | compact *4) | Y₂O₃ | 5.0 | (7) | Y | 24 | 0.03 | single phase | 34 | 84 |
| 286 | | Y₂O₃ | 5.0 | (6) | Y | 3 | 0.02 | single phase | 30 | 87 |
| | | CaCO₃ | 0.5 | | Ca | 2 | | | | |

*1) Content of the sintering aids is based on oxide conversion.
*2) Firing conditions:
(1) 1800° C. × 2 hours
(2) 1800° C. × 12 hours
(3) 1800° C. × 24 hours
(4) 1950° C. × 4 hours
(5) 1950° C. × 12 hours
(6) 2100° C. × 4 hours
(7) 2100° C. × 12 hours
(8) 2100° C. × 24 hours
(9) 2200° C. × 4 hours
(10) 2200° C. × 8 hours
(11) 2200° C. × 12 hours
*3) Content of the sintering aids in a sintered compact is shown by the weight rate of part par million. And, the content is the value by element conversion.
*4) Composition of the fired sintered compacts is a blend composition at the time of powder compacts, and, the amount of the sintering aid(s) is based on oxide conversion.

TABLE 10

| | Characteristics of the single crystal thin films | | |
|---|---|---|---|
| | formed on the sintered compact comprising an | | |
| | aluminum nitride as the main component | | |
| | | | Half width of the |
| | | Thickness | (002) X ray |
| | Composition | of the | diffraction |
| Experiment | of | thin film | rocking curve |
| No. | the thin film | (μm) | (second) |
| 252 | 100% GaN | 0.25 | 192 |
| 253 | 100% GaN | 0.25 | 117 |
| 254 | 100% GaN | 0.25 | 187 |
| 255 | 100% GaN | 0.25 | 122 |
| 256 | 100% GaN | 0.25 | 145 |
| 257 | 100% GaN | 0.25 | 96 |
| 258 | 100% GaN | 0.25 | 97 |
| 259 | 100% GaN | 0.25 | 91 |
| 260 | 100% InN | 0.25 | 139 |
| 261 | 100% GaN | 0.25 | 98 |
| 262 | 100% GaN | 0.25 | 94 |
| 263 | 100% GaN | 0.25 | 161 |
| 264 | 100% GaN | 0.25 | 90 |
| 265 | 100% GaN | 0.25 | 93 |
| 266 | 50 mol % GaN + | 0.25 | 144 |
| | 50 mol % InN | | |
| 267 | 100% GaN | 0.25 | 124 |
| 268 | 50 mol % GaN + | 6.0 | 95 |
| | 50 mol % AlN | | |
| 269 | 100% GaN | 0.25 | 92 |
| 270 | 100% GaN | 0.25 | 94 |
| 271 | 100% GaN | 0.25 | 98 |
| 272 | 100% GaN | 0.25 | 147 |
| 273 | 100% GaN | 0.25 | 137 |
| 274 | 100% GaN | 0.25 | 132 |
| 275 | 100% GaN | 0.25 | 143 |
| 276 | 100% GaN | 0.25 | 140 |
| 277 | 100% GaN | 0.25 | 135 |
| 278 | 100% GaN | 0.25 | 93 |
| 279 | 100% GaN | 0.25 | 90 |
| 280 | 100% GaN + | 0.25 | 126 |
| | 50 mol % InN | | |
| 281 | 100% GaN | 0.25 | 96 |
| 282 | 100% GaN | 0.25 | 89 |
| 283 | 100% GaN | 0.25 | 111 |
| 284 | 100% GaN | 0.25 | 91 |
| 285 | 100% GaN | 0.25 | 95 |
| 286 | 100% GaN | 0.25 | 89 |

### EXAMPLE 9

The substrates comprising the sintered compacts comprising aluminum nitride as a main component and formed the various thin conductive films were obtained by forming various materials, such as titanium, chromium, nickel, molybdenum, tungsten, platinum, aluminum, tantalum, tantalum nitride, titanium nitride, gold, copper, tungsten/copper alloy (W: 70 weight %+Cu: 30 weight %), etc., onto the both sides of the substrates by the RF Sputtering method of frequency 13.56 MHz and output 500 W-1500 W, using the substrates comprising the sintered compacts comprising aluminum nitride as a main component and have conduction vias made from tungsten, tungsten/copper, and copper, and the sintered compacts comprising aluminum nitride as a main component and have not conduction vias.

Sputtering was carried out under the substrate temperature of 250° C., passing Ar+N₂ gas into the decompression chamber.

The reflectances of the produced thin conductive films to the light with a wavelength of 605 nm were measured, and they are shown in Table 11.

The thin films comprising as a main component at least one selected from gallium nitride, indium nitride and aluminum nitride and added the doping agents suitably were formed in the thickness of 3 μm in one side of the substrates in which the various thin conductive films were formed.

As a result, even if it is the substrates in which various thin conductive films were formed beforehIt was confirmed that the thin films of an amorphous state, an orientated polycrystal, and a single crystal can form.

It was confirmed that the orientated polycrystalline thin films and the single-crystal thin films are formed in such a direction that its C axis is perpendicular to the substrate surface, respectively.

The result investigated about the crystallinity of such thin films was shown in Table 11.

The test method is that which measures the perpendicular tensile strength after the circular aluminum pin with the diameter of 3 mm was pasted up on the produced substrates by epoxy resin, and it was confirmed that the perpendicular tensile strength is not less than 2 kg/mm² altogether. The exfoliations exist in the adhesion interface between the epoxy resin and the thin films of various composition comprising as a main component at least one selected from gallium nitride, indium nitride and aluminum nitride, or in the adhesion interface between the epoxy resin and the pin, or in the inside of the epoxy resin, it was confirmed that the exfoliations or destructions between the thin conductive films and the thin films of various composition comprising as a main component at least one selected from gallium nitride, indium nitride and aluminum nitride are not seen, and good junction nature is formed.

TABLE 11

| | | | | | Characteristics of the thin films which comprise as the main component | | | | |
|---|---|---|---|---|---|---|---|---|---|
| | | | | | a gallium nitride, an indium nitride, and an aluminum nitride and were | | | | |
| | | | | | formed on the thin film conductivity material | | | | |
| | | | | | | Electric | | | Junction strength |
| | Used | Characteristics of the | | | | resistivity | | Half width of | with thin film |
| | sub- | thin film conductivity materials | | | | of | | the | conductivity |
| | strates | Constitution | | | | the thin film | | (002) X ray | material: |
| Experi- | Experi- | of thin film | | | | (Ω · cm) | Crystallized | diffraction | perpendicular |
| ment | ment | conductivity | Thickness | | | (in room | state of | rocking curve | tension |
| No. | No. | material | (μm) | Reflectance | Composition | temperature) | the thin film | (second) | (Kg/mm²) |
| 357 | 49 | Ti | 0.1 | — | 100 mol % GaN | 0.052 | Single crystal | 144 | 3.1 |
| 358 | 73 | Ti | 0.2 | — | 100 mol % AlN | — | Single crystal | 172 | 3.2 |
| 359 | 73 | Ti | 0.1 | — | 99.94 mol % GaN + | 0.009 | Single crystal | 160 | 3.0 |
| | | | | | 0.06 mol % Si | | | | |
| 360 | 75 | Cr | 0.2 | — | 99.94 mol % InN + | 0.007 | Amorphous | — | 3.1 |
| | | | | | 0.06 mol % Si | | | | |
| 361 | 75 | Ni | 2.0 | 64 | 19.98 mol % InN + | 0.34 | Single crystal | 150 | 2.8 |
| | | | | | 79.9 mol % GaN + | | | | |
| | | | | | 0.12 mol % Mg | | | | |
| 362 | 80 | Mo | 0.6 | 53 | 19.98 mol % GaN + | 0.085 | Amorphous | — | 3.0 |
| | | | | | 79.9 mol % InN + | | | | |
| | | | | | 0.12 mol % Mg | | | | |
| 363 | 80 | W | 1.0 | 52 | 49.94 mol % GaN + | 0.57 | Amorphous | — | 3.3 |
| | | | | | 49.94 mol % AlN + | | | | |
| | | | | | 0.12 mol % Si | | | | |
| 364 | 82 | W | 0.5 | 54 | 100 mol % InN | 0.020 | Amorphous | — | 2.9 |
| 365 | 82 | Pt | 0.5 | 77 | 50 mol % GaN + | — | Single crystal | 179 | 2.7 |
| | | | | | 50 mol % AlN | | | | |
| 366 | 110 | Al | 3.0 | 92 | 99.98 mol % AlN + | 116 | Amorphous | — | 2.6 |
| | | | | | 0.02 mol % Si | | | | |
| 367 | 284 | Ni—Cr | 0.8 | — | 100 mol % AlN | — | Amorphous | — | 2.8 |
| 368 | 305 | Ta | 0.6 | — | 49.94 mol % GaN + | 0.42 | Single crystal | 164 | 3.1 |
| | | | | | 49.94 mol % AlN + | | | | |
| | | | | | 0.12 mol % Si | | | | |
| 369 | 305 | Ta₂N | 0.5 | — | 100 mol % GaN | 0.060 | Amorphous | — | 2.9 |
| 370 | 305 | TiN | 0.5 | — | 100 mol % InN | 0.014 | Single crystal | 166 | 2.9 |
| 371 | 311 | Ti (adhesion) | 0.1 | 91 | 49.94 mol % GaN + | 3.2 | Single crystal | 90 | 2.4 |
| | | Pt (barrier) | 0.2 | | 49.94 mol % AlN + | | | | |
| | | Au (low | 0.6 | | 0.12 mol % Mg | | | | |
| | | resistance) | | | | | | | |
| 372 | 311 | Ti (adhesion) | 0.1 | 90 | 69.86 mol % GaN + | 1.6 | Orientated | 4790 | 2.8 |
| | | W (barrier) | 0.5 | | 29.94 mol % AlN + | | polycrystal | | |
| | | Au (low | 0.8 | | 0.20 mol % Mg | | | | |
| | | resistance) | | | | | | | |
| 373 | 317 | W: 70 wt % | 0.5 | 74 | 69.86 mol % GaN + | 0.56 | Single crystal | 89 | 2.6 |
| | | Cu: 30 wt | | | 29.94 mol % AlN + | | | | |
| | | alloy | | | 0.20 mol % Si | | | | |
| 374 | 317 | Cr (adhesion) | 0.1 | 91 | 99.90 mol % GaN + | 0.73 | Single crystal | 89 | 3.0 |
| | | Cu (low | 0.8 | | 0.10 mol % Mg | | | | |
| | | resistance) | | | | | | | |

### EXAMPLE 10

Using the things which were processed into the shape of a substrate of the size with the diameter of 25.4 mm×thickness of 0.5 mm and which carried out the mirror-surface polishing on the sintered compacts used in Example 9 and having conduction vias and comprise aluminum nitride as a main component, the sintered compacts having not conduction vias and comprise aluminum nitride as a main component, and each sintered compact of the experiment No.265, experiment No.269, and experiment No.271 which was produced in Example 9 and raised the purity of aluminum nitride, the thin films having various compositions and various crystallization states and comprising as a main component at least one selected from gallium nitride, indium nitride and aluminum nitride were formed in the thickness of 3 μm on one surface of each above sintered compact by the same method as Example 1, Example 2, and various thin film substrates were produced.

As for the compositions and the crystallization states of the thin films, they are shown in Table 12.

In addition to these, here prepared the thin film substrates in which the thin films comprising as a main component at least one selected from gallium nitride, indium nitride and aluminum nitride were formed further on the substrates comprising the sintered compacts which were produced in Example 9 and comprise aluminum nitride as a main component and has beforehand the various conductive materials, such as titanium, chromium, nickel, molybdenum, tungsten, platinum, aluminum, tantalum, nitriding tantalum, nitriding titanium, gold, copper, tungsten/copper alloy (W: 90 weight %+Cu 10 weight %), etc.

As for the thin film substrates produced in Example 9, though the compositions and crystallization states of the thin films were same as Example 9, they re-published in Table 13 anew.

Using the thin film substrates produced or prepared, the various thin conductive films comprising titanium, chromium, nickel, molybdenum, tungsten, platinum, aluminum, tantalum, tantalum nitride, titanium nitride, gold, and copper, etc. were formed by the same method as Example 9 on the thin films which are being formed on the thin film substrates and comprise as a main component at least one selected from gallium nitride, indium nitride and aluminum nitride.

As for the constitution and thickness of the various thin conductive films, they are as having been indicated in Tables 12 and 25.

After forming the various thin conductive films, observation of appearances was carried out about the thin films which are being formed in the used thin film substrates and comprising as a main component at least one selected from gallium nitride, indium nitride and aluminum nitride, as a result, especially faults, such as a crack and exfoliation in the interface with the thin conductive films, are not found, and are in good appearance states, it was confirmed that the thin conductive films which used the material of this invention have good junction nature to the thin films of various compositions comprising as a main component at least one selected from gallium nitride, indium nitride and aluminum nitride.

To confirm the junction nature between the thin conductive films and the thin films of various compositions comprising as a main component at least one selected from gallium nitride, indium nitride and aluminum nitride, the next test was carried out furthermore.

The test method is that which measures the perpendicular tensile strength after the circular aluminum pin with the diameter of 3 mm was pasted up on the thin conductive films formed in the produced substrates by epoxy resin, and it was confirmed that the perpendicular tensile strength is not less than 2 kg/mm² altogether. The exfoliations exist in the adhesion interface between the epoxy resin and the thin films of various composition comprising as a main component at least one selected from gallium nitride, indium nitride and aluminum nitride, or in the adhesion interface between the epoxy resin and the pin, or in the inside of the epoxy resin, it was confirmed that the exfoliations or destructions between the thin conductive films and the thin films of various composition comprising as a main component at least one selected from gallium nitride, indium nitride and aluminum nitride are not seen, and good junction nature is formed.

In addition, the lead and the thin conductive films were connected by the solder using the lead made from kovar having a pad with the diameter of 1.5 mm in the tip, about the things (each sample of the experiment No.494-497, 500, 502-504, and 512-515) of the constitution having gold and copper in the surface among the thin conductive films formed, and perpendicular tensile strength was measured.

As a result, the perpendicular tensile strength is not less than 4 kg/mm² altogether, after testing the leads and the portions to which the leads were joined in the thin film substrates were observed, all were being destroyed in the inside of the solders or in the portions between the solder and the lead, and the exfoliations or destructions between the thin films comprising as a main component at least one selected from gallium nitride, indium nitride and aluminum nitride and the thin conductive films were not observed.

Therefore, it was confirmed that the junction strength between the thin conductive films and the above thin films is originally not less than 4 kg/mm² and that the junction nature is high.

The junction nature was tested by the method which pastes up the pressure sensitive adhesive tape on the thin conductive films currently formed on the substrate produced and tears off the tape, but, the exfoliations or destructions between the thin conductive films and the thin films of various compositions comprising as a main component at least one selected from gallium nitride, indium nitride and aluminum nitride were not seen altogether.

The above examination result is proving that not only the junction nature between the thin conductive films and the thin films comprising as a main component at least one selected from gallium nitride, indium nitride and aluminum nitride is high, but also the junction nature between the sintered compacts comprising aluminum nitride as a main component and the thin conductive films, and the junction nature between the sintered compacts comprising aluminum nitride as a main component and the thin films comprising as a main component at least one selected from gallium nitride, indium nitride and aluminum nitride, are also high.

These results were described in Tables 12 and 13.

TABLE 12

| | | | | | Characteristics of the thin film conductivity | | |
|---|---|---|---|---|---|---|---|
| | Aluminum nitride sintered compacts in which the thin | | | | materials formed on the thin film which | | |
| | film of various composition was formed | | | | comprises as the main component | | |
| | Used | | | | a gallium nitride, an indium nitride, and | | |
| | aluminum | | | | an aluminum nitride | | |
| | nitride sintered | | | | | | Junction |
| | compacts | | | | Composition | | strength |
| | (Experiment | Characteristics of the thin films | | | and | | with |
| | No. in which | | Thickness | | the constitution | | the thin film: |
| | the sintered | Composition | of the | Crystallized | of the thin film | | perpendicular |
| Experiment | compact was | of | thin film | state of | conductivity | Thickness | tension |
| No. | produced) | the thin film | (μm) | the thin film | materials | (μm) | (Kg/mm²) |
| 476 | 269 | 100 mol % AlN | 3.0 | Single crystal | Ti | 0.2 | 4.2 |
| 477 | 49 | 100 mol % AlN | 3.0 | Amorphous | Ti | 0.2 | 3.6 |
| 478 | 49 | 100 mol % GaN | 3.0 | Single crystal | Ti | 0.2 | 4.0 |
| 479 | 49 | 100 mol % GaN | 3.0 | Amorphous | Ti | 0.2 | 2.9 |
| 480 | 49 | 100 mol % InN | 3.0 | Single crystal | Ti | 0.2 | 4.0 |
| 481 | 73 | 99.90 mol % GaN + | 3.0 | Single crystal | Ti | 0.2 | 3.5 |
| | | 0.10 mol % Mg | | | | | |
| 482 | 73 | 100 mol % AlN | 3.0 | Single crystal | Cr | 0.5 | 2.8 |
| 483 | 75 | 49.94 mol % GaN + | 3.0 | Single crystal | Cr | 0.2 | 3.1 |
| | | 49.94 mol AlN + | | | | | |
| | | 0.12 mol % Mg | | | | | |
| 484 | 75 | 50 mol % GaN + | 3.0 | Amorphous | Ni | 5.0 | 2.7 |
| | | 50 mol % AlN | | | | | |
| 485 | 80 | 100 mol % AlN | 3.0 | Orientated | Mo | 1.0 | 3.7 |
| | | | | polycrystal | | | |
| 486 | 82 | 99.94 mol % GaN + | 3.0 | Amorphous | W | 2.0 | 3.8 |
| | | 0.06 mol % Si | | | | | |
| 487 | 265 | 100 mol % AlN | 3.0 | Single crystal | W | 0.5 | 3.9 |
| 488 | 82 | 99.98 mol % AlN + | 3.0 | Single crystal | Pt | 0.5 | 2.5 |
| | | 0.02 mol % Si | | | | | |
| 489 | 110 | 100 mol % AlN | 3.0 | Single crystal | Al | 16 | 4.4 |
| 490 | 284 | 100 mol % AlN | 3.0 | Single crystal | Ni—Cr | 0.5 | 3.2 |
| 491 | 271 | 50 mol % GaN + | 3.0 | Single crystal | Ta | 0.6 | 3.4 |
| | | 50 mol % InN | | | | | |
| 492 | 305 | 100 mol % GaN | 3.0 | Single crystal | Ta₂N | 0.5 | 3.0 |
| 493 | 305 | 100 mol % InN | 3.0 | Amorphous | TiN | 0.5 | 4.0 |
| 494 | 311 | 100 mol % AlN | 3.0 | Single crystal | Ti (adhesion) | 0.1 | 5.1 |
| | | | | | Pt (barrier) | 0.2 | |
| | | | | | Au (low | 0.6 | |
| | | | | | resistance) | | |
| 495 | 311 | 100 mol % AlN | 3.0 | Single crystal | Ti (adhesion) | 0.1 | 5.4 |
| | | | | | W (barrier) | 0.5 | |
| | | | | | Au (low | 0.8 | |
| | | | | | resistance) | | |
| 496 | 317 | 49.94 mol % GaN + | 3.0 | Single crystal | Ti (adhesion) | 0.1 | 5.2 |
| | | 49.94 mol AlN + | | | Ni (barrier) | 1.8 | |
| | | 0.12 mol % Si | | | Au (low | 0.6 | |
| | | | | | resistance) | | |
| 497 | 317 | 100 mol % GaN | 3.0 | Single crystal | Cr (adhesion) | 0.1 | 4.4 |
| | | | | | Cu (low | 0.8 | |
| | | | | | resistance) | | |

TABLE 13

| | | | | | Characteristics of the thin film conductivity materials | | | |
|---|---|---|---|---|---|---|---|---|
| | Thin films of various composition formed on the substrate which | | | | formed on the thin film which comprises as the main | | | |
| | consists of a sintered compact comprising AlN as the main component | | | | component a gallium nitride, an indium nitride, and an | | | |
| | and formed beforehand the thin film conductivity material | | | | aluminum nitride | | | |
| | Thin film conductivity materials | | | | Composition | | Junction | |
| | formed beforehand | | Characteristics of the thin films | | and the | | strength | |
| | Experiment No. | Constitution | | Crystallized | constitution | | with | |
| | in which | of | | state | of | | the thin film: | |
| Experi- | the AlN sintered | the thin film | Composition | of the | the thin film | Thick- | perpendicular | |
| ment | compact | conductivity | of | thin | conductivity | ness | tension | Reflec- |
| No. | was produced | material | the thin film | film | material | (μm) | (Kg/mm²) | tance |
| 498 | 357 | Ti | 100 mol % GaN | Single crystal | TiN | 0.2 | 3.9 | 54 |
| 499 | 358 | Ti | 100 mol % AlN | Single crystal | Ti | 0.2 | 4.0 | — |
| 500 | 359 | Ti | 99.94 mol % GaN + 0.06 mol % | Single crystal | Cr (adhesion) | 0.1 | 4.2 | 90 |
| | | | Si | | Cu (low | 0.8 | | |
| | | | | | resistance) | | | |
| 501 | 360 | Cr | 99.94 mol % InN + 0.06 mol % | Amorphous | Pt | 0.5 | 3.2 | 78 |
| | | | Si | | | | | |
| 502 | 361 | Ni | 19.98 mol % InN + 79.9 mol % | Single crystal | Ti (adhesion) | 0.1 | 5.9 | 92 |
| | | | GaN + 0.12 mol % | | Pt (barrier) | 0.2 | | |
| | | | Mg | | Au (low) | 0.6 | | |
| | | | | | resistance | | | |
| 503 | 362 | Mo | 19.98 mol % GaN + 79.9 mol % | Amorphous | Ti (adhesion) | 0.1 | 5.6 | 90 |
| | | | InN + 0.12 mol % | | W (barrier) | 0.5 | | |
| | | | Mg | | Au (low | 0.8 | | |
| | | | | | resistance) | | | |
| 504 | 363 | W | 49.94 mol % GaN + 49.94 mol | Amorphous | Ti (adhesion) | 0.1 | 5.3 | 91 |
| | | | AlN + 0.12 mol % | | Ni (barrier) | 1.8 | | |
| | | | Si | | Au (low | 0.6 | | |
| | | | | | resistance) | | | |
| 505 | 364 | W | 100 mol % InN | Amorphous | Cr | 0.5 | 2.6 | — |
| 506 | 365 | Pt | 50 mol % GaN + 50 mol % | Single crystal | Ni | 1.0 | 2.7 | 67 |
| | | | AlN | | | | | |
| 507 | 366 | Al | 99.98 mol % AlN + 0.02 mol % | Amorphous | Mo | 0.5 | 3.5 | 55 |
| | | | Si | | | | | |
| 508 | 367 | Ni—Cr | 100 mol % AlN | Amorphous | W | 0.2 | 3.8 | 53 |
| 509 | 368 | Ta | 49.94 mol % GaN + 49.94 mol | Single crystal | Al | 12 | 4.0 | 91 |
| | | | AlN + 0.12 mol % | | | | | |
| | | | Si | | | | | |
| 510 | 369 | Ta₂N | 100 mol % GaN | Amorphous | Ni—Cr | 0.5 | 3.3 | — |
| 511 | 370 | TiN | 100 mol % InN | ingle crystal | Ta₂N | 0.5 | 3.1 | — |
| 512 | 371 | Ti (adhesion) | 49.94 mol % GaN + 49.94 mol | Single crystal | Ti (adhesion) | 0.1 | 5.5 | 90 |
| | | Pt (barrier) | AlN + 0.12 mol % | | Pt (barrier) | 0.2 | | |
| | | Au (low | Mg | | Au (low | 0.6 | | |
| | | resistance) | | | resistance) | | | |
| 513 | 372 | Ti (adhesion) | 69.86 mol % GaN + 29.94 mol | Orientated | Ti (adhesion) | 0.1 | 5.2 | 90 |
| | | W (barrier) | AlN + 0.20 mol % | polycrystal | W (barrier) | 0.5 | | |
| | | Au (low | Mg | | Au (low | 0.8 | | |
| | | resistance) | | | resistance) | | | |
| 514 | 373 | W: 70 wt % | 69.86 mol % GaN + 29.94 mol | Single crystal | W: 90 wt % | 0.5 | 5.7 | 62 |
| | | Cu: 30 wt | AlN + 0.20 mol % | | Cu: 10 wt | | | |
| | | Alloy | Si | | Alloy | | | |
| 515 | 374 | Cr (adhesion) | 99.90 mol % GaN + 0.10 mol % | Single crystal | Cr (adhesion) | 0.1 | 4.4 | 92 |
| | | Cu (low | Mg | | Cu (low | 0.8 | | |
| | | resistance) | | | resistance) | | | |

### EXAMPLE 11

This Example shows the examples of the multilayer thin film in which the single-crystal thin film comprising as a main component at least one selected from gallium nitride, indium nitride and aluminum nitride was formed furthermore on the thin films after forming beforehand a single-crystal thin film, an amorphous thin film, a polycrystalline thin film, and an orientated polycrystalline thin film comprising as a main component at least one selected from gallium nitride, indium nitride and aluminum nitride onto it by the method of not only the MOCVD but also the sputtering and ion-plating method using the sintered compacts comprising aluminum nitride as a main component, as a substrate.

This Example also shows the effects in which the thin films formed beforehand on the substrates comprising as a main component aluminum nitride affect the crystallinity of the single-crystal thin films formed furthermore on them.

In addition, the sintered compacts comprising aluminum nitride as a main component and were used as a substrate also include what has a conduction via.

As the sintered compacts comprising aluminum nitride as a main component, the things which contain the sintering-aids component and have comparatively many contents of an AlN component were used.

First, among the sintered compacts comprising aluminum nitride as a main component, as what does not have a conduction via, here prepared the things which were produced in the experiment No. 49 and 58 of Example 2 and the experiment No. 259, 261, 266, and 269 of Example 8 and which carried out ultrasonic washing with acetone and IPA after immersing into fluoro-nitric acid (50% HF+50% HNO₃) at room temperature after carrying out mirror-surface polish by the same method as Example 6, as a substrate.

As for the surface roughness Ra of the substrates without conduction vias, it was 26 nm in the case of the experiment No.49, 28 nm in the case of the experiment No.58, and 30 nm in the case of the experiment No.259, 261, 266, and 269.

As that having conduction vias, that which was produced in the experiment No. 80 and 83 of Example 3 was prepared as a substrate, and that was mirror-polished by the same method as Example 8 and washed with methylene chloride.

The surface roughness Ra was 26 nm in the case of the experiment No.80 and the experiment No.83, and 30 nm in the case of the experiment No.304.

Using that containing Er₂O₃ powder 4.02 volume % as that having conduction vias among the green sheets produced in Example 3, the through hole of 50 μm was punched in the green sheets, and they were filled up with what contains AlN 5.0 weight % among the conduction via pastes comprising tungsten as a main component, normal-pressure sintering was carried out at 1820° C. for 2 hours like Example 3, they are made into the same size as Example 3 by grinding and mirror-polishing, conduction vias were exposed, and the things which were washed with methylene chloride were prepared as a substrate.

The surface roughness Ra of the substrates having the conduction vias was 32 nm.

First, the thin films comprising as a main component at least one selected from gallium nitride, indium nitride and aluminum nitride and which are various crystallization states, such as a single-crystal thin film, an amorphous thin film, a polycrystalline thin film, and an orientated polycrystalline thin film, were formed on each substrate prepared by the MOCVD method, the sputtering method, and the ion-plating method.

When the thin film formation was carried out by the MOCVD method, the same raw materials and thin film formation conditions as Example 1 were used.

When thin film formation is carried out by the sputtering method, examination of thin film formation was carried out by the high frequency (RF) magnetron sputtering method with a frequency of 13.56 MHz, using the metal aluminum, AlN sintered compact, and AlN sintered compact containing 0.02-mol % Si component as the target material, under the condition where the mixed gas of Ar+N₂ of very small quantity was introduced in the mixture ratio of N₂/Ar=0.02-1.0, the pressure inside the chamber was 0.1-1.5 Pa, and the electric power was 400-1500 W. As for the substrate temperature, it was carried out in the range of room temperature-600° C.

When thin film formation is carried out by the ion-plating method, examination of thin film formation was carried out by the reaction nitriding of metal vapor, melting the Al metal used for the raw material for thin film formation under the condition where very-small-quantity N₂ gas was introduced in the decompression chamber and ionized on the ionization voltage of 20V-150V, and the applied voltage to the substrate was 500V-2000V. As for the substrate temperature, it was carried out in the range of room temperature-600° C.

As mentioned above, the crystallization states were investigated by X ray diffraction about the thin films which were formed directly on the substrates comprising an aluminum nitride-based sintered compact, and the electric resistivity at room temperature and the half width of the rocking curve of a lattice plane (002) were measured further about the thin films produced.

The result is shown in Table 14.

The appearance of the above thin films produced in the experiment No.706-709 was investigated, and, defects, such as a crack and a crevice, are not seen in all.

Though the exfoliation test was carried out using the pressure sensitive adhesive tape, in all the thin films, exfoliation was not seen between them and the substrates comprising an aluminum nitride-based sintered compact.

The thin conductive film of Ti/Pt/Au was formed on the surface of the thin films produced in the experiment No.706-709, the metal leads were soldered and perpendicular tensile strength was investigated, and it al is not less than 2 kg/mm², so the sintered compacts comprising aluminum nitride as a main component, and the thin films were integrally adhered.

TABLE 14

| | | Characteristics of the thin films formed on the sintered compact which comprises an aluminum nitride | | | | | | |
|---|---|---|---|---|---|---|---|---|
| | | as the main component | | | | | | |
| | | | | | | | Half width of the (002) | Surface |
| | | Formation | | | | | X ray diffraction rocking | roughness |
| | Content of | state and | Production | | | | curve of the single crystal | of |
| | the used | formation | method of | Composition | Thin film | Crystallized state | thin film and | the thin film |
| Experiment | AlN | position of | the | of | thickness | of | the orientated polycrystal | substrate |
| No. | substrate | the thin film | thin film | the thin film | (μm) | the thin film | (second) | Ra (nm) |
| 706 | produced | Single layer | Sputter | 100% AlN | 3.0 | Amorphous | — | 3.9 |
| 707 | in | Single layer | Sputter | 100% AlN | 3.0 | Polycrystal | — | 3.2 |
| 708 | Experiment | Single layer | Sputter | 100% AlN | 3.0 | Orientated polycrystal | 7910 | 1.9 |
| 709 | No. 49 | Single layer | MOCVD | 100% AlN | 3.0 | Single crystal | 187 | 6.7 |
| 710 | | Substrate side | Sputter | 100% AlN | 3.0 | Amorphous | — | 4.1 |
| | | Surface layer | MOCVD | 100% AlN | 3.0 | Single crystal | 89 | 2.4 |
| 711 | | Substrate side | Sputter | 100% AlN | 3.0 | Polycrystal | — | 3.4 |
| | | Surface layer | MOCVD | 100% AlN | 3.0 | Single crystal | 93 | 2.0 |
| 712 | | Substrate side | Sputter | 100% AlN | 3.0 | Orientated polycrystal | 7640 | 1.7 |
| | | Surface layer | MOCVD | 100% AlN | 3.0 | ingle crystal | 79 | 0.94 |
| 713 | | Substrate side | MOCVD | 100% AlN | 3.0 | ingle crystal | 184 | 6.6 |
| | | Surface layer | MOCVD | 100% AlN | 3.0 | Single crystal | 105 | 2.9 |
| 714 | | Single layer | MOCVD | 100% GaN | 3.0 | Single crystal | 179 | 5.9 |
| 715 | | Single layer | MOCVD | 100% InN | 3.0 | Single crystal | 194 | 5.0 |
| 716 | | Substrate side | Sputter | 100% AlN | 3.0 | Orientated polycrystal | 8290 | 1.8 |
| | | Surface layer | MOCVD | 100% GaN | 3.0 | Single crystal | 89 | 0.97 |
| 717 | | Substrate side | Sputter | 100% AlN | 3.0 | Orientated polycrystal | 7810 | 1.6 |
| | | Surface layer | MOCVD | 100% InN | 3.0 | Single crystal | 87 | 1.04 |
| 718 | | Substrate side | Sputter | 100% AlN | 3.0 | Amorphous | — | 3.8 |
| | | Surface layer | MOCVD | 100% GaN | 3.0 | Single crystal | 90 | 2.2 |
| 719 | | Substrate side | Sputter | 100% AlN | 3.0 | Polycrystal | — | 3.1 |
| | | Surface layer | MOCVD | 100% GaN | 3.0 | Single crystal | 92 | 2.3 |
| 720 | | Substrate side | MOCVD | 100% AlN | 3.0 | Single crystal | 179 | 6.9 |
| | | Surface layer | MOCVD | 100% GaN | 3.0 | Single crystal | 107 | 3.0 |
| 721 | | Single layer | MOCVD | 100% AlN | 3.0 | Orientated polycrystal | 4970 | 1.9 |
| 722 | | Single layer | IP *1) | 100% AlN | 3.0 | Polycrystal | — | 4.2 |
| 723 | | Substrate side | MOCVD | 100% AlN | 3.0 | Orientated polycrystal | 4880 | 1.8 |
| | | Surface layer | MOCVD | 100% AlN | 3.0 | Single crystal | 87 | 0.87 |
| 724 | | Substrate side | IP *1) | 100% AlN | 3.0 | Polycrystal | — | 3.7 |
| | | Surface layer | MOCVD | 100% AlN | 3.0 | Single crystal | 90 | 2.2 |
| 725 | | Single layer | CV *2) | 100% AlN | 3.0 | Single crystal | 177 | 7.6 |
| 726 | | Substrate side | Sputter | 100% AlN | 3.0 | Amorphous | — | 3.7 |
| | | Surface layer | CV *2) | 100% AlN | 3.0 | Single crystal | 91 | 2.5 |
| 727 | | Substrate side | Sputter | 100% AlN | 3.0 | Orientated polycrystal | 8320 | 1.7 |
| | | Surface layer | CV *2) | 100% AlN | 3.0 | Single crystal | 86 | 1.09 |
| 728 | | Single layer | MOCVD | 100% GaN | 3.0 | Amorphous | — | 3.1 |
| 729 | | Single layer | MOCVD | 100% GaN | 3.0 | Polycrystal | — | 3.3 |
| 730 | | Single layer | MOCVD | 100% GaN | 3.0 | Orientated polycrystal | 4710 | 1.7 |
| 731 | | Single layer | MOCVD | 100% InN | 3.0 | Orientated polycrystal | 4820 | 1.6 |
| 732 | | Substrate side | MOCVD | 100% GaN | 3.0 | Amorphous | — | 3.4 |
| | | Surface layer | MOCVD | 100% AlN | 3.0 | Single crystal | 93 | 2.5 |
| 733 | | Substrate side | MOCVD | 100% GaN | 3.0 | Polycrystal | — | 3.6 |
| | | Surface layer | MOCVD | 100% GaN | 3.0 | Single crystal | 93 | 2.6 |
| 734 | | Substrate side | MOCVD | 100% GaN | 3.0 | Orientated polycrystal | 4590 | 1.8 |
| | | Surface layer | MOCVD | 100% AlN | 3.0 | Single crystal | 87 | 1.07 |
| 735 | | Substrate side | MOCVD | 100% GaN | 3.0 | Orientated polycrystal | 4640 | 1.5 |
| | | Surface layer | MOCVD | 100% GaN | 3.0 | Single crystal | 87 | 0.97 |
| 736 | | Substrate side | MOCVD | 100% GaN | 3.0 | Orientated polycrystal | 4650 | 1.7 |
| | | Surface layer | MOCVD | 100% InN | 3.0 | Single crystal | 89 | 1.11 |
| 737 | | Substrate side | MOCVD | 100% InN | 3.0 | Orientated polycrystal | 4860 | 1.6 |
| | | Surface layer | MOCVD | 100% AlN | 3.0 | Single crystal | 94 | 1.03 |
| 738 | | Substrate side | MOCVD | 100% InN | 3.0 | Orientated polycrystal | 4790 | 1.7 |
| | | Surface layer | MOCVD | 100% GaN | 3.0 | Single crystal | 91 | 1.08 |
| 739 | | Substrate side | MOCVD | 100% InN | 3.0 | Orientated polycrystal | 4810 | 1.5 |
| | | Surface layer | MOCVD | 100% InN | 3.0 | Single crystal | 90 | 1.02 |

*1) IP: It is the abbreviation of the ion plating method.
*2) CV: It is the abbreviation of the Chloride VPE method.

### EXAMPLE 12

This Example shows the examples which investigated the influence in which the layer constitution of the thin films which are formed on them and comprise as a main component gallium nitride, indium nitride, and aluminum nitride gives to the crystallinity of the thin films formed, using the things in which the surface smoothness is comparatively coarse, among the substrates comprising the aluminum nitride-based sintered compact and the substrates comprising the sintered compacts comprising silicon carbide, silicon nitride, zinc oxide, beryllium oxide, and aluminum oxide as a main component.

First, the sintered compacts comprising aluminum nitride as a main component and were produced in the experiment No.49 of Example 2 were prepared.

In the other, the sintered compacts which were produced in Example 1 and comprise as a main component silicon carbide, silicon nitride, zinc oxide, beryllium oxide, and aluminum oxide were prepared.

Some of these substrates are what has the as-fired state and lap-polished state which were used in Example 6.

As for some of the sintered compacts prepared, the things in which the thin film formation side is in the as-fired state were used as they are, or some of them were processed by the lap polish or the blast polish, then they were processed further into the diameter of 25.4 mm and the thickness of 0.5 mm, and the substrates for thin film formation were produced.

Among the substrates newly produced in this Example, what has the substrate surface of the as-fired state and lap-polished state was processed by the same method as Example 6.

In all the substrates having the surface of the as-fired state, the surface adhesions were removed by brushing using a commercial alumina powder with the particle size of 3 μm.

In the substrates in which the lap polish was carried out, it was carried out using those with the particle size #240 of SiC in the case of the sintered compacts comprising aluminum nitride as a main component, it was carried out using those with the particle size #400 of SiC in the case of the sintered compacts comprising aluminum oxide as a main component, and it was carried out using those with the particle size #240 of SiC in the case of the sintered compacts comprising beryllium oxide as a main component.

The blast polish was carried out by the sandblast machine using those with the particle size #400 of alumina in the case of the sintered compacts comprising aluminum nitride as a main component, in the case of the sintered compacts comprising silicon carbide as a main component, it was carried out using those with the particle size #600 of alumina, in the case of the sintered compacts comprising as a main component silicon nitride, aluminum oxide, and zinc oxide, it was carried out using those with the particle size #800 of alumina, and in the case of the sintered compacts comprising beryllium oxide as a main component, it was carried out using those with the particle size #1200 of alumina.

The thin films were formed by the same method as what was shown in Example 11 to each prepared above substrate from which the surface smoothness differs.

That is, the thin films of 100 mol % AlN were formed beforehand on the substrates prepared by the same condition as the sputtering method carried out in the experiment No.706, 707, and 708, and as the MOCVD method carried out in the experiment No.709, in Example 11.

The thin films of 100 mol % GaN were formed beforehand by the same condition as the MOCVD method carried out in the experiment No.730.

The thickness of the thin films formed beforehand on the above substrates was made into 6 μm, respectively.

Using the substrates in which the AlN thin film, GaN thin film, and InN thin film were formed beforehand, the thin films of each composition of the same 100 mol % AlN and 100 mol % GaN were formed furthermore on them in the thickness of 3 μm by the MOCVD method.

As the condition of MOCVD, it was the same condition as Example 1 and Example 2.

The above experimental result was collectively shown in Table 15.

As a result, in the substrates comprising the aluminum nitride-based sintered compact, and on the substrates comprising the sintered compacts comprising as a main component silicon carbide, silicon nitride, zinc oxide, beryllium oxide, and aluminum oxide, the thin films of the same crystallization state as the thin films produced in Example 11 were formed beforehand directly in the substrates comprising each above sintered compact without being based on the surface state, that is, the AlN thin films formed by the same sputtering method as the experimental example 706 were the amorphous state, the AlN thin films formed by the same sputtering method as the experimental example 707 were the polycrystal, and the AlN thin films formed by the same sputtering method as the experimental example 708 were the orientated polycrystal.

On the other hand, and, when the sintered compacts comprising aluminum nitride as a main component were used as a substrate, the formation of the 100 mol % AlN single-crystal thin films was tried by the same MOCVD method as the experimental example 709, but the thin films formed on the substrates in which the average surface roughness Ra is larger than 2000 nm were the polycrystalline substance in which the diffraction peak is shown only from a lattice plane (002), (101), (102), and the direct formation of a single-crystal thin film was difficult on these substrates.

On the other hand, and, the single-crystal thin films were able to be formed directly on the substrates in which the average surface roughness Ra is not more than 2000 nm.

If the 100 mol % AlN thin film and the 100 mol % GaN thin film were formed furthermore on them after the 100 mol % AlN thin films having each crystallization state of an amorphous state, a polycrystal, and an orientated polycrystal were beforehand formed using the substrates comprising the sintered compacts comprising aluminum nitride as a main component and which are the average surface roughness Ra larger than 2000 nm, they are single-crystal-ized, and all of the half width of the rocking curve of the X ray diffraction from a lattice plane (002) of these single-crystal thin films were not more than 300 seconds.

If the 100 mol % AlN thin film and the 100 mol % GaN thin film were formed furthermore on them after the 100 mol % AlN thin films having each crystallization state of an amorphous state, a polycrystal, and an orientated polycrystal were beforehand formed using the substrates comprising the sintered compacts comprising aluminum nitride as a main component and which are the average surface roughness Ra larger than 2000 nm, they also are single-crystal-ized, and all of the half width of the rocking curve of the X ray diffraction from a lattice plane (002) of these single-crystal thin films were not more than 100 seconds.

When the sintered compacts comprising as a main component silicon carbide, silicon nitride, zinc oxide, beryllium oxide, and aluminum oxide are used as a substrate, the formation of the 100 mol % AlN single-crystal thin films was tried by the same MOCVD method as the experimental example 709, but the thin films formed on the substrates in which the average surface roughness Ra was larger than 1000 nm were the polycrystalline substance in which the diffraction peak is shown only from a lattice plane (002), (101), (102), and the direct formation of the single-crystal thin films was difficult in these substrates.

On the other hand, and, the single-crystal thin films were able to be formed directly on the substrates in which the average surface roughness Ra is not more than 1000 nm.

If the 100 mol % AlN thin film and the 100 mol % GaN thin film were formed furthermore on them after the 100 mol % AlN thin films having each crystallization state of an amorphous state, a polycrystal, and an orientated polycrystal were beforehand formed using the substrates comprising the sintered compacts comprising as a main component silicon carbide, silicon nitride, zinc oxide, beryllium oxide, and aluminum oxide and which are the average surface roughness Ra larger than 1000 nm, they are single-crystal-ized, and all of the half width of the rocking curve of the X ray diffraction from a lattice plane (002) of these single-crystal thin films were not more than 300 seconds.

If the 100 mol % AlN thin film and the 100 mol % GaN thin film were formed furthermore on them after the 100 mol % AlN thin films having each crystallization state of an amorphous state, a polycrystal, and an orientated polycrystal were beforehand formed using the substrates comprising the sintered compacts comprising as a main component silicon carbide, silicon nitride, zinc oxide, beryllium oxide, and aluminum oxide and which are the average surface roughness Ra not more than 1000 nm, they also are single-crystal-ized, and the half width of the rocking curve of the X ray diffraction from a lattice plane (002) of these single-crystal thin films was not more than 200 seconds.

If the 100 mol % AlN thin film and the 100 mol % GaN thin film were formed furthermore on them after the 100 mol % AlN thin films of the orientated polycrystal state were beforehand formed using the substrates comprising the sintered compacts comprising as a main component silicon carbide, silicon nitride, zinc oxide, beryllium oxide, and aluminum oxide and which are the average surface roughness Ra not more than 1000 nm, they also are single-crystal-ized, and the half width of the rocking curve of the X ray diffraction from a lattice plane (002) of these single-crystal thin films was not more than 150 seconds.

TABLE 15

| | Charateristics of the sintered | | | Characteristics of the thin films formed on the substrate which consists of a various sintered compact | | | | | |
|---|---|---|---|---|---|---|---|---|---|
| | compact substrates | | | | | | | Thin film formed furthermore on the | |
| | | Degree | | | | | | thin film formed beforehand on the | |
| | | of the | Processing | Thin film formed beforhand on the substrate | | | | substrate | |
| | | surface | state in | | | | Half width of | | Half width of |
| | | smooth- | the | | Formation | | the (002) X | | the (002) X ray |
| Experi- | | ness | surface | Composition | method | Cystallized state | ray diffraction | Composition | diffraction |
| ment | Main | R a | of the | of | of the | of | rocking curve | of | rocking curve |
| No. | component | (n m) | substrate | the thin film | thin film | the thin film | (second) | the thin film | (second) |

| | | | | | |
|---|---|---|---|---|---|
| 1093 1094 1095 1096 1097 1098 1099 1100 1101 1102 1103 1104 | 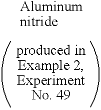 | 160 1160 2630 1460 820 1550 | as.fired Lap polish Blast polish | 100 mol % AlN 100 mol % AlN 100 mol % AlN 100 mol % AlN 100 mol % AlN 100 mol % AlN 100 mol % AlN 100 mol % AlN 100 mol % AlN 100 mol % AlN 100 mol % AlN 100 mol % GaN | |
| # Sputter Sputter Sputter Sputter Sputter MOCVD Sputter Sputter Sputter MOCVD Sputter MOCVD | Amorphous Orientated polycrystal Orientated polycrystal Amorphous Orientated polycrystal Single crystal Amorphous Polycrystal Orientated polycrystal Orientated polycrystal | | | | |
| # ——9460 —9630 4760 | 100 mol % AlN 100 mol % AlN 100 mol % GaN 100 mol % AlN 100 mol % AlN 100 mol % GaN 100 mol % AlN 100 mol % AlN 100 mol % AlN 100 mol % GaN 100 mol % GaN 100 mol % GaN | 94 89 88 95 91 98 95 96 90 97 91 87 | | | |
| 1105 1106 1107 1108 1109 1110 1111 1112 1113 | 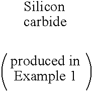 | 1460 820 1550 | as.fired Lap polish Blast polish | 100 mol % AlN 100 mol % AlN 100 mol % AlN 100 mol % AlN 100 mol % AlN 100 mol % AlN 100 mol % AlN 100 mol % AlN 100 mol % AlN | Sputter Sputter MOCVD Sputter Sputter MOCVD Sputter Sputter MOCVD |
| # Amorphous Orientated polycrystal Polycrystal Amorphous Orientated polycrystal Single c | | | | | |
| # 176 139 192 184 141 179 | | | | | |
| 1114 1115 1116 1117 1118 1119 1120 1121 1122 | 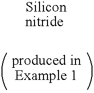 | 760 140 1270 | as.fired Lap polish Blast polish | 100 mol % AlN 100 mol % AlN 100 mol % AlN 100 mol % AlN 100 mol % AlN 100 mol % AlN 100 mol % AlN 100 mol % AlN 100 mol % AlN | Sputter Sputter MOCVD Sputter Sputter Sputter Sputter Sputter MOCVD |
| # Amorphous Orientated polycrstal Single crystal Amorphous Orientated polycrystal Orientated polycrystal Amorphous Orientated polycrystal Polycrystal | —15100 2060 —13700 14300 —16200 — | 100 mol % AlN 100 mol % AlN 100 mol % GaN 100 mol % AlN 100 mol % AlN 100 mol % GaN 100 mol % AlN | | | |
| # 100 mol % AlN 100 mol % GaN | —15100 # 2060 —13700 14300 —16200 — | | | | |
| 1123 1124 1125 1126 1127 1128 1129 1130 1131 | 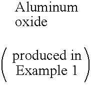 | 920 610 1230 | as.fired Lap polish Blast polish | 100 mol % AlN 100 mol % AlN 100 mol % AlN 100 mol % AlN 100 mol % AlN 100 mol % AlN 100 mol % AlN 100 mol % AlN 100 mol % AlN | Sputter Sputter MOCVD Sputter Sputter Sputter Sputter Sputter |
| # MOCVD | Amorphous Orientated polycrystal Single crystal Amorphous Orientated polycrystal Orientated crystal Amorphous Orientated polycrystal Polycrystal | —13800 1930 —13300 12800 —15400 — | 100 mol % AlN 100 mol % AlN 100 mol % GaN 100 mol % AlN 100 mol % AlN 100 mol % GaN 100 mol % AlN | | |
| # 100 mol % AlN 100 mol % GaN 146 127 176 153 132 129 158 134 170 | | | | | |
| 1132 1133 1134 1135 1136 1137 1138 1139 1140 | 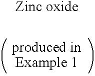 | 740 630 2130 | as.fire Lap polish Blast polish | 100 mol % AlN 100 mol % AlN 100 mol % AlN 100 mol % AlN 100 mol % AlN 100 mol % AlN 100 mol % AlN 100 mol % AlN 100 mol % AlN | Sputter Sputter MOCVD Sputter Sputter Sputter Sputter Sputter |
| # MOCVD | Amorphous Orientated polycrystal Single crystal Amorphous Orientated polycrstal Orientated polycrystal Amorphous Orientated polycrystal Polycrystal | —13700 1840 —14700 15100 —16100 — | 100 mol % AlN 100 mol % AlN 100 mol % GaN 100 mol % AlN 100 mol % AlN 100 mol % GaN 100 mol % AlN | | |
| # 100 mol % AlN 100 mol % GaN | 143 124 173 140 125 122 156 138 171 | | | | |
| 1141 1142 1143 1144 1145 1146 1147 1148 1149 | 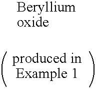 | 340 1410 950 | as.fired Lap polish Blast polish | 100 mol % AlN 100 mol % AlN 100 mol % AlN 100 mol % AlN 100 mol % AlN 100 mol % AlN 100 mol % AlN 100 mol % AlN 100 mol % AlN | Sputter Sputter Sputter Sputter Sputter MOCVD Sputter Sputter |
| # MOCVD | Amorphous Orientated polycrysta Orientated polycrstal Amorphous Orientated polycrystal Polycrystal Amorphous Orientated polycrystal Single crystal | —13800 13600 —16600 ——15200 2310 | 100 mol % AlN 100 mol % AlN 100 mol % GaN 100 mol % AlN 100 mol % AlN 100 mol % GaN 100 mol % AlN 100 mol % AlN | | |
| # 100 mol % GaN | 149 129 127 157 139 173 151 134 170 | | | | |

### EXAMPLE 13

This Example shows the examples which investigated about the compositions of these substrates, and about the influences which give to the crystallinity of the thin films which are formed on these substrates and comprise as a main component gallium nitride, indium nitride, and aluminum nitride, when the sintered compacts comprising as a main component zinc oxide are used as a substrate.

First, the guaranteed reagent powder by Kanto Kagaku Incorporated Company was prepared as zinc oxide (ZnO) powder, the Alcoa's brand name “A-16SG” was prepared as the raw material of alumina (Al₂O₃) powder, such powders were mixed by the ball mill so that they become the predetermined compositions by the same method as Example 1, then the paraffine wax was added and the powders for molding were produced, they were degreased after the powder compacts of the same size as Example 1 were molded by the uniaxial pressing, the normal-pressure sintering was carried out at 1460° C. for 1 hour in air after that, and the sintered compacts comprising zinc oxide as a main component and contain an aluminum component in various rate were produced.

Each of these sintered compacts was made dense to not less than 98% as the relative density.

As for the sintered compacts which were thus produced and comprise zinc oxide as a main component, while what does not contain an aluminum component was light white yellow, what colored into blue was seen in what contains an aluminum component, the coloring to deeper blue advances according as the content of an aluminum component increases, the deepest blue was presented in those which includes Al₂O₃ 3.0 mol %, and the degree of the blue color became weak and changed to the color tone of blue white gradually according as the content of an aluminum component increases after that.

In the other, the Fe₂O₃ powder of the purity not less than 99.99% and the Cr₂O₃ powder of the purity not less than 99.9% were prepared, and these powders were produced by Kojundo Chemical Laboratory Co., Ltd.

The Y₂O₃ powder of the purity not less than 99.99%, the Er₂O₃ powder of the purity not less than 99.99%, the Yb₂O₃ powder of the purity not less than 99.99%, the Dy₂O₃ powder of the purity not less than 99.99%, and the Ho₂O₃ powder of the purity not less than 99.99% were prepared as a rare earth element compound, and these powders were produced by Shin-Etsu Chemical Co., Ltd.

By the same method as what was shown in this Example, each above powder of the predetermined quantity was mixed with the zinc oxide powder and the alumina powder by using a ball mill, the uniaxial pressing was carried out, and the normal-pressure sintering was carried out at 1460° C. for 1 hour in air, and here produced a zinc oxide-based sintered compact and contains only an iron component, a zinc oxide-based sintered compact and contains only a chromium component, a zinc oxide-based sintered compact and contains only a yttrium component, a zinc oxide-based sintered compact and contains only an erbium component, a zinc oxide-based sintered compact and contains only a ytterbium component, the zinc oxide-based sintered compact and contains an aluminum component and an iron component simultaneously, the zinc oxide-based sintered compact and contains an aluminum component and a chromium component simultaneously, and the sintered compacts comprising zinc oxide as a main component and contain simultaneously an aluminum component and various rare earth element components.

The electric resistivity at room temperature of each sintered compact obtained was measured by the four-terminal method.

After that, each sintered compact obtained was mirror-polished by the abradant comprising as a main component a colloidal silicon oxide with the particle diameter of 0.02 μm, then the washing was carried out by the ultrasonic wave using a methylene chloride and IPA, and the substrates were produced.

The average surface roughness Ra of the mirror-polished substrates was in the range of 6.9 nm-7.7 nm.

The optical transmissivity to the light of 605 nm wavelength was measured by the same method as Example 2 using the substrates after polish.

The characteristics of the obtained substrates comprising a zinc oxide-based sintered compact are shown in Table 16.

In the above produced substrates comprising a zinc oxide-based sintered compact, the characteristics of the things which contain only an aluminum component, and of the things which do not contain an aluminum component and which contain only a chromium component, an iron component, a yttrium component, an erbium component, and a ytterbium component were indicated in Table 16.

In this Example, although the appearance of the thin films of the constitution indicated in Table 16 and all the other thin films produced was investigated, faults, such as a crack and a crevice, are not seen in all the thin films formed beforehand on the substrates and the thin films formed furthermore on them.

Though the exfoliation test was carried out using the pressure sensitive adhesive tape, in all the thin films, exfoliation was not seen between them and the substrates comprising a zinc oxide-based sintered compact, or between thin films.

The thin conductive film of Ti/Pt/Au was formed on the thin films of the surface of the substrates, the metal leads were soldered and the perpendicular tensile strength was investigated, but it all is not less than 2 kg/mm², so there are firm unifications between the sintered compacts comprising as a main component zinc oxide and the thin films formed beforehand on the substrates, and between these thin films and the thin films formed furthermore on them.

TABLE 16

| | Charateristics of the substrates which | | | | | | | |
|---|---|---|---|---|---|---|---|---|
| | consist of a sintered compact | | | | | | | |
| | which comprises a zinc | | | Charateristics of the thin films formed on the substrate which consists os a | | | | |
| | oxideas the main component | | | sintered compact which comprises a zinc oxide as the main component | | | | |
| | | | | The film formed beforehand on the substate which | | | Thin film formed futhermore on | |
| | | | | consist of a sintered compact which comprises a zinc oxide | | | the thin film formed beforehand on | |
| | | | | as the component | | | the sustrate | |
| Exeri- ment No. | 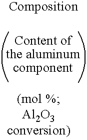 | Electric resistivity (Ω.cm) (room temperature | Optical transmissivity (%) | Composition of the thin film | Crystallized state of the thin film | Half width of the the (002) X ray diffraction rocking curve (secound) | Composition of the thin film | Half width of the (002) X ray diffraction rocking curve |
| # (second) | | | | | | | | |
| 1150 | 0.000 | > | 16 | (not formed) | — | — | 100 mol % AlN | 255 |
| 1151 | | 1 × 10⁸ | | 100 mol % AlN | Orientated polycrystal | 9430 | 100 mol % AlN | 136 |
| 1152 | 0.002 | 6.8 × 10¹ | 22 | (not formed) | — | — | 100 mol % AlN | 187 |
| 1153 | | | | 100 mol % AlN | Amorphous | — | 100 mol % AlN | 126 |
| 1154 | | | | 100 mol % AlN | Orientated polycrystal | 8190 | 100 mol % AlN | 107 |
| 1155 | 0.008 | 7.9 × 10⁰ | 24 | (not formed) | — | — | 100 mol % AlN | 159 |
| 1156 | | | | 100 mol % AlN | Orientated polycrystal | 7620 | 100 mol % AlN | 97 |
| 1157 | 0.03 | 7.4 × 10⁻¹ | 27 | (not formed) | — | — | 100 mol % GaN | 138 |
| 1158 | | | | 100 mol % AlN | Orientated polycrystal | 7690 | 100 mol % GaN | 95 |
| 1159 | 0.10 | 8.4 × 10⁻² | 36 | (not formed) | — | — | 100 mol % AlN | 126 |
| 1160 | | | | 100 mol % AlN | Orientated polycrystal | 7490 | 100 mol % AlN | 94 |
| 1161 | | | | 100 mol % AlN | Orientated polycrystal | 7650 | 100 mol % GaN | 93 |
| 1162 | 0.30 | 7.7 × 10⁻³ | 44 | (not formed) | — | — | 100 mol % AlN | 125 |
| 1163 | | | | 100 mol % AlN | Orientated polycrystal | 7540 | 100 mol % AlN | 93 |
| 1164 | 1.0 | 2.9 × 10⁻³ | 53 | (not formed) | — | — | 100 mol % AlN | 121 |
| 1165 | | | | 100 mol % AlN | Amorphous | — | 100 mol % AlN | 96 |
| 1166 | | | | 100 mol % AlN | Orientated polycrystal | 7470 | 100 mol % AlN | 89 |
| 1167 | 3.0 | 1.6 × 10⁻³ | 56 | (not formed) | — | — | 100 mol % AlN | 112 |
| 1168 | | | | (not formed) | — | — | 100 mol % GaN | 118 |
| 1169 | | | | (not formed) | — | — | 100 mol % AlN | 119 |
| 1170 | | | | 100 mol % AlN | Amorphous | — | 100 mol % AlN | 94 |
| 1171 | | | | 100 mol % AlN | Polycrystal | — | 100 mol % AlN | 96 |
| 1172 | | | | 100 mol % AlN | Orientated polycrystal | 7350 | 100 mol % AlN | 86 |
| 1173 | | | | 100 mol % AlN | Orientated polycrystal | 7320 | 100 mol % GaN | 88 |
| 1174 | | | | 100 mol % AlN | Orientated ploycrystal | 7460 | 100 mol % InN | 89 |
| 1175 | | | | 100 mol % AlN | Orientated polycrystal | 7390 | 50 mol % AlN | 87 |
| | | | | | | | +50 mol % GaN | |
| 1176 | | | | 100 mol % AlN | Single crystal | 115 | 100 mol % AlN | 96 |
| 1177 | | | | 100 mol % GaN | Amorphous | — | 100 mol % AlN | 93 |
| 1178 | | | | 100 mol % GaN | Orientated polycrystal | 7180 | 100 mol % AlN | 88 |
| 1179 | | | | 100 mol % InN | Orientated polycrystal | 7240 | 100 mol % AlN | 90 |
| 1180 | 10.0 | 6.3 × 10⁻³ | 52 | (not formed) | — | — | 100 mol % AlN | 118 |
| 1181 | | | | 100 mol % AlN | Orientated polycrystal | 7410 | 100 mol % AlN | 88 |
| 1182 | | | | 100 mol % AlN | Orientated polycrystal | 7390 | 100 mol % GaN | 91 |
| 1183 | | | | 100 mol % AlN | Orientated polycrystal | 7440 | 50 mol % GaN | 89 |
| | | | | | | | −50 mol % IaN | |
| 1184 | 20.0 | 8.9 × 10⁻³ | 42 | (not formed) | — | — | 100 mol % IaN | 119 |
| 1185 | | | | 100 mol % AlN | Orientated polycrystal | 7510 | 100 mol % IaN | 92 |
| 1186 | 30.0 | 8.2 × 10⁻³ | 33 | (not formed) | — | — | 100 mol % GaN | 127 |
| 1187 | | | | 100 mol % AlN | Amorphous | — | 100 mol % GaN | 96 |
| 1188 | | | | 100 mol % AlN | Orientated polycrystal | 7500 | 100 mol % GaN | 91 |
| 1189 | 40.0 | 7.8 × 10⁻¹ | 31 | (not formed) | — | — | 100 mol % AlN | 136 |
| 1190 | | | | 100 mol % AlN | Orientated polycrystal | 7570 | 100 mol % AlN | 94 |
| 1191 | | | | 100 mol % AlN | Orientated polycrystal | 7530 | 100 mol % IaN | 97 |
| 1192 | 50.0 | > | 17 | (not formed) | — | — | 100 mol % AlN | 229 |
| 1193 | | 1 × 10⁸ | | 100 mol % AlN | Orientated polycrystal | 9260 | 100 mol % AlN | 134 |
| 1194 | 1.0 | 8.7 × 10⁻¹ | 6.9 | (not formed) | — | — | 100 mol % AlN | 227 |
| 1195 | (Fe₂O₃) | | | 100 mol % AlN | Orientated polycrystal | 8710 | 100 mol % AlN | 124 |
| 1196 | 1.0 | 3.4 × 10⁻¹ | 9.2 | (not formed) | — | — | 100 mol % GaN | 220 |
| 1197 | (Cr₂O₃) | | | 100 mol % AlN | Orientated polycrystal | 8890 | 100 mol % GaN | 119 |
| 1198 | 0.04 | > | 57 | (not formed) | — | — | 100 mol % AlN | 192 |
| 1199 | (Y₂O₃) | 1 × 10⁸ | | 100 mol % AlN | Orientated polycrystal | 7770 | 100 mol % AlN | 104 |
| 1200 | 0.04 | > | 53 | (not formed) | — | — | 100 mol % GaN | 206 |
| 1201 | (Er₂O₃) | 1 × 10⁸ | | 100 mol % AlN | Orientated polycrystal | 7940 | 100 mol % GaN | 107 |
| 1202 | 0.04 | > | 54 | (not formed) | — | — | 100 mol % AlN | 203 |
| 1203 | (Yb₂O₃) | 1 × 10⁸ | | 100 mol % AlN | Orientated polycrystal | 7860 | 100 mol % AlN | 109 |

### EXAMPLE 14

This Example shows the examples which investigated about the compositions of these substrates, and about the influences which give to the crystallinity of the thin films which are formed on these substrates and comprise as a main component gallium nitride, indium nitride, and aluminum nitride, when the sintered compacts comprising as a main component beryllium oxide are used as a substrate.

First, those which was used in Example 1 and is 99% of purity by Kojundo Chemical Laboratory Co., Ltd. was prepared as beryllium oxide (BeO) powder, what is 99.99% of purity by Kojundo Chemical Laboratory Co., Ltd. was prepared as a magnesia (MgO) powder, what is 99.99% of purity by Kojundo Chemical Laboratory Co., Ltd. was prepared as calcium carbonate (CaCO₃) powder, and the “SO-E2” grade which is produced by Admatechs Corp. and is 99.9% of purity was prepared as a silica (SiO₂) powder.

These powders were pulverized and mixed by the ball mill so that they become the predetermined composition by the same method as Example 1, then a paraffine wax was added and the powders for molding were produced, they were degreased after the uniaxial pressing to the powder compacts of the same size as Example 1, the normal-pressure sintering was carried out at 1500° C. for 3 hours in air, and the sintered compacts comprising beryllium oxide as a main component and contain a magnesium component, a calcium component, and a silicon component in various rate were produced.

Each of these sintered compacts became dense to not less than 98% as the relative density.

Specular surface polish was carried out using the abradant comprising as a main component the colloidal alumina with the particle diameter of 0.05 μm like Example 6, the washing was carried out by the ultrasonic wave using a methylene chloride and IPA, and the substrates were produced.

The average surface roughness Ra of the mirror-polished substrates was in the range of 8.6 nm-9.5 nm.

The optical transmissivity to the light of 605 nm wavelength was measured by the same method as Example 2 using the substrates after polish.

The characteristics of the substrates which were obtained like that and comprise a sintered compact comprising as a main component beryllium oxide are shown in Table 17.

In this Example, although the appearance of the thin films of the constitution indicated in Table 17 and all the other thin films produced was investigated, faults, such as a crack and a crevice, are not seen in all the thin films formed beforehand on the substrates and the thin films formed furthermore on them.

Though the exfoliation test was carried out using the pressure sensitive adhesive tape, in all the thin films, exfoliation was not seen between them and the substrates comprising a sintered compact comprising beryllium oxide as a main component, or between thin films.

The thin conductive film of Ti/Pt/Au was formed on the thin films of the surface of the substrates, the metal leads were soldered and the perpendicular tensile strength was investigated, but it all is not less than 2 kg/mm², so there are firm unifications between the sintered compacts comprising as a main component beryllium oxide and the thin films formed beforehand on the substrates, and between these thin films and the thin films formed furthermore on them.

TABLE 17

| | | | | | | Characteristics of the thin films formed on the substrate | | |
|---|---|---|---|---|---|---|---|---|
| | Characteristics of the substrates which consist of | | | | | | Thin film formed furthermore | |
| | a sintered compact which comprises a | | | | | | on the thin film formed | |
| | beryllium oxide as the main component | | | | | | beforehand on the substrate | |
| | Composition of the sintered compact | | | | | Half width of the rocking | | Half width of the |
| | [Content of the component] | | | | Optical | curve of the AlN orientated | | (002) X ray |
| | (mol %; oxide conversion) | | | | transmissivity | polycrystal thin film | Composition | diffraction |
| Experiment | Components | | | | (%) | formed beforehand on the | of | rocking curve |
| No. | Magnesium | Calcium | Silicon | Other components | [605 nm] | substrate (second) | the thin film | (second) |
| 1262 | 0.0000 | 0.0000 | 0.0000 | 0.0000 | 14 | — (not formed) | 100 mol % AlN | 270 |
| 1263 | | | | (not added) | | 9670 | 100 mol % AlN | 139 |
| 1264 | 0.0001 | 0.0000 | 0.0000 | 0.0000 | 19 | — (not formed) | 100 mol % AlN | 221 |
| 1265 | | | | (not added) | | 9120 | 100 mol % AlN | 132 |
| 1266 | 0.0000 | 0.0004 | 0.0000 | 0.0000 | 26 | — (not formed) | 100 mol % AlN | 191 |
| 1267 | | | | (not added) | | 8540 | 100 mol % AlN | 124 |
| 1268 | 0.0000 | 0.0000 | 0.0020 | 0.0000 | 25 | — (not formed) | 100 mol % GaN | 168 |
| 1269 | | | | (not added) | | 7710 | 100 mol % GaN | 96 |
| 1270 | 0.0080 | 0.0000 | 0.0000 | 0.0000 | 31 | — (not formed) | 100 mol % AlN | 142 |
| 1271 | | | | (not added) | | 7740 | 100 mol % AlN | 95 |
| 1272 | 0.000 | 0.020 | 0.000 | 0.000 | 37 | — (not formed) | 100 mol % AlN | 122 |
| 1273 | | | | (not added) | | 7560 | 100 mol % AlN | 95 |
| 1274 | 0.00 | 0.00 | 0.40 | 0.00 | 36 | — (not formed) | 100 mol % AlN | 127 |
| 1275 | | | | (not added) | | 7730 | 100 mol % AlN | 97 |
| 1276 | 0.00 | 0.45 | 0.00 | 0.00 | 57 | — (not formed) | 100 mol % AlN | 109 |
| 1277 | | | | (not added) | | 7340 | 100 mol % AlN | 89 |
| 1278 | 0.60 | 0.00 | 0.00 | 0.00 | 45 | — (not formed) | 100 mol % AlN | 124 |
| 1279 | | | | (not added) | | 7540 | 100 mol % AlN | 95 |
| 1280 | 0.00 | 0.45 | 0.20 | 0.00 | 54 | — (not formed) | 100 mol % AlN | 108 |
| 1281 | | | | (not added) | | 7190 | 100 mol % AlN | 89 |
| 1282 | 0.60 | 0.00 | 0.20 | 0.00 | 47 | — (not formed) | 100 mol % AlN | 125 |
| 1283 | | | | (not added) | | 7650 | 100 mol % AlN | 96 |
| 1284 | 0.60 | 0.45 | 0.00 | 0.00 | 55 | — (not formed) | 100 mol % AlN | 114 |
| 1285 | | | | (not added) | | 7340 | 100 mol % AlN | 90 |
| 1286 | 0.60 | 0.45 | 0.20 | 0.00 | 52 | — (not formed) | 100 mol % AlN | 112 |
| 1287 | | | | (not added) | | 7290 | 100 mol % AlN | 92 |
| 1288 | 0.00 | 3.00 | 0.00 | 0.00 | 50 | — (not formed) | 100 mol % AlN | 111 |
| 1289 | | | | (not added) | | 7370 | 100 mol % AlN | 91 |
| 1290 | 0.00 | 10.00 | 0.00 | 0.00 | 53 | — (not formed) | 100 mol % AlN | 117 |
| 1291 | | | | (not added) | | 7410 | 100 mol % AlN | 93 |
| 1292 | 00.00 | 20.00 | 0.00 | 0.00 | 42 | — (not formed) | 100 mol % AlN | 119 |
| 1293 | | | | (not added) | | 7590 | 100 mol % AlN | 95 |
| 1294 | 30.00 | 0.00 | 0.00 | 0.00 | 24 | — (not formed) | 100 mol % AlN | 132 |
| 1295 | | | | (not added) | | 7650 | 100 mol % AlN | 96 |
| 1296 | 40.00 | 0.00 | 0.00 | 0.00 | 7.6 | — (not formed) | 100 mol % AlN | 217 |
| 1297 | | | | (not added) | | 9480 | 100 mol % AlN | 142 |
| 1298 | 0.0000 | 0.0004 | 0.0000 | 0.0002 | 35 | — (not formed) | 100 mol % AlN | 182 |
| 1299 | | | | (Y₂O₃) | | 7960 | 100 mol % AlN | 119 |
| 1300 | 0.000 | 0.020 | 0.000 | 0.0010 | 47 | — (not formed) | 100 mol % AlN | 121 |
| 1301 | | | | (Y₂O₃) | | 7490 | 100 mol % AlN | 93 |
| 1302 | 0.000 | 0.020 | 0.000 | 0.0040 | 54 | — (not formed) | 100 mol % AlN | 120 |
| 1303 | | | | (Y₂O₃) | | 7420 | 100 mol % AlN | 94 |
| 1304 | 0.000 | 0.020 | 0.000 | 0.010 | 67 | — (not formed) | 100 mol % GaN | 118 |
| 1305 | | | | (Y₂O₃) | | 7340 | 100 mol % GaN | 92 |
| 1306 | 0.00 | 0.45 | 0.00 | 0.040 | 81 | — (not formed) | 100 mol % AlN | 104 |
| 1307 | | | | (Y₂O₃) | | 7240 | 100 mol % AlN | 88 |
| 1308 | 0.0000 | 0.0004 | 0.0000 | 4.0 | 37 | — (not formed) | 100 mol % GaN | 176 |
| 1309 | | | | (Y₂O₃) | | 7890 | 100 mol % GaN | 121 |
| 1310 | 0.0000 | 0.0004 | 0.0000 | 6.0 | 28 | — (not formed) | 100 mol % AlN | 189 |
| 1311 | | | | (Y₂O₃) | | 7930 | 100 mol % AlN | 126 |
| 1312 | 0.00 | 0.45 | 0.00 | 0.040 | 76 | — (not formed) | 100 mol % GaN | 110 |
| 1313 | | | | (Dy₂O₃) | | 7310 | 100 mol % GaN | 91 |
| 1314 | 0.00 | 0.45 | 0.00 | 0.040 | 75 | — (not formed) | 100 mol % AlN | 107 |
| 1315 | | | | (Ho₂O₃) | | 7360 | 100 mol % AlN | 90 |
| 1316 | 0.00 | 0.45 | 0.00 | 0.040 | 80 | — (not formed) | 100 mol % AlN | 108 |
| 1317 | | | | (Er₂O₃) | | 7280 | 100 mol % AlN | 89 |
| 1318 | 0.00 | 0.45 | 0.00 | 0.040 | 78 | — (not formed) | 100 mol % GaN | 106 |
| 1319 | | | | (Yb₂O₃) | | 7330 | 100 mol % GaN | 90 |
| 1320 | 0.00 | 0.45 | 0.20 | 0.040 | 80 | — (not formed) | 100 mol % GaN | 109 |
| 1321 | | | | (Y₂O₃) | | 7220 | 100 mol % GaN | 89 |

### EXAMPLE 15

This Example shows the examples which investigated about the compositions of these substrates, and about the influences which give to the crystallinity of the thin films which are formed on these substrates and comprise as a main component gallium nitride, indium nitride, and aluminum nitride, when the sintered compacts comprising as a main component aluminum oxide are used as a substrate.

First, “A-31” grade by Nippon Light Metal Co., Ltd. was prepared as aluminum oxide (Al₂O₃) powder, what is 99.99% purity by Kojundo Chemical Laboratory Co., Ltd. was prepared as a magnesia (MgO) powder, what is 99.99% purity by Kojundo Chemical Laboratory Co., Ltd. was prepared as calcium carbonate (CaCO₃) powder, the “SO-E2” grade with the 99.9% purity made by Admatechs Corp. was prepared as a silica (SiO₂) powder.

These powders were pulverized and mixed by the ball mill so that they become the predetermined composition by the same method as Example 1, then a paraffine wax was added and the powders for molding were produced, they were degreased after the uniaxial pressing to the powder compacts of the same size as Example 1, the normal-pressure sintering was carried out at 1550° C. for 3 hours in air, and the sintered compacts comprising aluminum oxide as a main component and contain a magnesium component, a calcium component, and a silicon component in various rate were produced.

Each of these sintered compacts became dense to not less than 98% as a relative density.

Specular surface polish was carried out using the abradant comprising as a main component the colloidal alumina with the particle diameter of 0.05 μm like Example 6, the washing was carried out by the ultrasonic wave using a methylene chloride and IPA, and the substrates were produced.

The average surface roughness Ra of the mirror-polished substrates was in the range of 6.7 nm-7.6 nm.

The optical transmissivity to the light with a wavelength of 605 nm was measured by the same method as Example 2 using the substrates after polish.

Thus, the characteristics of the obtained substrates comprising the sintered compacts comprising as a main component aluminum oxide are shown in Table 18.

In this Example, although the appearance of the thin films of the constitution indicated in Table 18 and all the other thin films produced was investigated, faults, such as a crack and a crevice, are not seen in all the thin films formed beforehand on the substrates and the thin films formed furthermore on them.

Though the exfoliation test was carried out using the pressure sensitive adhesive tape, in all the thin films, exfoliation was not seen between them and the substrates comprising a sintered compact comprising aluminum oxide as a main component, or between thin films.

The thin conductive film of Ti/Pt/Au was formed on the thin films of the surface of the substrates, the metal leads were soldered and the perpendicular tensile strength was investigated, but it all is not less than 2 kg/mm², so there are firm unifications between the sintered compacts comprising as a main component aluminum oxide and the thin films formed beforehand on the substrates, and between these thin films and the thin films formed furthermore on them.

TABLE 18

| | | | | | | Characteristics of the thin films formed on the substrate | | |
|---|---|---|---|---|---|---|---|---|
| | Characteristics of the substrates which consist of | | | | | | Thin film formed furthermore | |
| | a sintered compact which comprises an | | | | | | on the thin film formed | |
| | aluminum oxide as the main component | | | | | | beforehand on the substrate | |
| | Composition of the sintered compact | | | | | Half width of the rocking | | Half width of the |
| | [Content of the component] | | | | Optical | curve of the AlN orientated | | (002) X ray |
| | (mol %; oxide conversion) | | | | transmissivity | polycrystal thin film | Composition | diffraction |
| Experiment | Components | | | | (%) | formed beforehand on the | of | rocking curve |
| No. | Magnesium | Calcium | Silicon | Other components | [605 nm] | substrate (second) | the thin film | (second) |
| 1322 | 0.0000 | 0.0000 | 0.0000 | 0.0000 | 18 | — (not formed) | 100 mol % AlN | 274 |
| 1323 | | | | (not added) | | 9720 | 100 mol % AlN | 142 |
| 1324 | 0.0000 | 0.0005 | 0.0000 | 0.0000 | 17 | — (not formed) | 100 mol % AlN | 215 |
| 1325 | | | | (not added) | | 9240 | 100 mol % AlN | 133 |
| 1326 | 0.0000 | 0.0000 | 0.0020 | 0.0000 | 24 | — (not formed) | 100 mol % AlN | 187 |
| 1327 | | | | (not added) | | 8660 | 100 mol % AlN | 122 |
| 1328 | 0.010 | 0.000 | 0.000 | 0.000 | 43 | — (not formed) | 100 mol % AlN | 156 |
| 1329 | | | | (not added) | | 7810 | 100 mol % AlN | 96 |
| 1330 | 0.000 | 0.050 | 0.000 | 0.000 | 36 | — (not formed) | 100 mol % AlN | 140 |
| 1331 | | | | (not added) | | 7830 | 100 mol % AlN | 97 |
| 1332 | 0.12 | 0.00 | 0.00 | 0.00 | 51 | — (not formed) | 100 mol % GaN | 119 |
| 1333 | | | | (not added) | | 7350 | 100 mol % GaN | 92 |
| 1334 | 0.60 | 0.00 | 0.20 | 0.00 | 47 | — (not formed) | 100 mol % AlN | 116 |
| 1335 | | | | (not added) | | 7310 | 100 mol % AlN | 93 |
| 1336 | 1.20 | 0.00 | 0.00 | 0.00 | 57 | — (not formed) | 100 mol % GaN | 114 |
| 1337 | | | | (not added) | | 7260 | 100 mol % GaN | 90 |
| 1338 | 1.00 | 0.20 | 0.00 | 0.00 | 55 | — (not formed) | 100 mol % AlN | 113 |
| 1339 | | | | (not added) | | 7240 | 100 mol % AlN | 91 |
| 1340 | 0.00 | 1.00 | 1.00 | 0.00 | 27 | — (not formed) | 100 mol % AlN | 124 |
| 1341 | | | | (not added) | | 7690 | 100 mol % AlN | 96 |
| 1342 | 0.60 | 0.80 | 0.80 | 0.00 | 46 | — (not formed) | 100 mol % GaN | 120 |
| 1343 | | | | (not added) | | 7740 | 100 mol % GaN | 94 |
| 1344 | 3.00 | 0.00 | 0.00 | 0.00 | 52 | — (not formed) | 100 mol % AlN | 117 |
| 1345 | | | | (not added) | | 7270 | 100 mol % AlN | 92 |
| 1346 | 2.00 | 2.00 | 4.00 | 0.00 | 50 | — (not formed) | 100 mol % AlN | 119 |
| 1347 | | | | (not added) | | 7480 | 100 mol % AlN | 93 |
| 1348 | 10.00 | 0.00 | 0.00 | 0.00 | 47 | — (not formed) | 100 mol % AlN | 124 |
| 1349 | | | | (not added) | | 7520 | 100 mol % AlN | 96 |
| 1350 | 6.00 | 2.00 | 8.00 | 0.00 | 41 | — (not formed) | 100 mol % GaN | 125 |
| 1351 | | | | (not added) | | 7450 | 100 mol % GaN | 92 |
| 1352 | 2.00 | 2.00 | 26.00 | 0.00 | 44 | — (not formed) | 100 mol % AlN | 126 |
| 1353 | | | | (not added) | | 7670 | 100 mol % AlN | 96 |
| 1354 | 0.00 | 20.00 | 20.00 | 0.00 | 22 | — (not formed) | 100 mol % AlN | 141 |
| 1355 | | | | (not added) | | 7830 | 100 mol % AlN | 97 |
| 1356 | 20.00 | 0.00 | 30.00 | 0.00 | 6.4 | — (not formed) | 100 mol % AlN | 226 |
| 1357 | | | | (not added) | | 9370 | 100 mol % AlN | 147 |
| 1358 | 0.000 | 0.050 | 0.000 | 0.040 | 37 | — (not formed) | 100 mol % AlN | 137 |
| 1359 | | | | (Y₂O₃) | | 7760 | 100 mol % AlN | 95 |
| 1360 | 1.20 | 0.00 | 0.00 | 0.040 | 59 | — (not formed) | 100 mol % GaN | 112 |
| 1361 | | | | (Y₂O₃) | | 7250 | 100 mol % GaN | 89 |
| 1362 | 1.20 | 0.00 | 0.00 | 0.040 | 56 | — (not formed) | 100 mol % AlN | 115 |
| 1363 | | | | (Ho₂O₃) | | 7310 | 100 mol % AlN | 91 |
| 1364 | 1.20 | 0.00 | 0.00 | 0.040 | 58 | — (not formed) | 100 mol % GaN | 115 |
| 1365 | | | | (Yb₂O₃) | | 7290 | 100 mol % GaN | 90 |
| 1366 | 0.000 | 1.00 | 1.00 | 0.0005 | 33 | — (not formed) | 100 mol % AlN | 118 |
| 1367 | | | | (Y₂O₃) | | 7600 | 100 mol % AlN | 94 |
| 1368 | 0.60 | 0.80 | 0.80 | 0.0080 | 57 | — (not formed) | 100 mol % AlN | 111 |
| 1369 | | | | (Y₂O₃) | | 7390 | 100 mol % AlN | 92 |
| 1370 | 0.60 | 0.00 | 0.20 | 0.040 | 69 | — (not formed) | 100 mol % AlN | 112 |
| 1371 | | | | (Y₂O₃) | | 7480 | 100 mol % AlN | 91 |
| 1372 | 0.000 | 1.00 | 1.00 | 8.0 | 36 | — (not formed) | 100 mol % GaN | 121 |
| 1373 | | | | (Y₂O₃) | | 7680 | 100 mol % GaN | 94 |
| 1374 | 0.000 | 1.00 | 1.00 | 12.0 | 27 | — (not formed) | 100 mol % AlN | 124 |
| 1375 | | | | (Y₂O₃) | | 7830 | 100 mol % AlN | 97 |
| 1376 | 1.00 | 0.20 | 0.00 | 0.040 | 82 | — (not formed) | 100 mol % AlN | 107 |
| 1377 | | | | (Y₂O₃) | | 7070 | 100 mol % AlN | 88 |
| 1378 | 1.00 | 0.20 | 0.00 | 0.040 | 78 | — (not formed) | 100 mol % AlN | 113 |
| 1379 | | | | (Dy₂O₃) | | 7240 | 100 mol % AlN | 90 |
| 1380 | 1.00 | 0.20 | 0.00 | 0.040 | 81 | — (not formed) | 100 mol % GaN | 109 |
| 1381 | | | | (Er₂O₃) | | 7160 | 100 mol % GaN | 89 |

### EXAMPLE 16

This Example shows the examples, wherein the optical permeability is investigated about the substrates comprising a sintered compact comprising as a main component zirconium oxide, magnesium oxide, magnesium aluminate, and yttrium oxide, and formation of the single-crystal thin films comprising as a main component at least one selected from gallium nitride, indium nitride and aluminum nitride was tried on it by forming beforehand the thin film(s) comprising as a main component at least one selected from gallium nitride, indium nitride and aluminum nitride and having at least one of the crystallization states selected from an amorphous state, a polycrystal, an orientated polycrystal, and a single crystal, using these substrates.

As for the substrates comprising a sintered compact comprising as a main component zirconium oxide, magnesium oxide, and magnesium aluminate, two kinds, that are the sintered compacts produced in Example 1, and the sintered compacts newly produced in this Example, were prepared, respectively.

The substrate comprising a sintered compact comprising yttrium oxide as a main component was newly produced in this Example.

In this Example, the sintered compacts comprising as a main component zirconium oxide, magnesium oxide, magnesium aluminate, and yttrium oxide by the method shown below were newly produced.

That is, here prepared the zirconium oxide raw material which includes 3 mol % Y₂O₃ as the same stabilization agent as what was used in Example 1, the sintering aids were not added to the raw material powder like Example 1, but the paraffine wax was added, and the powder for molding was produced, it degreased after molding this powder by a uniaxial press, a hot press was carried out under the pressure of 150 kg/cm² at 1400° C. for 2 hours in air, thus the sintered compacts comprising zirconium oxide as a main component were produced.

The same magnesium oxide raw material as what was used in Example 1 was prepared, CaO and Y₂O₃ were added by 1 weight % respectively, as sintering aids, pulverization mixture was carried out by the ball mill like Example 1, it degreased after the powder in which a paraffine wax was added was molded by the uniaxial press, normal-pressure sintering was carried out at 1600° C. for 6 hours in air, and the sintered compacts comprising magnesium oxide as a main component were produced.

The same magnesium aluminate raw material as what was used in Example 1 is prepared, CaO and Y₂O₃ were added by 0.1 weight % respectively as sintering aids, like the case of the magnesium oxide, pulverization mixture was carried out by the ball mill, a paraffine wax was added and the powder for molding was produced, it degreased after the uniaxial pressing, normal-pressure sintering was carried out at 1650° C. for 8 hours in hydrogen current, and the sintered compacts comprising magnesium aluminate as a main component were produced.

The same Y₂O₃ powder, Dy₂O₃ powder, and Ho₂O₃ powder as what was used in Example 13 were prepared, the powder for moulding was produced adding a paraffine wax after pulverization by the ball mill using only the above Y₂O₃ powder as a main component, it degreased after the uniaxial pressing, normal-pressure sintering was carried out at 1 600° C. for 3 hours in air, and the sintered compacts comprising as a main component yttrium oxide were produced.

In the other, the Dy₂O₃ and Ho₂O₃ powder were added to the above Y₂O₃ powder 99.5 weight % by 0.25 weight % respectively, as sintering aids, and pulverization mixture was carried out by the ball mill, the powder for moulding was produced adding a paraffine wax, they degreased after the uniaxial pressing, normal-pressure sintering was carried out at 2100° C. for 3 hours in hydrogen current, and the sintered compacts comprising as a main component yttrium oxide were produced.

The mirror-polishing of each sintered compact produced in Example 1 and this Example was carried out using the abradant comprising a colloidal aluminum oxide with the particle diameter of 0.05 μm after the grinding processing, they were washed by acetone and iso-propyl alcohol, and the disk-like substrates with the diameter of 25.4 mm and the thickness of 0.5 mm were produced.

Though the optical permeability to the light with a wavelength of 605 nm was measured about the substrates produced like this, it was confirmed that all the substrates have optical permeability.

After that, the thin film(s) comprising as a main component at least one selected from gallium nitride, indium nitride and aluminum nitride and in an amorphous, polycrystalline or orientated polycrystalline state was formed beforehand on these substrates in the thickness of 3 μm, and the formation of the single-crystal thin films comprising as a main component at least one selected from gallium nitride, indium nitride and aluminum nitride was tried on it in the thickness of 3 μm.

It was thus confirmed that the single-crystal thin films can clearly be formed on the substrates comprising a sintered compact which was produced in this Example and comprising as a main component zirconium oxide, magnesium oxide, and magnesium aluminate.

These results are shown in Table 19.

In this Example, although the appearance of the thin films of the constitution indicated in Table 19 was investigated, faults, such as a crack and a crevice, are not seen in all the thin films formed beforehand on the substrates and the thin films formed furthermore on them.

Though the exfoliation test was carried out using the pressure sensitive adhesive tape, in all the thin films, exfoliation was not seen between them and the substrates comprising the sintered compacts comprising zirconium oxide, magnesium oxide, magnesium aluminate, and yttrium oxide as a main component, or between thin films.

The thin conductive film of Ti/Pt/Au was formed on the thin films of the surface of the substrates, the metal leads were soldered and the perpendicular tensile strength was investigated, but it all is not less than 2 kg/mm², so there are firm unifications between the sintered compacts comprising as a main component zirconium oxide, magnesium oxide, magnesium aluminate, and yttrium oxide and the thin films formed beforehand on the substrates, and between these thin films and the thin films formed furthermore on them.

TABLE 19

| | | | | Characteristics of the thin films formed on the substrate which consists of a various sintered compact | | | | | |
|---|---|---|---|---|---|---|---|---|---|
| | Characteristics of the sintered | | | | | | | Thin film formed furthermore | |
| | compact substrates | | | | | | | on the thin film formed | |
| | Main | Average | | Thin film formed beforehand on the substrate | | | | beforehand on the substrate | |
| | component | surface | Optical | | | | Half width of | | Half width of |
| Ex- | [Sintering aids, | rough- | trans- | | Formation | | the (002) Xray | | the (002) Xray |
| peri- | and | ness | mis- | Composition | method of | | diffraction | Composition | diffraction |
| ment | additive agents] | Ra | sivity | of | the | | rocking curve | of | rocking curve |
| No. | (Firing method) | (nm) | (%) | the thin film | thin film | Crystallized state | (second) | the thin film | (second) |
| 1382 | Zirconium | 7.1 | 27 | 100 mol % AlN | Sputter | Amorphous | — | 100 mol % AlN | 187 |
| 1383 | dioxide | | | 100 mol % AlN | Sputter | Orientated polycrystal | 9670 | 100 mol % AlN | 180 |
| 1384 | [Y₂O₃] | | | 100 mol % AlN | MOCVD | Orientated polycrystal | 7970 | 100 mol % GaN | 163 |
| | (Firing in air) | | | | | | | | |
| 1385 | Zirconium | 4.2 | 59 | 100 mol % AlN | Sputter | Amorphous | — | 100 mol % AlN | 137 |
| 1386 | dioxide | | | 100 mol % AlN | Sputter | Polycrystal | — | 100 mol % AlN | 138 |
| 1387 | [Y₂O₃] | | | 100 mol % AlN | Sputter | Orientated polycrystal | 7820 | 100 mol % AlN | 133 |
| 1388 | (Hot press) | | | 100 mol % AlN | MOCVD | Orientated polycrystal | 6570 | 100 mol % GaN | 118 |
| 1389 | | | | 100 mol % GaN | MOCVD | Orientated polycrystal | 6800 | 100 mol % GaN | 120 |
| 1390 | | | | 100 mol % InN | MOCVD | Orientated polycrystal | 7090 | 100 mol % GaN | 122 |
| 1391 | Magnesium | 7.9 | 34 | 100 mol % AlN | Sputter | Amorphous | — | 100 mol % AlN | 185 |
| 1392 | oxide | | | 100 mol % AlN | Sputter | Orientated polycrystal | 9420 | 100 mol % AlN | 171 |
| 1393 | [no additive] | | | 100 mol % AlN | Sputter | Orientated polycrystal | 9240 | 100 mol % GaN | 166 |
| | (Firing in air) | | | | | | | | |
| 1394 | Magnesium | 4.4 | 83 | 100 mol % AlN | Sputter | Amorphous | — | 100 mol % AlN | 139 |
| 1395 | oxide | | | 100 mol % AlN | Sputter | Polycrystal | — | 100 mol % AlN | 144 |
| 1396 | [CaO + Y₂O₃] | | | 100 mol % AlN | Sputter | Orientated polycrystal | 7880 | 100 mol % AlN | 119 |
| 1397 | (Firing in air) | | | 100 mol % AlN | MOCVD | Orientated polycrystal | 6940 | 100 mol % GaN | 120 |
| 1398 | | | | 100 mol % AlN | Sputter | Orientated polycrystal | 7730 | 50 mol % GaN + | 122 |
| | | | | | | | | 50 mol % InN | |
| 1399 | | | | 100 mol % GaN | MOCVD | Orientated polycrystal | 6950 | 100 mol % GaN | 125 |
| 1400 | | | | 100 mol % InN | MOCVD | Orientated polycrystal | 7170 | 100 mol % GaN | 126 |
| 1401 | Magnesium | 8.4 | 32 | 100 mol % AlN | Sputter | Amorphous | — | 100 mol % AlN | 191 |
| 1402 | aluminate | | | 100 mol % AlN | Sputter | Orientated polycrystal | 9440 | 100 mol % AlN | 157 |
| 1403 | [no additive] | | | 100 mol % AlN | Sputter | Orientated polycrystal | 9620 | 100 mol % GaN | 154 |
| | (Firing in air) | | | | | | | | |
| 1404 | Magnesium | 5.7 | 79 | 100 mol % AlN | Sputter | Amorphous | — | 100 mol % AlN | 144 |
| 1405 | aluminate | | | 100 mol % AlN | Sputter | Polycrystal | — | 100 mol % AlN | 149 |
| 1406 | [CaO + Y₂O₃] | | | 100 mol % AlN | Sputter | Orientated polycrystal | 8590 | 100 mol % AlN | 134 |
| 1407 | (Firing in | | | 100 mol % AlN | MOCVD | Orientated polycrystal | 7160 | 100 mol % GaN | 124 |
| 1408 | hydrogen) | | | 100 mol % AlN | Sputter | Orientated polycrystal | 7970 | 50 mol % AlN + | 128 |
| | | | | | | | | 50 mol % GaN | |
| 1409 | | | | 100 mol % GaN | MOCVD | Orientated polycrystal | 7140 | 100 mol % GaN | 122 |
| 1410 | | | | 100 mol % InN | MOCVD | Orientated polycrystal | 7310 | 100 mol % GaN | 129 |
| 1411 | Yttrium oxide | 6.9 | 42 | 100 mol % AlN | Sputter | Amorphous | — | 100 mol % AlN | 177 |
| 1412 | [no additive] | | | 100 mol % AlN | Sputter | Orientated polycrystal | 9330 | 100 mol % AlN | 152 |
| 1413 | (Firing in air) | | | 100 mol % AlN | Sputter | Orientated polycrystal | 9410 | 100 mol % GaN | 155 |
| 1414 | Yttrium oxide | 7.6 | 82 | 100 mol % AlN | Sputter | Amorphous | — | 100 mol % AlN | 139 |
| 1415 | [Dy₂O₃ + | | | 100 mol % AlN | Sputter | Polycrystal | — | 100 mol % AlN | 141 |
| | Ho₂O₃] | | | | | | | | |
| 1416 | (Firing in | | | 100 mol % AlN | Sputter | Orientated polycrystal | 7760 | 100 mol % AlN | 126 |
| 1417 | hydrogen) | | | 100 mol % AlN | MOCVD | Orientated polycrystal | 6510 | 100 mol % GaN | 115 |
| 1418 | | | | 100 mol % GaN | MOCVD | Orientated polycrystal | 6740 | 100 mol % AlN | 112 |
| 1419 | | | | 100 mol % GaN | MOCVD | Orientated polycrystal | 6690 | 100 mol % GaN | 117 |
| 1420 | | | | 100 mol % InN | MOCVD | Orientated polycrystal | 7170 | 100 mol % GaN | 121 |

### EXAMPLE 17

This Example shows the examples which investigated the luminous efficiency of the light-emitting devices produced using the aluminum nitride-based sintered compact, as a substrate.

First, using the sintered compacts which are produced in this invention and comprise aluminum nitride as a main component, as a substrate, the things from which the composition (the content of an aluminum nitride component) and the optical transmissivity differ respectively were prepared.

The things having conduction vias were prepared.

The substrates prepared have disk-like shape with the diameter of 25.4 mm and the thickness of 0.5 mm, and the mirror-polishing and subsequent washing have been carried out by the method which uses the abradant comprising a chromic oxide as a main component like Example 6

The average surface roughness Ra is in the range of 19 nm-33 nm.

As the thin film of the 1st layer, the thin film(s) comprising as a main component a material selected from gallium nitride or aluminum nitride and having at least one of the crystallization states selected from an amorphous state, a polycrystal, an orientated polycrystal, and a single crystal was formed suitably on the substrates prepared in the thickness of 3 μm by the same sputtering method or MOCVD method as what was shown in the experiment No.706, 707, 708, 709 and 730 in Example 11.

After that, onto these substrates having a thin film, furthermore the single-crystal thin film comprising as a main component a material selected from gallium nitride or aluminum nitride was suitably formed in the thickness of 3 μm by the same method as what was shown in Example 1, as the thin film of the 2nd layer.

In addition, there are the things which do not form the above thin films and used the sintered compacts comprising aluminum nitride as a main component, as a substrate as it is, or the things which do not form the single-crystal thin film of the 2nd layer and comprising only one layer of thin film.

Each thin conductive film of Cr, Mo, W, W/Cu alloy, Ru, Rh, Pd, Os, Ir, Pt, Ti, and Ni was formed suitably on the other substrates prepared in the thickness of 0.5 μm by the same sputtering method as what was shown in Example 9 and Example 10, and the orientated polycrystalline thin films comprising as a main component at least one selected from gallium nitride or aluminum nitride were formed furthermore suitably on these thin conductive films in the thickness of 3 μm by the same sputtering method or MOCVD method as what was shown in the experiment No.708 and 730 in Example 11, as the thin film of the 1st layer.

The single-crystal thin films comprising as a main component at least one selected from gallium nitride and aluminum nitride were suitably formed furthermore on them in the thickness of 3 μm by the same MOCVD method as what was shown in Example 1, as the thin film of the 2nd layer.

Production of the light-emitting devices was tried using these substrates in which the thin film comprising as a main component a material selected from gallium nitride or aluminum nitride, and/or each thin conductive film of Cr, Mo, W, W/Cu alloy, Ru, Rh, Pd, Os, Ir, Pt, Ti, and Ni were formed on the sintered compacts comprising aluminum nitride as a main component.

For comparison, the commercial sapphire substrates having the diameter of 25.4 mm, thickness of 0.5 mm and an average surface roughness Ra of 1.2 nm, the substrate surface being C plane (namely, C axis is perpendicular to the substrate surface), were produced by KYOCERA Corp., and the production of the light-emitting devices was tried on them.

As for these sapphire substrates, here prepared the things with the surface states as they are, and the things having the thin films of one or two layers comprising as a main component at least one selected from gallium nitride and aluminum nitride into the surface by the method by this Example, and the light-emitting devices were produced.

The characteristics of each above substrate used for light-emitting device production are shown in Table 20.

The origins of the substrates used in this Example (produced experiment No.) are also shown in Table 20.

The optical transmissivity of each substrate in Table 20 is those to the light with a wavelength of 605 nm.

Each above substrate prepared was put into the reaction container of the same MOCVD equipment as what was used in Example 1, and the preliminary heating was carried out at 950-1050° C., flowing H₂.

After that, using trimethyl gallium for a gallium raw material, and using H₂ for a career gas, and NH₃ for a reactive gas, the GaN film was formed on each above substrate as a buffer layer, in the thickness of 500 Å and the substrate temperature of 520° C., by the MOCVD method of the same equipment as what was used in above Example 1.

Onto each buffer layer formed, a Si doping epitaxial growth GaN thin film which becomes the contact layer and the barrier layer of a single quantum well was formed in the thickness of 5 μm using trimethyl gallium as a main raw material, and using further SiH₄ gas as a raw material for the doping component by the MOCVD method of the same conditions as the above except having made the substrate temperature into 1000° C.

Onto it, 2 components mixture composition thin film of undoped epitaxially grown InGaN which becomes a well layer of the single quantum well which is a luminescence layer was formed in the thickness of 30 Å using the trimethyl gallium and trimethyl indium as a main raw material without using the doping component by the MOCVD method of the same conditions as the above except having made the substrate temperature into 800° C.

As for the composition of the InGaN thin film which becomes a luminescence layer, three kinds of things, i.e., In_{0.06}Ga_{0.94}N, In_{0.20}Ga_{0.80}N, and In_{0.45}Ga_{0.55}N, were produced.

Onto it, the epitaxially grown thin film of Al_{0.20}Ga_{0.80}N composition which doped Mg and which becomes a barrier layer of a single quantum well was formed in the thickness of 0.15 μm using the trimethyl gallium and trimethyl aluminum as a main raw material, and using further bis-cyclopentadienyl magnesium (MgCp₂) as a raw material for the doping component by the MOCVD method of the same conditions as the above except having made the substrate temperature into 1050° C.

Onto it, the epitaxially grown GaN thin film which doped Mg and which becomes a contact layer was formed in the thickness of 0.5 μm using trimethyl gallium as a main raw material, and using further bis-cyclopentadienyl magnesium (MgCp₂) as a raw material for the doping component by the MOCVD method of the same conditions as the above except having made the substrate temperature into 1000° C.

After that, the substrates in which the thin films were formed were taken out from the reaction container, and they were heated at 700° C. in N₂.

The masks of predetermined shape were formed on the P-type GaN thin film layers in which Mg was doped and which were made like that, etching was carried out until the GaN thin film layers of the above Si doping were exposed, and the electrodes were produced by two layers of metal thin films of Ti/Al on these GaN thin film layers of the Si doping.

The electrodes were produced by two layers of metal thin films of Ni/Au onto these Mg doping GaN thin film layers currently formed on the top layer.

After that, the substrates in which the thin films were formed were cut into the chips with the outside size of 1 mm×1 mm, and the light-emitting devices (LED) of single quantum well structure were produced.

The actuating currents of Table 20 are the value at the time of having made the light-emitting devices drive on the operating voltage of 3.6 volts.

As a result, in the case of the light-emitting devices of the single quantum well structure which were produced using the sapphire substrates, the luminous efficiency was small regardless of the existence of the thin films, it was 6.7% in that which does not form the gallium-nitride and aluminum-nitride thin films in the surface of these sapphire substrates, and it is in the range of 6.9%-7.4% even if one or two layers of the gallium-nitride and aluminum-nitride thin films are formed, on the other hand in the case of the light-emitting devices which were produced using the substrates of this invention comprising an aluminum nitride-based sintered compact, the luminous efficiency was not less than 10% altogether.

In the light-emitting devices produced using the substrates of this invention comprising an aluminum nitride-based sintered compact having a thin conductive film, the luminous efficiency was not less than 10% altogether.

The luminous efficiency of the light-emitting devices produced using the substrates in which the thin conductive film(s) was formed did not lower compared with the luminous efficiency of the light-emitting devices produced using the substrates which do not form the thin conductive film(s) in the same substrate.

TABLE 20

| | Characteristics of the substrates which consist of a sintered compact comprising an | | | | | | | | | | | |
|---|---|---|---|---|---|---|---|---|---|---|---|---|
| | aluminum nitride as the main component and are used for light emitting device production | | | | | | | | | | | |
| | Characteristics of the substrates | | | | | | | | | | | |
| | which consist of a sintered | | | | | | | | | | | |
| | compact comprising an | | | | | | | | | | | |
| | aluminum nitride as the | | | | Characteristics of the thin films formed on the substrate | | | | | | | |
| | main component | | | | 1st layer | | | 2nd layer | | | | |
| | Used AlN | | Optical | | | Crys- | Half | (single crystal) | | Characteristics of the | | |
| Ex- | substrate | AlN | trans- | Thin | | tal- | width of | | Half width of | light emitting devices produced | | |
| peri- | (Experiment | content | mis- | film | Thin | lized | the rocking | Thin | the rocking | Actuating | Luminecence | Luminous |
| ment | No. which | (volume | sivity | conductivity | film | state | curve | film | curve | current | output | efficiency |
| No. | produced) | %) | (%) | material | material | *6) | (second) | material | (second) | (mA) | (mW) | (%) |
| 1421 | 47 | 99.0 | 25 | none | none | — | — | none | — | 480 | 270 | 15.6 |
| 1422 | | | | none | AlN | A | — | none | — | 490 | 310 | 17.6 |
| 1423 | | | | none | AlN | P | — | none | — | 470 | 290 | 17.1 |
| 1424 | | | | none | AlN | O | 7790 | none | — | 480 | 320 | 18.5 |
| 1425 | | | | none | AlN | S | 181 | none | — | 490 | 300 | 17.0 |
| 1426 | | | | none | AlN | A | — | AlN | 89 | 480 | 380 | 22 |
| 1427 | | | | none | AlN | P | — | AlN | 93 | 480 | 360 | 21 |
| 1428 | | | | none | AlN | O | 8060 | AlN | 92 | 490 | 420 | 24 |
| 1429 | | | | none | AlN | S | 187 | AlN | 97 | 500 | 360 | 20 |
| 1430 | 49 | 96.7 | 34 | none | AlN | O | 7640 | AlN | 79 | 490 | 440 | 25 |
| 1431 | | | | W | AlN | O | 7430 | AlN | 86 | 490 | 440 | 26 |
| 1432 | | | | *4) | AlN | O | 7210 | AlN | 90 | 510 | 510 | 28 |
| 1433 | | | | *5) | GaN | O | 7710 | AlN | 88 | 500 | 560 | 31 |
| 1434 | | | | Ru | AlN | O | 7350 | AlN | 94 | 490 | 480 | 27 |
| 1435 | | | | Rh | AlN | O | 4870 | AlN | 93 | 500 | 490 | 27 |
| 1436 | | | | Pd | AlN | O | 7990 | GaN | 92 | 500 | 500 | 28 |
| 1437 | | | | Os | AlN | O | 7830 | GaN | 94 | 500 | 520 | 29 |
| 1438 | | | | Ir | AlN | O | 7760 | GaN | 87 | 490 | 510 | 29 |
| 1439 | | | | Pt | AlN | O | 8140 | AlN | 91 | 490 | 480 | 27 |
| 1440 | | | | Ni | AlN | O | 7070 | AlN | 83 | 480 | 450 | 26 |
| 1441 | 60 | 99.0 | 17 | none | AlN | O | 8120 | AlN | 88 | 480 | 270 | 15.6 |
| 1442 | 106 | 99.8 | 54 | none | AlN | O | 7940 | AlN | 86 | 510 | 590 | 32 |
| 1443 | | | | none | GaN | A | — | none | — | 500 | 670 | 37 |
| 1444 | 108 | 99.8 | 74 | none | AlN | O | 7830 | AlN | 84 | 520 | 950 | 51 |
| 1445 | 110 | 97.0 | 67 | none | AlN | O | 7890 | GaN | 86 | 520 | 820 | 44 |
| 1446 | 259 | *2) | 81 | none | AlN | O | 7470 | AlN | 81 | 560 | 1070 | 53 |
| 1447 | 269 | *2) | 86 | none | AlN | O | 7390 | GaN | 82 | 550 | 1110 | 56 |
| 1448 | 279 | *2) | 85 | none | AlN | O | 7420 | AlN | 80 | 530 | 1070 | 56 |
| 1449 | 284 | *2) | 88 | none | AlN | O | 7520 | AlN | 81 | 540 | 1210 | 62 |
| 1450 | 387 | 99.5 | 46 | none | AlN | O | 7760 | AlN | 87 | 530 | 550 | 29 |
| 1451 | 425 | 98.0 | 6.9 | none | AlN | O | 7240 | AlN | 87 | 490 | 290 | 16.4 |
| 1452 | 433 | 70.0 | 0.8 | none | AlN | O | 6970 | GaN | 89 | 490 | 280 | 15.6 |
| 1453 | 887 | 25.0 | 0.0 | none | AlN | O | 7150 | AlN | 89 | 480 | 220 | 12.7 |
| 1454 | 73 *1) | 96.0 | 32 | Mo | AlN | O | 7760 | AlN | 94 | 500 | 380 | 21 |
| 1455 | 80 *1) | 96.7 | 36 | W | GaN | O | 4560 | GaN | 91 | 500 | 470 | 26 |
| 1456 | 311 *1) | *3) | 82 | none | GaN | O | 4620 | GaN | 89 | 520 | 1010 | 54 |
| 1457 | Sapphire substrate | | 92 | none | none | — | — | none | — | 440 | 106 | 6.7 |
| 1458 | | | | | GaN | A | — | GaN | 80 | | | 7.4 |
| 1459 | | | | | AlN | O | 7190 | AlN | 81 | | | 6.9 |
| 1460 | 49 | 96.7 | 34 | none | GaN | O | 4540 | AlN | 89 | 480 | 380 | 22 |
| 1461 | | | | Ti | AlN | O | 7420 | GaN | 93 | 510 | 420 | 23 |
| 1462 | 108 | 99.8 | 74 | none | AlN | O | 7830 | AlN | 84 | 550 | 870 | 44 |
| 1463 | 110 | 97.0 | 67 | none | none | — | — | none | — | 540 | 820 | 42 |
| 1464 | 265 | *2) | 86 | none | AlN | O | 7750 | AlN | 82 | 530 | 950 | 50 |
| 1465 | 279 | *2) | 85 | none | AlN | O | 7420 | AlN | 80 | 540 | 910 | 47 |
| 1466 | 284 | *2) | 88 | none | AlN | O | 7510 | GaN | 84 | 520 | 950 | 51 |
| 1467 | 80 *1) | 96.7 | 36 | Cr | AlN | O | 7230 | AlN | 88 | 490 | 410 | 23 |
| 1468 | 311 *1) | *3) | 82 | none | GaN | O | 4620 | GaN | 89 | 510 | 860 | 47 |

| | | | | | | | | | | | |
|---|---|---|---|---|---|---|---|---|---|---|---|
| 1469 | Sapphire substrate | 92 | none | none | — | — | none | — | 420 | 82 | 5.4 |
| 1470 | | | | GaN | A | — | none | — | | | 5.9 |

*1) Conduction via(s) is formed.
*2) AlN single phase (Additives have vaporized, and it is almost 100% AlN. The details about composition are shown in Table 11).
*3) AlN single phase (Additives have vaporized, and it is almost 100% AlN. Y and Ca ingredient of an additive is 0.6 ppm or less, respectively).
*4) W/Cu alloy which has the composition, wherein tungsten is 90 weight % and copper is 10 weight %.
*5) W/Cu alloy which has the composition, wherein tungsten is 70 weight % and copper is 30 weight %.
*6) The crystallized state of the thin film of the 1st layer beforehand formed on the substrate is shown as follows, respectively, amorphous state: A. polycrystal: P. orientated polycrystal: O. single crystal: S
In addition, GaN thin film formed in the experiment No. 1455, 1456, and 1468 doped Si and has conductivity.

### EXAMPLE 18

This Example shows the examples which investigated the luminous efficiency, carrying out the trial of production of the light-emitting devices using the sintered compacts comprising as a main component each silicon carbide, silicon nitride, zinc oxide, beryllium oxide, aluminum oxide, zirconium oxide, magnesium oxide, magnesium aluminate, and yttrium oxide, as a substrate.

First, using each sintered compact which was produced in this invention and comprising as a main component silicon carbide, silicon nitride, zinc oxide, beryllium oxide, aluminum oxide, zirconium oxide, magnesium oxide, magnesium aluminate, and yttrium oxide, as a substrate, the things from which the composition (content of each ceramic main components) and optical transmissivity differ respectively were prepared.

The substrates prepared have the shape of disk with the diameter of 25.4 mm and the thickness of 0.5 mm, and mirror-polishing and subsequent washing have been carried out.

The average surface roughness Ra of each substrate is the same as each origin, i.e., what was shown in Example 1, Example 6, Example 13, Example 14, Example 15, and Example 16 (Ra of the substrate comprising a sintered compact which was produced in Example 1 and comprising zirconium oxide as a main component is 36 nm, Ra of the substrate comprising a sintered compact comprising magnesium oxide as a main component is 60 nm, Ra of the substrate comprising a sintered compact comprising magnesium aluminate as a main component is 63 nm, and all the remaining substrates are the average surface roughness not more than those).

The thin films comprising as a main component a material selected from gallium nitride or aluminum nitride and have at least one of the crystallization states selected from an amorphous state, a polycrystal, an orientated polycrystal, and a single crystal were formed suitably on the substrates prepared in the thickness of 3 μm as the thin film of the 1st layer by the same sputtering method or MOCVD method as what was shown in the experiment No.706, 707, 708, 709 and 730 in Example 11.

After that, onto these substrates in which a thin film was formed, furthermore the single-crystal thin films comprising as a main component a material selected from gallium nitride or aluminum nitride were suitably formed in the thickness of 3 μm by the same method as what was shown in Example 1, as the thin film of the 2nd layer.

In addition, there are the things which do not form the above thin films and used the sintered compacts as a substrate as they are, or the things with only one layer of thin films which do not form the single-crystal thin film of the 2nd layer The characteristics of each above substrate used for light-emitting device production are shown in Table 21.

The origin (the produced experiment No.) of the substrates used in this Example is also shown in Table 21.

Hereafter, production of the light-emitting devices of single quantum well structure was tried as well as Example 17 using each substrate prepared in this Example.

As a result, in all the produced light-emitting devices, the luminous efficiency is not less than 8%, and superior clearly compared with the luminous efficiency of the light-emitting device produced in Example 17 using the sapphire substrate.

TABLE 21

| | Charateristics of the sustrates which consist of a various sintered compact comprising a ceramic material | | | | | | | | | | | |
|---|---|---|---|---|---|---|---|---|---|---|---|---|
| | as the main component and are used for the light emitting device production | | | | | | | | | | | |
| | Charateristics of the substrates which consist of a | | | | | | | | | Characteristics of the | | |
| | various sintered compact comprising a ceramic | | | | | | | | | light emitting devices | | |
| | material as the main component | | | | Characteristics of the thin films formed on the substrate produced | | | | | | | |
| | | | | | | | | 2nd layer (single | | | | |
| | Used substrates | | | | 1st layer | | | crystal) | | | | |
| Experi- ment No. | Main component | Example which produced | 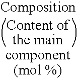 | Optical trans- missivity (%) | Thin film material | Crystall- ized state * 19) | Half width of the rocking curve (second) | Thin film material | Half width of the rocking curve (second) | Actu- ating current (mA) | Lumine- cence output (mW) | Luminous efficiency (%) |
| 1471 | Silicon | Example 8 | 98.0 | 0.0 | AlN | A | — | none | — | 470 | 180 | 10.6 |
| 1472 | carbide | | * 1) | | AlN | O | 9900 | GaN | 147 | 480 | 230 | 13.3 |
| 1473 | Silicon | Example 8 | 96.0 | 0.0 | AlN | O | 11740 | none | — | 460 | 190 | 11.5 |
| 1474 | nitride | | * 1) | | AlN | O | 10880 | AlN | 163 | 470 | 230 | 13.6 |
| 1475 | Zinc | Example | * 2) | 6.9 | AlN | O | 8710 | AlN | 124 | 480 | 240 | 13.9 |
| 1476 | oxide | 30 | ˜100 | 16 | none | — | — | none | — | 460 | 170 | 10.3 |
| 1477 | | | * 3) | | AlN | A | — | none | — | 470 | 210 | 12.4 |
| 1478 | | | | | AlN | P | — | none | — | 470 | 190 | 11.2 |
| 1479 | | | | | AlN | O | 9370 | none | — | 470 | 220 | 13.0 |
| 1480 | | | | | AlN | S | 255 | none | — | 470 | 200 | 11.8 |
| 1481 | | | | | AlN | A | — | AlN | 143 | 480 | 250 | 14.5 |
| 1482 | | | | | AlN | P | — | AlN | 145 | 480 | 240 | 13.9 |
| 1483 | | | | | AlN | O | 9430 | AlN | 136 | 480 | 260 | 15.0 |
| 1484 | | | | | AlN | S | 261 | AlN | 186 | 480 | 250 | 14.5 |
| 1485 | | | * 4) | 24 | AlN | O | 7620 | AlN | 97 | 480 | 290 | 16.8 |
| 1486 | | | * 5) | 36 | AlN | O | 7650 | GaN | 93 | 490 | 330 | 18.7 |
| 1487 | | | * 6) | 44 | AlN | O | 7540 | AlN | 93 | 500 | 470 | 26 |
| 1488 | | | * 7) | 56 | AlN | O | 7350 | GaN | 86 | 490 | 550 | 31 |
| 1489 | | | | | AlN | O | 7320 | AlN | 88 | 510 | 510 | 28 |
| 1490 | | | | | GaN | O | 7180 | AlN | 88 | 500 | 520 | 29 |
| 1491 | | | * 8) | 68 | AlN | O | 7520 | AlN | 93 | 490 | 650 | 37 |
| 1492 | | | * 9) | 75 | GaN | O | 6790 | GaN | 89 | 520 | 860 | 46 |
| 1493 | | | | | AlN | O | 7510 | AlN | 92 | 510 | 790 | 43 |
| 1494 | | | * 10) | 84 | AlN | O | 7470 | AlN | 87 | 540 | 970 | 50 |
| 1495 | | | | | GaN | O | 6920 | GaN | 87 | 540 | 1070 | 55 |
| 1496 | Beryllium | Example | * 11) | 14 | AlN | O | 9670 | AlN | 139 | 470 | 250 | 14.8 |
| 1497 | oxide | 31 | * 12) | 57 | AlN | O | 7340 | AlN | 89 | 500 | 560 | 31 |
| 1498 | | | * 13) | 76 | AlN | O | 7310 | GaN | 91 | 520 | 790 | 42 |
| 1499 | | | * 14) | 81 | AlN | O | 7240 | AlN | 88 | 550 | 1030 | 52 |
| 1500 | Aluminum | Example | * 15) | 57 | AlN | O | 7260 | AlN | 90 | 490 | 510 | 29 |
| 1501 | oxide | 32 | * 16) | 78 | AlN | O | 7240 | AlN | 90 | 500 | 790 | 44 |
| 1502 | | | * 17) | 82 | AlN | O | 7070 | AlN | 88 | 510 | 940 | 51 |
| 1503 | Zirconium | Example 1 | 97.0 | 27 | AlN | O | 7970 | GaN | 163 | 460 | 240 | 15.5 |
| 1504 | oxide | Example | | 59 | GaN | A | — | none | — | 470 | 360 | 21 |
| 1505 | | 33 | | | GaN | O | 6800 | GaN | 120 | 480 | 470 | 27 |
| 1506 | Magnesium | Example 1 | ≧99 | 34 | AlN | O | 9420 | AlN | 171 | 490 | 320 | 18.1 |
| 1507 | oxide | | * 1) | | AlN | O | 9240 | GaN | 166 | 490 | 330 | 18.7 |
| 1508 | | Example | 98.0 | 83 | AlN | A | — | AlN | 139 | 540 | 930 | 48 |
| 1509 | | 33 | * 1) | | AlN | O | 7880 | AlN | 119 | 540 | 990 | 51 |
| 1510 | Magnesium | Example 1 | ≧99 | 32 | AlN | O | 9470 | none | — | 480 | 270 | 15.6 |
| 1511 | aluminate | | * 1) | | AlN | O | 9620 | GaN | 154 | 490 | 330 | 18.7 |
| 1512 | | Example | | 81 | AlN | O | 8590 | AlN | 134 | 540 | 870 | 45 |
| 1513 | | 33 | | | AlN | O | 7160 | GaN | 124 | 530 | 960 | 50 |
| 1514 | Yttrium | Example | * 18) | 42 | AlN | O | 9330 | AlN | 152 | 500 | 400 | 22 |
| 1515 | oxide | 33 | | | AlN | O | 9410 | GaN | 155 | 490 | 410 | 23 |
| 1516 | | | 99.5 | 83 | AlN | O | 7760 | AlN | 126 | 520 | 880 | 47 |
| 1517 | | | * 1) | | GaN | O | 6510 | GaN | 115 | 540 | 990 | 51 |

* 1) shown by weight %.
* 2): 99. 0 (what produced in Experiment No.1194-1195).
* 3): not using sintering aids, it produces only from a raw material (produced in Experiment No.1150-1151).
* 4): 99.992 (what produced in Experiment No.1156).
* 5): 99.9 (what produced in Experiment No.1169-1161).
* 6): 99.7 (what produced in Experiment No.1162-1163).
* 7): 97.0 (what produced in Experimenc No.1167-1179).
* 8): 99.93 (what produced in Experiment No.1218-1219).
* 9): 99.66 (what produced in Experimenc No.1236-1237).
* 10): 96.96 (what produced in Experimenc No.1240-1241).
* 11): 100 (what produced in Experiment No.1262-1263).
* 12): 99.55 (what produced in Experiment No.1276-1277).
* 13): 99.51 (what produced in Experiment No.1312—1313).
* 14): 99.51 (what produced in Experiment No.1306-1307).
* 15): 98.80 (what produced in Experiment No.1336-1337).
* 16): 98.76 (what produced in Experiment No.1378-1379).
* 17): 98.76 (what produced in Experiment No.1376-1377).
* 18) it is produced only from a raw material without using sintering aids. (it is produced in Experiment No.1412-1413).
* 19) The crystallized state of the thin film of the 1st layer beforehand formed on the substrate is shown as follows, respectively amorphous state: A. polycrystal: P, orientated polycrystal: O, single crystal: S.
In addition, GaN thin film formed in Experiment No. 1492 and 1495 doped Si and has conductivity.

### EXAMPLE 19

This Example shows the examples which investigated the characteristics about the gallium nitride-based sintered compacts.

First, the raw material powders of gallium nitride were prepared by the following method.
1) First, the metal gallium with the purity of 4N by Kojundo Chemical Laboratory Co., Ltd. was prepared.

This metal gallium was put into the alumina container, and put on the heating part of the reaction container made from a silica tube having the heating part and the reaction part, the metal gallium was evaporated by heating at 1200° C. in argon gas current containing hydrogen 5 volume % and it was led to the reaction part by the argon gas current, and nitrogen gas was introduced into the reaction part and reacted with the evaporated metal gallium at 1100° C.

As a result, a deposit of ash gray powder was accepted near the exit of the reaction container in which the temperature is low, and it was confirmed that it is gallium nitride by the result of X ray diffraction.

The average particle diameter of the powder was 14 μm.

In addition, the reaction container is one silica tube, and the heating part and the reaction part are connected directly, feed port for career gas, such as argon gas, is provided in the entrance of the container, and feed ports for reactive gas, such as nitrogen gas and ammonia gas, are provided in the reaction part of the container.

The heating part and reaction part of the reaction container are heated by the external heater.

Especially the heater for heating is not prepared at the gas entrance portion of the container, but natural cooling is carried out.

The powder obtained was ground by the ball mill and gallium nitride powder with an average particle diameter of 1.7 μm was produced.

Oxygen was contained in this gallium nitride powder 1.1 weight %.

The gallium nitride powder by the direct nitriding method of metal was produced in this way.
2) the gallium oxide (Ga₂O₃) powder with the purity of 4N by Kojundo Chemical Laboratory Co., Ltd. and the commercial carbon black powder were prepared, and 300 g of the gallium oxide powder and 90 g of the carbon black powder were mixed in the dry state by the ball mill.

This mixed powder was put into the carbon container, and heated at 1350° C. for 5 hours in nitrogen gas by the furnace made from carbon, and the reaction has been carried out.

The mixed powder was taken out after heating, a remaining carbon black was oxidized and removed by heating at 500° C. for 2 hours in air, after that.

When the remaining powder was analyzed by X ray diffraction, it was confirmed that it is only the peak of gallium nitride clearly.

The average particle diameter of this powder was 0.9 μm.

The oxygen content of this powder was 0.8 weight %.

The gallium nitride powder by the oxide reduction method was produced in this way.
3) the gallium trichloride (GaCl₃) with the purity of 5N by Kojundo Chemical Laboratory Co., Ltd. was prepared.

This gallium trichloride was put into the quartz container, and it was heated at 90° C. and fused, the gallium trichloride gas was led to the reaction container made from a silica tube by being bubbled with the nitrogen gas containing hydrogen 20 volume %, and the ammonia gas introduced to the reaction container and the evaporated gallium trichloride were reacted at 1050° C.

As the result, a deposit of ash gray powder was accepted near the exit of the reaction container in which the temperature is low, and it was confirmed that it is gallium nitride by the result of X ray diffraction.

Average particle diameter of the powder was 0.4 μm.

The oxygen content of this powder was 1.3 weight %.

The gallium nitride powder by the chemical transport method was produced in this way.

The Y₂O₃ powder, Er₂O₃ powder, Yb₂O₃ powder, Dy₂O₃ powder, and Ho₂O₃ powder which are the purity not less than 99.99% and which were produced by Shin-Etsu Chemical Co., Ltd., were prepared as a rare earth element compound, CaCO₃ powder was prepared as an alkaline-earth-metal component, Si₃N₄ powder was prepared as a silicon component, AlN powder was prepared as an aluminum component, and MoO₃ powder was prepared as a transition metal component. These powders of the suitable quantity shown in Table 22 were added to the gallium nitride raw material powder produced in this Example, and they were mixed with ethanol which is a solvent for 24 hours by the ball mill in wet state, then they were dried and the ethanol was vaporized.

Paraffine wax was added 5 weight % in these mixed powders after dried, and the powders for moulding were produced, the uniaxial pressing of these powders was carried out under the pressure of 500 kg/cm², and the disk-like powder compacts with the diameter of 32 mm and thickness of 1.5 mm were obtained.

In addition, as the powder for moulding, and the powder compact, the things which only used three kinds of gallium nitride raw material powders produced in this Example as they were without adding each above additive component were also produced.

After these powder compacts were degreased at 300° C. under reduced pressure state, they were fired at 1450° C. in nitrogen atmosphere for 2 hours, and the gallium nitride-based sintered compacts were obtained.

The sintered compacts after fired became dense to the relative density not less than 99%, even if which raw material was used.

After mirror-polishing the surfaces of these sintered compacts obtained using the abradant comprising a colloidal silica, the washing was carried out by the ultrasonic wave using acetone and the substrates were produced.

The range of average surface roughness Ra of the mirror-polished sintered compacts was 17-24 nm.

In the sintered compacts obtained, the electric resistivity in room temperature, and the optical permeability to the light with a wavelength of 605 nm were measured.

In all the produced gallium nitride-based sintered compacts, the electric resistivity at room temperature was not more than 1×10⁸ Ω·cm as shown in Table 22.

It was confirmed that the gallium nitride-based sintered compacts and contain silicon have the conductivity not more than 1×10⁴ Ω·cm.

In the gallium nitride-based sintered compacts and contain silicon in the range of 0.00001 mol %-10.0 mol % on an element basis, the things in which the electric resistivity at room temperature is at least not more than 1×10³ Ω·cm are easily obtained.

In the gallium nitride-based sintered compacts and contain silicon in the range of 0.00001 mol %-7.0 mol % on an element basis, the things in which the electric resistivity at room temperature is at least not more than 1×10¹ Ω·cm were obtained.

In the gallium nitride-based sintered compacts and contain silicon in the range of 0.00001-5.0 mol % on an element basis, the things in which the electric resistivity at room temperature is at least not more than 1×10⁰ Ω·cm were obtained.

In the gallium nitride-based sintered compacts and contain silicon in the range of 0.00001-3.0 mol % on an element basis, the things in which the electric resistivity at room temperature is at least not more than 1×10⁻¹ Ω·cm were obtained.

In the produced gallium nitride-based sintered compacts, what has high conductivity, such that the electric resistivity at room temperature is the lowest 1.4×10⁻³ Ω·cm, were obtained.

Almost all the gallium nitride-based sintered compacts had optical permeability.

Among them, even if the gallium nitride-based sintered compacts comprise substantially only gallium as a metal element without additives, they had optical permeability.

An alkaline earth metal and a rare earth element component are effective to the optical permeability of the gallium nitride-based sintered compacts, in the sintered compacts in which at least one selected from an alkaline earth metal and a rare earth element are contained not more than 30.0 mol % on an oxide basis and comprising gallium nitride as a main component, the things in which the optical transmissivity is not less than 10% are producible.

In the sintered compacts in which at least one selected from the above alkaline earth metal component and rare earth element component are contained not more than 20 mol % on an oxide basis and comprising gallium nitride as a main component, the optical permeability becomes easily improved, and the things in which the optical transmissivity is not less than 20% were obtained.

In the sintered compacts in which at least one selected from an alkaline-earth-metal component and a rare earth element component on an oxide basis are contained not more than 15 mol % and comprising gallium nitride as a main component, the things in which the optical transmissivity is not less than 30% were obtained.

In the sintered compacts in which at least one selected from an alkaline-earth-metal component and a rare earth element component on an oxide basis are contained not more than 10.0 mol % and comprising gallium nitride as a main component, the things in which the optical transmissivity is not less than 40% were obtained.

In the sintered compacts in which at least one selected from an alkaline-earth-metal component and a rare earth element component on an oxide basis are contained not more than 8.0 mol % and comprising gallium nitride as a main component, the things in which the optical transmissivity is not less than 50% were obtained.

In the sintered compacts in which at least one selected from an alkaline-earth-metal component and a rare earth element component on an oxide basis are contained not more than 6.0 mol % and comprising gallium nitride as a main component, it was confirmed that the things in which the optical transmissivity is not less than 60% were obtained.

In this Example, in the gallium nitride-based sintered compact and contains yttrium oxide 0.01 mol % on the basis of Y₂O₃, the highest optical transmissivity was 86%.

Even if the gallium nitride-based sintered compacts contained an alkaline earth metal component and a rare earth element component, it was confirmed that they had good optical permeability like those containing them separately.

In the gallium nitride-based sintered compacts and contain a molybdenum component, the things in which the optical transmissivity is not less than 10% were obtained.

In the gallium nitride-based sintered compacts and contain silicon nitride, the things in which the optical transmissivity is not less than 10% were obtained.

In the gallium nitride-based sintered compacts and contain aluminum nitride, the things in which the optical transmissivity is not less than 10% were obtained.

In the sintered compact which was produced in this Example and comprising gallium nitride as a main component and containing simultaneously silicon nitride 0.01 mol % on a silicon basis and yttrium oxide 0.01 mol % on the basis of Y₂O₃, the optical transmissivity is high as 82%, and the conductivity is also high like the electric resistivity at room temperature is 1.7×10⁻² Ω·cm.

In the gallium nitride-based sintered compact and containing simultaneously a total of three kinds of components which are silicon nitride of 0.01 mol % on a silicon basis, calcium oxide of 0.2 mol % by on a CaO basis, and yttrium oxide of 0.2 mol % on the basis of Y₂O₃, the optical transmissivity is high as 76%, and the conductivity is also high like the electric resistivity at room temperature is 2.4×10⁻² Ω·cm.

The thin films comprising as a main component at least one selected from gallium nitride, indium nitride and aluminum nitride and have at least one of the crystallization states selected from a single crystal, an amorphous state, a polycrystal, and an orientated polycrystal were formed in the thickness of 3 μm on the produced substrates using the sputtering method and the MOCVD method under the same conditions as Example 11, after that.

It was thus confirmed that the single-crystal thin films can clearly be formed directly on the sintered compacts which were produced in this Example and comprise gallium nitride as a main component.

It was confirmed that the thin films in an amorphous, polycrystalline or orientated polycrystalline state can be formed.

As for the crystallinity of the orientated polycrystal thin films comprising gallium nitride as a main component, the phenomenon of being easy to have a tendency superior to the things comprising aluminum nitride as a main component was seen.

Selecting suitably from the substrates in which the thin films of such various crystallization states were formed, the formation of the single-crystal thin films comprising as a main component at least one selected from gallium nitride, indium nitride and aluminum nitride was tried furthermore on them in the thickness of 3 μm.

As a result, in the gallium nitride-based sintered compacts and formed beforehand the thin films comprising as a main component at least one selected from gallium nitride, indium nitride and aluminum nitride and have at least one of the crystallization states selected from a single crystal, an amorphous state, a polycrystal, and an orientated polycrystal, it was confirmed that the single-crystal thin films more excellent in crystallinity can be formed.

These results are shown in Table 22.

In addition, the thin films indicated in Table 22 and have at least one of the crystallization states selected from an amorphous state, a polycrystal, and an orientated polycrystal were formed by the sputtering method, and the single-crystal thin films were formed by the MOCVD method.

The sputtering target used at the time of forming the GaN thin films by the sputtering method was produced using the gallium nitride-based sintered compact and produced using the raw material powder produced in this Example by the method of oxide reduction without adding an additive.

As for the production conditions for the GaN thin films by the sputtering method, they were carried out like Example 11, except having used the above gallium nitride-based sintered compact as a sputtering target

In the gallium nitride-based sintered compacts shown in Table 22, it was confirmed that the single-crystal thin films comprising as a main component at least one selected from gallium nitride, indium nitride and aluminum nitride and are excellent in crystallinity, such that the half width of the rocking curve of the X-ray diffraction from a lattice plane (002) is not more than 300 seconds, can be formed.

When the things in which at least one selected from the above alkaline earth metal component and rare earth element component are contained not more than 30.0 mol % on an oxide basis were used, the single-crystal thin films comprising as a main component at least one selected from gallium nitride, indium nitride and aluminum nitride and are excellent in crystallinity, such that the half width of the rocking curve of the X-ray diffraction from a lattice plane (002) is not more than 200 seconds, can be formed directly on them.

When the sintered compacts in which at least one selected from the above alkaline earth metal component and rare earth element component are contained not more than 20 mol % on an oxide basis and comprising gallium nitride as a main component were used, the single-crystal thin films excellent in crystallinity, such that the half width of the rocking curve of the X-ray diffraction from a lattice plane (002) is not more than 150 seconds, can be formed directly on them.

When the sintered compacts in which at least one selected from the above alkaline earth metal component and rare earth element component are contained not more than 10.0 mol % on an oxide basis and comprising gallium nitride as a main component were used, it was confirmed that the single-crystal thin films excellent in crystallinity, such that the half width of the rocking curve of the X-ray diffraction from a lattice plane (002) is not more than 130 seconds, can be formed directly on them.

Even if the gallium nitride-based sintered compacts are the things in which an alkaline earth metal component and a rare earth element component are contained simultaneously, it was confirmed that the crystallinity of the single-crystal thin films formed on them is good as well as what is respectively contained separately.

In the gallium nitride-based sintered compacts and contain a molybdenum component, the single-crystal thin films excellent in crystallinity, such that the half width of the rocking curve of the X-ray diffraction from a lattice plane (002) is not more than 300 seconds, can be formed directly on them.

In the gallium nitride-based sintered compacts and contain silicon nitride, the single-crystal thin films excellent in crystallinity, such that the half width of the rocking curve of the X-ray diffraction from a lattice plane (002) is not more than 300 seconds, can be formed directly on them.

In the gallium nitride-based sintered compacts and contain aluminum nitride, the single-crystal thin films excellent in crystallinity, such that the half width of the rocking curve of the X-ray diffraction from a lattice plane (002) is not more than 300 seconds, can be formed directly on them.

When the single-crystal thin films comprising as a main component at least one selected from gallium nitride, indium nitride and aluminum nitride were formed on the things having beforehand the thin films comprising as a main component at least one selected from gallium nitride, indium nitride and aluminum nitride and are single crystal, amorphous, polycrystal, and orientated polycrystal, using the same gallium nitride-based sintered compacts, the things in which the crystallinity of these single-crystal thin films is superior to the things formed directly on the gallium nitride-based sintered compacts were obtained.

In this Example, as for the crystallinity of the single-crystal thin films which are formed on the gallium nitride-based sintered compacts and comprise as a main component at least one selected from gallium nitride, indium nitride and aluminum nitride, it was confirmed that it is easily improved according as the optical permeability of the gallium nitride-based sintered compacts is improved

In addition, although not shown in Table 22, it was confirmed that the thin films comprising gallium nitride as a main component and have at least one of the crystallization states selected from an amorphous state, a polycrystal, and an orientated polycrystal can be formed suitably in the gallium nitride-based sintered compacts, even if the MOCVD method is used.

As for the crystallinity of the orientated polycrystal thin films formed using the MOCVD method, the half width of the rocking curve of the X-ray diffraction from a lattice plane (002) is 4000 seconds-6000 seconds, and it was superior to the case formed using the sputtering method.

In this Example, although all the appearance of the thin films of the constitution indicated in Table 22, and the thin films produced in this Example was investigated, faults, such as a crack and a crevice, are not seen in all the thin films formed beforehand on the substrates and the thin films formed furthermore on them.

Though the exfoliation test was carried out using the pressure sensitive adhesive tape, in all the thin films, exfoliation was not seen between them and the substrates comprising a gallium nitride-based sintered compact, or between thin films.

The thin conductive film of Ti/Pt/Au was formed on the thin films of the surface of the substrates, the metal leads were soldered and the perpendicular tensile strength was investigated, but it all is not less than 2 kg/mm², so there are firm unifications between the gallium nitride-based sintered compacts and the thin films formed beforehand on the substrates, and between these thin films and the thin films formed furthermore on them.

TABLE 22

| | | | | | | | Characteristics of the thin films formed on the substrate | | | | |
|---|---|---|---|---|---|---|---|---|---|---|---|
| | | Characteristics of the substrates which consist of | | | | | made from a sintered compact comprising a gallium | | | | |
| | | a sintered compact comprising a gallium nitride | | | | | nitride as the main component | | | | |
| | | as the main component | | | | | | | | Single crystal thin | |
| | | Composition of | | | | | | | | films formed on | |
| | | the sintered compacts | | | | | Thin films beforehand formed | | | the thin film | |
| | | [content of the component(s)] | | | | | on the substrate | | | formed beforehand | |
| | | *) (mol %) | | | | Electric | | | Half width | | Half width |
| | Method of | Components | | | Optical | resistivity | | | of the | | of the |
| Experi- | producing a | alkaline- | | other | trans- | (Ω · cm) | Thin | | rocking | Thin | rocking |
| ment | raw | earth | rare earth | compo- | missivity | (in room | film | | curve | film | curve |
| No. | material | metals | elements | nents | (%) | temperature) | material | Crystallized state | (second) | material | (second) |
| 1518 | Direct | — | — | — | 6.2 | 4.4 × 10² | — | (not formed) | — | AlN | 185 |
| 1519 | nitriding | | | | | | AlN | orientated polycrystal | 8320 | AlN | 107 |
| 1520 | method of | 5.0 | — | — | 47 | not | — | (not formed) | — | AlN | 119 |
| 1521 | metal | (CaO) | | | | measured | AlN | polycrystal | — | AlN | 95 |
| 1522 | | — | 0.5 | — | 66 | 9.4 × 10¹ | — | (not formed) | — | GaN | 113 |
| 1523 | | | (Y₂O₃) | | | | AlN | orientated polycrystal | 7160 | GaN | 89 |
| 1524 | | 0.2 | 0.2 | — | 62 | 7.7 × 10¹ | — | (not formed) | — | AlN | 110 |
| 1525 | | (CaO) | (Y₂O₃) | | | | GaN | orientated polycrystal | 6740 | AlN | 86 |
| 1526 | | — | — | 0.05 | 25 | 2.4 × 10⁻³ | — | (not formed) | — | GaN | 127 |
| 1527 | | | | (Si₃N₄) | | | GaN | amorphous | — | GaN | 91 |
| 1528 | Method | — | — | — | 34 | 9.4 × 10¹ | — | (not formed) | — | GaN | 124 |
| 1529 | of oxide | | | | | | GaN | orientated polycrystal | 6550 | GaN | 92 |
| 1530 | reduction | 0.01 | — | — | 82 | 9.2 × 10¹ | — | (not formed) | — | GaN | 109 |
| 1531 | | (CaO) | | | | | GaN | amorphous | — | GaN | 82 |
| 1532 | | 0.5 | — | — | 74 | 7.8 × 10¹ | — | (not formed) | — | AlN | 122 |
| 1533 | | (CaO) | | | | | AlN | orientated polycrystal | 7420 | AlN | 93 |
| 1534 | | 12.0 | — | — | 27 | 9.1 × 10¹ | — | (not formed) | — | AlN | 134 |
| 1535 | | (CaO) | | | | | AlN | amorphous | — | AlN | 95 |
| 1536 | | — | 0.001 | — | 71 | 5.9 × 10¹ | — | (not formed) | — | AlN | 110 |
| 1537 | | | (Y₂O₃) | | | | AlN | orientated polycrystal | 7280 | AlN | 94 |
| 1538 | | — | 0.01 | — | 86 | 7.5 × 10¹ | — | (not formed) | — | GaN | 104 |
| 1539 | | | (Y₂O₃) | | | | GaN | orientated polycrystal | 6390 | GaN | 80 |
| 1540 | | — | 1.0 | — | 73 | 7.2 × 10¹ | — | (not formed) | — | GaN | 107 |
| 1541 | | | (Y₂O₃) | | | | GaN | orientated polycrystal | 6600 | GaN | 82 |
| 1542 | | — | 12.0 | — | 23 | not | — | (not formed) | — | AlN | 135 |
| 1543 | | | (Y₂O₃) | | | measured | AlN | orientated polycrystal | 7470 | AlN | 96 |
| 1544 | | — | 24.0 | — | 14 | 1.4 × 10² | — | (not formed) | — | GaN | 162 |
| 1545 | | | (Y₂O₃) | | | | GaN | orientated polycrystal | 7810 | GaN | 104 |
| 1546 | | — | 7.0 | — | 56 | 9.3 × 10¹ | — | (not formed) | — | GaN | 116 |
| 1547 | | | (Dy₂O₃) | | | | InN | orientated polycrystal | 7840 | GaN | 89 |
| 1548 | | — | 1.0 | — | 67 | 8.4 × 10¹ | — | (not formed) | — | AlN | 112 |
| 1549 | | | (Ho₂O₃) | | | | AlN | orientated polycrystal | 7360 | AlN | 84 |
| 1550 | | — | 1.0 | — | 71 | 8.8 × 10¹ | — | (not formed) | — | GaN | 111 |
| 1551 | | | (Er₂O₃) | | | | GaN | orientated polycrystal | 6440 | GaN | 85 |
| 1552 | | — | 1.0 | — | 70 | 7.9 × 10¹ | — | (not formed) | — | | 109 |
| 1553 | | | (Yb₂O₃) | | | | GaN | amorphous | — | GaN | 84 |
| 1554 | | — | — | 0.001 | 31 | 2.5 × 10⁻² | — | (not formed) | — | GaN | 125 |
| 1555 | | | | (Si₃N₄) | | | GaN | amorphous | — | GaN | 89 |
| 1556 | | — | 0.01 | 0.01 | 82 | 1.7 × 10⁻² | — | (not formed) | — | GaN | 106 |
| 1557 | | | (Y₂O₃) | (Si₃N₄) | | | GaN | orientated polycrystal | 6520 | GaN | 82 |
| 1558 | | — | — | 0.05 | 34 | 8.1 × 10¹ | — | (not formed) | — | AlN | 123 |
| 1559 | | | | (AlN) | | | AlN | amorphous | — | AlN | 91 |
| 1560 | | — | — | 24.0 | 26 | 1.7 × 10² | — | (not formed) | — | AlN | 176 |
| 1561 | | | | (AlN) | | | AlN | orientated polycrystal | 7590 | AlN | 106 |
| 1562 | | — | — | 0.05 | 31 | 8.9 × 10¹ | — | (not formed) | — | AlN | 127 |
| 1563 | | | | (MoO₃) | | | GaN | orientated polycrystal | 6530 | AlN | 94 |
| 1564 | Chemical | — | — | — | 31 | 9.0 × 10¹ | — | (not formed) | — | GaN | 126 |
| 1565 | transport | | | | | | GaN | amorphous | — | GaN | 93 |
| 1566 | method | 0.2 | 0.2 | 0.01 | 76 | 2.4 × 10⁻² | — | (not formed) | — | GaN | 108 |
| 1567 | | (CaO) | (Y₂O₃) | (Si₃N₄) | | | AlN | amorphous | — | GaN | 86 |
| 1568 | | — | 2.0 | — | 66 | not | — | (not formed) | — | AlN | 111 |
| 1569 | | | (Y₂O₃) | | | measured | AlN | orientated polycrystal | 7320 | AlN | 87 |
| 1570 | | — | — | 1.0 | 30 | 7.6 × 10⁻² | — | (not formed) | — | GaN | 127 |
| 1571 | | | | (Si₃N₄) | | | GaN | amorphous | — | GaN | 93 |

*) The content of an alkaline-earth-metals component and a rare earth elements component is base on oxide conversion, and the content of other components is based on metal element conversion.

### EXAMPLE 20

This Example shows the examples which investigated about the effect of the optical permeability of the gallium nitride-based sintered compacts exerted on the luminous efficiency of the light-emitting devices produced using the gallium nitride-based sintered compacts, and the effect of the thin films formed on the gallium nitride-based sintered compacts.

Selecting suitably from the gallium nitride-based sintered compacts and were produced in Example 19, the thin films comprising as a main component at least one selected from gallium nitride, indium nitride and aluminum nitride and have at least one of the crystallization states selected from a single crystal, an amorphous state, a polycrystal, and an orientated polycrystal were formed in the thickness of 3 μm on these sintered compacts using the sputtering method and the MOCVD method under the same conditions as Example 11, and the single crystals comprising as a main component at least one selected from gallium nitride and aluminum nitride were further formed on them in the thickness of 3 μm by the suitable sputtering method and MOCVD method, and the substrates which are used for production of the light-emitting devices and comprise a gallium nitride-based sintered compact were produced.

The formation of the above thin films comprising as a main component at least one selected from gallium nitride or aluminum nitride and have at least one of the crystallization states selected from an amorphous state, a polycrystal, and an orientated polycrystal was carried out by the sputtering method altogether, and the gallium nitride-based sintered compact produced in Example 19 was used as a sputtering target when forming the GaN thin films.

In addition, some gallium nitride-based sintered compact substrates were used without forming a thin film.

Some substrates were not provided with a2nd-layer single-crystal thin film.

Using the substrates thus produced, the laminates comprising the thin films comprising at least one selected from gallium nitride, indium nitride and aluminum nitride as a main component and contain at least N-type semiconductor layer, luminescence layer, and P-type semiconductor layer were formed by the same method as Examples 17 and 18, and the light-emitting devices having a single quantum well structure as a luminescence layer were produced.

The luminous efficiency was investigated by impressing the potential of 3.5 volts-3.8 volts into each light-emitting device as well as Examples 17 and 18.

These results are shown in Table 23.

In addition, the actuating current shown in Table 23 is the value at the time of making the light-emitting devices drive on the operating voltage of 3.6 volts.

The light-emitting devices produced with the gallium nitride-based sintered compacts were clearly superior in luminous efficiency to those produced with the sapphire substrate.

TABLE 23

| | Characteristics of the substrate which consist of a sintered compact comprising a gallium | | | | | | | | | | | |
|---|---|---|---|---|---|---|---|---|---|---|---|---|
| | nitride as the main component and are used for light emitting device production | | | | | | | | | | | |
| | Characteristics of the substrates which | | | | | | | | | | | |
| | consist of a sintered compact | | | | | | | | | | | |
| | comprising a gallium | | | | | | | | | | | |
| | nitride as the main component | | | | Characteristics of the thin films | | | | | | | |
| | Composition of the sintered | | | | formed on the substrate | | | | | | | |
| | compact [content of the | | | | | | | 2nd layer | | | | |
| | component(s)] *1) | | | | 1st layer | | | (single crystal) | | | | |
| | (mol %) | | | | | | Half width | | Half width | Characteristics of the | | |
| | Components | | | Optical | | | of the | | of the | light emitting devices produced | | |
| Experi- | alkaline- | | other | transmis- | Thin | | rocking | Thin | rocking | Actuating | Luminecence | Luminous |
| ment | earth | rare earth | compo- | sivity | film | Crystallized | curve | film | curve | current | output | efficiency |
| No. | metals | elements | nents | (%) | material | state *2) | (second) | material | (second) | (mA) | (mW) | (%) |
| 1572 | — | — | — | 6.2 | AlN | O | 8320 | AlN | 110 | 470 | 230 | 13.6 |
| 1573 | | | | | GaN | O | 7880 | GaN | 105 | 490 | 260 | 14.7 |
| 1574 | — | 24.0 | — | 14 | AlN | O | 8270 | AlN | 107 | 480 | 260 | 15.0 |
| 1575 | | (Y₂O₃) | | | GaN | O | 7810 | GaN | 104 | 490 | 270 | 15.3 |
| 1576 | — | 24.0 | 0.05 | 25 | AlN | A | — | AlN | 97 | 490 | 330 | 18.7 |
| 1577 | | (Y₂O₃) | (Si₃N₄) | | GaN | A | — | GaN | 91 | 490 | 370 | 21 |
| 1578 | — | — | — | 34 | none | O | — | none | — | 500 | 450 | 25 |
| 1579 | | | | | AlN | O | 7460 | AlN | 94 | 520 | 520 | 28 |
| 1580 | | | | | GaN | O | 6550 | GaN | 92 | 510 | 570 | 31 |
| 1581 | 5.0 | — | — | 47 | none | — | — | none | — | 520 | 520 | 28 |
| 1582 | (CaO) | | | | AlN | P | — | AlN | 95 | 540 | 600 | 31 |
| 1583 | | | | | GaN | P | — | GaN | 95 | 530 | 650 | 34 |
| 1584 | — | 7.0 | — | 56 | AlN | S | 121 | none | — | 520 | 670 | 36 |
| 1585 | | (Dy₂O₃) | | | GaN | S | 116 | none | — | 530 | 730 | 38 |
| 1586 | | | | | InN | O | 7840 | AlN | 93 | 510 | 590 | 32 |
| 1587 | | | | | InN | O | 7840 | GaN | 89 | 520 | 660 | 35 |
| 1588 | — | 2.0 | — | 66 | none | — | — | — | — | 530 | 800 | 42 |
| 1589 | | (Y₂O₃) | | | AlN | O | 7420 | AlN | 87 | 540 | 890 | 46 |
| 1590 | | | | | AlN | O | 7420 | GaN | 85 | 530 | 920 | 48 |
| 1591 | | | | | GaN | O | 6510 | AlN | 86 | 540 | 930 | 48 |
| 1592 | | | | | GaN | O | 6510 | GaN | 84 | 520 | 940 | 50 |
| 1593 | — | 1.0 | — | 71 | AlN | O | 7320 | none | — | 550 | 990 | 50 |
| 1594 | | (Er₂O₃) | | | GaN | O | 6440 | none | — | 540 | 990 | 51 |
| 1595 | | | | | AlN | O | 7320 | GaN | 86 | 560 | 1050 | 52 |
| 1596 | | | | | GaN | O | 6440 | GaN | 85 | 530 | 1070 | 56 |
| 1597 | 0.2 | 0.2 | 0.01 | 76 | AlN | A | — | none | — | 540 | 1010 | 52 |
| 1598 | (CaO) | (Y₂O₃) | (Si₃N₄) | | GaN | A | — | none | — | 520 | 1030 | 55 |
| 1599 | | | | | AlN | A | — | AlN | 86 | 540 | 1010 | 52 |
| 1600 | | | | | GaN | A | — | GaN | 84 | 520 | 1080 | 58 |
| 1601 | — | 0.01 | 0.01 | 82 | none | — | — | none | — | 560 | 1090 | 54 |
| 1602 | | (Y₂O₃) | (Si₃N₄) | | AlN | O | 7260 | AlN | 83 | 530 | 1090 | 57 |
| 1603 | | | | | GaN | O | 6520 | GaN | 82 | 530 | 1200 | 63 |
| 1604 | — | 0.01 | — | 86 | none | — | — | none | — | 550 | 1070 | 54 |
| 1605 | | (Y₂O₃) | | | AlN | O | 7130 | none | — | 540 | 1130 | 58 |
| 1606 | | | | | GaN | O | 6390 | none | — | 530 | 1160 | 61 |
| 1607 | | | | | AlN | O | 7130 | AlN | 82 | 520 | 1120 | 60 |
| 1608 | | | | | GaN | O | 6390 | GaN | 80 | 540 | 1260 | 65 |

*1) The content of an alkaline-earth-metals component and a rare earth elements component is based on oxide conversion, and the content of other components is based on metal element conversion.
*2) Crystallized state; [S: single crystal, A: amorphous state, P: polycrystal, O: orientated polycrystal]

### EXAMPLE 21

This Example shows the examples which investigated about the effect exerted on the luminous efficiency of the light-emitting devices produced using the sintered compacts having comparatively large surface roughness and are used to produce light-emitting devices and comprising a ceramic material as a main component.

Here suitably prepared the same sintered compacts which were used in Examples 17 and 18 and comprise as a main component each aluminum nitride, silicon carbide, silicon nitride, gallium nitride, zinc oxide, beryllium oxide, aluminum oxide, zirconium oxide, magnesium oxide, magnesium aluminate, and yttrium oxide, as the ceramic-based sintered compacts,.

Processing was carried out suitably to the surface of these sintered compacts, to provide those as-fired, those mirror-polished, those sandblasted, those lap-polished, those etched with caustic soda, and those with regular unevenness.

In all the sintered compacts having the as-fired surface state, the surface adhesion things were removed by brush using a commercial alumina powder with the particle size of 3 μm.

The mirror-polished sintered compacts were the same as in Examples 17 and 19.

As for the sandblast polish, in the sintered compacts comprising zinc oxide and gallium nitride as a main component, three kinds of things in which the particle size of alumina abradant is #600, #1200, and #5000 were used, and in the sintered compacts comprising each silicon carbide, silicon nitride, beryllium oxide, aluminum oxide, zirconium oxide, magnesium oxide, magnesium aluminate, and yttrium oxide as a main component, those in which the particle size of alumina abradant is #1200 was used, and they were were produced by the methods in which other conditions are the same as Example 12.

In the sintered compacts which carried out lap polish, the silicon carbide abradant with the particle size of #400 was used, and they were produced by the same method as Example 12.

The sintered compacts etched with caustic soda and those lapped with #800 alumina abrasive were immersed in a 5-N caustic soda solution at 90° C. for 1 minute and then washed with distilled water.

The sintered compacts with regular unevenness are the things having hollows of regular meshes as deep as 0.5 μm and as wide as 1 μm (projections with the square of 1μm×1 μm and the height of 0.5 μm were regularly formed at intervals of 2 μm) by etching with SF₆+O₂ plasma, after forming the shape of meshes to which the windows of 1 μm width intersected regularly in right angle at intervals of 2 μm by optical lithography, after the commercial resist was applied to each sintered compact. The form is shown in FIG. 73.

The average surface roughness Ra of these sintered compacts was measured. The measurement result is shown in Table 24. the average surface roughness Ra of the ceramic-based sintered compacts was 79-3240 nm. the light-emitting devices having a single quantum well structure as a luminescence layer were produced by the same method as Example 17.

The luminous efficiency was investigated by impressing the potential of 3.5 volts-3.8 volts into each light-emitting device as well as Example 34, Example 35, Example 37, and Example 38.

These results are shown in Table 24.

The actuating current shown in Table 24 is the value at the time of making the light-emitting devices drive on the operating voltage of 3.6 volts.

As a result, as shown in Table 24 in this Example, it was confirmed that the luminous efficiency of the light-emitting devices produced using the ceramic-based sintered compacts and have comparatively large surface roughness is at least equivalent compared with the luminous efficiency of the light-emitting devices produced using the things with the small surface roughness, even if the sintered compacts comprising as a main component a ceramic material are the same things which were produced in Examples 17, 18 and 20.

Thus, formation of the single-crystal thin films comprising gallium nitride and aluminum nitride as a main component is also possible onto the ceramic-based sintered compacts and have large surface roughness, and it was confirmed that the light-emitting devices having high luminous efficiency are producible.

As illustrated in Example 21, even if the thin films comprising as a main component at least one selected from gallium nitride, indium nitride and aluminum nitride are formed on the ceramic-based sintered compacts with comparatively large surface roughness, the ceramic-based sintered compacts and the thin films are strongly bonded without cracks and exfoliation in these thin films.

TABLE 24

| | Characteristics of the substrates which consist of a various sintered compact comprising a | | | | | | | | | | | | |
|---|---|---|---|---|---|---|---|---|---|---|---|---|---|
| | ceramic material as the main component and are used for light emitting device production | | | | | | | | | | | | |
| | | | | | | Characteristics of the thin films | | | | | | | |
| | Characteristics of the substrates which consist of | | | | | formed on the substrate | | | | | | | |
| | a various sintered compact comprising a ceramic | | | | | | | | 2nd layer | | | | |
| | material as the main component | | | | | 1st layer | | | (single crystal) | | | | |
| | | Example | | | | | | Half | | Half | Characteristics of the light | | |
| | | or | Optical | Surface state | | | | width | | width | emitting devices produced | | |
| Ex- | | Experiment | trans- | Pro- | | | | of the | | of the | Actu- | Lumi- | |
| peri- | | No. | mis- | cess- | | Thin | Crystal- | rocking | Thin | rocking | ating | necence | Luminous |
| ment | Main | which | sivity | ing | Ra | film | lized | curve | film | curve | current | output | efficiency |
| No. | component | produced | (%) | method | (nm) | material | state *) | (second) | material | (second) | (mA) | (mW) | (%) |
| 1659 | Aluminum | Experiment | 8.8 | Lap polish | 870 | GaN | O | 7200 | GaN | 87 | 610 | 1580 | 72 |
| 1660 | nitride | No. | | Blast polish | 1810 | GaN | A | — | GaN | 87 | 620 | 1580 | 71 |
| 1661 | | 284 | | | 640 | AlN | O | 7810 | AlN | 89 | 620 | 1560 | 70 |
| 1662 | | | | | 79 | GaN | A | — | GaN | 88 | 600 | 1580 | 73 |
| 1663 | | | | Caustic soda | 2470 | AlN | A | — | AlN | 92 | 590 | 1470 | 69 |
| 1664 | | | | Plasma | 630 | GaN | O | 7650 | GaN | 87 | 610 | 1600 | 73 |
| | | | | processing | | | | | | | | | |
| 1665 | | Experiment | 74 | as-fired | 110 | AlN | A | — | AlN | 82 | 560 | 1230 | 61 |
| 1666 | | No. | | Lap polish | 670 | GaN | A | — | GaN | 87 | 560 | 1250 | 62 |
| 1667 | | 108 | | Blast polish | 590 | GaN | O | 7720 | GaN | 86 | 550 | 1230 | 62 |
| 1668 | | Experiment | 54 | Blast polish | 680 | AlN | O | 8040 | AlN | 86 | 540 | 910 | 47 |
| 1669 | | No. | | Caustic soda | 3240 | GaN | A | — | GaN | 91 | 530 | 950 | 50 |
| 1670 | | 106 | | Plasma | 600 | GaN | O | 6930 | GaN | 88 | 530 | 990 | 52 |
| | | | | processing | | | | | | | | | |
| 1671 | | Experiment | 34 | as-fired | 160 | AlN | O | 7740 | [symbol] | — | 510 | 700 | 38 |
| 1672 | | No. | | Lap polish | 710 | GaN | O | 6930 | [symbol] | — | 500 | 720 | 40 |
| 1673 | | 49 | | Blast polish | 120 | GaN | O | 6810 | GaN | 88 | 520 | 750 | 40 |
| 1674 | Silicon | Example 8 | 0.0 | Lap polish | 340 | GaN | A | — | [symbol] | — | 490 | 580 | 33 |
| 1675 | carbide | | | Blast polish | 230 | GaN | O | 7940 | GaN | 125 | 490 | 620 | 35 |
| 1676 | Silicon | Example 8 | 0.0 | Blast polish | 390 | GaN | O | 8260 | [symbol] | — | 490 | 510 | 29 |
| 1677 | nitride | | | Caustic soda | 1040 | GaN | A | — | GaN | 134 | 480 | 550 | 32 |
| 1678 | Gallium | Experiment | 86 | Lap polish | 920 | AlN | O | 7870 | [symbol] | — | 600 | 1470 | 68 |
| 1679 | nitride | No. | | Blast polish | 150 | GaN | O | 6720 | [symbol] | — | 630 | 1610 | 71 |
| 1680 | | 1538 | | | 640 | AlN | O | 7360 | AlN | 89 | 630 | 1660 | 73 |
| 1681 | | 1539 | | Caustic soda | 1360 | GaN | O | 7490 | GAN | 94 | 620 | 1560 | 70 |
| 1682 | | Experiment | 76 | as-fired | 270 | AlN | O | 7320 | AlN | 90 | 610 | 1430 | 65 |
| 1683 | | No. | | Blast polish | 590 | GaN | O | 6940 | GaN | 91 | 590 | 1400 | 66 |
| 1684 | | 1566 | | | 1630 | AlN | A | — | AlN | 93 | 600 | 1400 | 65 |
| 1685 | | 1567 | | Plasma | 670 | GaN | A | — | GaN | 89 | 610 | 1470 | 67 |
| | | | | processing | | | | | | | | | |
| 1686 | Zinc oxide | Experiment | 84 | as-fire | 380 | AlN | A | — | [symbol] | — | 610 | 1400 | 64 |
| 1687 | | No. | | Blast polish | 2140 | AlN | O | 8080 | AlN | 97 | 610 | 1430 | 65 |
| 1688 | | 1240 | | | 710 | GaN | A | — | GaN | 89 | 650 | 1640 | 70 |
| 1689 | | 1241 | | plasma | 660 | GaN | O | 6950 | GaN | 90 | 660 | 1690 | 71 |
| | | | | processing | | | | | | | | | |
| 1690 | | Experiment | 68 | as-fired | 520 | GaN | A | — | GaN | 92 | 520 | 1120 | 60 |
| 1691 | | No. | | Blast polish | 170 | AlN | O | 7450 | AlN | 88 | 530 | 1130 | 59 |
| 1692 | | 1218 | | | 650 | GaN | O | 6920 | GaN | 91 | 530 | 1180 | 62 |
| | | 1219 | | | | | | | | | | | |
| 1693 | Berylium | Example | 81 | Lap polish | 860 | AlN | A | — | AlN | 92 | 590 | 1420 | 67 |
| 1694 | oxide | 31 | | Blast polish | 910 | GaN | O | 7100 | GaN | 90 | 620 | 1540 | 69 |
| 1695 | Aluminum | Example | 78 | Blast polish | 590 | AlN | O | 7860 | [symbol] | — | 560 | 1290 | 64 |
| 1696 | oxide | 32 | | Plasma | 580 | GaN | O | 6990 | GaN | 88 | 570 | 1130 | 66 |
| | | | | processing | | | | | | | | | |
| 1697 | Zirconium | Example | 59 | Lap polish | 670 | AlN | O | 8110 | [symbol] | — | 500 | 700 | 39 |
| 1698 | oxide | 33 | | Blast polish | 360 | GaN | O | 6930 | GaN | 109 | 490 | 780 | 44 |
| 1699 | Magnesium | Example | 83 | as-fired | 420 | GaN | A | — | GaN | 94 | 630 | 1540 | 68 |
| 1700 | oxide | 33 | | Blast polish | 670 | GaN | O | 6860 | GaN | 91 | 660 | 1690 | 71 |
| 1701 | Magnesium | Example | 81 | Blast polish | 640 | GaN | O | 6940 | AlN | 110 | 620 | 1540 | 69 |
| 1702 | aluminate | 33 | | Plasma | 620 | GaN | O | 6860 | GaN | 95 | 640 | 1610 | 70 |
| | | | | processing | | | | | | | | | |
| 1703 | Yttrium | Example | 83 | Lap polish | 940 | AlN | A | — | AlN | 116 | 630 | 1590 | 70 |
| 1704 | oxide | 33 | | Blast polish | 690 | GaN | O | 7010 | GaN | 96 | 650 | 1660 | 71 |

*) The crystallized state of the thin film of the 1st layer beforehand formed on the substrate is shown as follows, respectively, amorphous state: A, orientated polycrystal: O

### INDUSTRIAL APPLICATION

According to this invention, the single-crystal thin film or various crystallized thin film comprising as a main component at least one selected from gallium nitride, indium nitride and aluminum nitride can be formed on the aluminum nitride-based sintered compact substrate, or on the substrate comprising various ceramic-based sintered compacts.

This single-crystal thin film has high crystallinity of the grade which can be used for a part of the light-emitting device or for an optical waveguide.

In such a aluminum nitride-based sintered compact substrate, a substrate comprising various ceramic-based sintered compacts, and a thin film substrate having a single-crystal thin film or a thin film of various crystallization states onto these substrates, a light-emitting device comprising a nitride semiconductor that comprises as a main component at least one selected from gallium nitride, indium nitride and aluminum nitride became producible, even if any substrate is used.

As for the luminous efficiency of this light-emitting device, compared with the light-emitting device produced using conventional bulk-like single crystal substrates, such as sapphire, it was equivalent at least, or has been improved greatly into a maximum of 4-5 or more times.

Therefore, the way in which a light-emitting device is used for the general lighting, such as the lighting for home, which was conventionally difficult, was opened substantially.

An optical waveguide which can transmit ultraviolet light at low loss became producible using the aluminum nitride-based thin film formed on the aluminum nitride-based sintered compact substrate.

Thus, according to this invention, as for the substrate comprising a sintered compact comprising as a main component various ceramicss including aluminum nitride, and the thin film substrate in which the single-crystal thin film or various crystallized thin film comprising as a main component at least one selected from gallium nitride, indium nitride and aluminum nitride are formed on the substrate, since they can be applied for extensive uses, such as a display in which the thin film is used for a field emission material, a surface acoustic emission device, or a circuit substrate, other than the above light-emitting device or optical waveguide, the effect which gives to industry is large.

1. A semiconductor device comprising a thin film comprising at least one selected from gallium nitride, indium nitride and aluminum nitride, which is integrally adhered to a ceramic-based sintered compact, said thin film being at least partially a single crystal or having at least a single crystal layer.

2. The semiconductor device as described in claim 1, wherein said sintered compact has optical permeability.

3. The semiconductor device as described in claim 1, wherein said sintered compact comprises aluminum nitride as a main component.

4. The semiconductor device as described in claim 1, wherein said ceramic-based sintered compact has a hexagonal and/or trigonal crystal structure.

5. The semiconductor device as described in claim 4, wherein said ceramic material contains at least one selected from zinc oxide, beryllium oxide, aluminum oxide, silicon carbide, silicon nitride, and gallium nitride.

6. The semiconductor device as described in claim 1, wherein said sintered compact comprises as a main component at least one ceramic material selected from zirconium oxide, magnesium oxide, magnesium aluminate, titanium oxide, barium titanate, lead titanate zirconate, a rare earth oxide, thorium oxide, various ferrites, mullite, forsterite, steatite and glass.

7. The semiconductor device as described in claim 1, wherein at least one selected from gallium nitride, indium nitride and aluminum nitride is at least 50 mol % in said thin film.

8. The semiconductor device as described in claim 1, wherein said thin film further contains at least one selected from magnesium, beryllium, calcium, zinc, cadmium, carbon, silicon, germanium, oxygen, boron, selenium and tellurium.

9. The semiconductor device as described in claim 8 wherein at least one selected from magnesium, beryllium, calcium, zinc, cadmium, carbon, silicon, germanium, oxygen, boron, selenium and tellurium is 0.0000-10 mol %.
